(19) United States
(12) Patent Application Publication
(10) Pub. No.: US 2025/0359480 A1
(43) Pub. Date: Nov. 20, 2025

(54) ORGANIC LIGHT EMITTING DEVICE

(71) Applicant: LG CHEM, LTD., Seoul (KR)

(72) Inventors: Kyunghee KIM, Daejeon (KR); Sujeong GEUM, Daejeon (KR); Woochul LEE, Daejeon (KR); Woo Jin CHO, Daejeon (KR); Ji Young CHOI, Daejeon (KR); Jae Seung HA, Daejeon (KR)

(21) Appl. No.: 18/669,234

(22) Filed: May 20, 2024

(30) Foreign Application Priority Data
May 26, 2023 (KR) 10-2023-0068331

(51) Int. Cl. H10K 85/60; C09K 11/06; H10K 85/20

(52) U.S. Cl. CPC H10K 85/658; C09K 11/06; H10K 85/20; H10K 85/622; H10K 85/656; H10K 85/6574; H10K 85/6576

(57) ABSTRACT

Disclosed is an organic light emitting device including: an anode; a cathode; and a light emitting layer provided between the anode and the cathode, in which the light emitting layer includes a compound represented by Chemical Formula 1 and a compound represented by Chemical Formula 2.

### TECHNICAL FIELD

This application claims priority to and the benefit of Korean Patent Application No. 10-2023-0068331 filed in the Korean Intellectual Property Office on May 26, 2023, the entire contents of which are incorporated herein by reference.

The present specification relates to an organic light emitting device.

### BACKGROUND ART

An organic light emission phenomenon generally refers to a phenomenon converting electrical energy to light energy using an organic material. An organic light emitting device using the organic light emitting phenomenon usually has a structure including an anode, a cathode, and an organic material layer interposed therebetween. Here, the organic material layer has in many cases a multi-layered structure composed of different materials in order to improve the efficiency and stability of the organic light emitting device, and for example, may be composed of a hole injection layer, a hole transport layer, a light emitting layer, an electron transport layer, an electron injection layer, and the like. In such a structure of the organic light emitting device, if a voltage is applied between the two electrodes, holes are injected from the anode into the organic material layer and electrons are injected from the cathode into the organic material layer, and when the injected holes and electrons meet each other, an exciton is formed, and light is emitted when the exciton falls down again to a ground state.

There is a continuous need for developing a new material for the aforementioned organic light emitting device.

### RELATED ART DOCUMENTS

### Patent Documents

(Patent Document 1) Korean Patent Application Laid-Open No. 10-2012-0112277

### DISCLOSURE

### Technical Problem

The present specification has been made in an effort to provide an organic light emitting device.

### Technical Solution

An exemplary embodiment of the present invention provides an organic light emitting device including: an anode; a cathode; and a light emitting layer provided between the anode and the cathode, in which the light emitting layer includes a compound represented by the following Chemical Formula 1 and a compound represented by the following Chemical Formula 2.

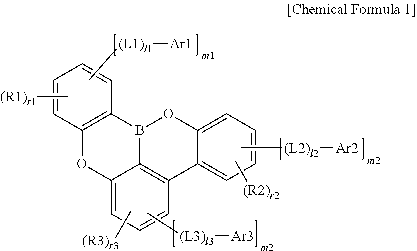

In Chemical Formula 1,
L1 to L3 are the same as or different from each other, and are each independently a direct bond; or a substituted or unsubstituted arylene group,
Ar1 to Ar3 are the same as or different from each other, and are each independently a substituted or unsubstituted polycyclic aryl group,
R1 to R3 are the same as or different from each other, and are each independently hydrogen; deuterium; a substituted or unsubstituted alkyl group; a substituted or unsubstituted aryl group; or a substituted or unsubstituted heteroaryl group,
l1 to l3 are each an integer from 1 to 3, and when l1 to l3 are each 2 or higher, structures in each parenthesis are the same as or different from each other,
m1 to m3 are each an integer of 0 or 1, and m1+m2+m3 is an integer from 1 to 3,
r1 and r2 are each an integer from 1 to 4, and when r1 and r2 are 2 or higher, structures in each parenthesis are the same as or different from each other, r3 is 1 or 2, and when r3 is 2, structures in the parenthesis are the same as or different from each other, r1+m1 is an integer from 1 to 4, r2+m2 is an integer from 1 to 4, and r3+m3 is an integer from 1 to 3,

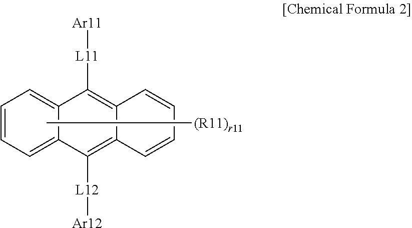

in Chemical Formula 2,
L11 and L12 are the same as or different from each other, and are each independently a direct bond; a substituted or unsubstituted arylene group; or a substituted or unsubstituted heteroarylene group,
Ar11 and Ar12 are the same as or different from each other, and are each independently a substituted or unsubstituted aryl group; or a substituted or unsubstituted heteroaryl group,
R11 is hydrogen; deuterium; a substituted or unsubstituted alkyl group; a substituted or unsubstituted aryl group; or a substituted or unsubstituted heteroaryl group, and
r11 is an integer from 1 to 8, and when r11 is 2 or higher, two or more R11's are the same as or different from each other.

### Advantageous Effects

The organic light emitting device described in the present specification has effects of low driving voltage, high efficiency and/or long service life by including both a compound represented by Chemical Formula 1 and a compound represented by Chemical Formula 2 in a light emitting layer.

### BRIEF DESCRIPTION OF THE DRAWINGS

FIGS. 1 to 4 illustrate an organic light emitting device according to some exemplary embodiments of the present specification.

### BEST MODE

Hereinafter, terms used in the present specification will be described in more detail to aid understanding.

When one member is said to be disposed “on” or “over” another member in the present specification, this includes not only a case where the one member is brought into contact with another member, but also a case where still another member is present between the two members.

When one part “includes” one constituent element in the present specification, unless otherwise specifically described, this does not mean that another constituent element is excluded, but means that another constituent element may be further included.

In the present specification, the “layer” has a meaning compatible with a “film” usually used in the art, and means a coating covering a target region. The size of the “layer” is not limited, and the sizes of the respective “layers” may be the same as or different from one another. In an exemplary embodiment, the size of the “layer” may be the same as that of the entire device, may correspond to the size of a specific functional region, and may also be as small as a single sub-pixel.

In the present specification, when a specific A material is included in a B layer, this means both i) the fact that one or more A materials are included in one B layer and ii) the fact that the B layer is composed of one or more layers, and the A material is included in one or more layers of the multi-layered B layer.

In the present specification, when a specific A material is included in a C layer or a D layer, this means all of i) the fact that the A material is included in one or more layers of the C layer having one or more layers, ii) the fact that the A material is included in one or more layers of the D layer having one or more layers, and iii) the fact that the A material is included in each of the C layer having one or more layers and the D layer having one or more layers.

In the present specification, “or” refers to a comprehensive “or” and not to an exclusive “or.” For example, condition A or B is satisfied by any one of the followings: A is true (or is present), B is false (or is not present), A is false (or is not present) and B is true (or is present), and both A and B are true (or are present).

In the present specification, the “energy level” or “level of energy” means the magnitude of energy. Therefore, the energy level is interpreted to mean the absolute value of the corresponding energy value. For example, a low or deep energy level means that the absolute value increases in the negative direction from the vacuum level.

In the present specification, the “highest occupied molecular orbital (HOMO)” means the molecular orbital function (highest occupied molecular orbital) in the region with the highest energy in the region where electrons can participate in bonding, and the HOMO energy level means the distance from the vacuum level to the HOMO.

Further, the “lowest unoccupied molecular orbital (LUMO)” means the molecular orbital function (lowest unoccupied molecular orbital) in which an electron is in the lowest energy region of the antibonding region, and the LUMO energy level means the distance from the vacuum level to the LUMO.

In the present specification, the “singlet-energy” or “singlet energy” is expressed as S. This is typically a system in which all electrons in a molecule are paired, meaning an electronic state with a spin quantum number of 0.

In the present specification, the “triplet energy” means an electronic state with a spin quantum number of 1 in a molecule.

Unless otherwise defined, all technical and scientific terms used in the present specification have the same meaning as commonly understood by one with ordinary skill in the art to which the present invention pertains. Although methods and materials similar to or equivalent to those described in the present specification may be used in the practice or in the test of exemplary embodiments of the present invention, suitable methods and materials will be described below. All publications, patent applications, patents, and other references mentioned in the present specification are hereby incorporated by reference in their entireties, and in the case of conflict, the present specification, including definitions, will control unless a particular passage is mentioned. The materials, methods, and examples mentioned in the present specification are illustrative only and are not intended to limit the present invention.

Hereinafter, the substituents mentioned in the present specification will be described with reference to examples, but are not limited thereto.

In the present specification, - - - - - - and

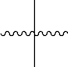

means a moiety bonded to another substituent or a bonding portion.

In the present specification, the term “substitution” means that a hydrogen atom bonded to a carbon atom of a compound is changed into another substituent, and a position to be substituted is not limited as long as the position is a position at which the hydrogen atom is substituted, that is, a position at which the substituent may be substituted, and when two or more are substituted, the two or more substituents may be the same as or different from each other.

In the present specification, the term “substituted or unsubstituted” means being substituted with one or more substituents selected from the group consisting of deuterium, a hydroxyl group, a cyano group, a halogen group, a nitro group, an alkoxy group, an amine group, an alkyl group, a cycloalkyl group, a silyl group, an aryl group, and a heteroaryl group, being substituted with a substituent to which two or more substituents among the exemplified substituents are linked, or having no substituent.

In the present invention, the fact that two or more substituents are linked indicates that hydrogen of any one substituent is linked to another substituent. For example, when two substituents are linked to each other, a phenyl group and a naphthyl group may be linked to each other to form a substituent of

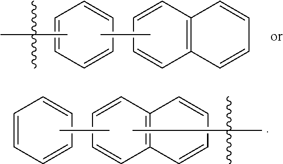

Further, the case where three substituents are linked to one another includes not only a case where (Substituent 1)-(Substituent 2)-(Substituent 3) are consecutively linked to one another, but also a case where (Substituent 2) and (Substituent 3) are linked to (Substituent 1). For example, a phenyl group, a naphthyl group, and an isopropyl group may be linked to one another to form a substituent of

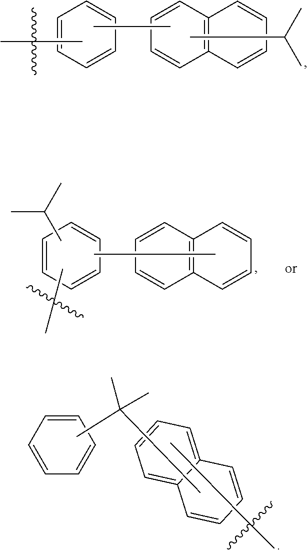

The above-described definition also applies equally to the case where four or more substituents are linked to one another.

In the present specification, examples of a halogen group include fluorine (—F), chlorine (—Cl), bromine (—Br) or iodine (—I).

In the present specification, a silyl group may be represented by a formula of —SiYaYbYc, and Ya, Yb, and Yc may be each hydrogen; a substituted or unsubstituted alkyl group; or a substituted or unsubstituted aryl group. Specific examples of the silyl group include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and the like, but are not limited thereto.

In the present specification, the alkyl group may be linear or branched, and the number of carbon atoms thereof is not particularly limited, but is preferably 1 to 60. In an exemplary embodiment, the number of carbon atoms of the alkyl group is 1 to 30. In another exemplary embodiment, the number of carbon atoms of the alkyl group is 1 to 20. In still another exemplary embodiment, the number of carbon atoms of the alkyl group is 1 to 10. Specific examples of the alkyl group include a methyl group, an ethyl group, a propyl group, an n-propyl group, an isopropyl group, a butyl group, an n-butyl group, an isobutyl group, a tert-butyl group, a pentyl group, an n-pentyl group, a hexyl group, an n-hexyl group, a heptyl group, an n-heptyl group, an octyl group, an n-octyl group, and the like, but are not limited thereto.

In the present specification, an alkoxy group may be straight-chained, branched, or cyclic. The number of carbon atoms of the alkoxy group is not particularly limited, but is preferably 1 to 20. Specific examples thereof include methoxy, ethoxy, n-propoxy, isopropoxy, i-propyloxy, n-butoxy, isobutoxy, tert-butoxy, sec-butoxy, n-pentyloxy, neopentyloxy, isopentyloxy, n-hexyloxy, 3,3-dimethylbutyloxy, 2-ethylbutyloxy, n-octyloxy, n-nonyloxy, n-decyloxy, and the like, but are not limited thereto.

Substituents including an alkyl group, an alkoxy group, and other alkyl group moieties described in the present specification include both a straight-chained form and a branched form.

In the present specification, a cycloalkyl group is not particularly limited, but has preferably 3 to 60 carbon atoms, and in an exemplary embodiment, the number of carbon atoms of the cycloalkyl group is 3 to 30. In another exemplary embodiment, the number of carbon atoms of the cycloalkyl group is 3 to 20. In still another exemplary embodiment, the number of carbon atoms of the cycloalkyl group is 3 to 6. Specific examples thereof may include a cyclopropyl group, a cyclobutyl group, a cyclopentyl group, a cyclohexyl group, a cycloheptyl group, a cyclooctyl group and the like, but are not limited thereto.

In the present specification, an amine group is-NH₂, and the amine group may be substituted with the above-described alkyl group, aryl group, heteroaryl group, cycloalkyl group, a combination thereof, and the like. The number of carbon atoms of the substituted amine group is not particularly limited, but is preferably 1 to 30. In an exemplary embodiment, the number of carbon atoms of the amine group is 1 to 20. In an exemplary embodiment, the number of carbon atoms of the amine group is 1 to 10. Specific examples of the substituted amine group include a methylamine group, a dimethylamine group, an ethylamine group, a diethylamine group, a phenylamine group, a 9,9-dimethylfluorenylphenylamine group, a pyridylphenylamine group, a diphenylamine group, a phenylpyridylamine group, a naphthylamine group, a biphenylamine group, an anthracenylamine group, a dibenzofuranylphenylamine group, a 9-methylanthracenylamine group, a diphenylamine group, a phenylnaphthylamine group, a ditolylamine group, a phenyltolylamine group, a diphenylamine group, and the like, but are not limited thereto.

In the present specification, an aryl group is not particularly limited, but has preferably 6 to 60 carbon atoms, and may be a monocyclic aryl group or a polycyclic aryl group. In an exemplary embodiment, the number of carbon atoms of the aryl group is 6 to 30. Examples of the monocyclic aryl group include a phenyl group, a biphenyl group, a terphenyl group, a quaterphenyl group, and the like, but are not limited thereto. Examples of the polycyclic aryl group include a naphthyl group, an anthracene group, a phenanthrene group, a pyrene group, a perylene group, a chrysene group, a fluorene group, a triphenylene group, a benzophenanthrene group, a fluoranthene group, and the like, but are not limited thereto. The number of carbon atoms of the polycyclic aryl group may be 10 to 60, or 10 to 30.

In the present specification, the fused aryl group in which two or more hydrocarbon rings are fused may be the polycyclic aryl group. Examples thereof include a naphthyl group, an anthracene group, a phenanthrene group, a pyrene group, a perylene group, a chrysene group, a fluorene group, a triphenylene group, a benzophenanthrene group, a fluoranthene group, and the like, but are not limited thereto.

In the present specification, a fluorene group may be substituted, and two substituents may be bonded to each other to form a spiro structure.

When the fluorene group is substituted, the fluorene group may be a spirofluorene group such as

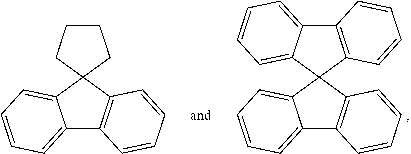

and a substituted fluorene group such as

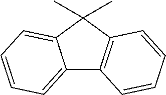

(a 9,9-dimethylfluorene group) and

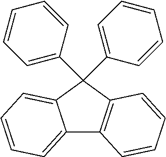 [SMILES: c1ccc(C2(c3ccccc3)c3ccccc3-c3ccccc32)cc1]

(a 9,9-diphenylfluorene group). However, the fluorene group is not limited thereto.

In the present specification, a heteroaryl group is a cyclic group including one or more of N, O, P, S, Si, and Se as a heteroatom, and the number of carbon atoms thereof is not particularly limited, but is preferably 2 to 60. In an exemplary embodiment, the number of carbon atoms of the heteroaryl group is 2 to 30. In an exemplary embodiment, the number of carbon atoms of the heteroaryl group is 2 to 20. Examples of the heteroaryl group include a pyridine group, a pyrrole group, a pyrimidine group, a quinoline group, a pyridazine group, a furan group, a thiophene group, an imidazole group, a pyrazole group, a dibenzofuran group, a dibenzothiophene group, a carbazole group, a benzocarbazole group, a naphthobenzofuran group, a benzonaphthothiophene group, an indenocarbazole group, a triazine group, a benzobisbenzofuran group, and the like, but are not limited thereto.

In the present specification, the description on the aryl group may be applied to an arylene group except for a divalent arylene group.

The hydrocarbon ring may be an aromatic ring, an aliphatic ring, or a fused ring of the aromatic ring and the aliphatic ring, and may be selected from the examples of the cycloalkyl group or the aryl group.

In the present specification, the aliphatic hydrocarbon ring means a ring composed only of carbon and hydrogen atoms as a non-aromatic ring. Examples of the aliphatic hydrocarbon ring include cyclopropane, cyclobutane, cyclobutene, cyclopentane, cyclopentene, cyclohexane, cyclohexene, 1,4-cyclohexadiene, cycloheptane, cycloheptene, cyclooctane, cyclooctene, and the like, but are not limited thereto.

In the present specification, an aromatic hydrocarbon ring means an aromatic ring composed only of carbon and hydrogen atoms. Examples of the aromatic hydrocarbon ring include benzene, naphthalene, anthracene, phenanthrene, perylene, fluoranthene, triphenylene, phenalene, pyrene, tetracene, chrysene, pentacene, fluorene, indene, acenaphthylene, benzofluorene, spirofluorene, and the like, but are not limited thereto. In the present specification, the aromatic hydrocarbon ring may be interpreted to have the same meaning as the aryl group.

Hereinafter, exemplary embodiments of the present specification will be described.

An exemplary embodiment of the present specification provides an organic light emitting device including: an anode; a cathode; and a light emitting layer provided between the anode and the cathode, in which the light emitting layer includes a compound represented by the following Chemical Formula 1 and a compound represented by the following Chemical Formula 2.

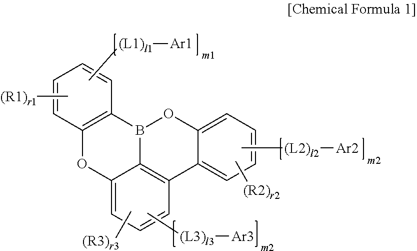

In Chemical Formula 1,
L1 to L3 are the same as or different from each other, and are each independently a direct bond; or a substituted or unsubstituted arylene group,
Ar1 to Ar3 are the same as or different from each other, and are each independently a substituted or unsubstituted polycyclic aryl group,
R1 to R3 are the same as or different from each other, and are each independently hydrogen; deuterium; a substituted or unsubstituted alkyl group; a substituted or unsubstituted aryl group; or a substituted or unsubstituted heteroaryl group,
l1 to l3 are each an integer from 1 to 3, and when l1 to l3 are each 2 or higher, structures in each parenthesis are the same as or different from each other,
m1 to m3 are each an integer of 0 or 1, and m1+m2+m3 is an integer from 1 to 3,
r1 and r2 are each an integer from 1 to 4, and when r1 and r2 are 2 or higher, structures in each parenthesis are the same as or different from each other, r3 is 1 or 2, and when r3 is 2, structures in the parenthesis are the same as or different from each other, r1+m1 is an integer from 1 to 4, r2+m2 is an integer from 1 to 4, and r3+m3 is an integer from 1 to 3,

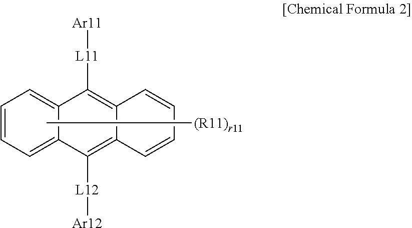

in Chemical Formula 2,
L11 and L12 are the same as or different from each other, and are each independently a direct bond; a substituted or unsubstituted arylene group; or a substituted or unsubstituted heteroarylene group,
Ar11 and Ar12 are the same as or different from each other, and are each independently a substituted or unsubstituted aryl group; or a substituted or unsubstituted heteroaryl group,
R11 is hydrogen; deuterium; a substituted or unsubstituted alkyl group; a substituted or unsubstituted aryl group; or a substituted or unsubstituted heteroaryl group, and
r11 is an integer from 1 to 8, and when r11 is 2 or higher, two or more R11's are the same as or different from each other.

For an organic light emitting device to exhibit excellent service life and efficiency, two or more components (for example, 2, 3 or 4 components) are required in the light emitting layer. In this case, a very complicated process and high cost are required compared to a light emitting layer having a single host material. Therefore, premixing two or more materials and evaporating the two or more materials from one raw material may reduce the complexity of the manufacturing process. For this purpose, the adopted hole transport host(s) and another type of host (for example, an electron transport host) may be mixed, and may be co-evaporated in one crucible to achieve stable evaporation.

However, the co-evaporation needs to be stable, which means that the composition of the evaporated film needs to be kept constant during the manufacturing process. Any change in composition may adversely affect device performance. After a mixture is formed from two or more compounds under vacuum conditions, a stable co-evaporation mixture is obtained from the mixture. As one condition for a stable co-evaporation mixture, it is expected that the compounds need to have the same evaporation temperature under the same conditions. However, it is expected that the same evaporation temperature is not the only parameter that acts in obtaining a stable co-evaporation mixture. For example, when two compounds are mixed, the two compounds may interact with each other, which may change the evaporation properties of the individual compounds. Alternatively, a stable co-evaporation mixture may be produced from two compounds even though the two compounds have different evaporation temperatures. Therefore, it is difficult to achieve a stable co-evaporation mixture. Although various host materials were present, there is little literature describing examples of whether a stable co-evaporation mixture can be obtained from the host materials.

The present inventors have discovered suitable materials that are useful as a blue fluorescent host material while simultaneously providing a stable co-evaporation mixture after premixing. Specifically, a combination of a boron-containing host material (represented by Chemical Formula 1) and an anthracene host material (represented by Chemical Formula 2), which is useful as a blue fluorescent host material and may be premixed to provide a stable co-evaporation mixture is presented in the present specification.

The inventors confirmed that by using two materials simultaneously, a number of factors other than temperature, which contribute to evaporation (for example, miscibility of different materials, different phase transitions) are adjusted to show a similar evaporation temperature, a similar mass reduction rate and/or a similar vapor pressure, thereby improving the stability when applied to an organic light emitting device.

The compound represented by Chemical Formula 1 in the present specification (first compound) has a structure containing boron. Since the compound has a relatively higher triplet energy level than a compound having an anthracene structure, it is possible to exhibit an additional efficiency increasing effect through electron transfer to the triplet level of the dopant material.

The compound represented by Chemical Formula 2 (second compound) in the present specification has an anthracene structure. Although this has an advantage of having excellent movement and injection of electrons and holes, there is a disadvantage in that the energy efficiency is not high while emitting fluorescence through a singlet energy level.

When the light emitting layer includes both the first compound represented by Chemical Formula 1 and the second compound represented by Chemical Formula 2, it is possible to simultaneously obtain an additional efficiency increasing effect that the first compound has while maintaining stable performance through the appropriate energy level and electron/hole balance of the second compound.

Hereinafter, the compound represented by Chemical Formula 1 will be described in detail.

In an exemplary embodiment of the present specification, m1+m2+m3 is an integer from 1 to 3.

In an exemplary embodiment of the present specification, m1+m2+m3 is 1.

In an exemplary embodiment of the present specification, when m1 is 1 and m2 and m3 are 0, Chemical Formula 1 is represented by the following Chemical Formula 1-1.

In an exemplary embodiment of the present specification, when m2 is 1 and m1 and m3 are 0, Chemical Formula 1 is represented by the following Chemical Formula 1-2.

In an exemplary embodiment of the present specification, when m3 is 1 and m1 and m2 are 0, Chemical Formula 1 is represented by the following Chemical Formula 1-3.

In an exemplary embodiment of the present specification, Chemical Formula 1 is any one of the following Chemical Formulae 1-1 to 1-3.

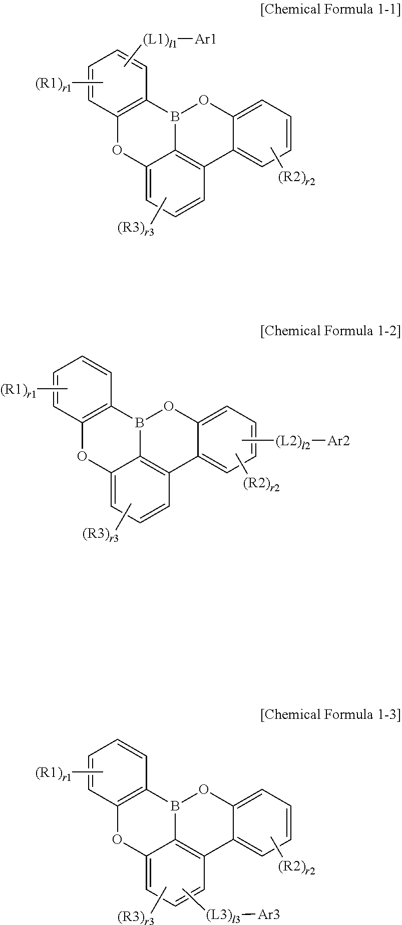

In Chemical Formulae 1-1 to 1-3,
R1 to R3, r1 to r3, L1 to L3, l1 to l3, and Ar1 to Ar3 are the same as those defined in Chemical Formula 1.

In an exemplary embodiment of the present specification, r1 and r3 of Chemical Formula 1-1 are each an integer from 1 to 3, and when r2 is an integer from 1 to 4 and r1 to r3 are 2 or higher, structures in each parenthesis are the same as or different from each other.

In an exemplary embodiment of the present specification, r2 and r3 of Chemical Formula 1-2 are each an integer from 1 to 3, and when r1 is an integer from 1 to 4 and r1 to r3 are 2 or higher, structures in each parenthesis are the same as or different from each other.

In an exemplary embodiment of the present specification, r3 of Chemical Formula 1-3 is 1 or 2, and when r3 is 2, structures in the parenthesis are the same as or different from each other, r1 and r2 are each an integer from 1 to 4, and when r1 and r2 are 2 or higher, structures in each parenthesis are the same as or different from each other.

In an exemplary embodiment of the present specification, Ar1 to Ar3 are the same as or different from each other, and are each independently a substituted or unsubstituted polycyclic aryl group having 10 to 30 carbon atoms.

In an exemplary embodiment of the present specification, Ar1 to Ar3 are the same or different from each other, are each independently substituted or unsubstituted, and are a fused aryl group in which two or more hydrocarbon rings are fused.

In an exemplary embodiment of the present specification, Ar1 to Ar3 are the same as or different from each other, and are each independently a substituted or unsubstituted pyrene group; a substituted or unsubstituted benzophenanthrene group; a substituted or unsubstituted phenanthrene group; a substituted or unsubstituted fluoranthene group; a substituted or unsubstituted triphenylene group; or a substituted or unsubstituted chrysene group.

In an exemplary embodiment of the present specification, Ar1 to Ar3 are the same as or different from each other, and are each independently any one of the following structures.

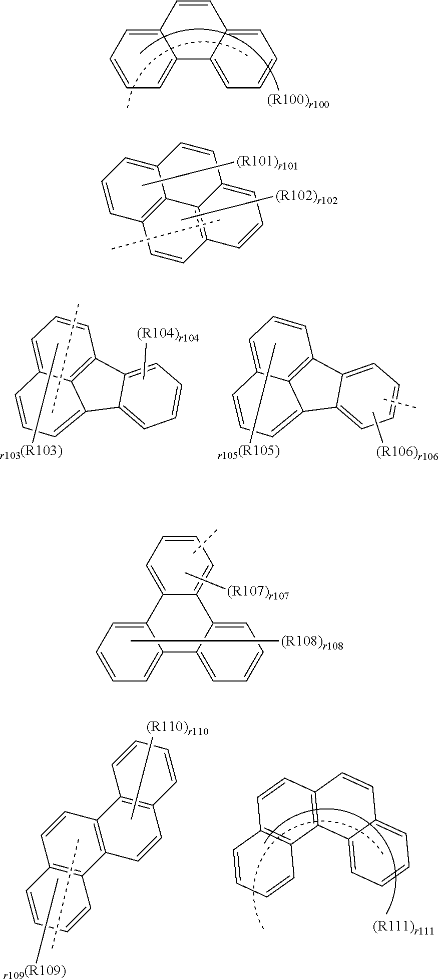

In the structures,
R100 to R111 are the same as or different from each other, and are each independently hydrogen; deuterium; a substituted or unsubstituted alkyl group; a substituted or unsubstituted aryl group; or a substituted or unsubstituted heteroaryl group,
r100 is an integer from 1 to 9, r101, r103 and r109 are an integer from 1 to 5, r102 and r104 are an integer from 1 to 4, r105 and r110 are an integer from 1 to 6, r106 and r107 are an integer from 1 to 3, r108 is an integer from 1 to 8, and r111 is an integer from 1 to 11,
when r100 to r111 are 2 or higher, substituents in each parenthesis are the same as or different from each other, and
- - - - - - is a moiety bonded to Chemical Formula 1.

In an exemplary embodiment of the present specification, R100 to R111 are the same as or different from each other, and are each independently hydrogen; deuterium; a substituted or unsubstituted alkyl group having 1 to 30 carbon atoms; a substituted or unsubstituted aryl group having 6 to 30 carbon atoms; or a substituted or unsubstituted heteroaryl group having 2 to 30 carbon atoms.

In an exemplary embodiment of the present specification, R100 to R111 are the same as or different from each other, and are each independently hydrogen; deuterium; an alkyl group; an aryl group; or a heteroaryl group.

In an exemplary embodiment of the present specification, R100 to R111 are the same as or different from each other, and are each independently hydrogen; deuterium; or an aryl group.

In an exemplary embodiment of the present specification, R100 to R111 are the same as or different from each other, and are each independently hydrogen; deuterium; or a phenyl group.

In an exemplary embodiment of the present specification, Ar1 to Ar3 are the same as or different from each other, and are each a pyrene group unsubstituted or substituted with one or more selected from the group consisting of deuterium, an alkyl group and an aryl group; a benzophenanthrene group unsubstituted or substituted with one or more selected from the group consisting of deuterium, an alkyl group and an aryl group; a phenanthrene group unsubstituted or substituted with one or more selected from the group consisting of deuterium, an alkyl group and an aryl group; a fluoranthene group unsubstituted or substituted with one or more selected from the group consisting of deuterium, an alkyl group and an aryl group; a triphenylene group unsubstituted or substituted with one or more selected from the group consisting of deuterium, an alkyl group and an aryl group; or a chrysene group unsubstituted or substituted with one or more selected from the group consisting of deuterium, an alkyl group and an aryl group.

In an exemplary embodiment of the present specification, Ar1 to Ar3 are the same as or different from each other, and are each a pyrene group unsubstituted or substituted with one or more selected from the group consisting of deuterium and an aryl group; a benzophenanthrene group unsubstituted or substituted with one or more selected from the group consisting of deuterium and an aryl group; a phenanthrene group unsubstituted or substituted with one or more selected from the group consisting of deuterium and an aryl group; a fluoranthene group unsubstituted or substituted with one or more selected from the group consisting of deuterium and an aryl group; a triphenylene group unsubstituted or substituted with one or more selected from the group consisting of deuterium and an aryl group; or a chrysene group unsubstituted or substituted with one or more selected from the group consisting of deuterium and an aryl group.

In an exemplary embodiment of the present specification, Ar1 to Ar3 are the same as or different from each other, and are each a pyrene group unsubstituted or substituted with one or more selected from the group consisting of deuterium and a phenyl group; a benzophenanthrene group unsubstituted or substituted with one or more selected from the group consisting of deuterium and a phenyl group; a phenanthrene group unsubstituted or substituted with one or more selected from the group consisting of deuterium and a phenyl group; a fluoranthene group unsubstituted or substituted with one or more selected from the group consisting of deuterium and a phenyl group; a triphenylene group unsubstituted or substituted with one or more selected from the group consisting of deuterium and a phenyl group; or a chrysene group unsubstituted or substituted with one or more selected from the group consisting of deuterium and a phenyl group.

In an exemplary embodiment of the present specification, Ar1 to Ar3 are the same as or different from each other, and are each a pyrene group unsubstituted or substituted with one or more selected from the group consisting of deuterium and a phenyl group; a benzophenanthrene group; a phenanthrene group; a fluoranthene group; a triphenylene group; or a chrysene group.

In an exemplary embodiment of the present specification, R1 to R3 are the same as or different from each other, and are each independently hydrogen; deuterium; a substituted or unsubstituted alkyl group having 1 to 30 carbon atoms; a substituted or unsubstituted aryl group having 6 to 30 carbon atoms; or a substituted or unsubstituted heteroaryl group having 2 to 30 carbon atoms.

In an exemplary embodiment of the present specification, R1 to R3 are the same as or different from each other, and are each independently hydrogen; deuterium; an alkyl group; an aryl group; or a heteroaryl group.

In an exemplary embodiment of the present specification, R1 to R3 are the same as or different from each other, and are each independently hydrogen; or deuterium.

In an exemplary embodiment of the present specification, l1 to l3 are each 1 or 2.

In an exemplary embodiment of the present specification, L1 to L3 are the same as or different from each other, and are each independently a direct bond; or a substituted or unsubstituted arylene group having 6 to 30 carbon atoms.

In an exemplary embodiment of the present specification, L1 to L3 are the same as or different from each other, and are each independently a direct bond; or an arylene group having 6 to 30 carbon atoms, which is unsubstituted or substituted with deuterium.

In an exemplary embodiment of the present specification, L1 to L3 are the same as or different from each other, and are each independently a direct bond; a substituted or unsubstituted phenylene group; a substituted or unsubstituted biphenylene group; or a substituted or unsubstituted naphthylene group.

In an exemplary embodiment of the present specification, L1 to L3 are the same as or different from each other, and are each independently a direct bond; a phenylene group unsubstituted or substituted with deuterium; a biphenylene group unsubstituted or substituted with deuterium; or a naphthylene group unsubstituted or substituted with deuterium.

In an exemplary embodiment of the present specification, the compound represented by Chemical Formula 1 is any one of the following structures.

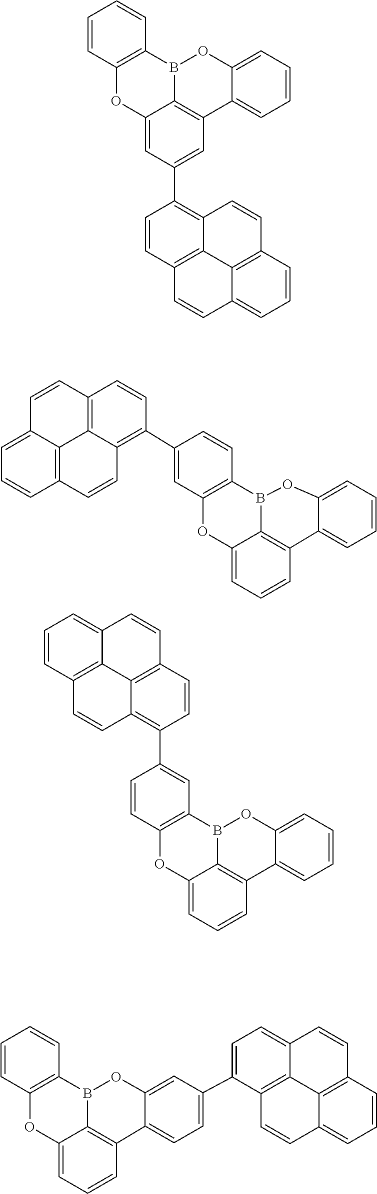

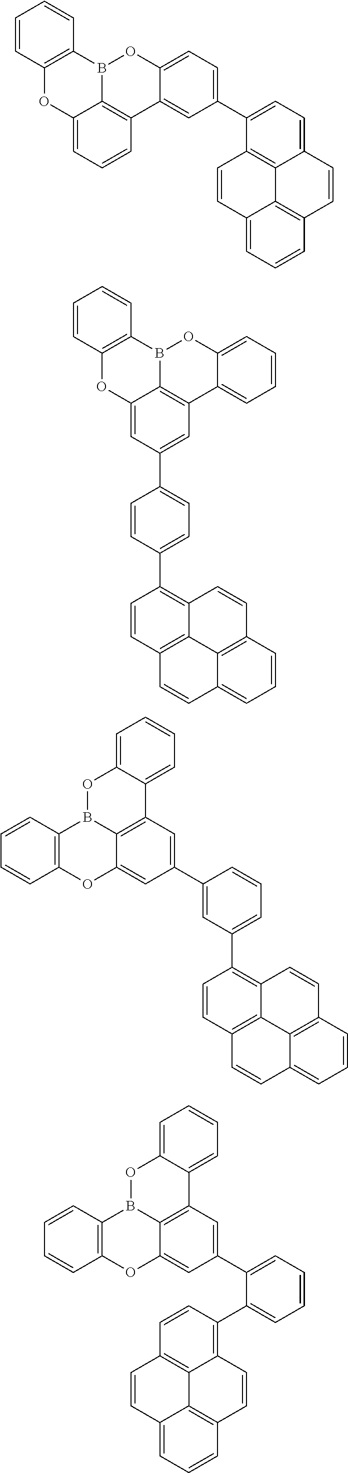

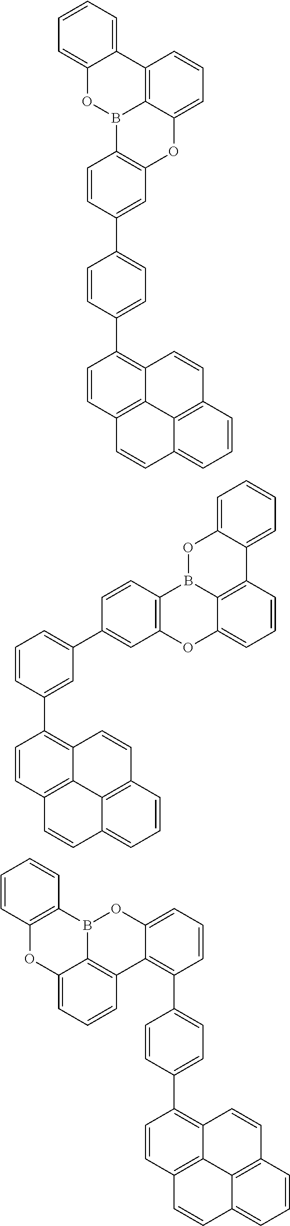

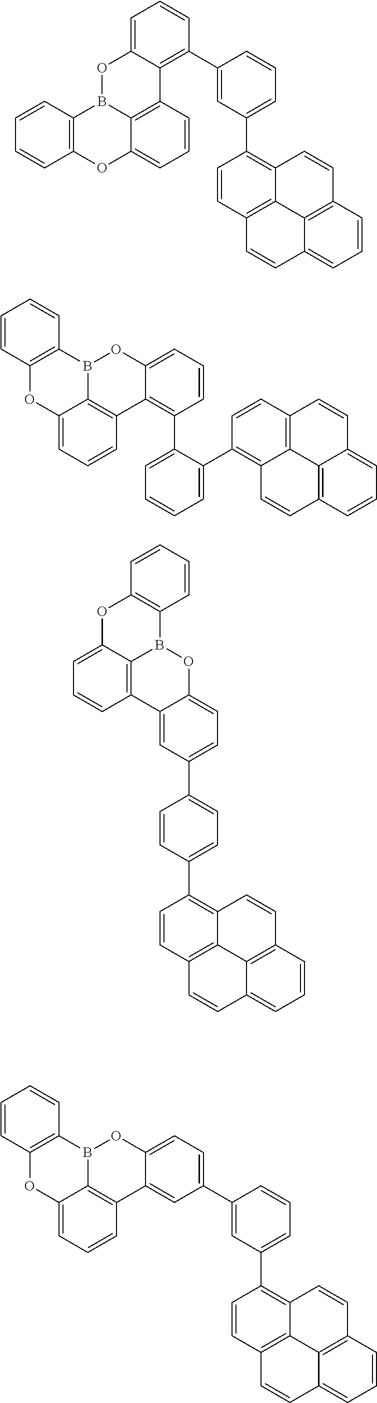

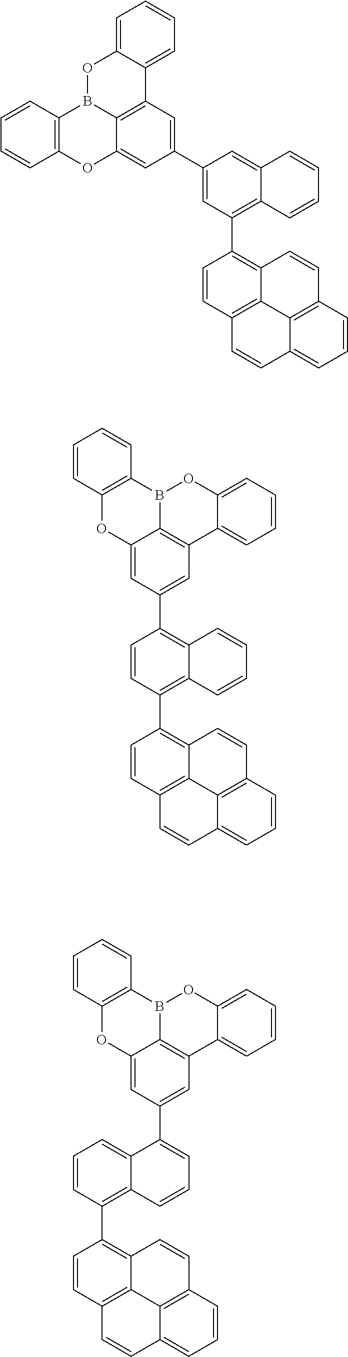 [SMILES: c1ccc2c(c1)Oc1cc(-c3cc(-c4ccc5ccc6cccc7ccc4c5c67)c4ccccc4c3)cc3c1B2Oc1ccccc1-3 ; c1ccc2c(c1)Oc1cc(-c3ccc(-c4ccc5ccc6cccc7ccc4c5c67)c4ccccc34)cc3c1B2Oc1ccccc1-3 ; c1ccc2c(c1)Oc1cc(-c3cccc4c(-c5ccc6ccc7cccc8ccc5c6c78)cccc34)cc3c1B2Oc1ccccc1-3]

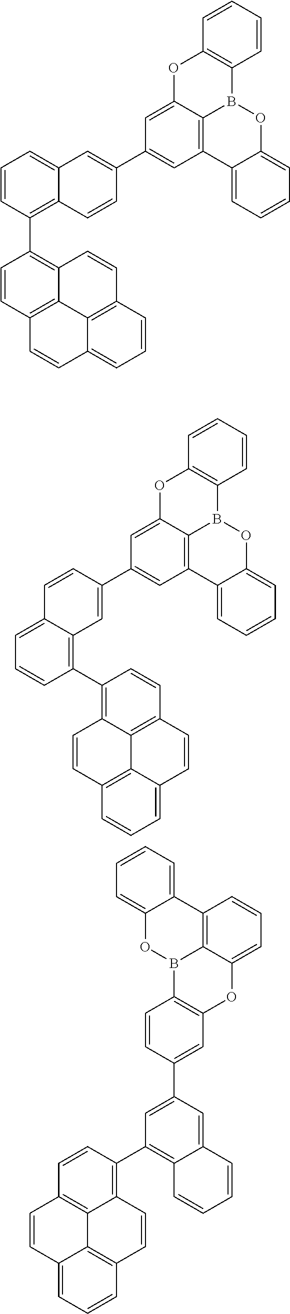

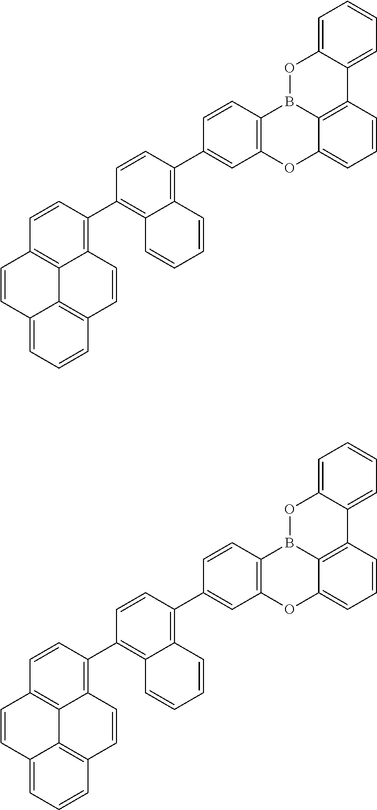 [SMILES: c1ccc2c(c1)OB1c3ccc(-c4ccc(-c5ccc6ccc7cccc8ccc5c6c78)c5ccccc45)cc3Oc3cccc-2c31 ; c1ccc2c(c1)OB1c3ccc(-c4ccc(-c5ccc6ccc7cccc8ccc5c6c78)c5ccccc45)cc3Oc3cccc-2c31]

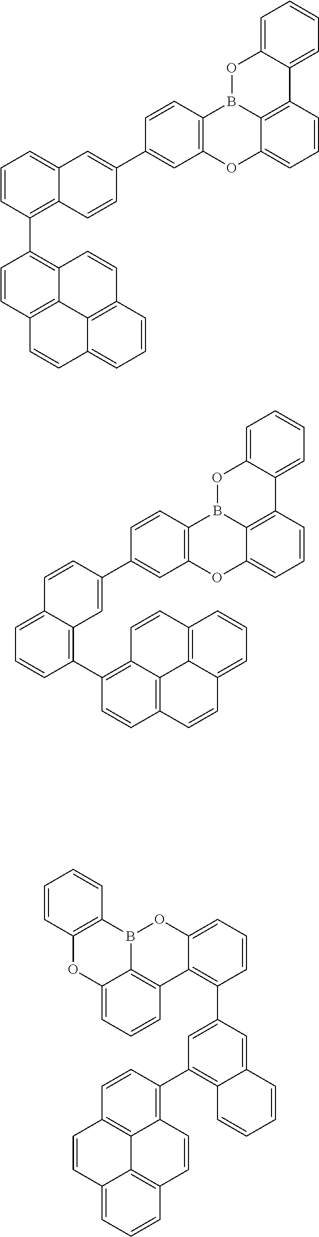 [SMILES: c1ccc2c(c1)OB1c3ccc(-c4ccc5c(-c6ccc7ccc8cccc9ccc6c7c89)cccc5c4)cc3Oc3cccc-2c31 ; c1ccc2c(c1)OB1c3ccc(-c4ccc5cccc(-c6ccc7ccc8cccc9ccc6c7c89)c5c4)cc3Oc3cccc-2c31 ; c1ccc2c(c1)Oc1cccc3c1B2Oc1cccc(-c2cc(-c4ccc5ccc6cccc7ccc4c5c67)c4ccccc4c2)c1-3]

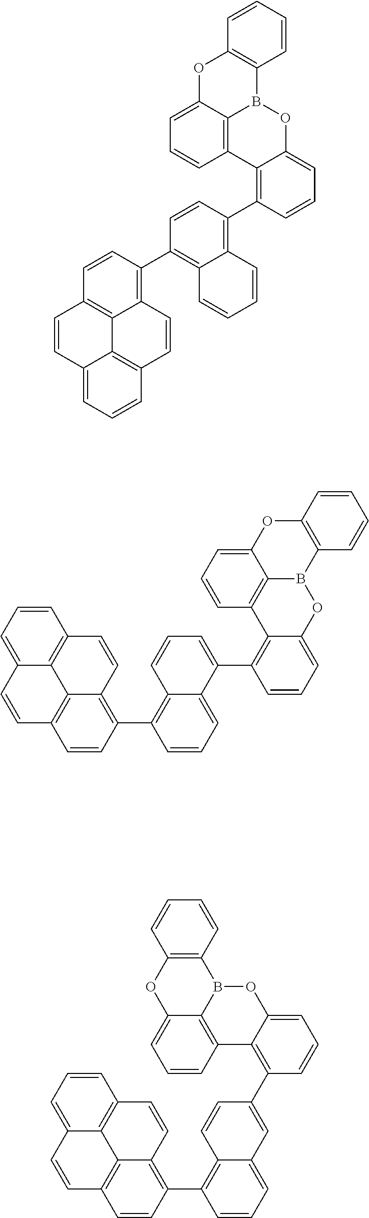 [SMILES: c1ccc2c(c1)Oc1cccc3c1B2Oc1cccc(-c2ccc(-c4ccc5ccc6cccc7ccc4c5c67)c4ccccc24)c1-3 ; c1ccc2c(c1)Oc1cccc3c1B2Oc1cccc(-c2cccc4c(-c5ccc6ccc7cccc8ccc5c6c78)cccc24)c1-3 ; c1ccc2c(c1)Oc1cccc3c1B2Oc1cccc(-c2ccc4c(-c5ccc6ccc7cccc8ccc5c6c78)cccc4c2)c1-3]

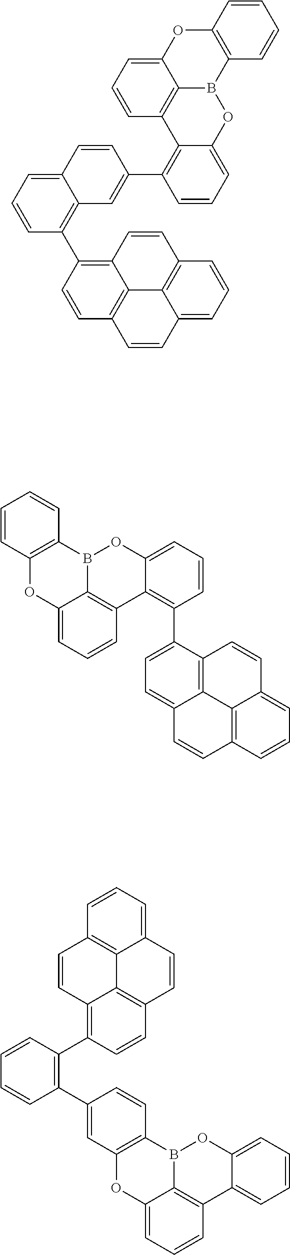

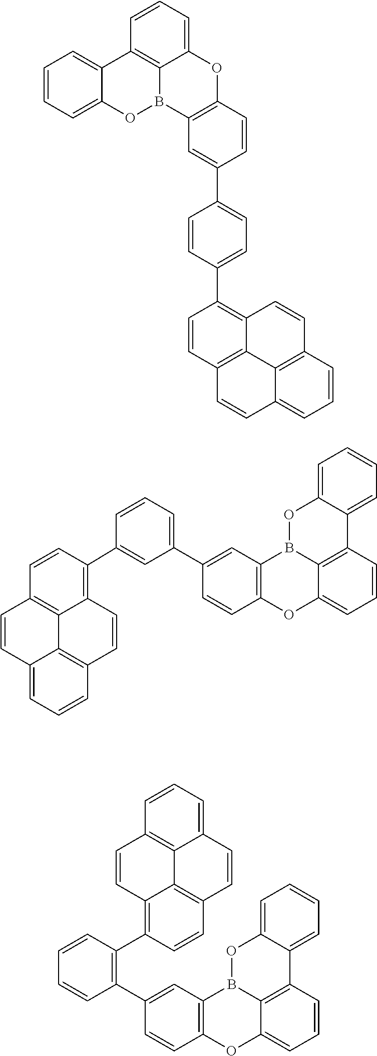 [SMILES: c1ccc2c(c1)OB1c3cc(-c4ccc(-c5ccc6ccc7cccc8ccc5c6c78)cc4)ccc3Oc3cccc-2c31 ; c1cc(-c2ccc3c(c2)B2Oc4ccccc4-c4cccc(c42)O3)cc(-c2ccc3ccc4cccc5ccc2c3c45)c1 ; c1ccc2c(c1)OB1c3cc(-c4ccccc4-c4ccc5ccc6cccc7ccc4c5c67)ccc3Oc3cccc-2c31]

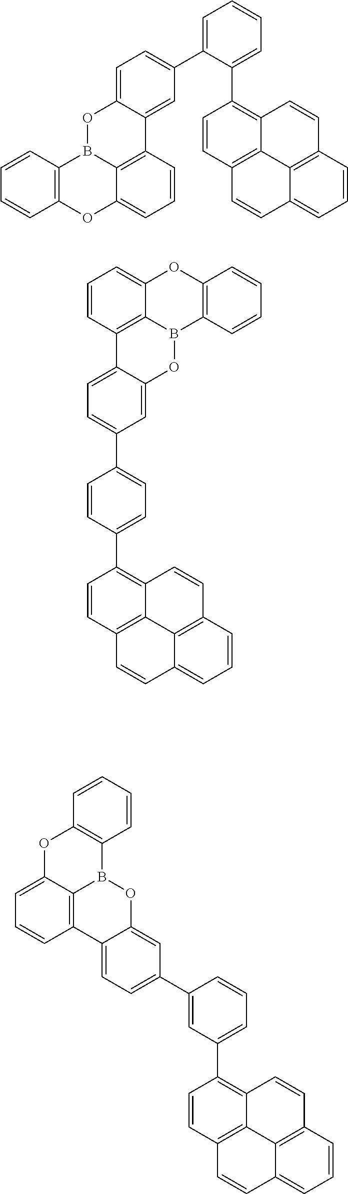 [SMILES: c1ccc2c(c1)Oc1cccc3c1B2Oc1ccc(-c2ccccc2-c2ccc4ccc5cccc6ccc2c4c56)cc1-3 ; c1ccc2c(c1)Oc1cccc3c1B2Oc1cc(-c2ccc(-c4ccc5ccc6cccc7ccc4c5c67)cc2)ccc1-3 ; c1cc(-c2ccc3c(c2)OB2c4ccccc4Oc4cccc-3c42)cc(-c2ccc3ccc4cccc5ccc2c3c45)c1]

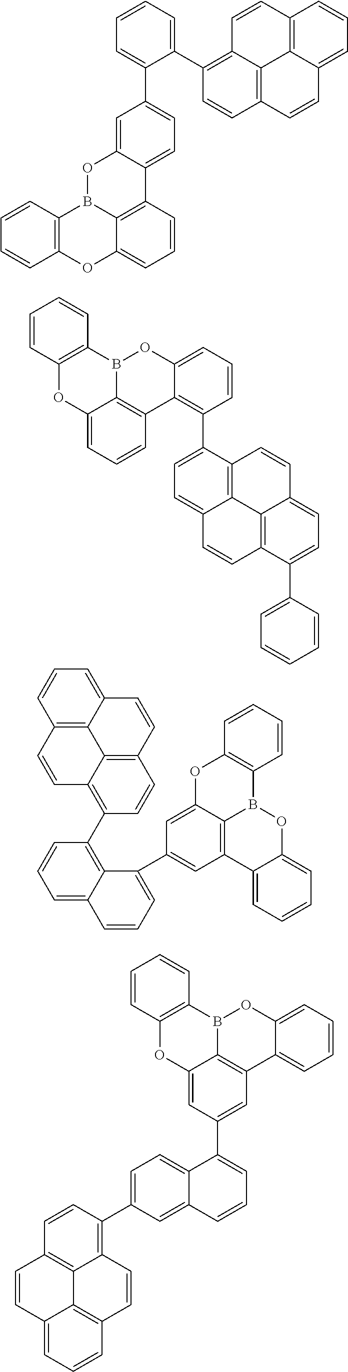

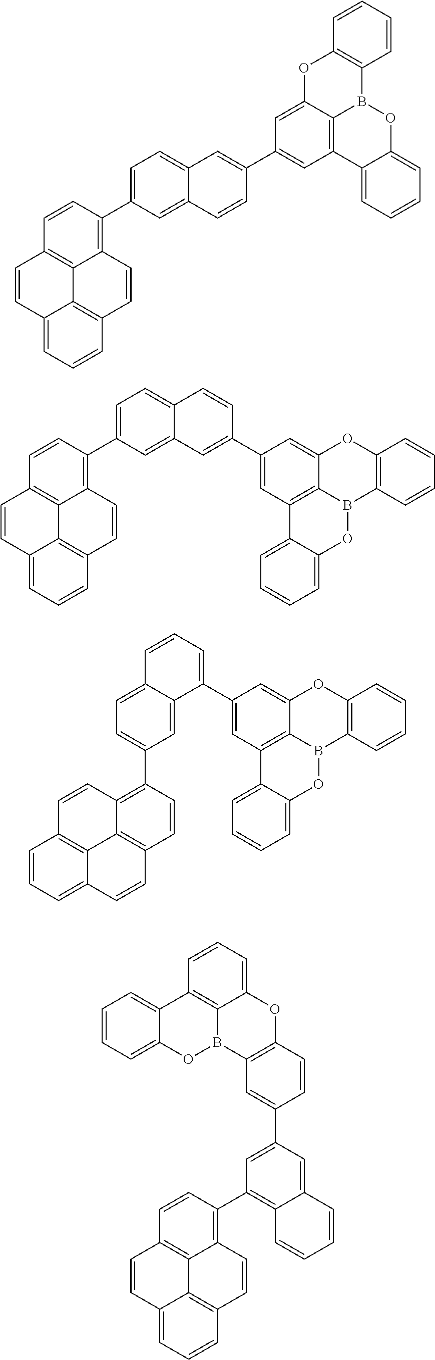 [SMILES: c1ccc2c(c1)Oc1cc(-c3ccc4cc(-c5ccc6ccc7cccc8ccc5c6c78)ccc4c3)cc3c1B2Oc1ccccc1-3 ; c1ccc2c(c1)Oc1cc(-c3ccc4ccc(-c5ccc6ccc7cccc8ccc5c6c78)cc4c3)cc3c1B2Oc1ccccc1-3 ; c1ccc2c(c1)Oc1cc(-c3cccc4ccc(-c5ccc6ccc7cccc8ccc5c6c78)cc34)cc3c1B2Oc1ccccc1-3 ; c1ccc2c(c1)OB1c3cc(-c4cc(-c5ccc6ccc7cccc8ccc5c6c78)c5ccccc5c4)ccc3Oc3cccc-2c31]

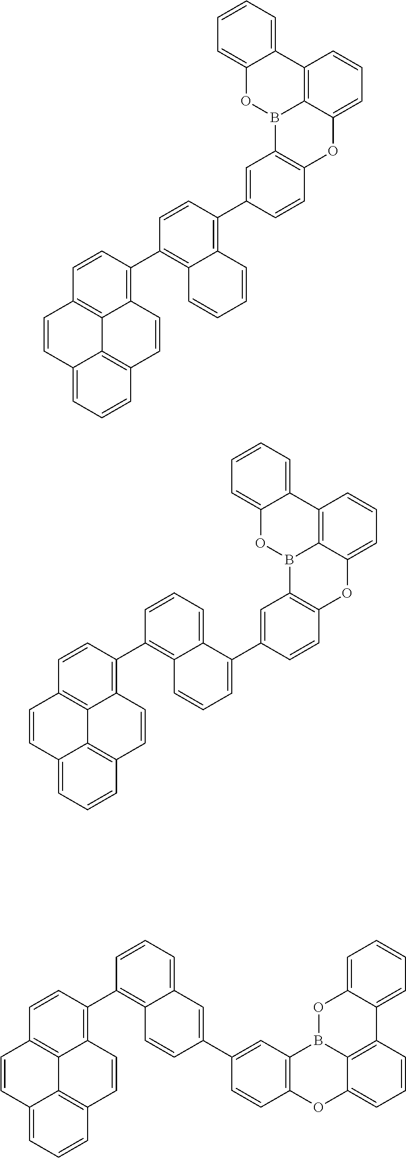 [SMILES: c1ccc2c(c1)OB1c3cc(-c4ccc(-c5ccc6ccc7cccc8ccc5c6c78)c5ccccc45)ccc3Oc3cccc-2c31 ; c1ccc2c(c1)OB1c3cc(-c4cccc5c(-c6ccc7ccc8cccc9ccc6c7c89)cccc45)ccc3Oc3cccc-2c31 ; c1ccc2c(c1)OB1c3cc(-c4ccc5c(-c6ccc7ccc8cccc9ccc6c7c89)cccc5c4)ccc3Oc3cccc-2c31]

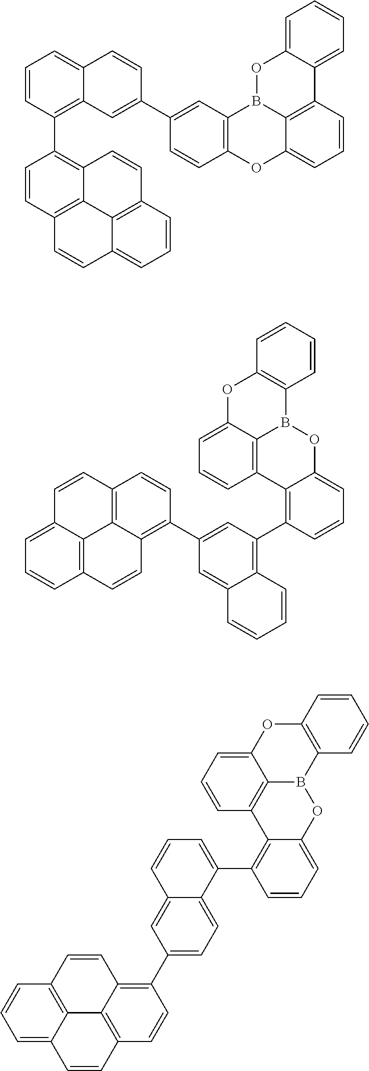 [SMILES: c1ccc2c(c1)OB1c3cc(-c4ccc5cccc(-c6ccc7ccc8cccc9ccc6c7c89)c5c4)ccc3Oc3cccc-2c31 ; c1ccc2c(c1)Oc1cccc3c1B2Oc1cccc(-c2cc(-c4ccc5ccc6cccc7ccc4c5c67)cc4ccccc24)c1-3 ; c1ccc2c(c1)Oc1cccc3c1B2Oc1cccc(-c2cccc4cc(-c5ccc6ccc7cccc8ccc5c6c78)ccc24)c1-3]

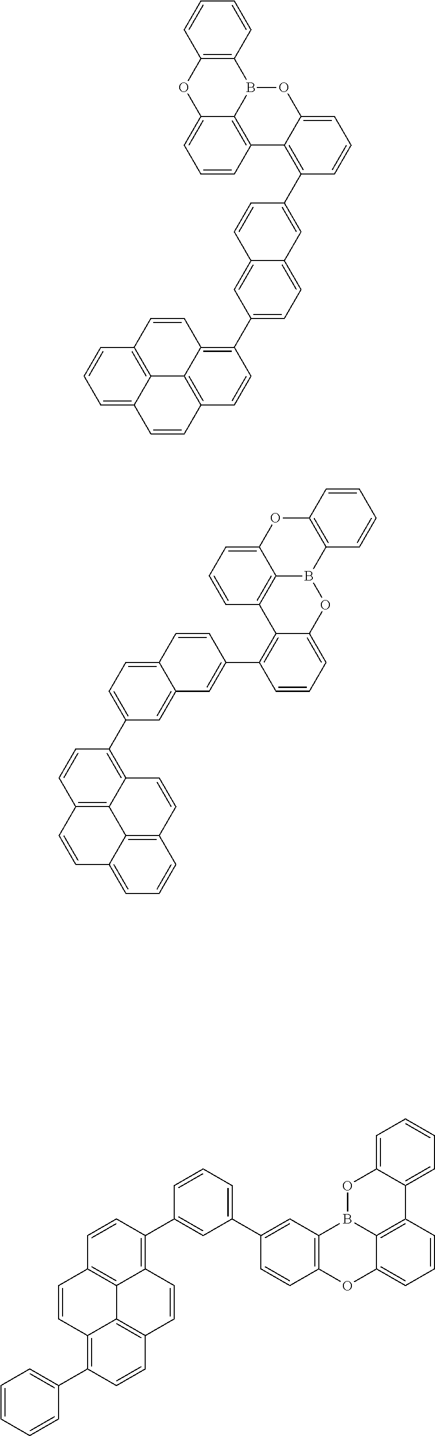 [SMILES: c1ccc2c(c1)Oc1cccc3c1B2Oc1cccc(-c2ccc4cc(-c5ccc6ccc7cccc8ccc5c6c78)ccc4c2)c1-3 ; c1ccc2c(c1)Oc1cccc3c1B2Oc1cccc(-c2ccc4ccc(-c5ccc6ccc7cccc8ccc5c6c78)cc4c2)c1-3 ; c1ccc(-c2ccc3ccc4c(-c5cccc(-c6ccc7c(c6)B6Oc8ccccc8-c8cccc(c86)O7)c5)ccc5ccc2c3c54)cc1]

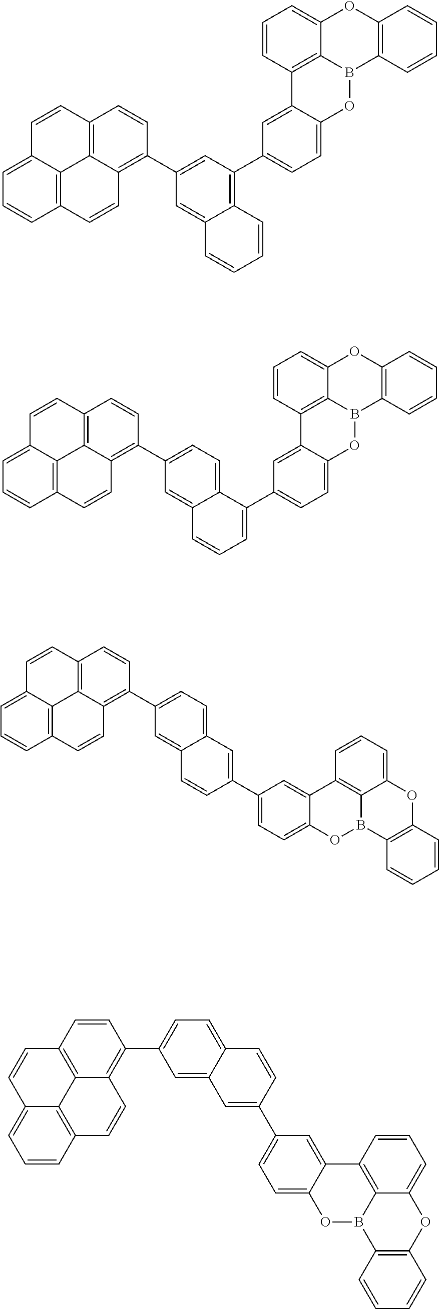 [SMILES: c1ccc2c(c1)Oc1cccc3c1B2Oc1ccc(-c2cc(-c4ccc5ccc6cccc7ccc4c5c67)cc4ccccc24)cc1-3 ; c1ccc2c(c1)Oc1cccc3c1B2Oc1ccc(-c2cccc4cc(-c5ccc6ccc7cccc8ccc5c6c78)ccc24)cc1-3 ; c1ccc2c(c1)Oc1cccc3c1B2Oc1ccc(-c2ccc4cc(-c5ccc6ccc7cccc8ccc5c6c78)ccc4c2)cc1-3 ; c1ccc2c(c1)Oc1cccc3c1B2Oc1ccc(-c2ccc4ccc(-c5ccc6ccc7cccc8ccc5c6c78)cc4c2)cc1-3]

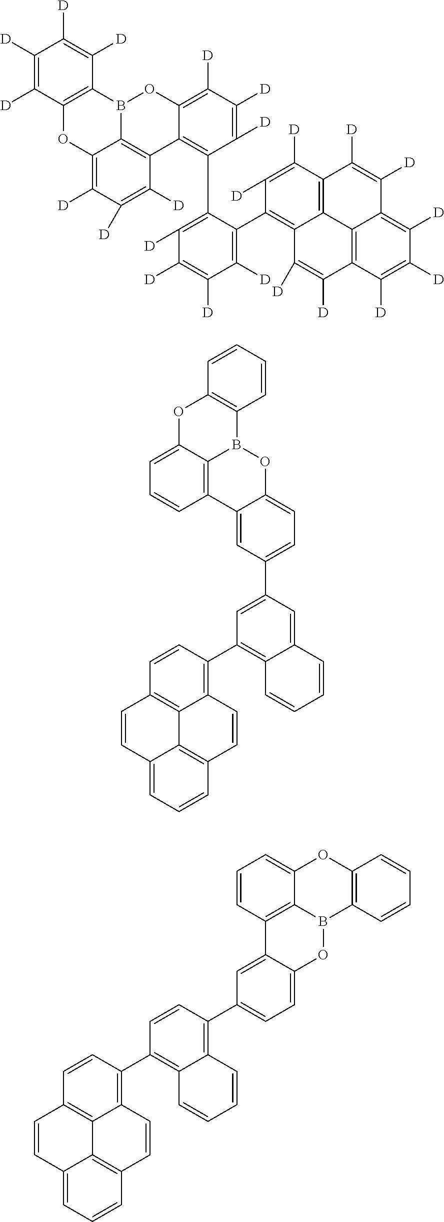

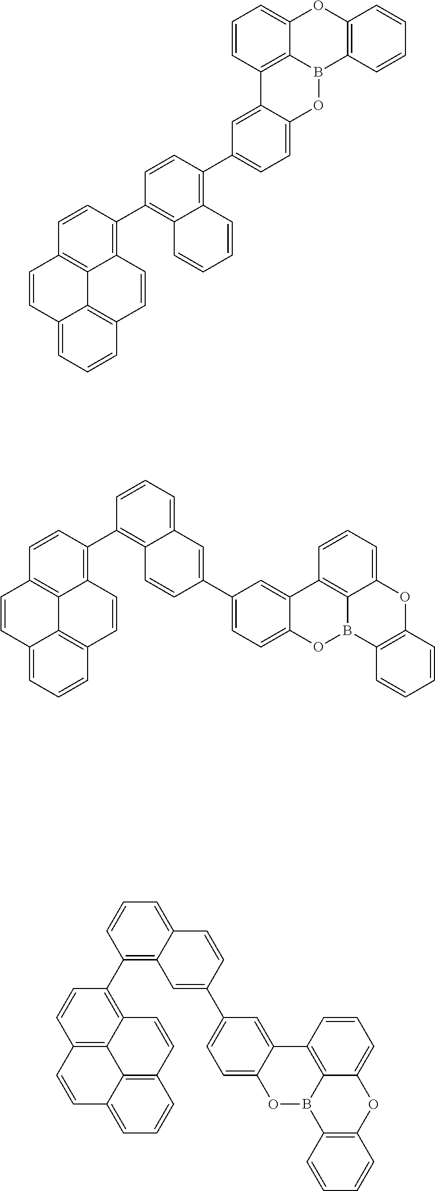 [SMILES: c1ccc2c(c1)Oc1cccc3c1B2Oc1ccc(-c2ccc(-c4ccc5ccc6cccc7ccc4c5c67)c4ccccc24)cc1-3 ; c1ccc2c(c1)Oc1cccc3c1B2Oc1ccc(-c2ccc4c(-c5ccc6ccc7cccc8ccc5c6c78)cccc4c2)cc1-3 ; c1ccc2c(c1)Oc1cccc3c1B2Oc1ccc(-c2ccc4cccc(-c5ccc6ccc7cccc8ccc5c6c78)c4c2)cc1-3]

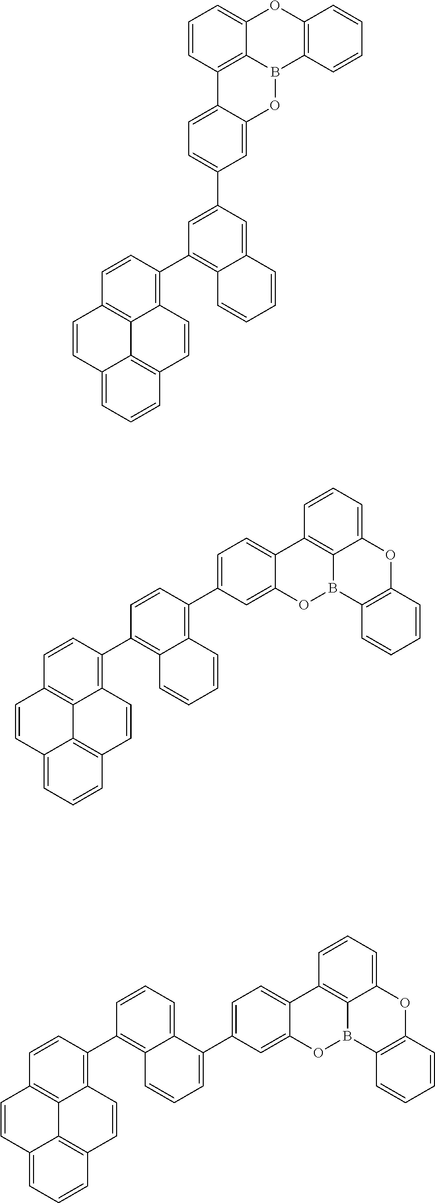 [SMILES: c1ccc2c(c1)Oc1cccc3c1B2Oc1cc(-c2cc(-c4ccc5ccc6cccc7ccc4c5c67)c4ccccc4c2)ccc1-3 ; c1ccc2c(c1)Oc1cccc3c1B2Oc1cc(-c2ccc(-c4ccc5ccc6cccc7ccc4c5c67)c4ccccc24)ccc1-3 ; c1ccc2c(c1)Oc1cccc3c1B2Oc1cc(-c2cccc4c(-c5ccc6ccc7cccc8ccc5c6c78)cccc24)ccc1-3]

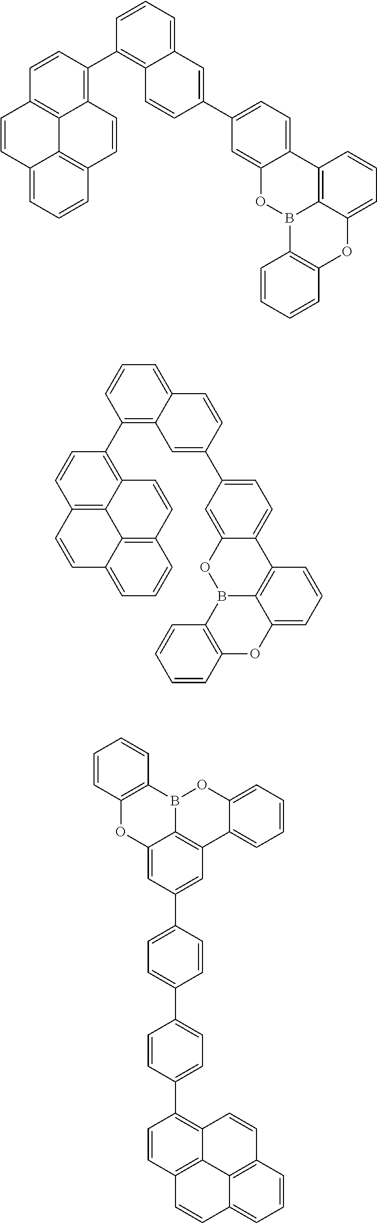 [SMILES: c1ccc2c(c1)Oc1cccc3c1B2Oc1cc(-c2ccc4c(-c5ccc6ccc7cccc8ccc5c6c78)cccc4c2)ccc1-3 ; c1ccc2c(c1)Oc1cccc3c1B2Oc1cc(-c2ccc4cccc(-c5ccc6ccc7cccc8ccc5c6c78)c4c2)ccc1-3 ; c1ccc2c(c1)Oc1cc(-c3ccc(-c4ccc(-c5ccc6ccc7cccc8ccc5c6c78)cc4)cc3)cc3c1B2Oc1ccccc1-3]

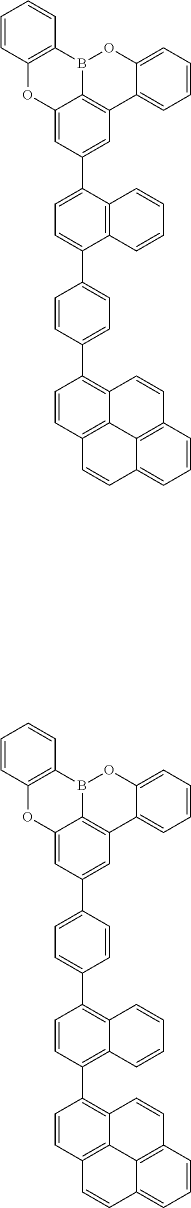 [SMILES: c1ccc2c(c1)Oc1cc(-c3ccc(-c4ccc(-c5ccc6ccc7cccc8ccc5c6c78)cc4)c4ccccc34)cc3c1B2Oc1ccccc1-3 ; c1ccc2c(c1)Oc1cc(-c3ccc(-c4ccc(-c5ccc6ccc7cccc8ccc5c6c78)c5ccccc45)cc3)cc3c1B2Oc1ccccc1-3]

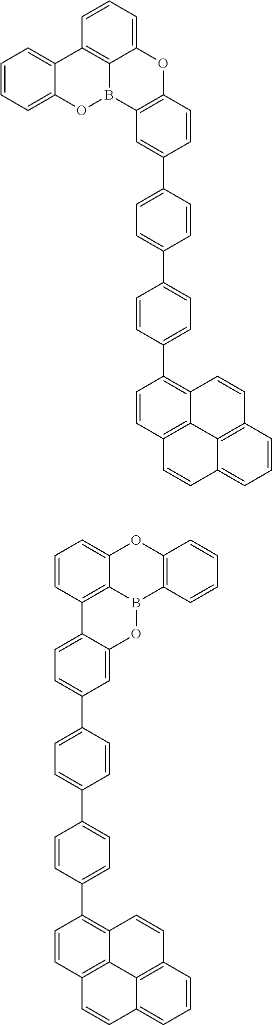 [SMILES: c1ccc2c(c1)OB1c3cc(-c4ccc(-c5ccc(-c6ccc7ccc8cccc9ccc6c7c89)cc5)cc4)ccc3Oc3cccc-2c31 ; c1ccc2c(c1)Oc1cccc3c1B2Oc1cc(-c2ccc(-c4ccc(-c5ccc6ccc7cccc8ccc5c6c78)cc4)cc2)ccc1-3]

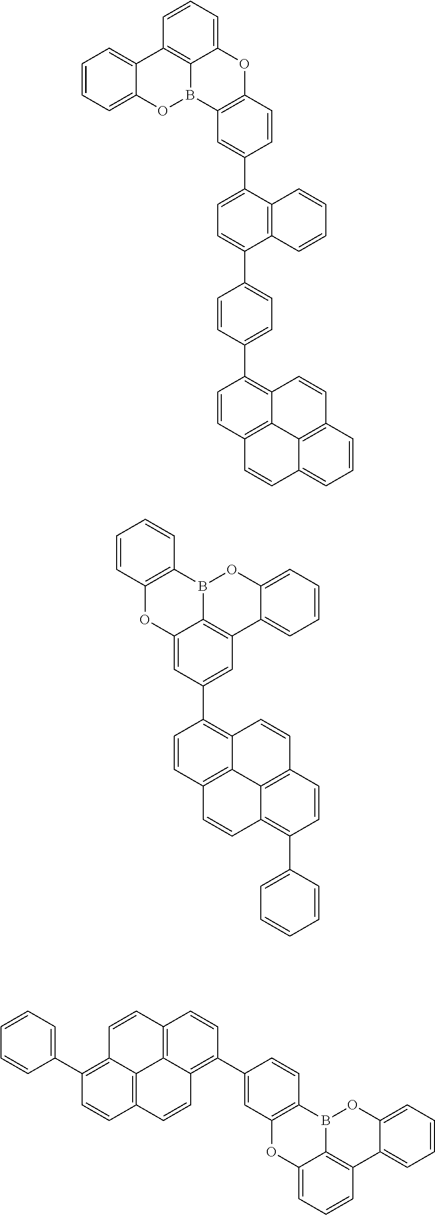 [SMILES: c1ccc2c(c1)OB1c3cc(-c4ccc(-c5ccc(-c6ccc7ccc8cccc9ccc6c7c89)cc5)c5ccccc45)ccc3Oc3cccc-2c31 ; c1ccc(-c2ccc3ccc4c(-c5cc6c7c(c5)-c5ccccc5OB7c5ccccc5O6)ccc5ccc2c3c54)cc1 ; c1ccc(-c2ccc3ccc4c(-c5ccc6c(c5)Oc5cccc7c5B6Oc5ccccc5-7)ccc5ccc2c3c54)cc1]

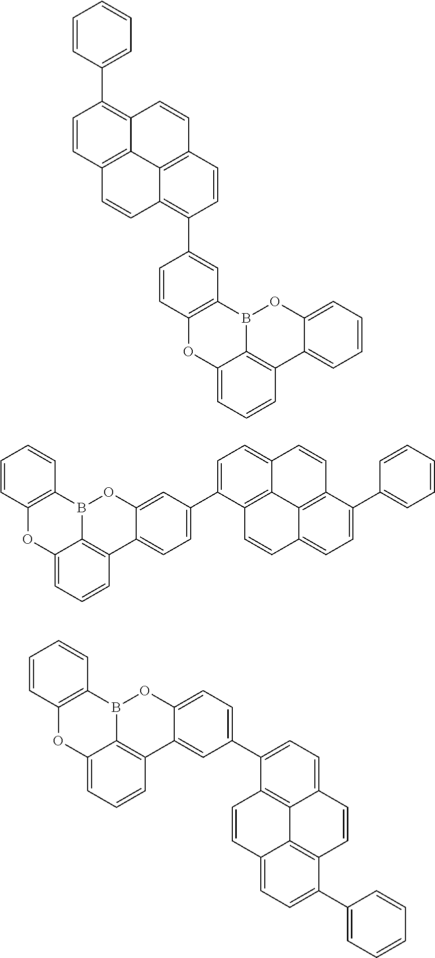

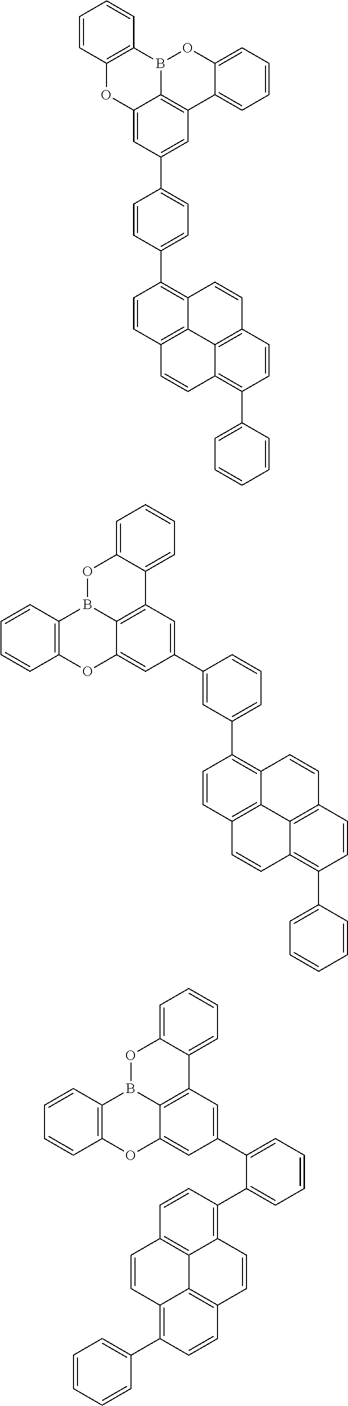 [SMILES: c1ccc(-c2ccc3ccc4c(-c5ccc(-c6cc7c8c(c6)-c6ccccc6OB8c6ccccc6O7)cc5)ccc5ccc2c3c54)cc1 ; c1ccc(-c2ccc3ccc4c(-c5cccc(-c6cc7c8c(c6)-c6ccccc6OB8c6ccccc6O7)c5)ccc5ccc2c3c54)cc1 ; c1ccc(-c2ccc3ccc4c(-c5ccccc5-c5cc6c7c(c5)-c5ccccc5OB7c5ccccc5O6)ccc5ccc2c3c54)cc1]

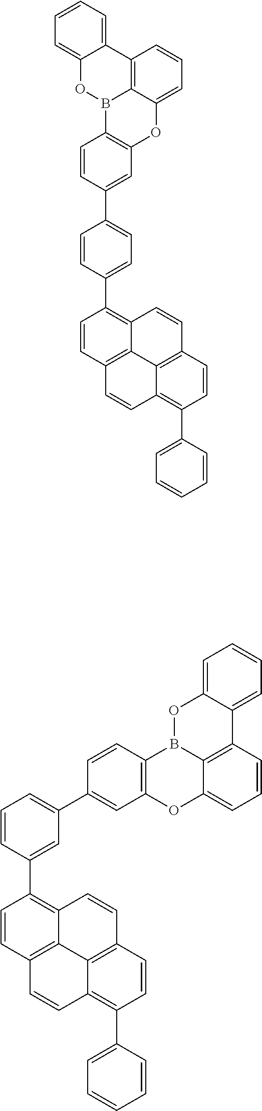 [SMILES: c1ccc(-c2ccc3ccc4c(-c5ccc(-c6ccc7c(c6)Oc6cccc8c6B7Oc6ccccc6-8)cc5)ccc5ccc2c3c54)cc1 ; c1ccc(-c2ccc3ccc4c(-c5cccc(-c6ccc7c(c6)Oc6cccc8c6B7Oc6ccccc6-8)c5)ccc5ccc2c3c54)cc1]

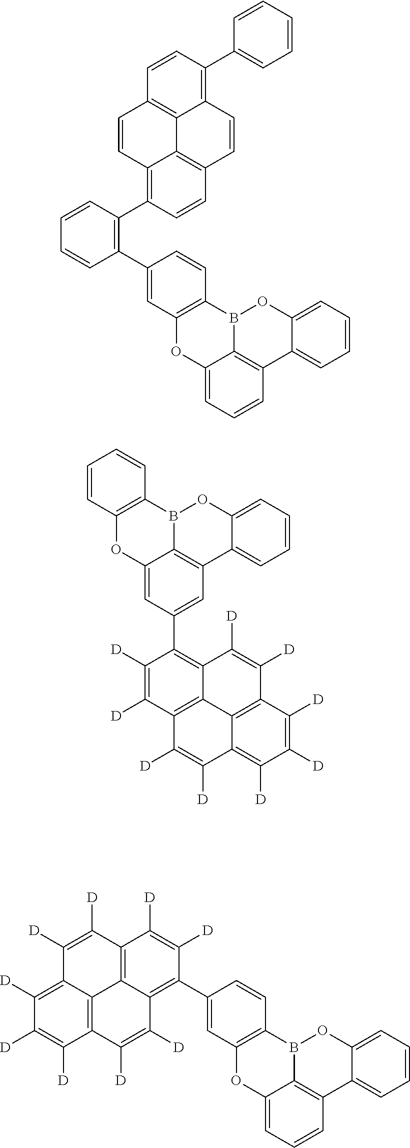 [SMILES: c1ccc(-c2ccc3ccc4c(-c5ccccc5-c5ccc6c(c5)Oc5cccc7c5B6Oc5ccccc5-7)ccc5ccc2c3c54)cc1 ; [2H]c1c([2H])c2c([2H])c([2H])c3c([2H])c([2H])c(-c4cc5c6c(c4)-c4ccccc4OB6c4ccccc4O5)c4c([2H])c([2H])c(c1[2H])c2c34 ; [2H]c1c([2H])c2c([2H])c([2H])c3c([2H])c([2H])c(-c4ccc5c(c4)Oc4cccc6c4B5Oc4ccccc4-6)c4c([2H])c([2H])c(c1[2H])c2c34]

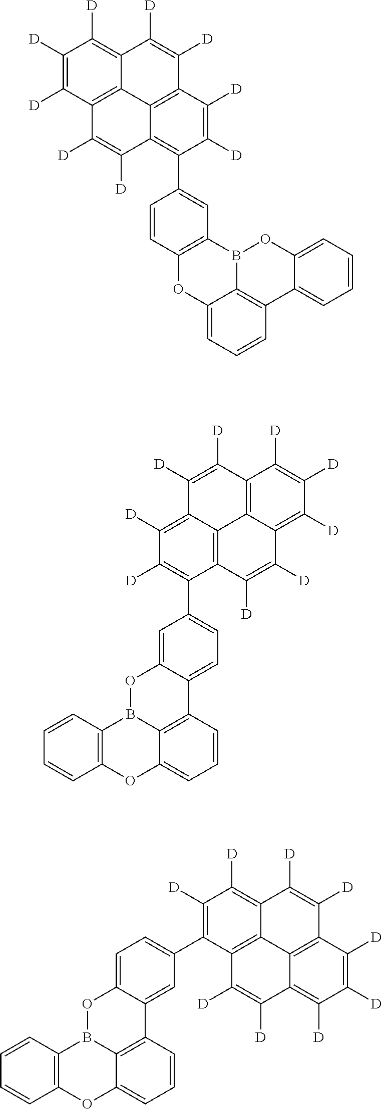 [SMILES: [2H]c1c([2H])c2c([2H])c([2H])c3c([2H])c([2H])c(-c4ccc5c(c4)B4Oc6ccccc6-c6cccc(c64)O5)c4c([2H])c([2H])c(c1[2H])c2c34 ; [2H]c1c([2H])c2c([2H])c([2H])c3c([2H])c([2H])c(-c4ccc5c(c4)OB4c6ccccc6Oc6cccc-5c64)c4c([2H])c([2H])c(c1[2H])c2c34 ; [2H]c1c([2H])c2c([2H])c([2H])c3c([2H])c([2H])c(-c4ccc5c(c4)-c4cccc6c4B(O5)c4ccccc4O6)c4c([2H])c([2H])c(c1[2H])c2c34]

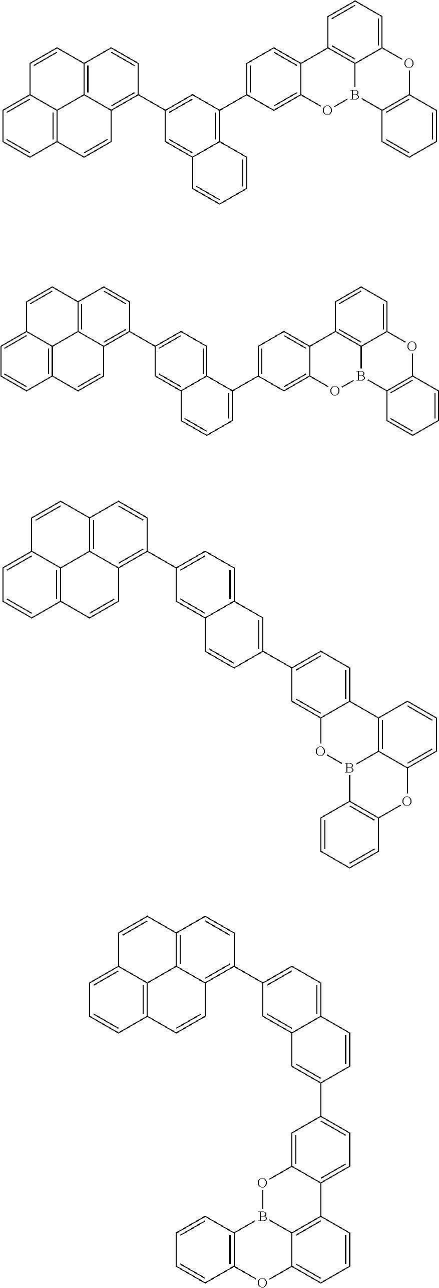 [SMILES: c1ccc2c(c1)Oc1cccc3c1B2Oc1cc(-c2cc(-c4ccc5ccc6cccc7ccc4c5c67)cc4ccccc24)ccc1-3 ; c1ccc2c(c1)Oc1cccc3c1B2Oc1cc(-c2cccc4cc(-c5ccc6ccc7cccc8ccc5c6c78)ccc24)ccc1-3 ; c1ccc2c(c1)Oc1cccc3c1B2Oc1cc(-c2ccc4cc(-c5ccc6ccc7cccc8ccc5c6c78)ccc4c2)ccc1-3 ; c1ccc2c(c1)Oc1cccc3c1B2Oc1cc(-c2ccc4ccc(-c5ccc6ccc7cccc8ccc5c6c78)cc4c2)ccc1-3]

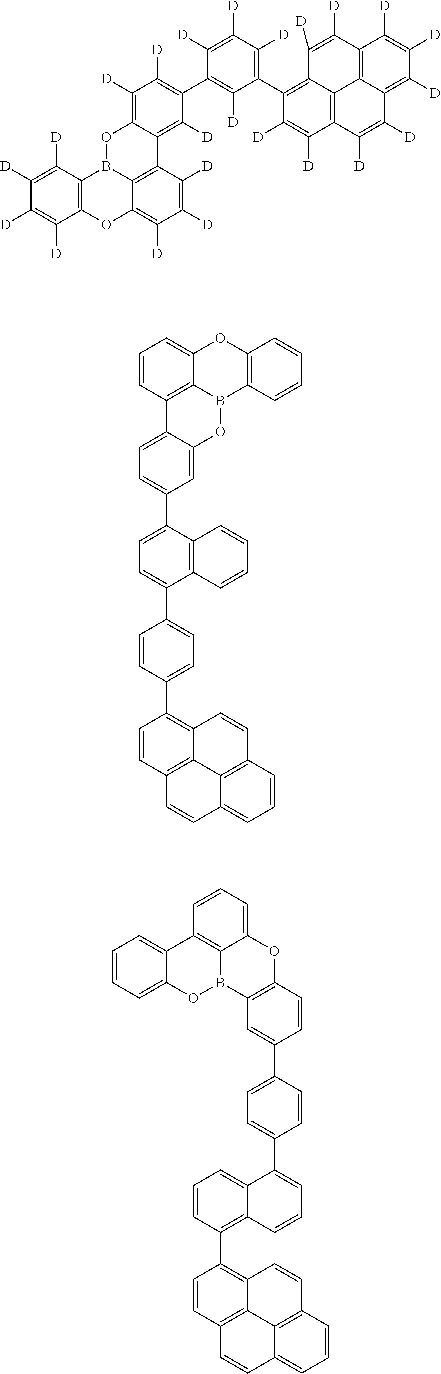 [SMILES: [2H]c1c([2H])c([2H])c2c(c1[2H])Oc1c([2H])c([2H])c([2H])c3c1B2Oc1c([2H])c([2H])c(-c2c([2H])c([2H])c([2H])c(-c4c([2H])c([2H])c5c([2H])c([2H])c6c([2H])c([2H])c([2H])c7c([2H])c([2H])c4c5c67)c2[2H])c([2H])c1-3 ; c1ccc2c(c1)Oc1cccc3c1B2Oc1cc(-c2ccc(-c4ccc(-c5ccc6ccc7cccc8ccc5c6c78)cc4)c4ccccc24)ccc1-3 ; c1ccc2c(c1)OB1c3cc(-c4ccc(-c5cccc6c(-c7ccc8ccc9cccc%10ccc7c8c9%10)cccc56)cc4)ccc3Oc3cccc-2c31]

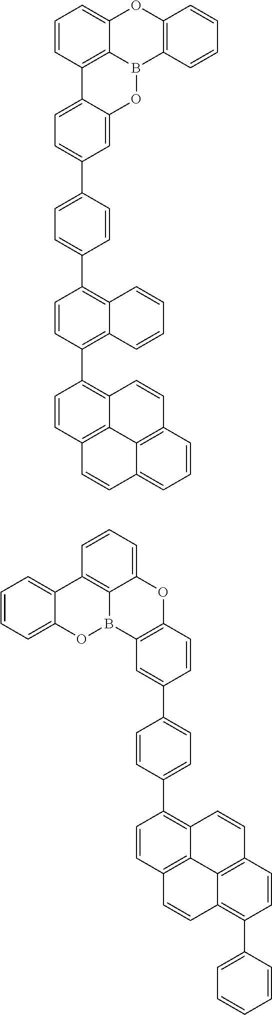

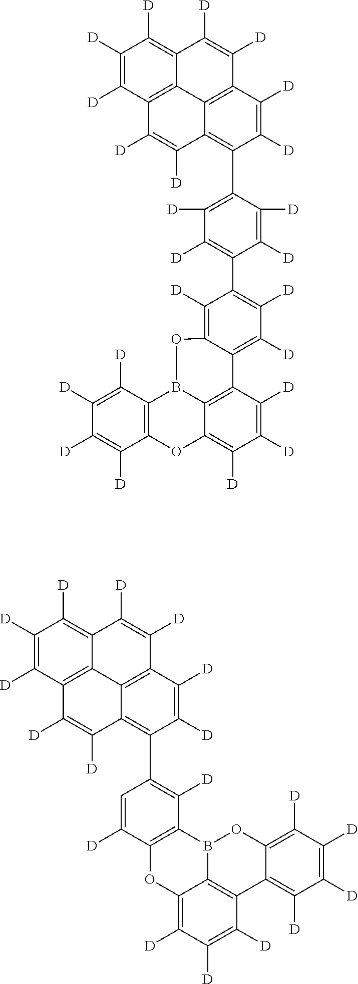 [SMILES: [2H]c1c([2H])c([2H])c2c(c1[2H])Oc1c([2H])c([2H])c([2H])c3c1B2Oc1c([2H])c(-c2c([2H])c([2H])c(-c4c([2H])c([2H])c5c([2H])c([2H])c6c([2H])c([2H])c([2H])c7c([2H])c([2H])c4c5c67)c([2H])c2[2H])c([2H])c([2H])c1-3 ; [2H]c1cc(-c2c([2H])c([2H])c3c([2H])c([2H])c4c([2H])c([2H])c([2H])c5c([2H])c([2H])c2c3c45)c([2H])c2c1Oc1c([2H])c([2H])c([2H])c3c1B2Oc1c([2H])c([2H])c([2H])c([2H])c1-3]

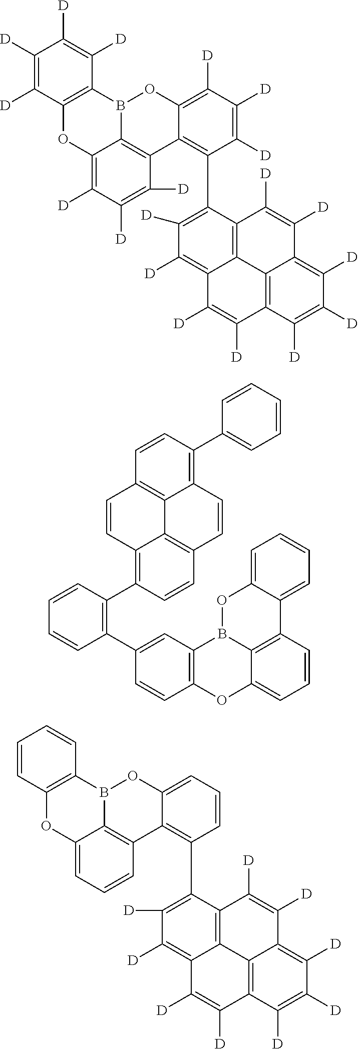

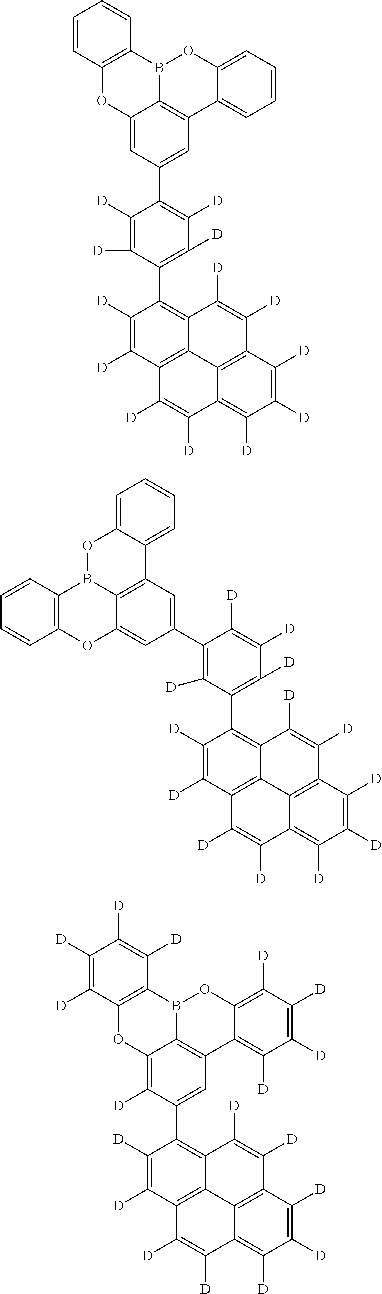 [SMILES: [2H]c1c([2H])c(-c2c([2H])c([2H])c3c([2H])c([2H])c4c([2H])c([2H])c([2H])c5c([2H])c([2H])c2c3c45)c([2H])c([2H])c1-c1cc2c3c(c1)-c1ccccc1OB3c1ccccc1O2 ; [2H]c1c([2H])c(-c2cc3c4c(c2)-c2ccccc2OB4c2ccccc2O3)c([2H])c(-c2c([2H])c([2H])c3c([2H])c([2H])c4c([2H])c([2H])c([2H])c5c([2H])c([2H])c2c3c45)c1[2H] ; [2H]c1c([2H])c([2H])c2c(c1[2H])Oc1c([2H])c(-c3c([2H])c([2H])c4c([2H])c([2H])c5c([2H])c([2H])c([2H])c6c([2H])c([2H])c3c4c56)cc3c1B2Oc1c([2H])c([2H])c([2H])c([2H])c1-3]

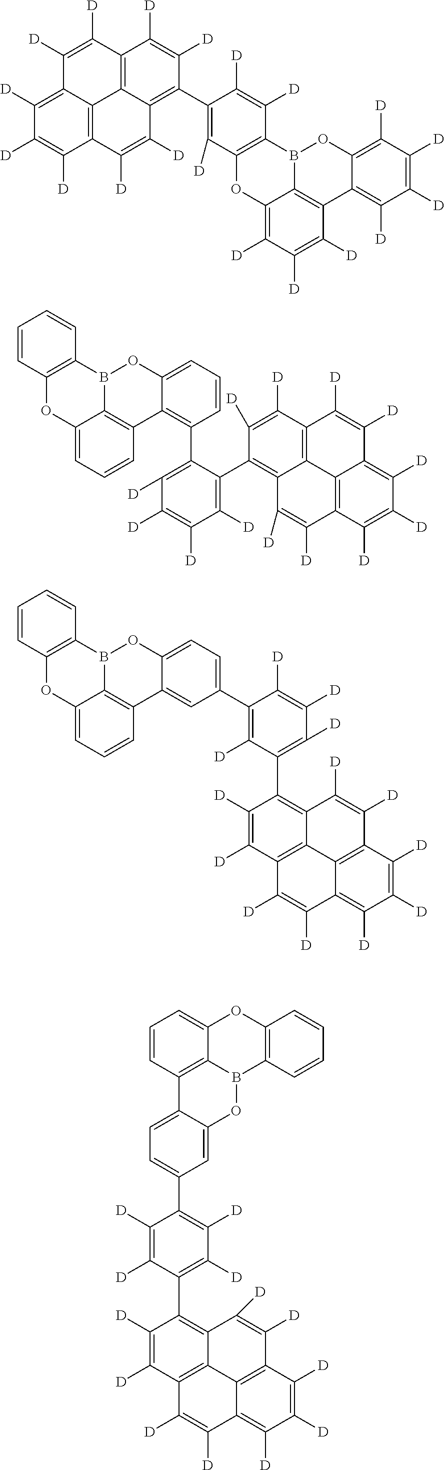

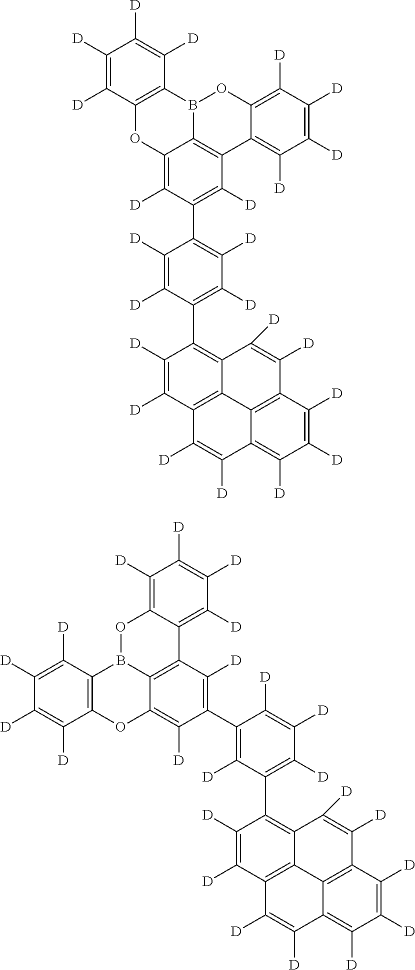 [SMILES: [2H]c1c([2H])c([2H])c2c(c1[2H])Oc1c([2H])c(-c3c([2H])c([2H])c(-c4c([2H])c([2H])c5c([2H])c([2H])c6c([2H])c([2H])c([2H])c7c([2H])c([2H])c4c5c67)c([2H])c3[2H])c([2H])c3c1B2Oc1c([2H])c([2H])c([2H])c([2H])c1-3 ; [2H]c1c([2H])c([2H])c2c(c1[2H])Oc1c([2H])c(-c3c([2H])c([2H])c([2H])c(-c4c([2H])c([2H])c5c([2H])c([2H])c6c([2H])c([2H])c([2H])c7c([2H])c([2H])c4c5c67)c3[2H])c([2H])c3c1B2Oc1c([2H])c([2H])c([2H])c([2H])c1-3]

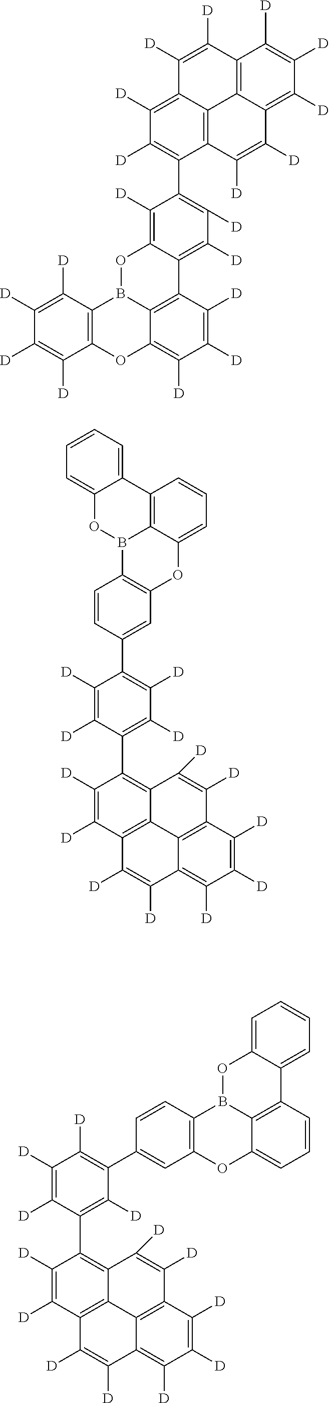 [SMILES: [2H]c1c([2H])c([2H])c2c(c1[2H])Oc1c([2H])c([2H])c([2H])c3c1B2Oc1c([2H])c(-c2c([2H])c([2H])c4c([2H])c([2H])c5c([2H])c([2H])c([2H])c6c([2H])c([2H])c2c4c56)c([2H])c([2H])c1-3 ; [2H]c1c([2H])c(-c2c([2H])c([2H])c3c([2H])c([2H])c4c([2H])c([2H])c([2H])c5c([2H])c([2H])c2c3c45)c([2H])c([2H])c1-c1ccc2c(c1)Oc1cccc3c1B2Oc1ccccc1-3 ; [2H]c1c([2H])c(-c2ccc3c(c2)Oc2cccc4c2B3Oc2ccccc2-4)c([2H])c(-c2c([2H])c([2H])c3c([2H])c([2H])c4c([2H])c([2H])c([2H])c5c([2H])c([2H])c2c3c45)c1[2H]]

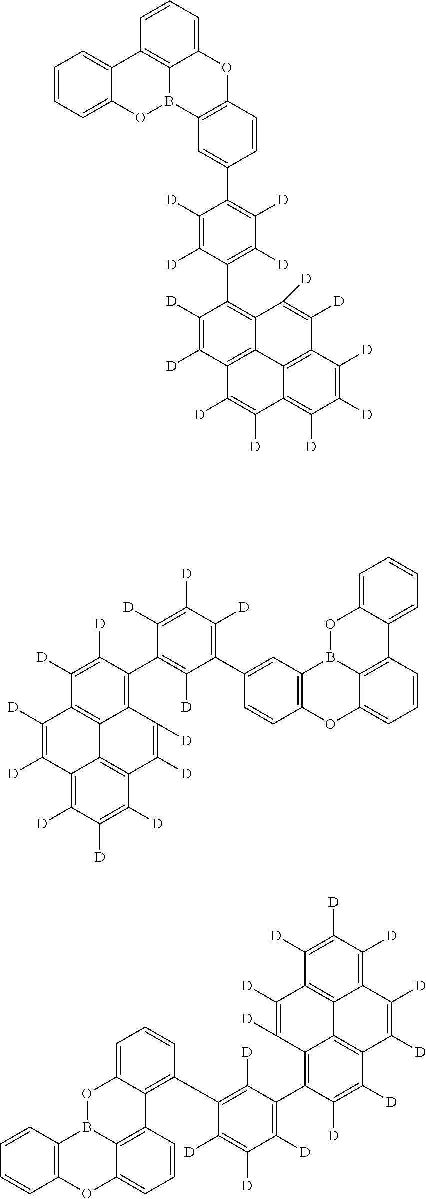 [SMILES: [2H]c1c([2H])c(-c2c([2H])c([2H])c3c([2H])c([2H])c4c([2H])c([2H])c([2H])c5c([2H])c([2H])c2c3c45)c([2H])c([2H])c1-c1ccc2c(c1)B1Oc3ccccc3-c3cccc(c31)O2 ; [2H]c1c([2H])c(-c2ccc3c(c2)B2Oc4ccccc4-c4cccc(c42)O3)c([2H])c(-c2c([2H])c([2H])c3c([2H])c([2H])c4c([2H])c([2H])c([2H])c5c([2H])c([2H])c2c3c45)c1[2H] ; [2H]c1c([2H])c(-c2cccc3c2-c2cccc4c2B(O3)c2ccccc2O4)c([2H])c(-c2c([2H])c([2H])c3c([2H])c([2H])c4c([2H])c([2H])c([2H])c5c([2H])c([2H])c2c3c45)c1[2H]]

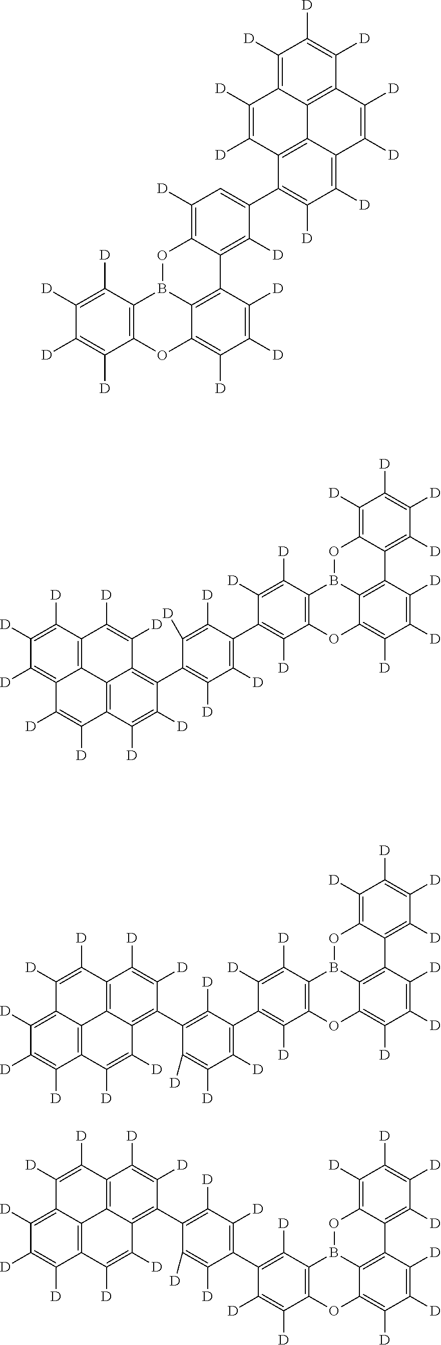

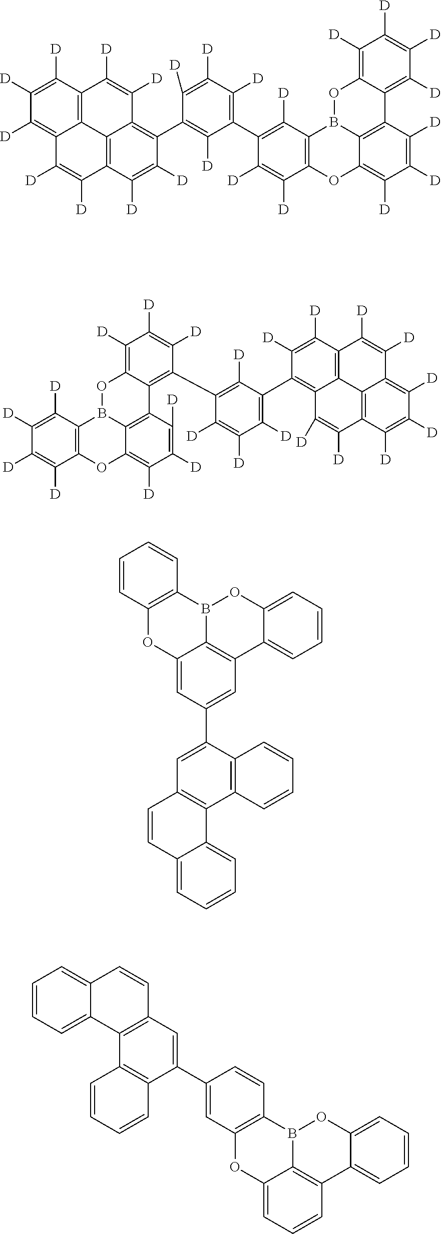

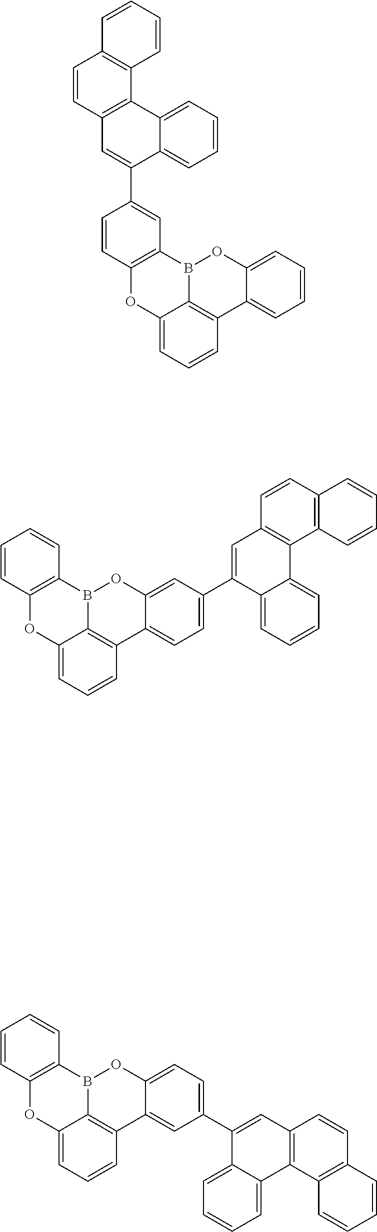

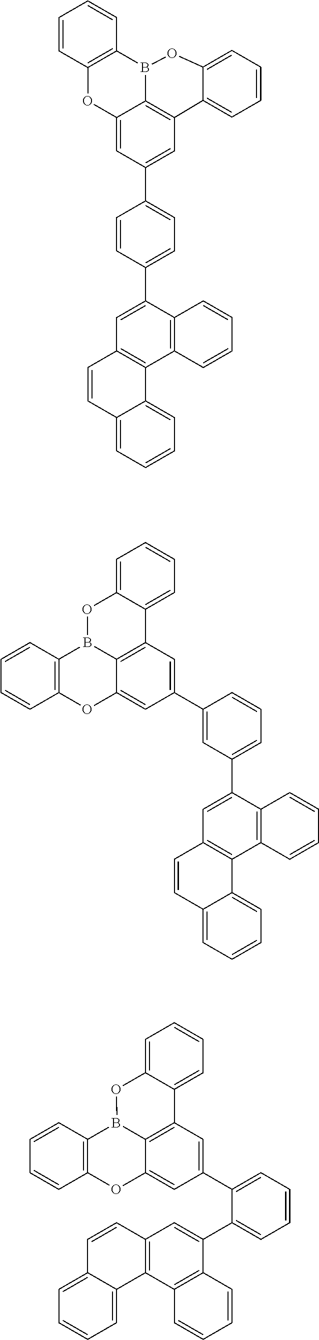

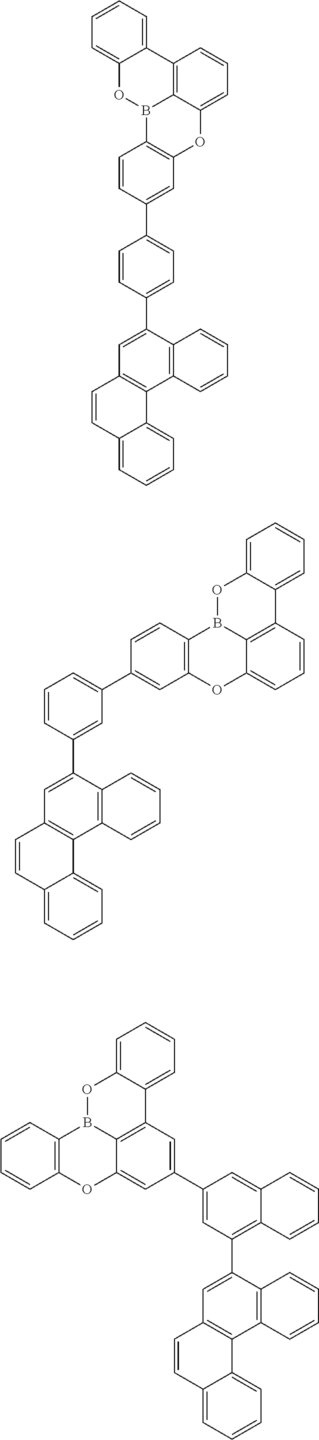 [SMILES: c1ccc2c(c1)OB1c3ccc(-c4ccc(-c5cc6ccc7ccccc7c6c6ccccc56)cc4)cc3Oc3cccc-2c31 ; c1cc(-c2ccc3c(c2)Oc2cccc4c2B3Oc2ccccc2-4)cc(-c2cc3ccc4ccccc4c3c3ccccc23)c1 ; c1ccc2c(c1)Oc1cc(-c3cc(-c4cc5ccc6ccccc6c5c5ccccc45)c4ccccc4c3)cc3c1B2Oc1ccccc1-3]

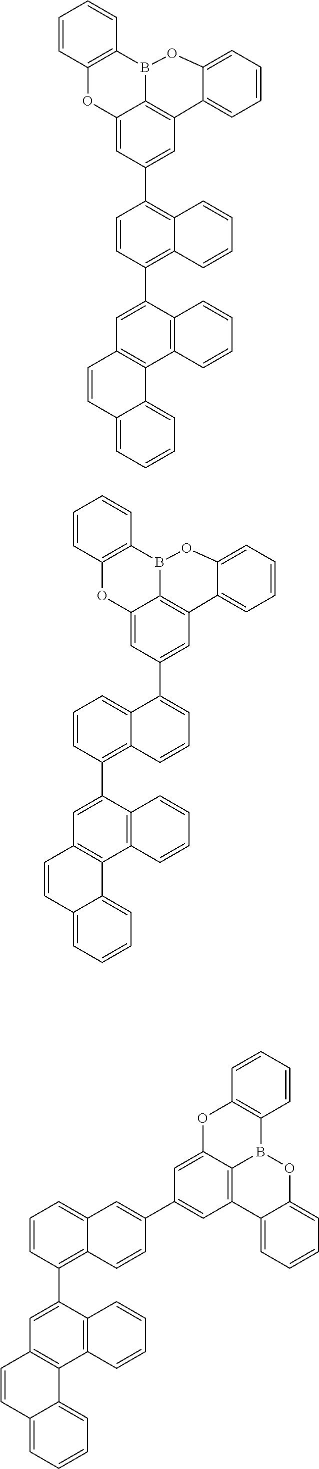

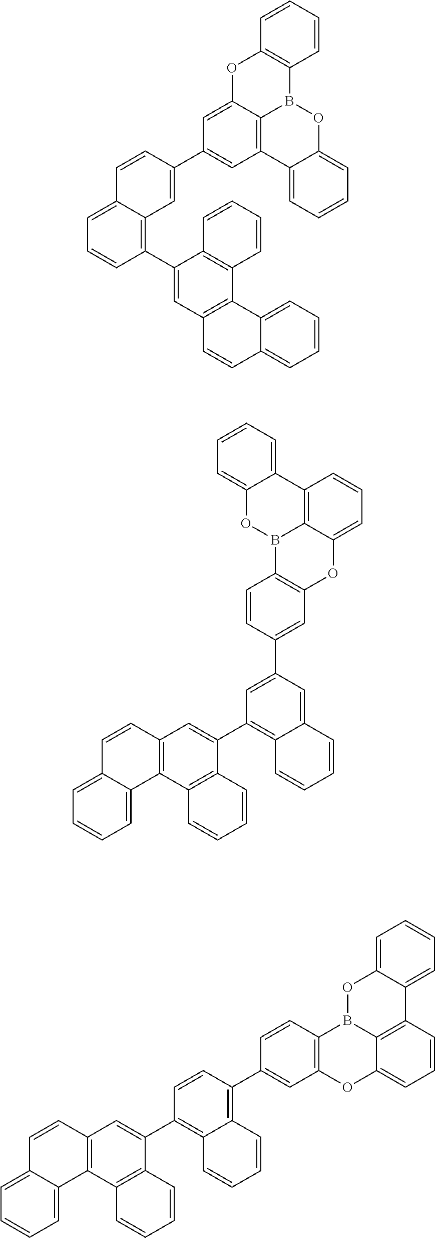 [SMILES: c1ccc2c(c1)Oc1cc(-c3ccc4cccc(-c5cc6ccc7ccccc7c6c6ccccc56)c4c3)cc3c1B2Oc1ccccc1-3 ; c1ccc2c(c1)OB1c3ccc(-c4cc(-c5cc6ccc7ccccc7c6c6ccccc56)c5ccccc5c4)cc3Oc3cccc-2c31 ; c1ccc2c(c1)OB1c3ccc(-c4ccc(-c5cc6ccc7ccccc7c6c6ccccc56)c5ccccc45)cc3Oc3cccc-2c31]

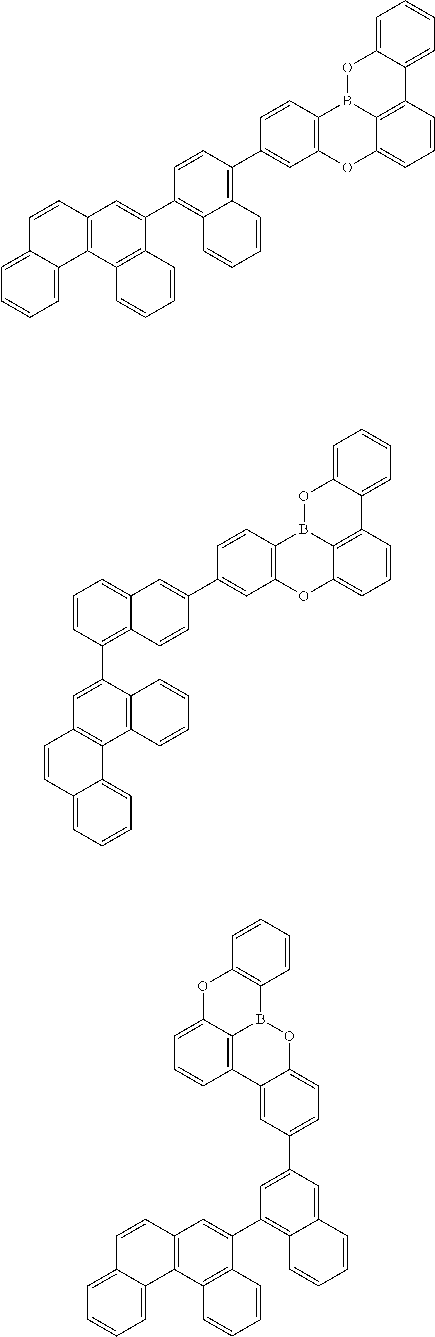 [SMILES: c1ccc2c(c1)OB1c3ccc(-c4ccc(-c5cc6ccc7ccccc7c6c6ccccc56)c5ccccc45)cc3Oc3cccc-2c31 ; c1ccc2c(c1)OB1c3ccc(-c4ccc5c(-c6cc7ccc8ccccc8c7c7ccccc67)cccc5c4)cc3Oc3cccc-2c31 ; c1ccc2c(c1)Oc1cccc3c1B2Oc1ccc(-c2cc(-c4cc5ccc6ccccc6c5c5ccccc45)c4ccccc4c2)cc1-3]

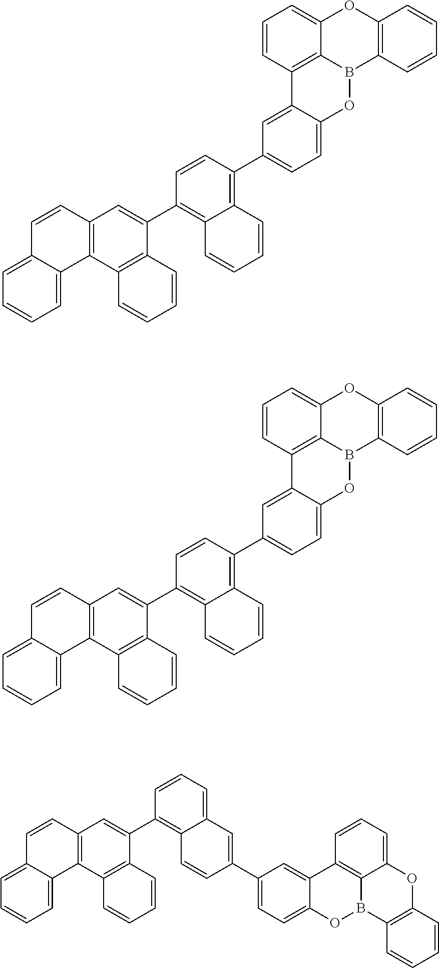 [SMILES: c1ccc2c(c1)Oc1cccc3c1B2Oc1ccc(-c2ccc(-c4cc5ccc6ccccc6c5c5ccccc45)c4ccccc24)cc1-3 ; c1ccc2c(c1)Oc1cccc3c1B2Oc1ccc(-c2ccc(-c4cc5ccc6ccccc6c5c5ccccc45)c4ccccc24)cc1-3 ; c1ccc2c(c1)Oc1cccc3c1B2Oc1ccc(-c2ccc4c(-c5cc6ccc7ccccc7c6c6ccccc56)cccc4c2)cc1-3]

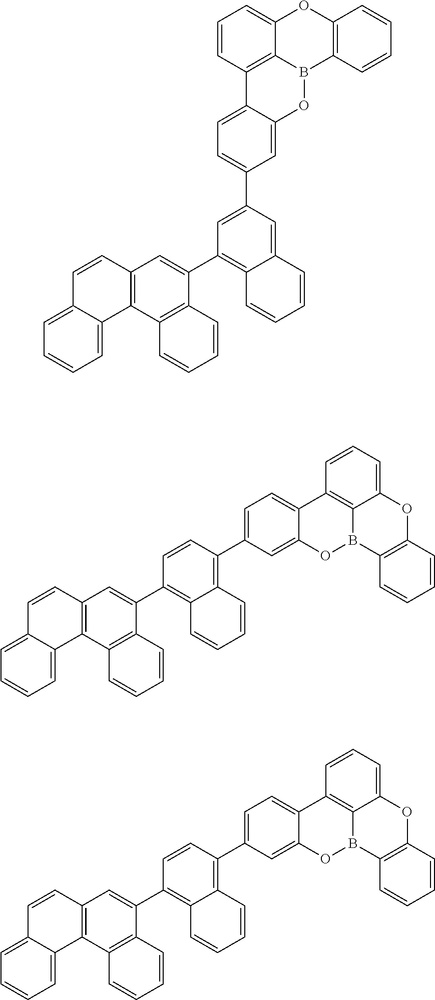 [SMILES: c1ccc2c(c1)Oc1cccc3c1B2Oc1cc(-c2cc(-c4cc5ccc6ccccc6c5c5ccccc45)c4ccccc4c2)ccc1-3 ; c1ccc2c(c1)Oc1cccc3c1B2Oc1cc(-c2ccc(-c4cc5ccc6ccccc6c5c5ccccc45)c4ccccc24)ccc1-3 ; c1ccc2c(c1)Oc1cccc3c1B2Oc1cc(-c2ccc(-c4cc5ccc6ccccc6c5c5ccccc45)c4ccccc24)ccc1-3]

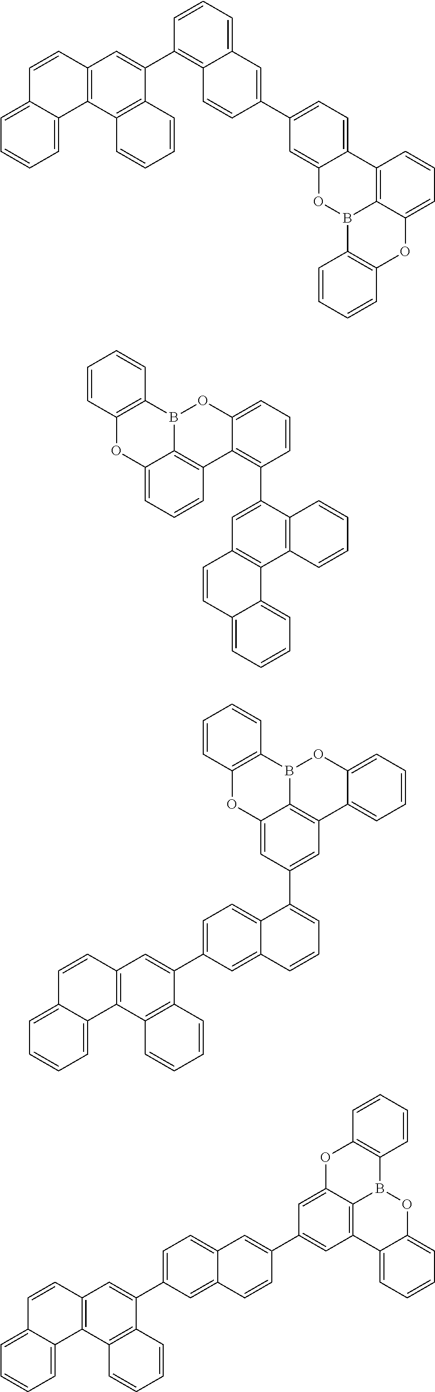 [SMILES: c1ccc2c(c1)Oc1cccc3c1B2Oc1cc(-c2ccc4c(-c5cc6ccc7ccccc7c6c6ccccc56)cccc4c2)ccc1-3 ; c1ccc2c(c1)Oc1cccc3c1B2Oc1cccc(-c2cc4ccc5ccccc5c4c4ccccc24)c1-3 ; c1ccc2c(c1)Oc1cc(-c3cccc4cc(-c5cc6ccc7ccccc7c6c6ccccc56)ccc34)cc3c1B2Oc1ccccc1-3 ; c1ccc2c(c1)Oc1cc(-c3ccc4cc(-c5cc6ccc7ccccc7c6c6ccccc56)ccc4c3)cc3c1B2Oc1ccccc1-3]

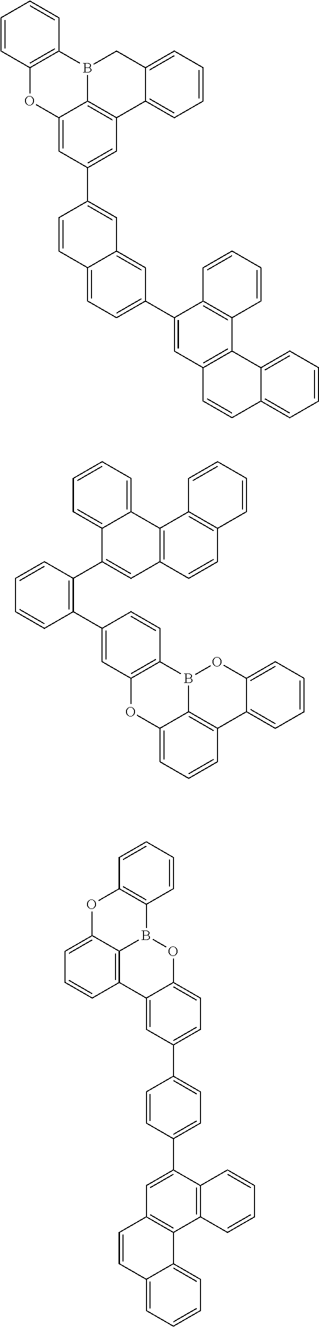

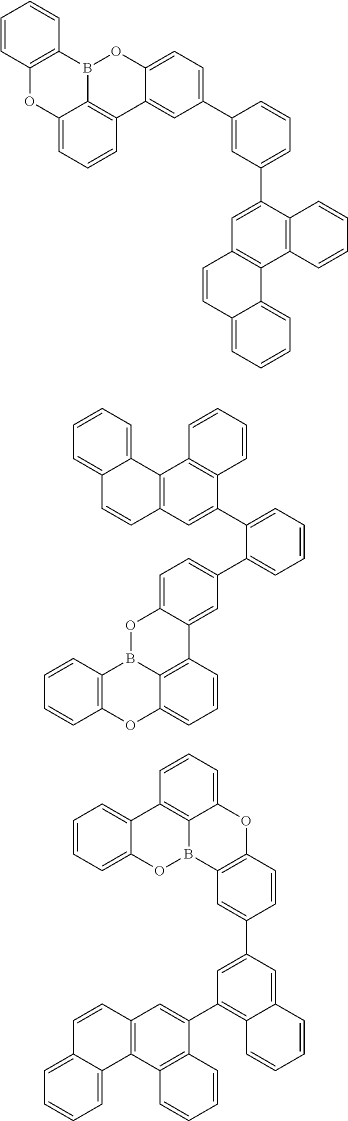

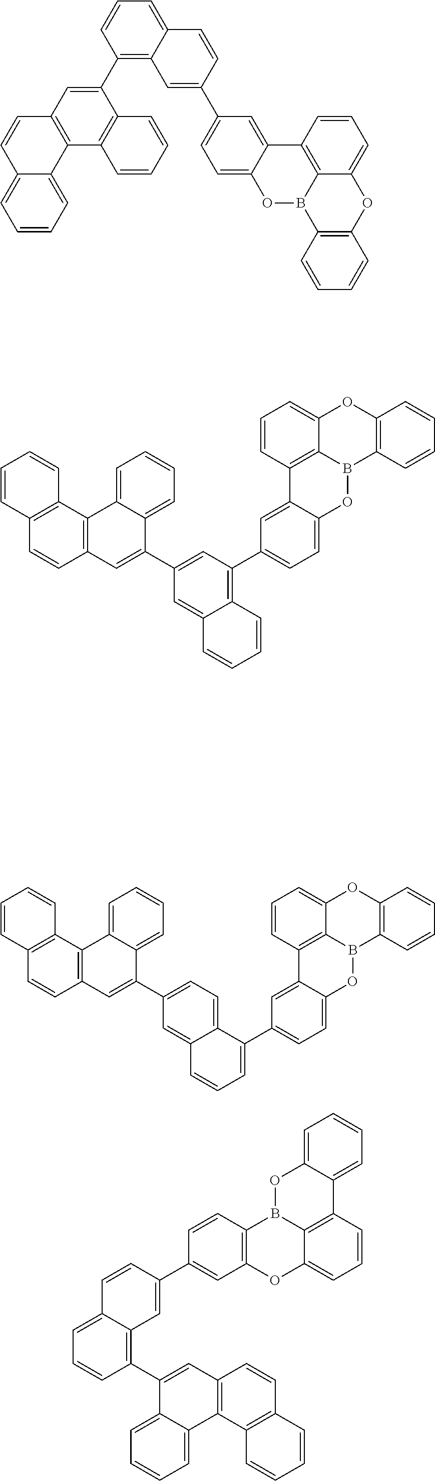 [SMILES: c1ccc2c(c1)Oc1cccc3c1B2Oc1ccc(-c2ccc4cccc(-c5cc6ccc7ccccc7c6c6ccccc56)c4c2)cc1-3 ; c1ccc2c(c1)Oc1cccc3c1B2Oc1ccc(-c2cc(-c4cc5ccc6ccccc6c5c5ccccc45)cc4ccccc24)cc1-3 ; c1ccc2c(c1)Oc1cccc3c1B2Oc1ccc(-c2cccc4cc(-c5cc6ccc7ccccc7c6c6ccccc56)ccc24)cc1-3 ; c1ccc2c(c1)OB1c3ccc(-c4ccc5cccc(-c6cc7ccc8ccccc8c7c7ccccc67)c5c4)cc3Oc3cccc-2c31]

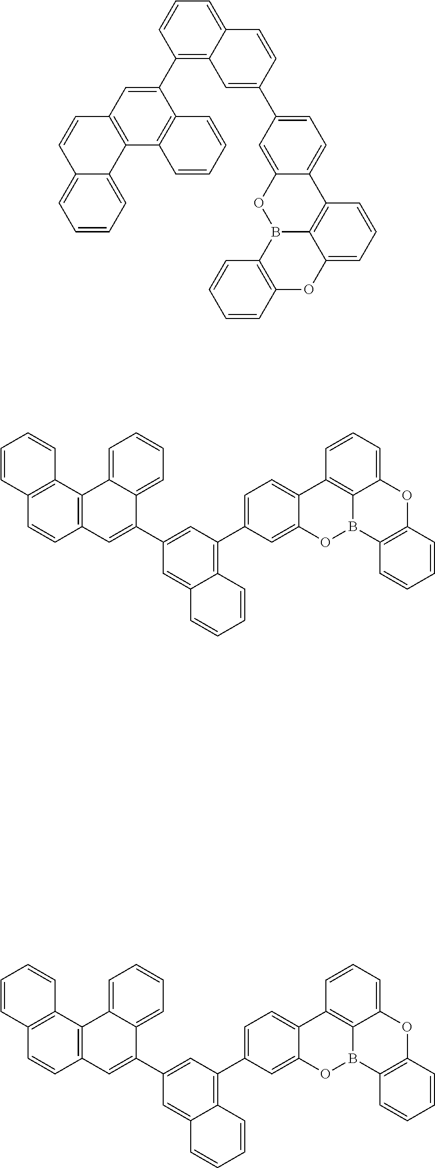 [SMILES: c1ccc2c(c1)Oc1cccc3c1B2Oc1cc(-c2ccc4cccc(-c5cc6ccc7ccccc7c6c6ccccc56)c4c2)ccc1-3 ; c1ccc2c(c1)Oc1cccc3c1B2Oc1cc(-c2cc(-c4cc5ccc6ccccc6c5c5ccccc45)cc4ccccc24)ccc1-3 ; c1ccc2c(c1)Oc1cccc3c1B2Oc1cc(-c2cc(-c4cc5ccc6ccccc6c5c5ccccc45)cc4ccccc24)ccc1-3]

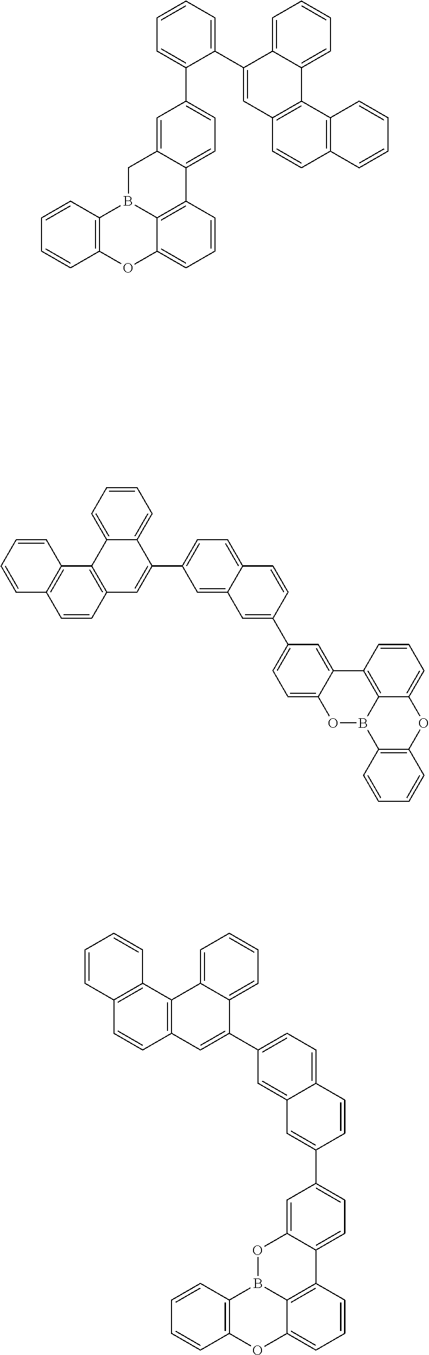 [SMILES: c1ccc2c(c1)Oc1cccc3c1B2Cc1cc(-c2ccccc2-c2cc4ccc5ccccc5c4c4ccccc24)ccc1-3 ; c1ccc2c(c1)Oc1cccc3c1B2Oc1ccc(-c2ccc4ccc(-c5cc6ccc7ccccc7c6c6ccccc56)cc4c2)cc1-3 ; c1ccc2c(c1)Oc1cccc3c1B2Oc1cc(-c2ccc4ccc(-c5cc6ccc7ccccc7c6c6ccccc56)cc4c2)ccc1-3]

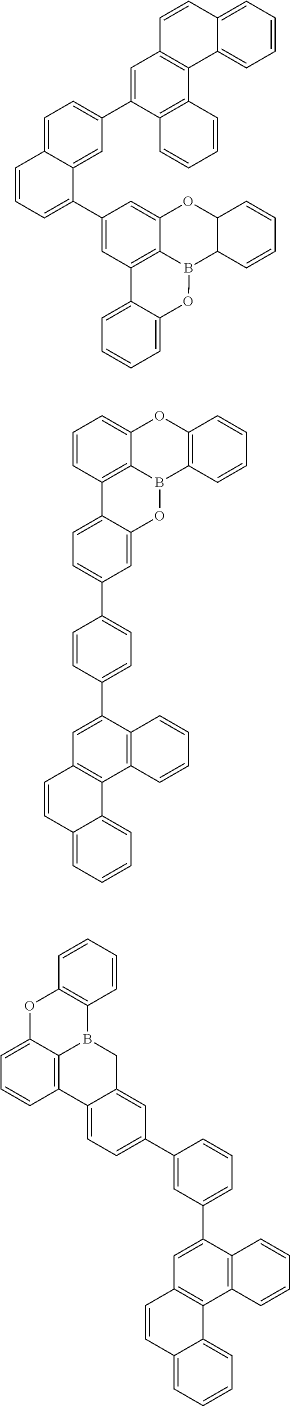 [SMILES: C1=CC2Oc3cc(-c4cccc5ccc(-c6cc7ccc8ccccc8c7c7ccccc67)cc45)cc4c3B(Oc3ccccc3-4)C2C=C1 ; c1ccc2c(c1)Oc1cccc3c1B2Oc1cc(-c2ccc(-c4cc5ccc6ccccc6c5c5ccccc45)cc2)ccc1-3 ; c1cc(-c2ccc3c(c2)CB2c4ccccc4Oc4cccc-3c42)cc(-c2cc3ccc4ccccc4c3c3ccccc23)c1]

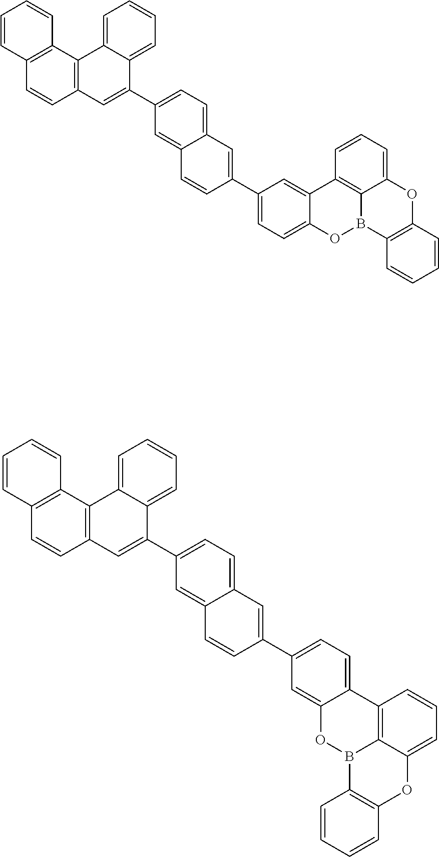 [SMILES: c1ccc2c(c1)Oc1cccc3c1B2Oc1ccc(-c2ccc4cc(-c5cc6ccc7ccccc7c6c6ccccc56)ccc4c2)cc1-3 ; c1ccc2c(c1)Oc1cccc3c1B2Oc1cc(-c2ccc4cc(-c5cc6ccc7ccccc7c6c6ccccc56)ccc4c2)ccc1-3]

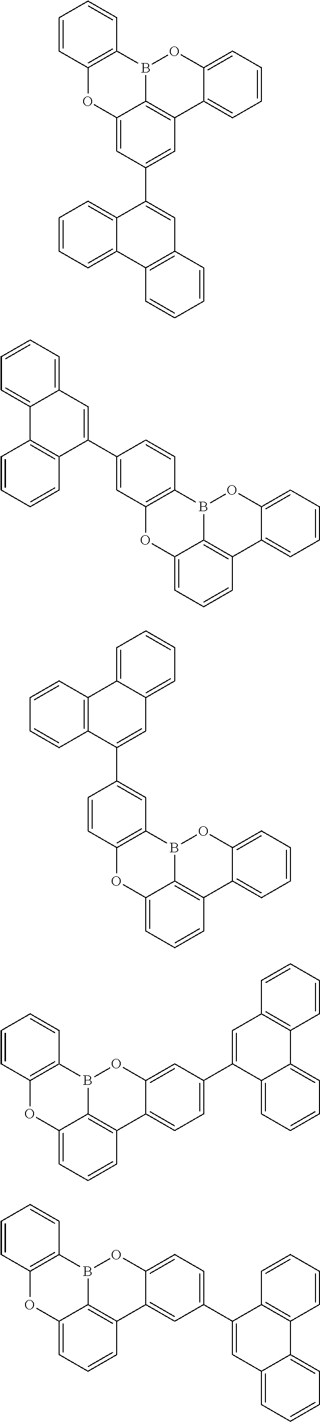 [SMILES: c1ccc2c(c1)Oc1cc(-c3cc4ccccc4c4ccccc34)cc3c1B2Oc1ccccc1-3 ; c1ccc2c(c1)OB1c3ccc(-c4cc5ccccc5c5ccccc45)cc3Oc3cccc-2c31 ; c1ccc2c(c1)OB1c3cc(-c4cc5ccccc5c5ccccc45)ccc3Oc3cccc-2c31 ; c1ccc2c(c1)Oc1cccc3c1B2Oc1cc(-c2cc4ccccc4c4ccccc24)ccc1-3 ; c1ccc2c(c1)Oc1cccc3c1B2Oc1ccc(-c2cc4ccccc4c4ccccc24)cc1-3]

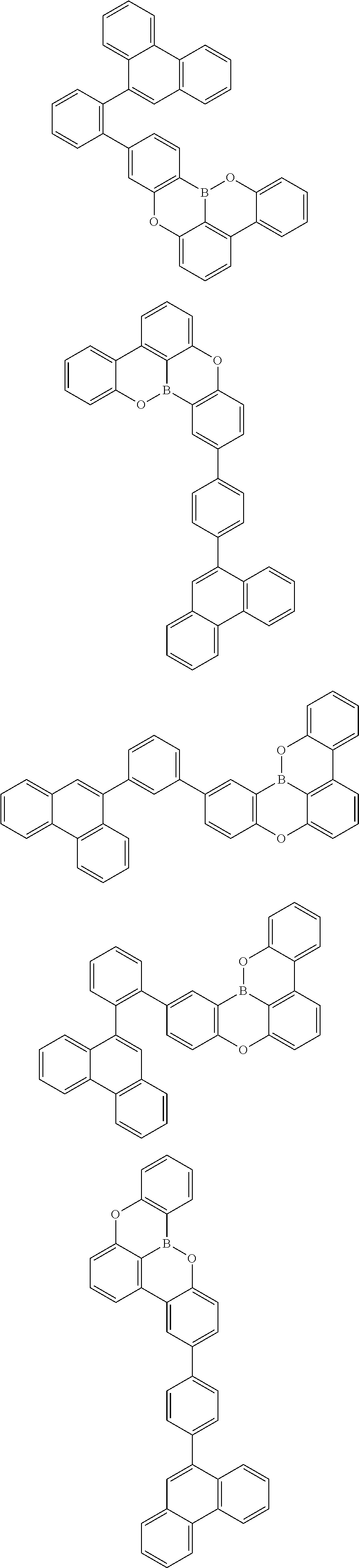

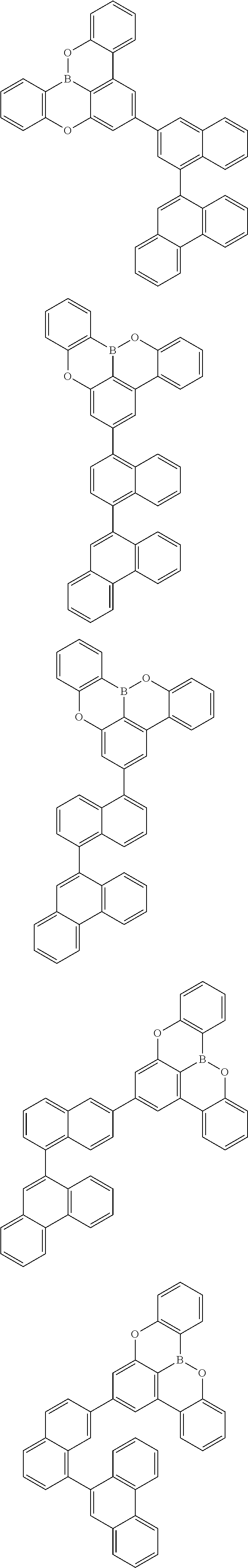

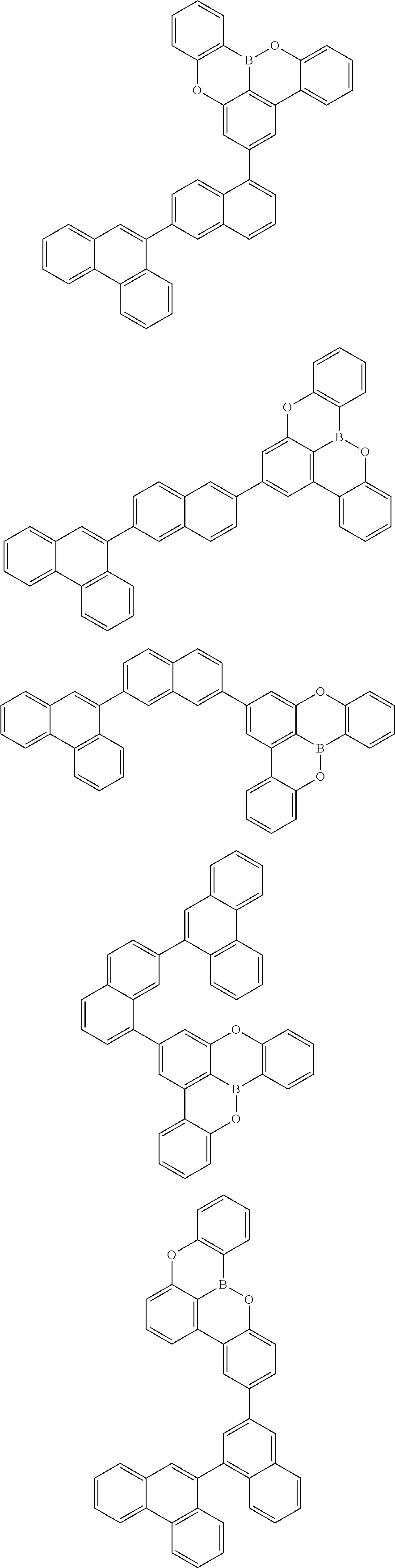

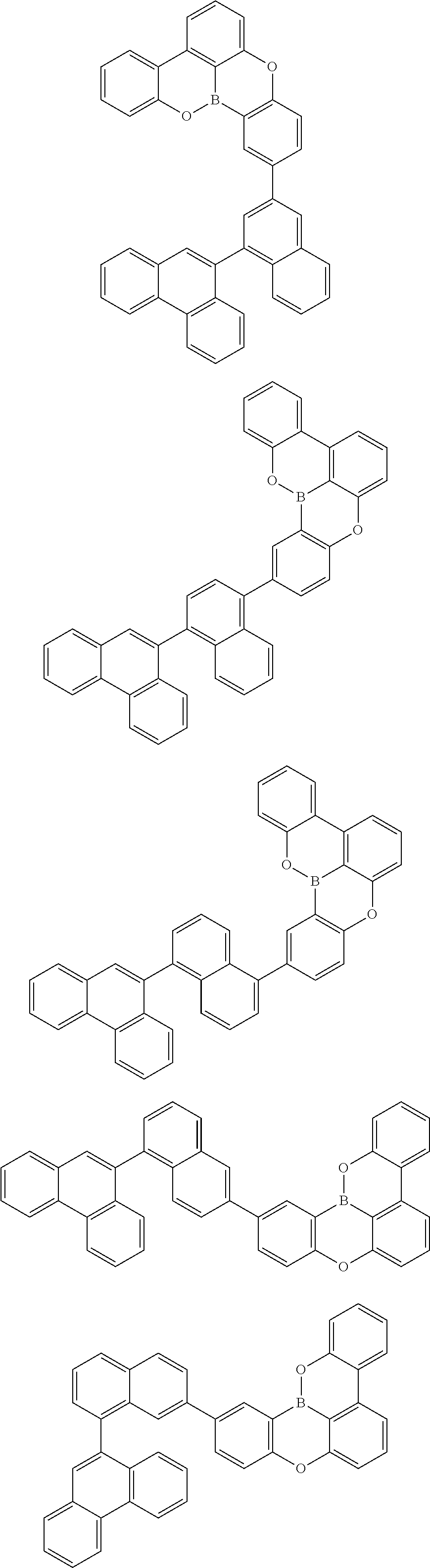

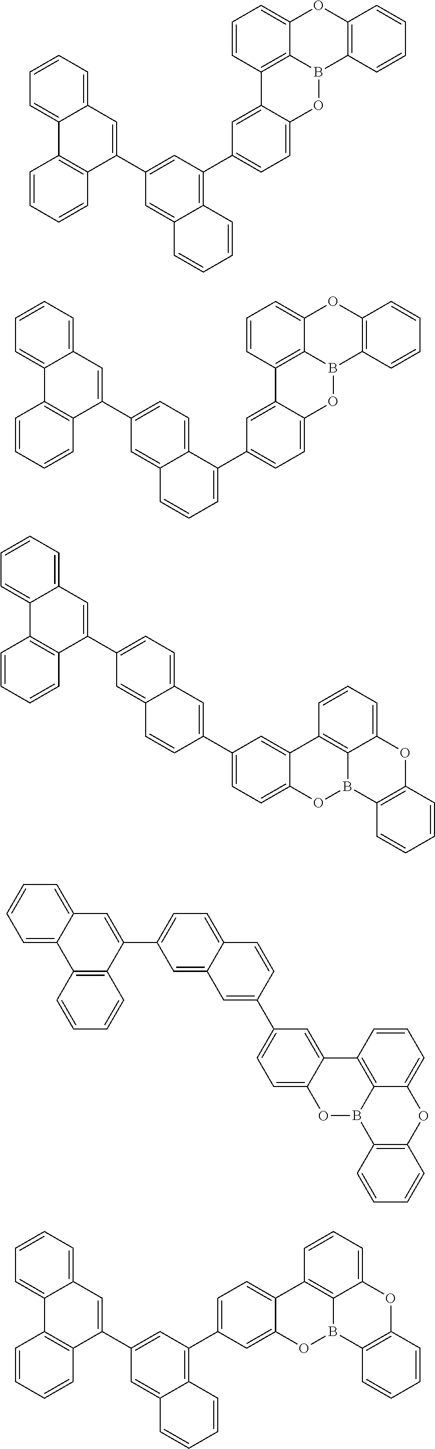 [SMILES: c1ccc2c(c1)Oc1cccc3c1B2Oc1ccc(-c2cc(-c4cc5ccccc5c5ccccc45)cc4ccccc24)cc1-3 ; c1ccc2c(c1)Oc1cccc3c1B2Oc1ccc(-c2cccc4cc(-c5cc6ccccc6c6ccccc56)ccc24)cc1-3 ; c1ccc2c(c1)Oc1cccc3c1B2Oc1ccc(-c2ccc4cc(-c5cc6ccccc6c6ccccc56)ccc4c2)cc1-3 ; c1ccc2c(c1)Oc1cccc3c1B2Oc1ccc(-c2ccc4ccc(-c5cc6ccccc6c6ccccc56)cc4c2)cc1-3 ; c1ccc2c(c1)Oc1cccc3c1B2Oc1cc(-c2cc(-c4cc5ccccc5c5ccccc45)cc4ccccc24)ccc1-3]

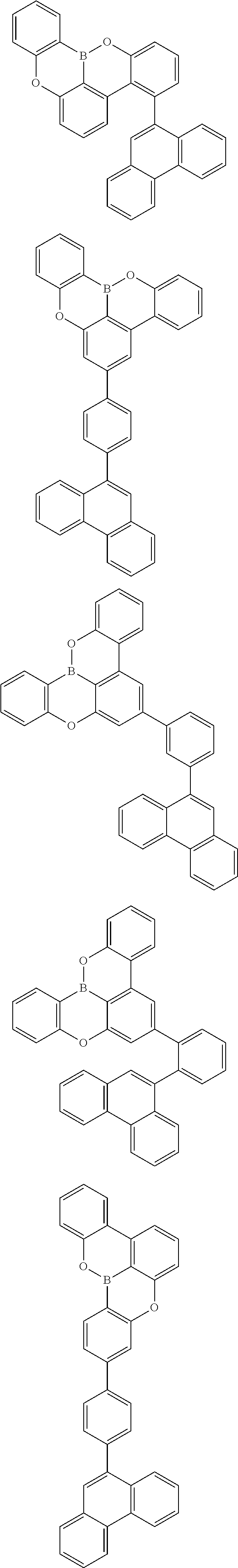

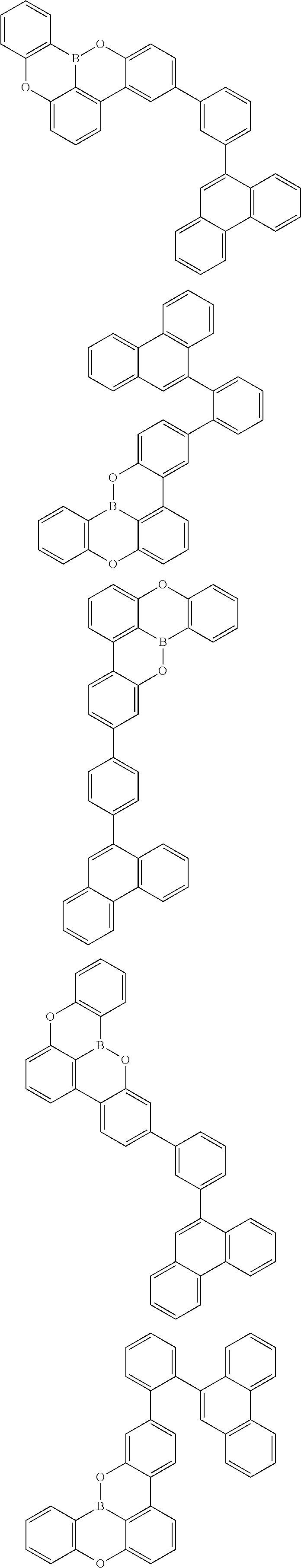

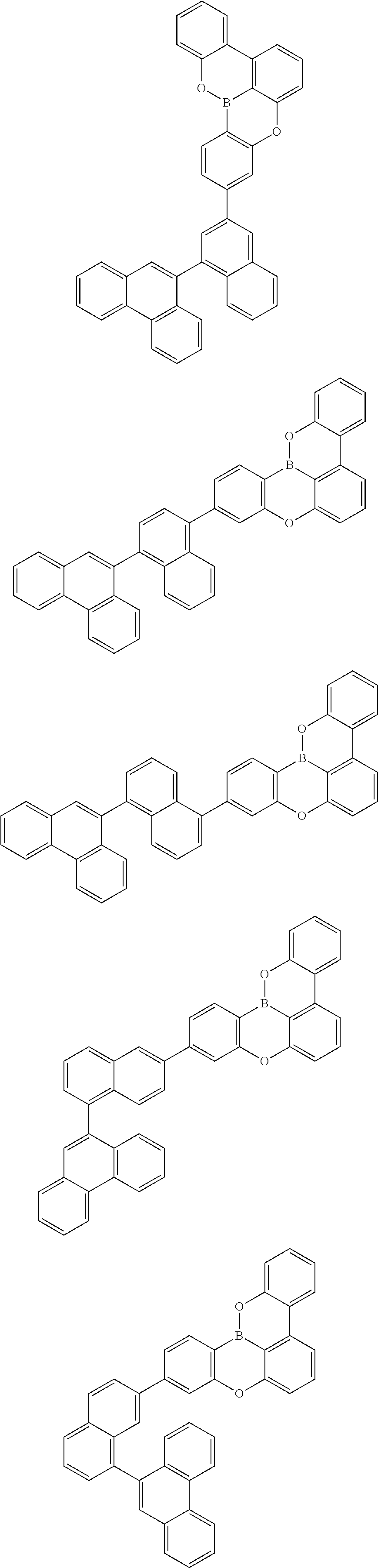 [SMILES: c1ccc2c(c1)OB1c3ccc(-c4cc(-c5cc6ccccc6c6ccccc56)c5ccccc5c4)cc3Oc3cccc-2c31 ; c1ccc2c(c1)OB1c3ccc(-c4ccc(-c5cc6ccccc6c6ccccc56)c5ccccc45)cc3Oc3cccc-2c31 ; c1ccc2c(c1)OB1c3ccc(-c4cccc5c(-c6cc7ccccc7c7ccccc67)cccc45)cc3Oc3cccc-2c31 ; c1ccc2c(c1)OB1c3ccc(-c4ccc5c(-c6cc7ccccc7c7ccccc67)cccc5c4)cc3Oc3cccc-2c31 ; c1ccc2c(c1)OB1c3ccc(-c4ccc5cccc(-c6cc7ccccc7c7ccccc67)c5c4)cc3Oc3cccc-2c31]

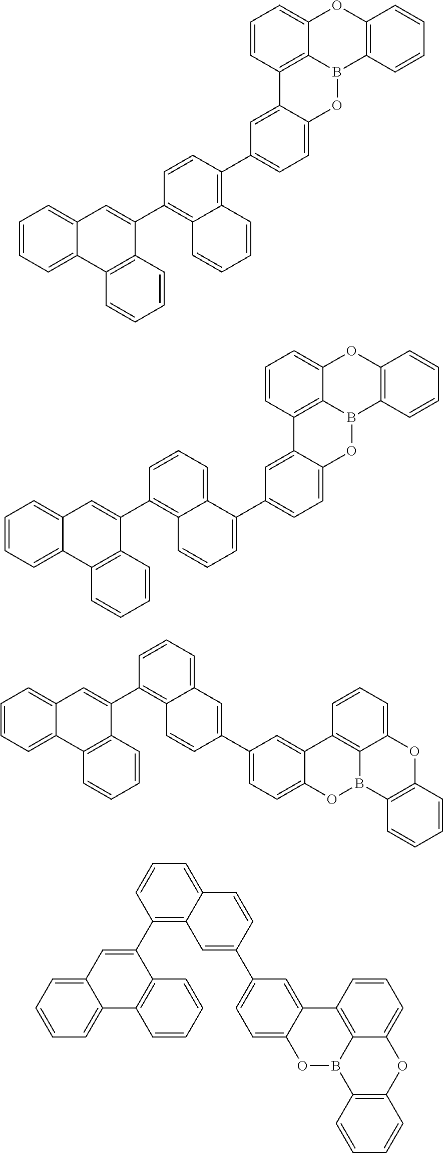

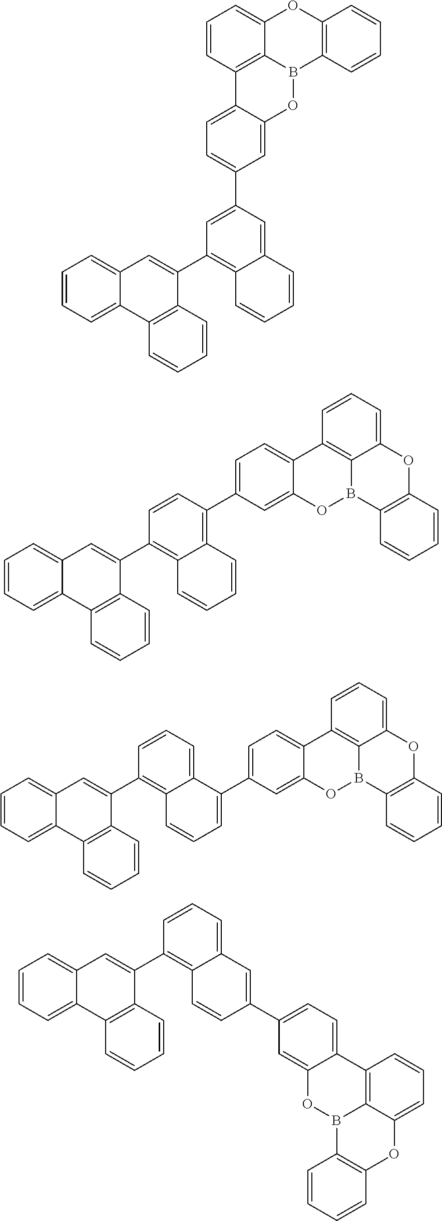 [SMILES: c1ccc2c(c1)Oc1cccc3c1B2Oc1cc(-c2cc(-c4cc5ccccc5c5ccccc45)c4ccccc4c2)ccc1-3 ; c1ccc2c(c1)Oc1cccc3c1B2Oc1cc(-c2ccc(-c4cc5ccccc5c5ccccc45)c4ccccc24)ccc1-3 ; c1ccc2c(c1)Oc1cccc3c1B2Oc1cc(-c2cccc4c(-c5cc6ccccc6c6ccccc56)cccc24)ccc1-3 ; c1ccc2c(c1)Oc1cccc3c1B2Oc1cc(-c2ccc4c(-c5cc6ccccc6c6ccccc56)cccc4c2)ccc1-3]

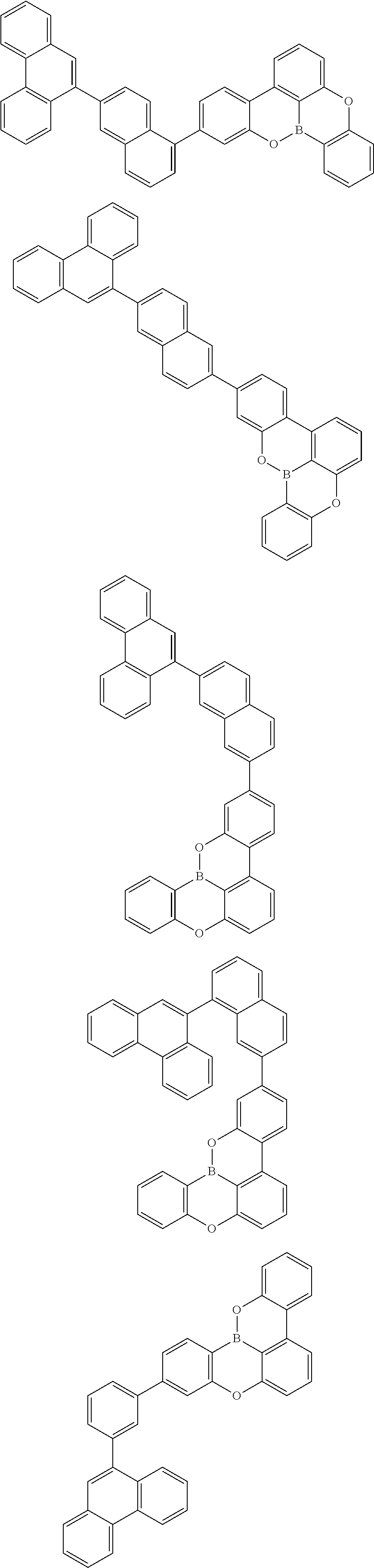

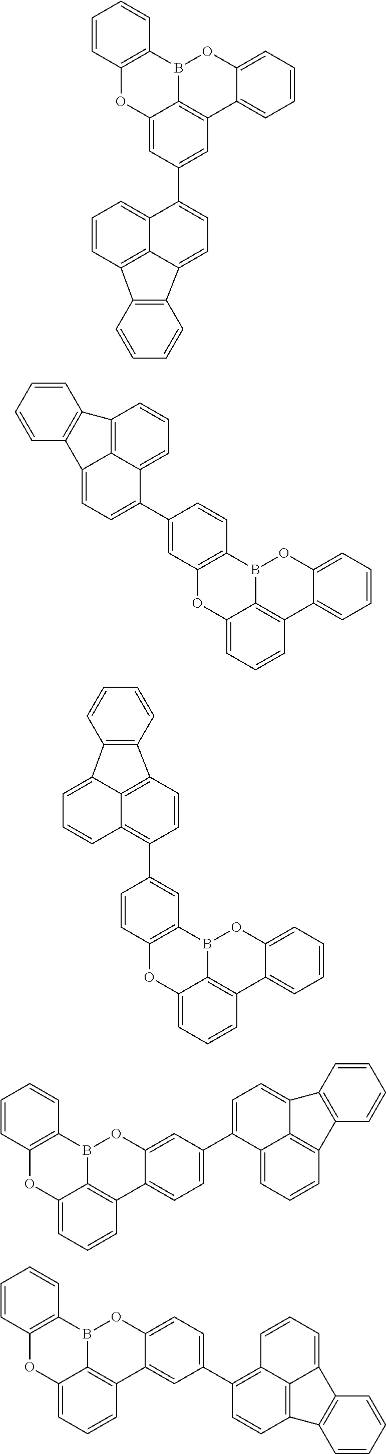

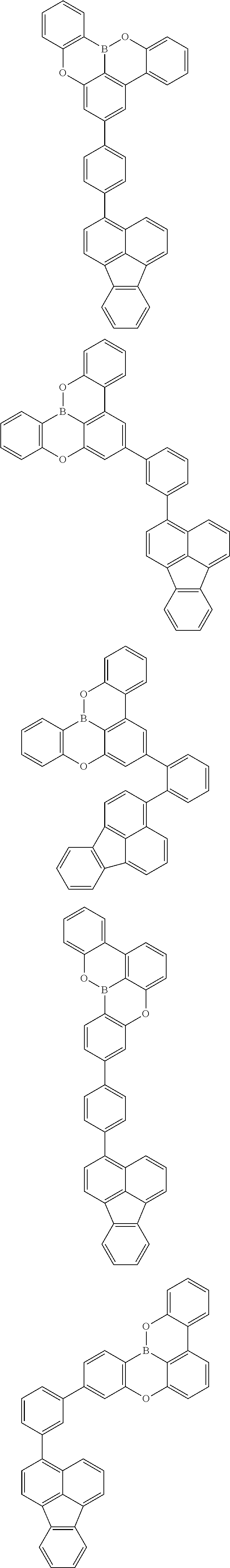

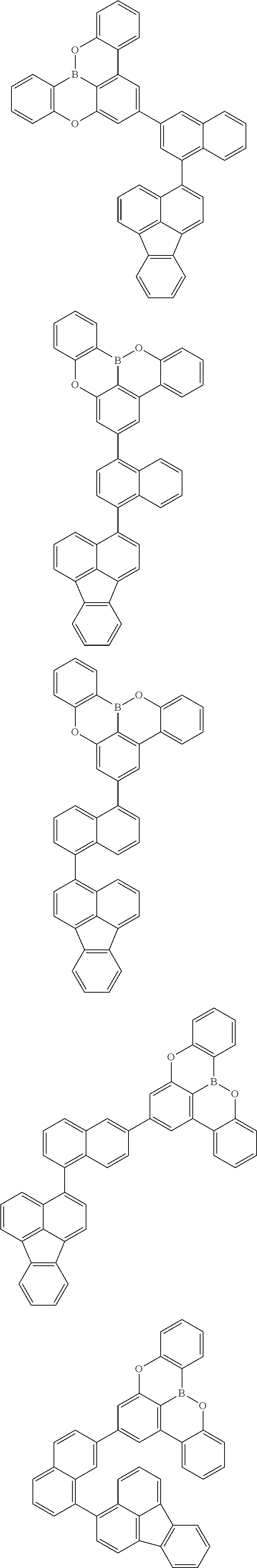

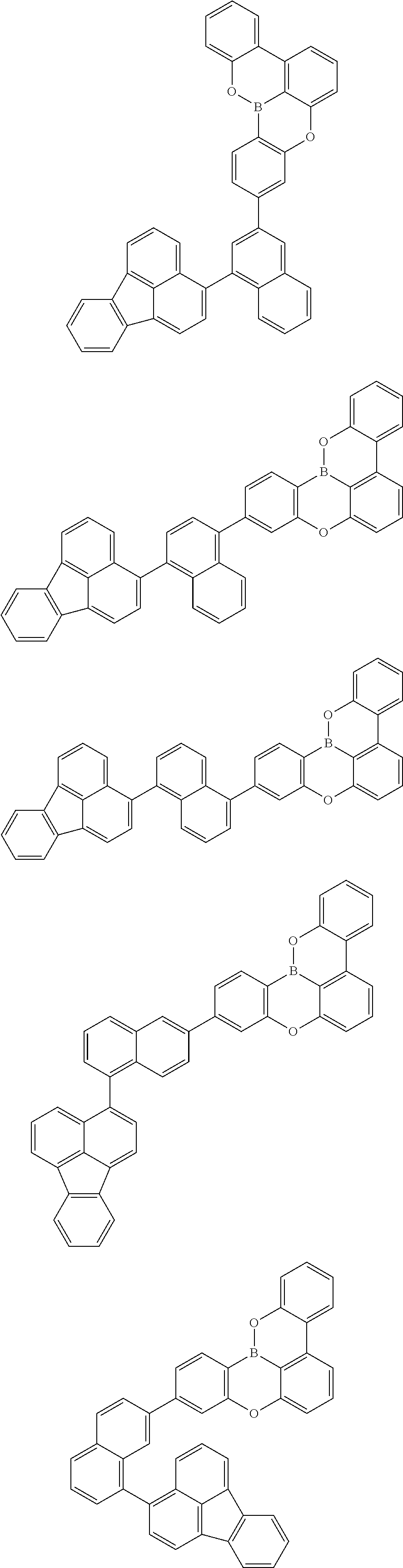 [SMILES: c1ccc2c(c1)OB1c3ccc(-c4cc(-c5ccc6c7c(cccc57)-c5ccccc5-6)c5ccccc5c4)cc3Oc3cccc-2c31 ; c1ccc2c(c1)OB1c3ccc(-c4ccc(-c5ccc6c7c(cccc57)-c5ccccc5-6)c5ccccc45)cc3Oc3cccc-2c31 ; c1ccc2c(c1)OB1c3ccc(-c4cccc5c(-c6ccc7c8c(cccc68)-c6ccccc6-7)cccc45)cc3Oc3cccc-2c31 ; c1ccc2c(c1)OB1c3ccc(-c4ccc5c(-c6ccc7c8c(cccc68)-c6ccccc6-7)cccc5c4)cc3Oc3cccc-2c31 ; c1ccc2c(c1)OB1c3ccc(-c4ccc5cccc(-c6ccc7c8c(cccc68)-c6ccccc6-7)c5c4)cc3Oc3cccc-2c31]

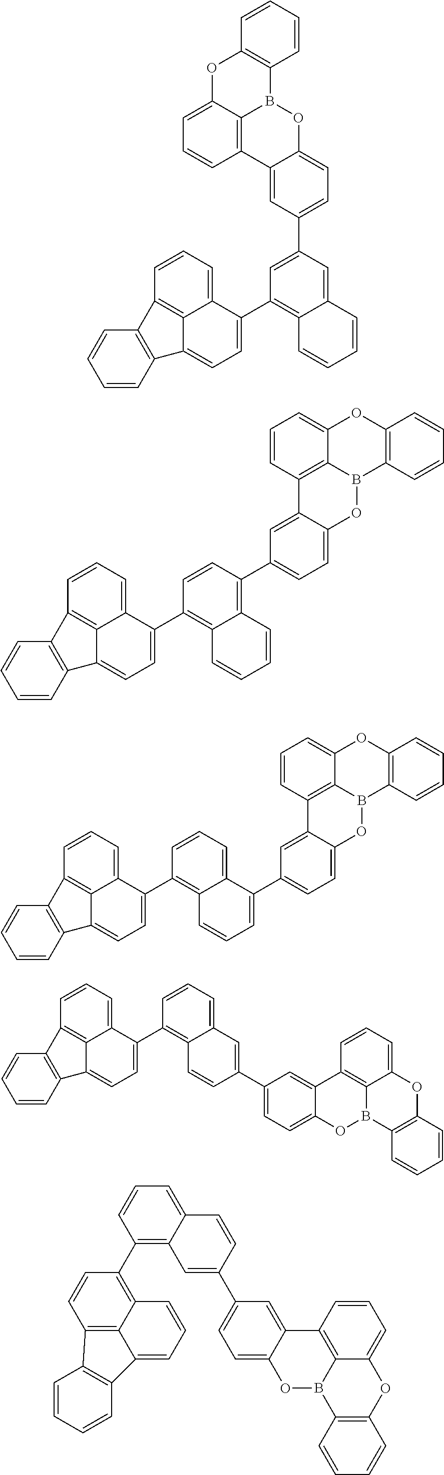

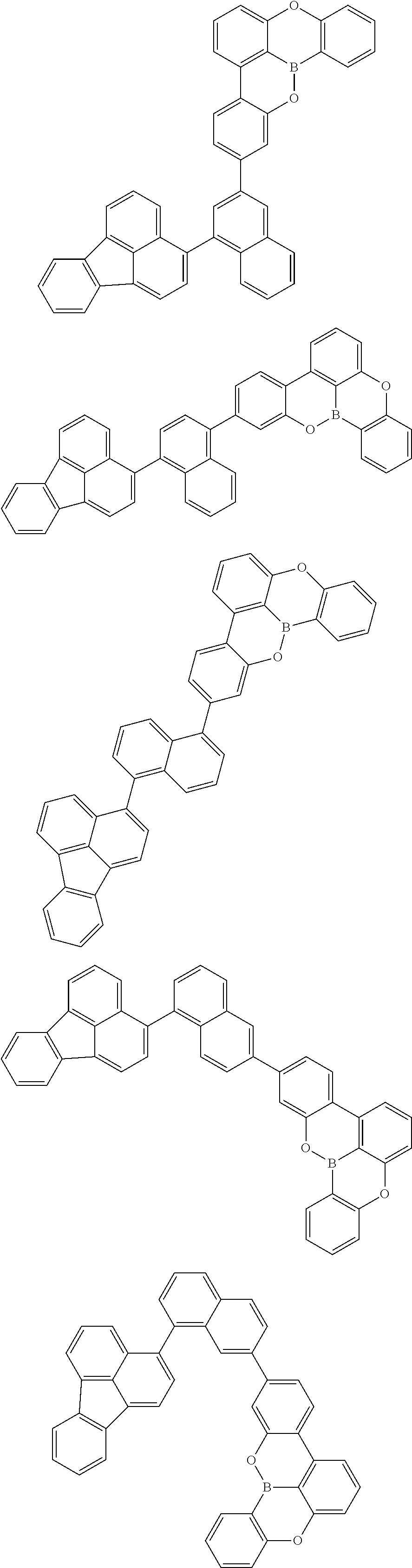

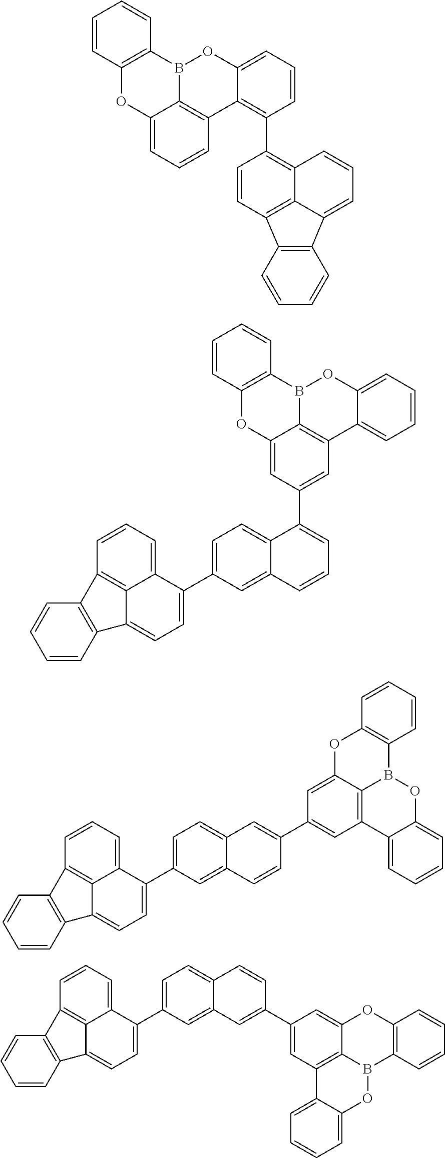

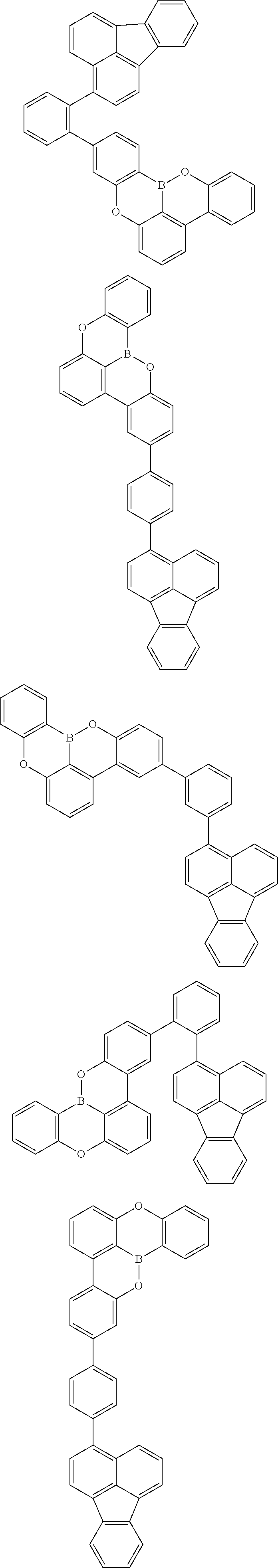

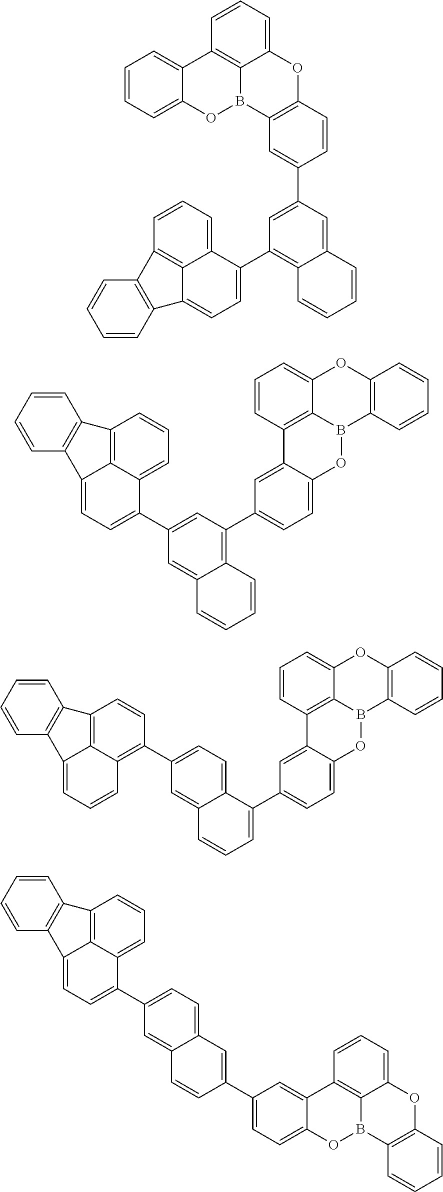 [SMILES: c1ccc2c(c1)OB1c3cc(-c4cc(-c5ccc6c7c(cccc57)-c5ccccc5-6)c5ccccc5c4)ccc3Oc3cccc-2c31 ; c1ccc2c(c1)Oc1cccc3c1B2Oc1ccc(-c2cc(-c4ccc5c6c(cccc46)-c4ccccc4-5)cc4ccccc24)cc1-3 ; c1ccc2c(c1)Oc1cccc3c1B2Oc1ccc(-c2cccc4cc(-c5ccc6c7c(cccc57)-c5ccccc5-6)ccc24)cc1-3 ; c1ccc2c(c1)Oc1cccc3c1B2Oc1ccc(-c2ccc4cc(-c5ccc6c7c(cccc57)-c5ccccc5-6)ccc4c2)cc1-3]

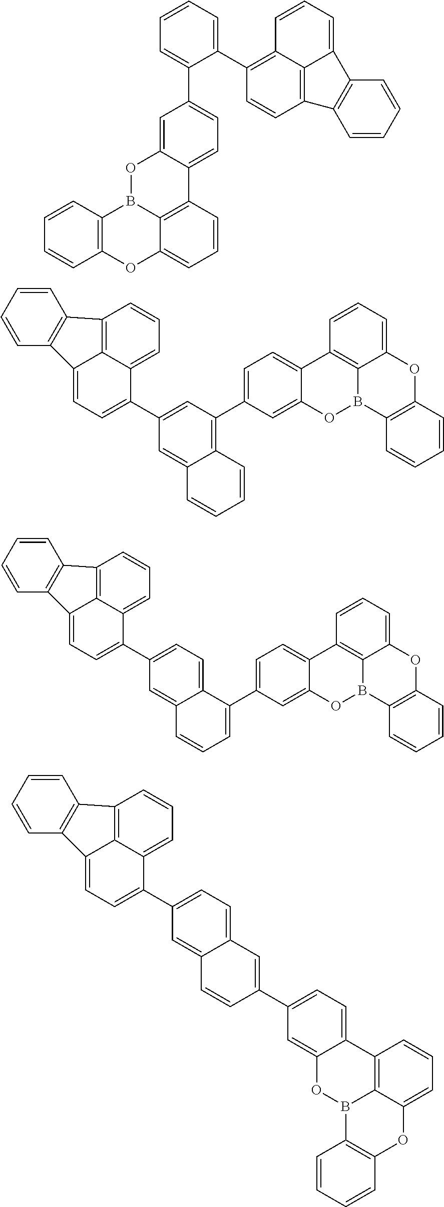

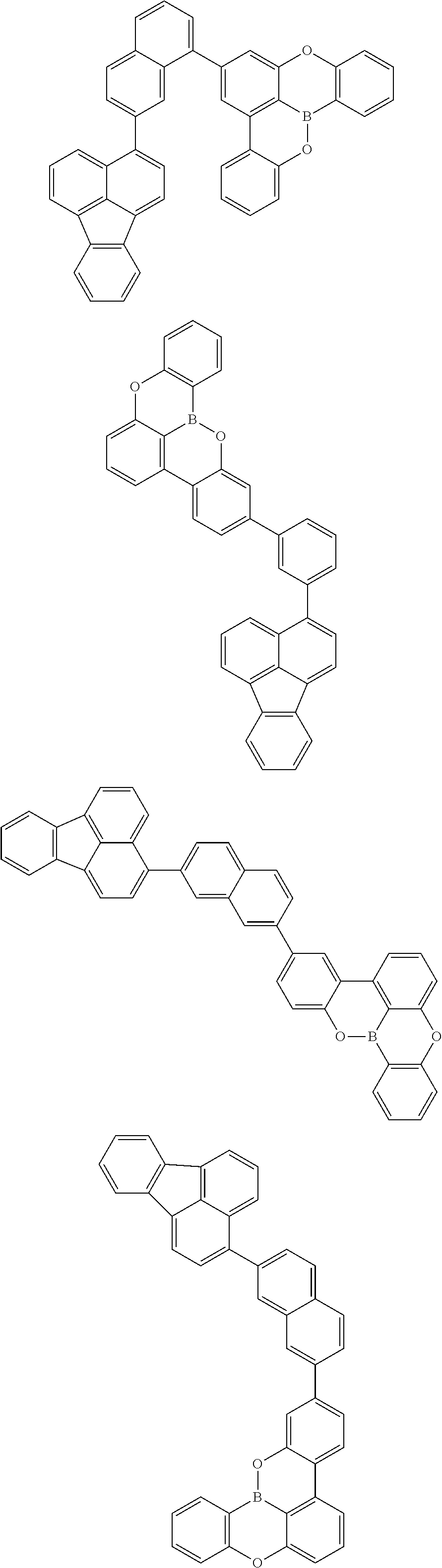 [SMILES: c1ccc2c(c1)Oc1cc(-c3cccc4ccc(-c5ccc6c7c(cccc57)-c5ccccc5-6)cc34)cc3c1B2Oc1ccccc1-3 ; c1cc(-c2ccc3c(c2)OB2c4ccccc4Oc4cccc-3c42)cc(-c2ccc3c4c(cccc24)-c2ccccc2-3)c1 ; c1ccc2c(c1)Oc1cccc3c1B2Oc1ccc(-c2ccc4ccc(-c5ccc6c7c(cccc57)-c5ccccc5-6)cc4c2)cc1-3 ; c1ccc2c(c1)Oc1cccc3c1B2Oc1cc(-c2ccc4ccc(-c5ccc6c7c(cccc57)-c5ccccc5-6)cc4c2)ccc1-3]

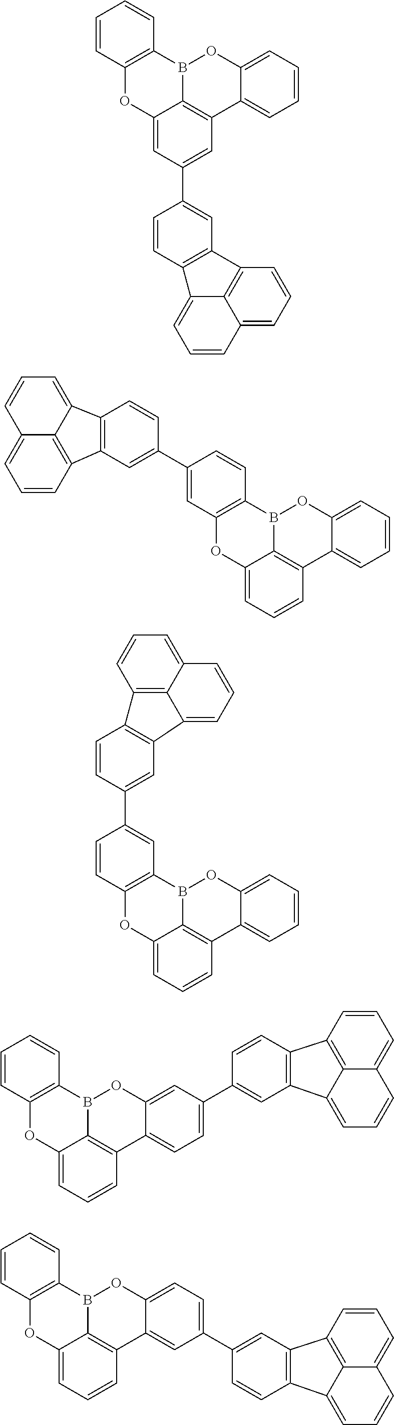 [SMILES: c1ccc2c(c1)Oc1cc(-c3ccc4c(c3)-c3cccc5cccc-4c35)cc3c1B2Oc1ccccc1-3 ; c1ccc2c(c1)OB1c3ccc(-c4ccc5c(c4)-c4cccc6cccc-5c46)cc3Oc3cccc-2c31 ; c1ccc2c(c1)OB1c3cc(-c4ccc5c(c4)-c4cccc6cccc-5c46)ccc3Oc3cccc-2c31 ; c1ccc2c(c1)Oc1cccc3c1B2Oc1cc(-c2ccc4c(c2)-c2cccc5cccc-4c25)ccc1-3 ; c1ccc2c(c1)Oc1cccc3c1B2Oc1ccc(-c2ccc4c(c2)-c2cccc5cccc-4c25)cc1-3]

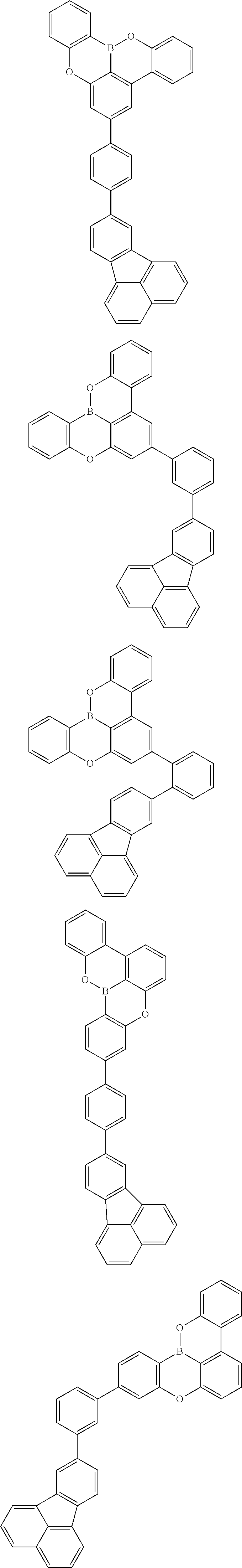

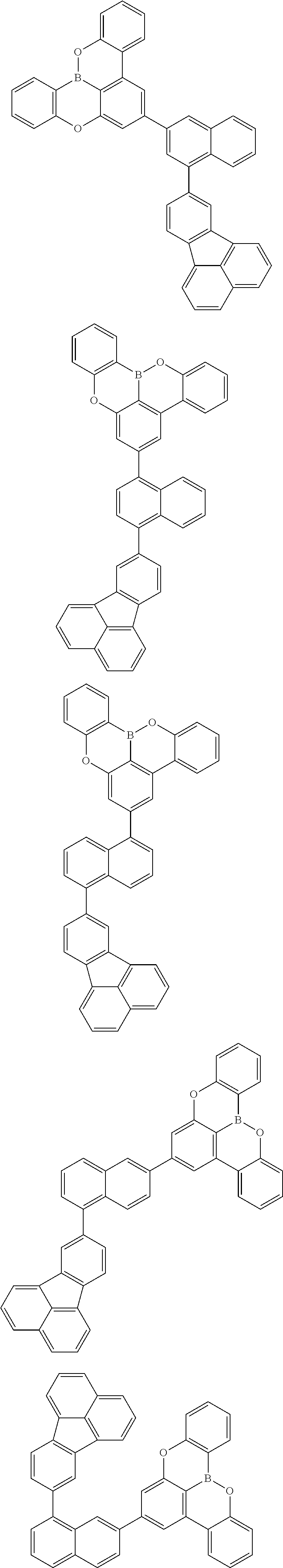

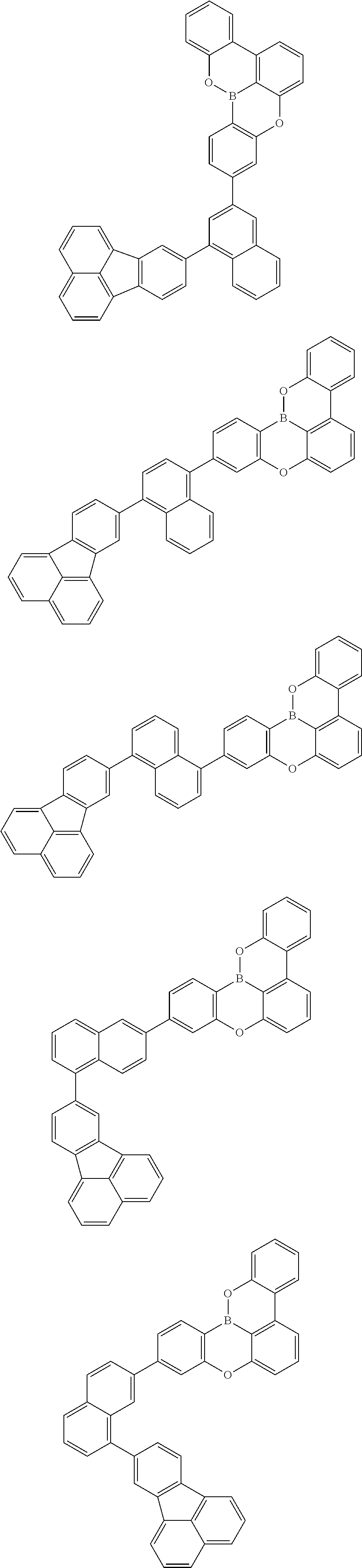 [SMILES: c1ccc2c(c1)OB1c3ccc(-c4cc(-c5ccc6c(c5)-c5cccc7cccc-6c57)c5ccccc5c4)cc3Oc3cccc-2c31 ; c1ccc2c(c1)OB1c3ccc(-c4ccc(-c5ccc6c(c5)-c5cccc7cccc-6c57)c5ccccc45)cc3Oc3cccc-2c31 ; c1ccc2c(c1)OB1c3ccc(-c4cccc5c(-c6ccc7c(c6)-c6cccc8cccc-7c68)cccc45)cc3Oc3cccc-2c31 ; c1ccc2c(c1)OB1c3ccc(-c4ccc5c(-c6ccc7c(c6)-c6cccc8cccc-7c68)cccc5c4)cc3Oc3cccc-2c31 ; c1ccc2c(c1)OB1c3ccc(-c4ccc5cccc(-c6ccc7c(c6)-c6cccc8cccc-7c68)c5c4)cc3Oc3cccc-2c31]

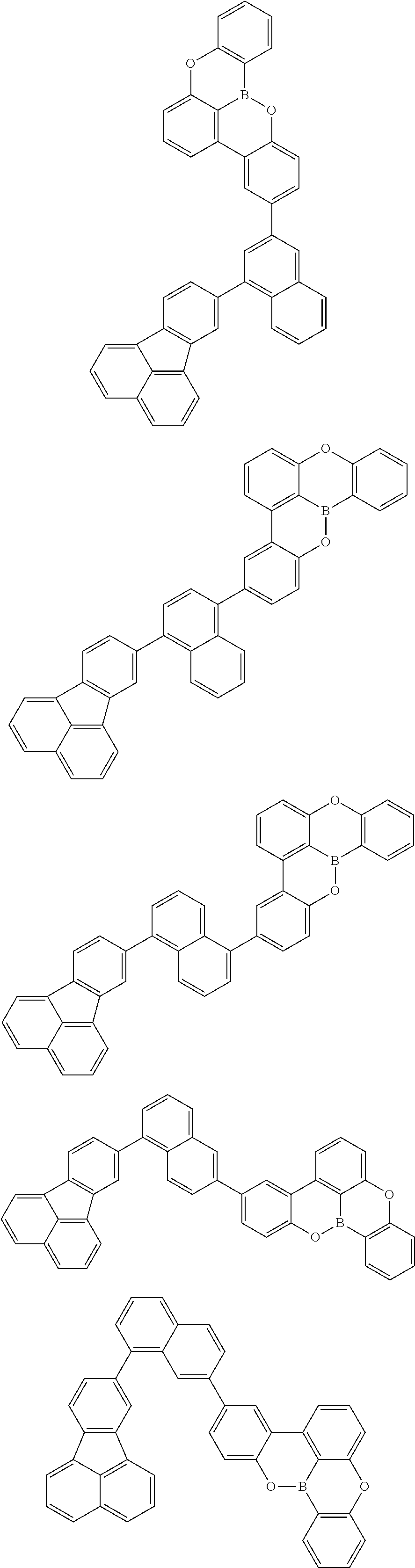 [SMILES: c1ccc2c(c1)Oc1cccc3c1B2Oc1ccc(-c2cc(-c4ccc5c(c4)-c4cccc6cccc-5c46)c4ccccc4c2)cc1-3 ; c1ccc2c(c1)Oc1cccc3c1B2Oc1ccc(-c2ccc(-c4ccc5c(c4)-c4cccc6cccc-5c46)c4ccccc24)cc1-3 ; c1ccc2c(c1)Oc1cccc3c1B2Oc1ccc(-c2cccc4c(-c5ccc6c(c5)-c5cccc7cccc-6c57)cccc24)cc1-3 ; c1ccc2c(c1)Oc1cccc3c1B2Oc1ccc(-c2ccc4c(-c5ccc6c(c5)-c5cccc7cccc-6c57)cccc4c2)cc1-3 ; c1ccc2c(c1)Oc1cccc3c1B2Oc1ccc(-c2ccc4cccc(-c5ccc6c(c5)-c5cccc7cccc-6c57)c4c2)cc1-3]

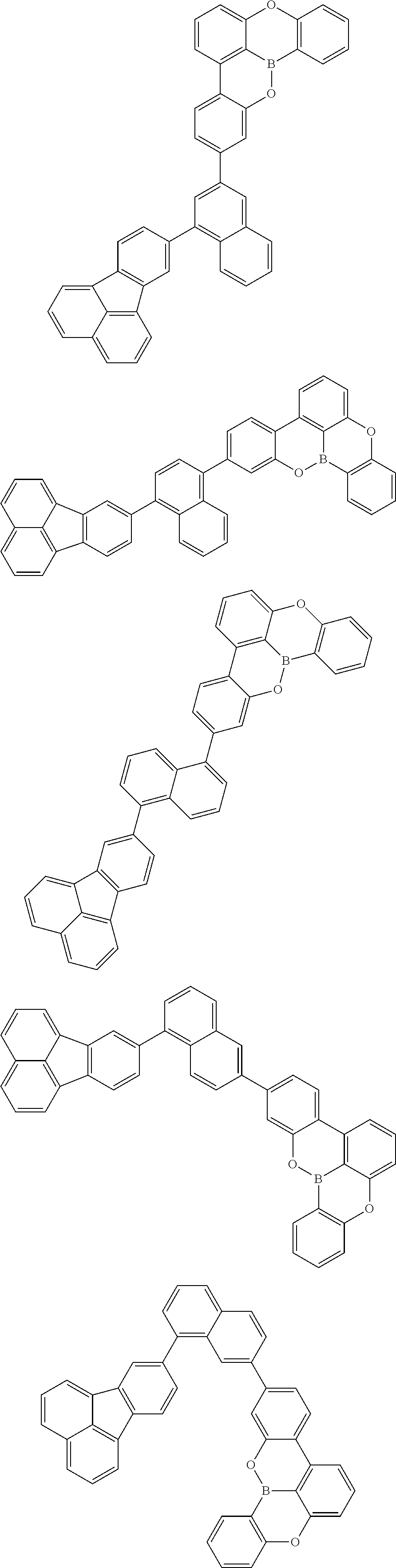 [SMILES: c1ccc2c(c1)Oc1cccc3c1B2Oc1cc(-c2cc(-c4ccc5c(c4)-c4cccc6cccc-5c46)c4ccccc4c2)ccc1-3 ; c1ccc2c(c1)Oc1cccc3c1B2Oc1cc(-c2ccc(-c4ccc5c(c4)-c4cccc6cccc-5c46)c4ccccc24)ccc1-3 ; c1ccc2c(c1)Oc1cccc3c1B2Oc1cc(-c2cccc4c(-c5ccc6c(c5)-c5cccc7cccc-6c57)cccc24)ccc1-3 ; c1ccc2c(c1)Oc1cccc3c1B2Oc1cc(-c2ccc4c(-c5ccc6c(c5)-c5cccc7cccc-6c57)cccc4c2)ccc1-3 ; c1ccc2c(c1)Oc1cccc3c1B2Oc1cc(-c2ccc4cccc(-c5ccc6c(c5)-c5cccc7cccc-6c57)c4c2)ccc1-3]

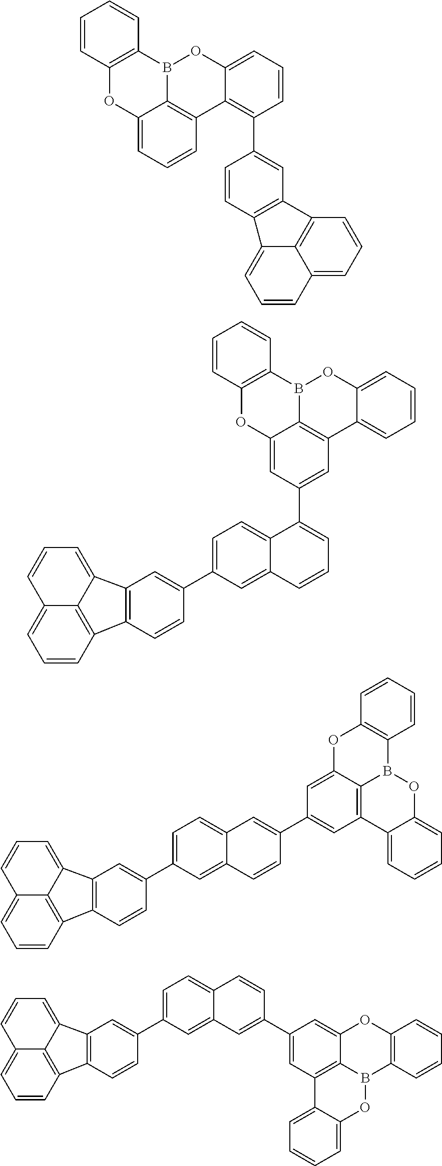

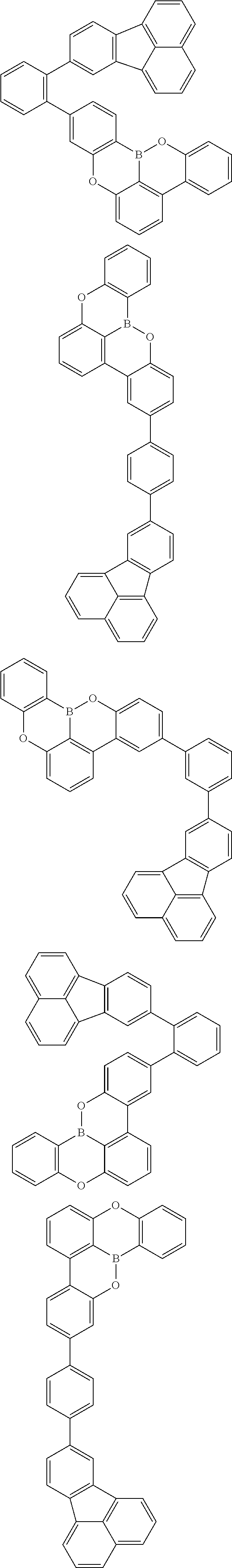

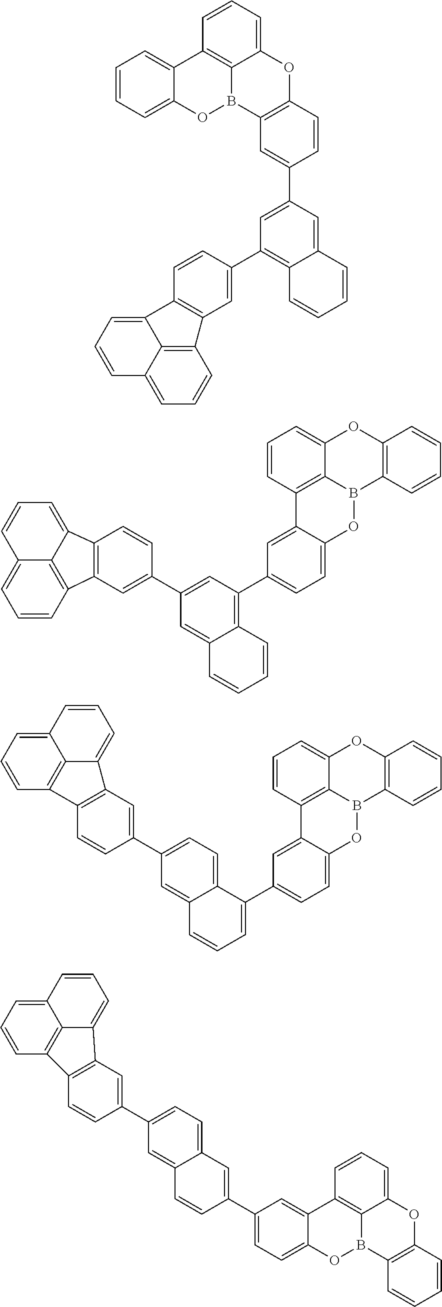 [SMILES: c1ccc2c(c1)OB1c3cc(-c4cc(-c5ccc6c(c5)-c5cccc7cccc-6c57)c5ccccc5c4)ccc3Oc3cccc-2c31 ; c1ccc2c(c1)Oc1cccc3c1B2Oc1ccc(-c2cc(-c4ccc5c(c4)-c4cccc6cccc-5c46)cc4ccccc24)cc1-3 ; c1ccc2c(c1)Oc1cccc3c1B2Oc1ccc(-c2cccc4cc(-c5ccc6c(c5)-c5cccc7cccc-6c57)ccc24)cc1-3 ; c1ccc2c(c1)Oc1cccc3c1B2Oc1ccc(-c2ccc4cc(-c5ccc6c(c5)-c5cccc7cccc-6c57)ccc4c2)cc1-3]

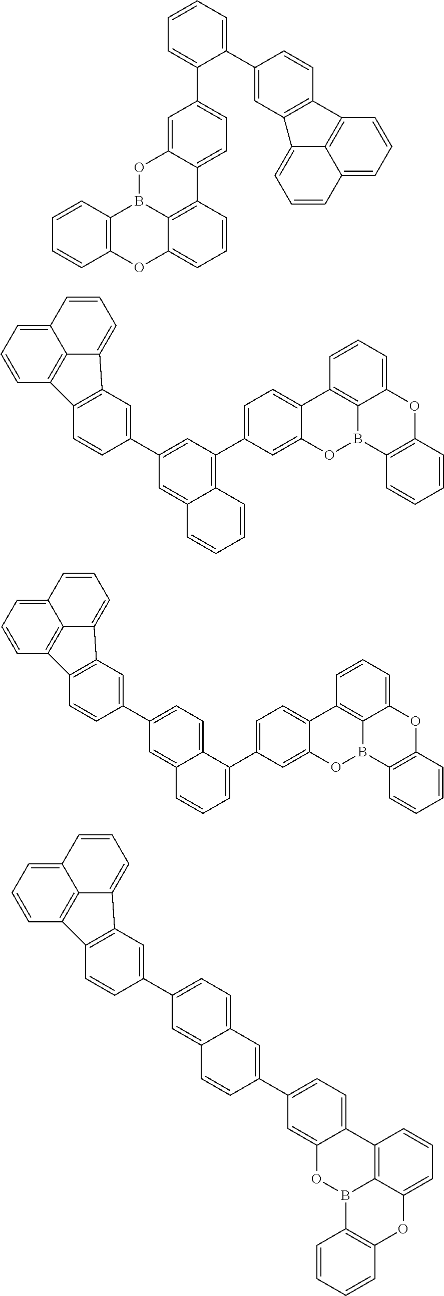

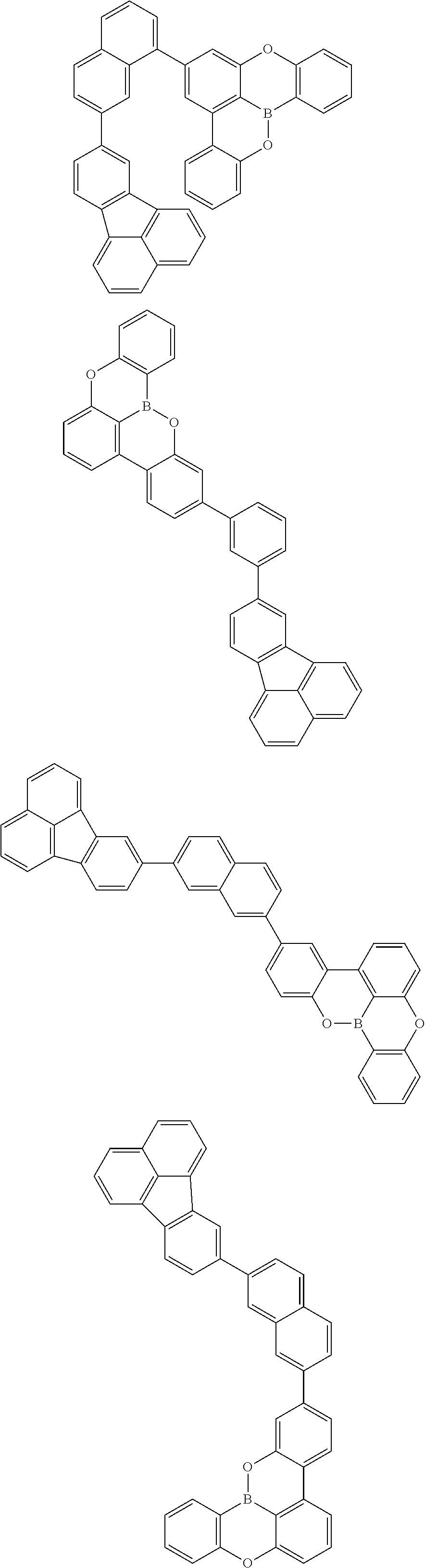

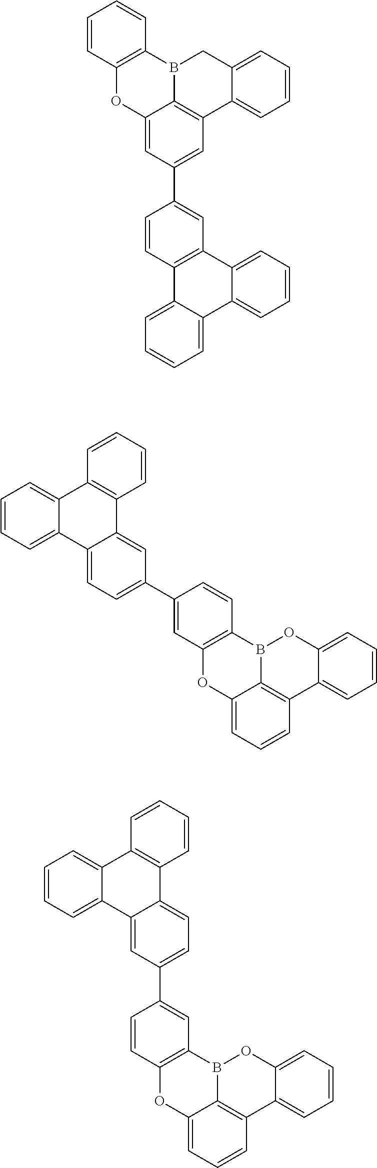 [SMILES: c1ccc2c(c1)CB1c3ccccc3Oc3cc(-c4ccc5c6ccccc6c6ccccc6c5c4)cc-2c31 ; c1ccc2c(c1)OB1c3ccc(-c4ccc5c6ccccc6c6ccccc6c5c4)cc3Oc3cccc-2c31 ; c1ccc2c(c1)OB1c3cc(-c4ccc5c6ccccc6c6ccccc6c5c4)ccc3Oc3cccc-2c31]

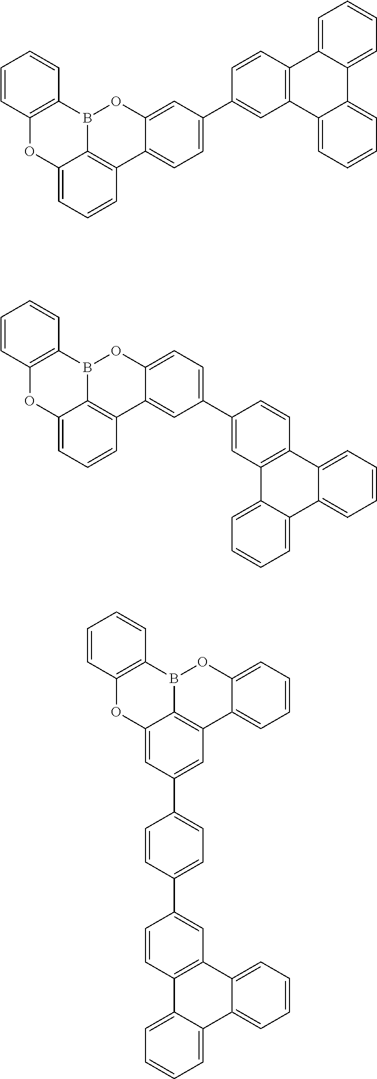

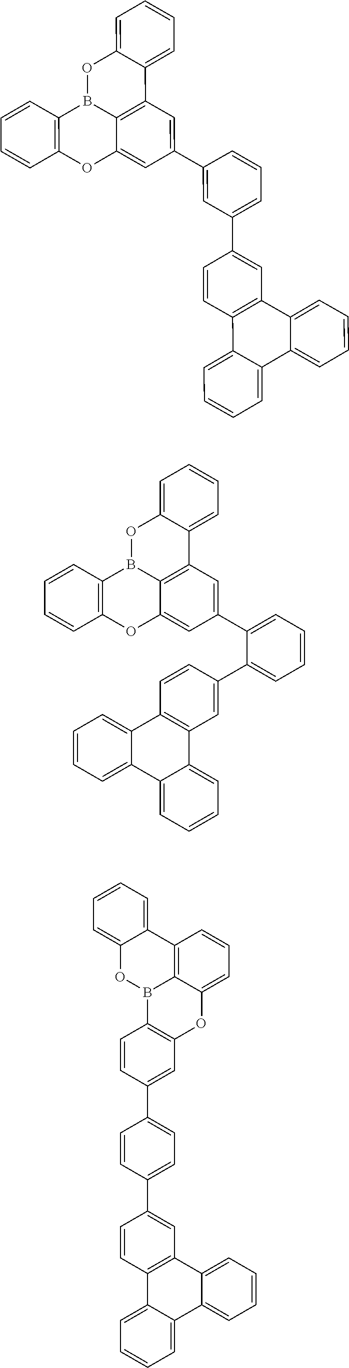 [SMILES: c1cc(-c2cc3c4c(c2)-c2ccccc2OB4c2ccccc2O3)cc(-c2ccc3c4ccccc4c4ccccc4c3c2)c1 ; c1ccc2c(c1)Oc1cc(-c3ccccc3-c3ccc4c5ccccc5c5ccccc5c4c3)cc3c1B2Oc1ccccc1-3 ; c1ccc2c(c1)OB1c3ccc(-c4ccc(-c5ccc6c7ccccc7c7ccccc7c6c5)cc4)cc3Oc3cccc-2c31]

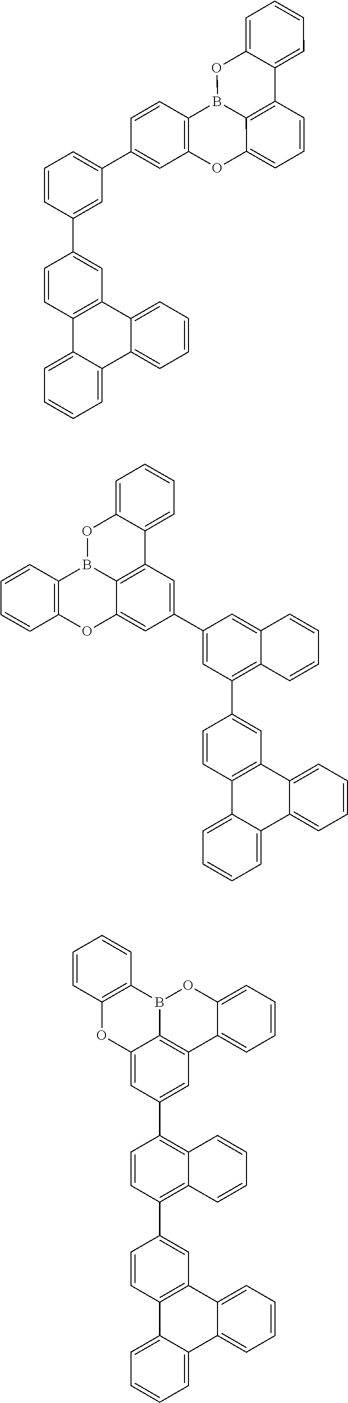 [SMILES: c1cc(-c2ccc3c(c2)Oc2cccc4c2B3Oc2ccccc2-4)cc(-c2ccc3c4ccccc4c4ccccc4c3c2)c1 ; c1ccc2c(c1)Oc1cc(-c3cc(-c4ccc5c6ccccc6c6ccccc6c5c4)c4ccccc4c3)cc3c1B2Oc1ccccc1-3 ; c1ccc2c(c1)Oc1cc(-c3ccc(-c4ccc5c6ccccc6c6ccccc6c5c4)c4ccccc34)cc3c1B2Oc1ccccc1-3]

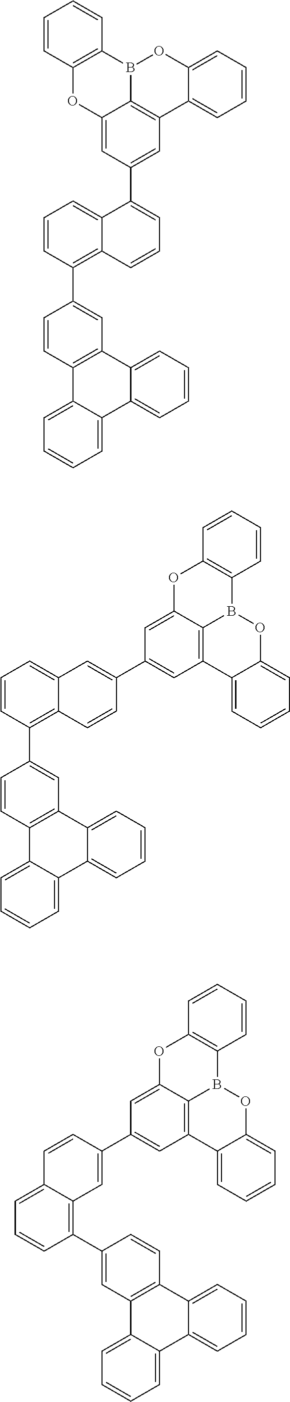

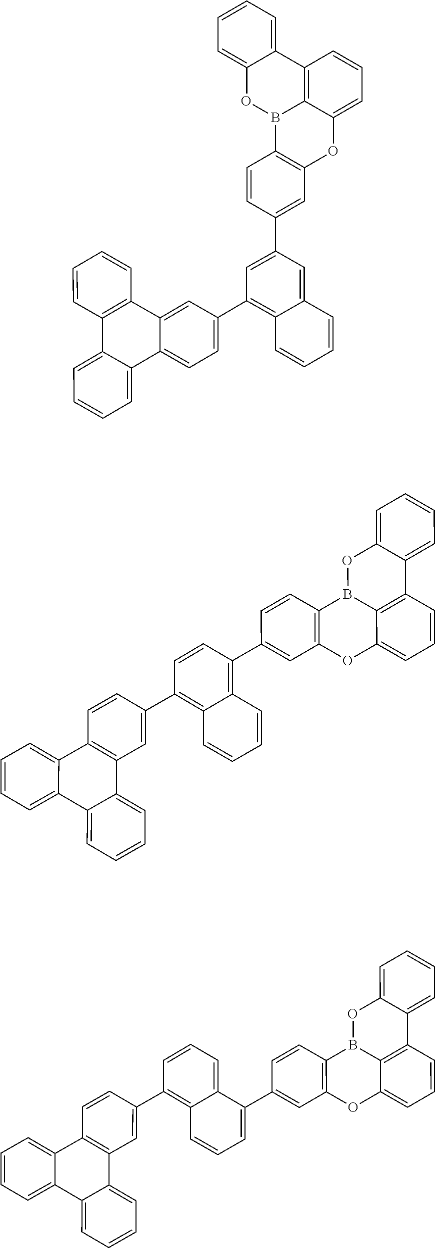 [SMILES: c1ccc2c(c1)OB1c3ccc(-c4cc(-c5ccc6c7ccccc7c7ccccc7c6c5)c5ccccc5c4)cc3Oc3cccc-2c31 ; c1ccc2c(c1)OB1c3ccc(-c4ccc(-c5ccc6c7ccccc7c7ccccc7c6c5)c5ccccc45)cc3Oc3cccc-2c31 ; c1ccc2c(c1)OB1c3ccc(-c4cccc5c(-c6ccc7c8ccccc8c8ccccc8c7c6)cccc45)cc3Oc3cccc-2c31]

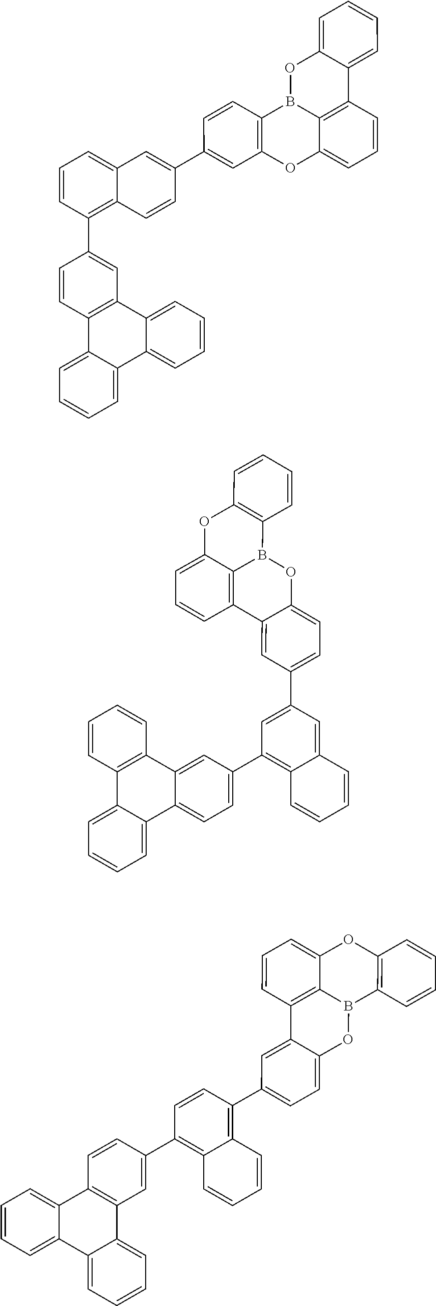 [SMILES: c1ccc2c(c1)OB1c3ccc(-c4ccc5c(-c6ccc7c8ccccc8c8ccccc8c7c6)cccc5c4)cc3Oc3cccc-2c31 ; c1ccc2c(c1)Oc1cccc3c1B2Oc1ccc(-c2cc(-c4ccc5c6ccccc6c6ccccc6c5c4)c4ccccc4c2)cc1-3 ; c1ccc2c(c1)Oc1cccc3c1B2Oc1ccc(-c2ccc(-c4ccc5c6ccccc6c6ccccc6c5c4)c4ccccc24)cc1-3]

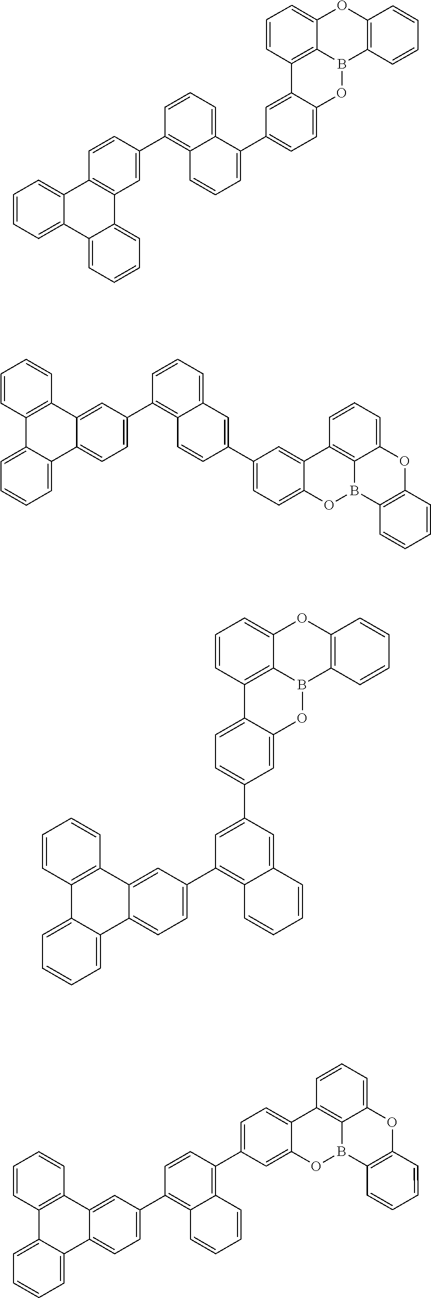 [SMILES: c1ccc2c(c1)Oc1cccc3c1B2Oc1ccc(-c2cccc4c(-c5ccc6c7ccccc7c7ccccc7c6c5)cccc24)cc1-3 ; c1ccc2c(c1)Oc1cccc3c1B2Oc1ccc(-c2ccc4c(-c5ccc6c7ccccc7c7ccccc7c6c5)cccc4c2)cc1-3 ; c1ccc2c(c1)Oc1cccc3c1B2Oc1cc(-c2cc(-c4ccc5c6ccccc6c6ccccc6c5c4)c4ccccc4c2)ccc1-3 ; c1ccc2c(c1)Oc1cccc3c1B2Oc1cc(-c2ccc(-c4ccc5c6ccccc6c6ccccc6c5c4)c4ccccc24)ccc1-3]

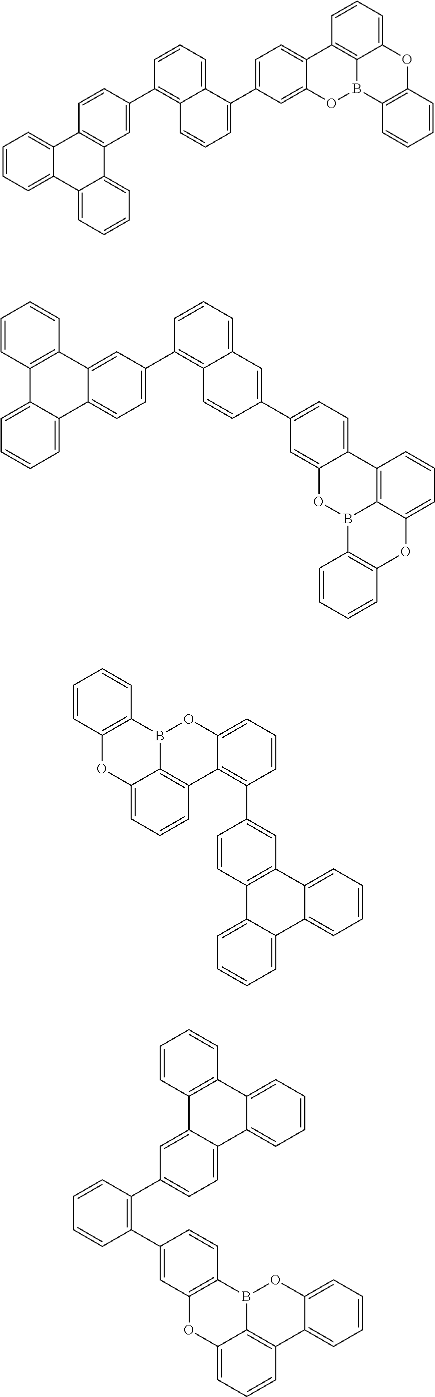 [SMILES: c1ccc2c(c1)Oc1cccc3c1B2Oc1cc(-c2cccc4c(-c5ccc6c7ccccc7c7ccccc7c6c5)cccc24)ccc1-3 ; c1ccc2c(c1)Oc1cccc3c1B2Oc1cc(-c2ccc4c(-c5ccc6c7ccccc7c7ccccc7c6c5)cccc4c2)ccc1-3 ; c1ccc2c(c1)Oc1cccc3c1B2Oc1cccc(-c2ccc4c5ccccc5c5ccccc5c4c2)c1-3 ; c1ccc2c(c1)OB1c3ccc(-c4ccccc4-c4ccc5c6ccccc6c6ccccc6c5c4)cc3Oc3cccc-2c31]

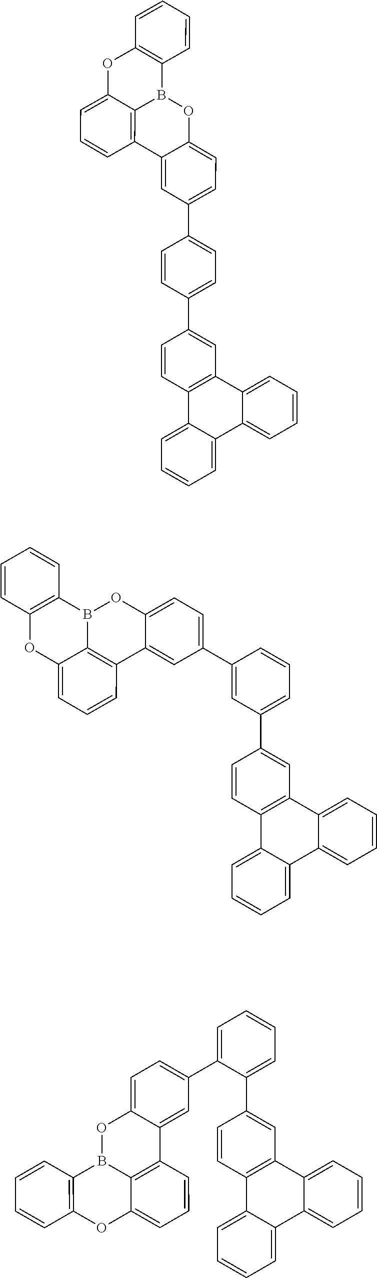 [SMILES: c1ccc2c(c1)Oc1cccc3c1B2Oc1ccc(-c2ccc(-c4ccc5c6ccccc6c6ccccc6c5c4)cc2)cc1-3 ; c1cc(-c2ccc3c(c2)-c2cccc4c2B(O3)c2ccccc2O4)cc(-c2ccc3c4ccccc4c4ccccc4c3c2)c1 ; c1ccc2c(c1)Oc1cccc3c1B2Oc1ccc(-c2ccccc2-c2ccc4c5ccccc5c5ccccc5c4c2)cc1-3]

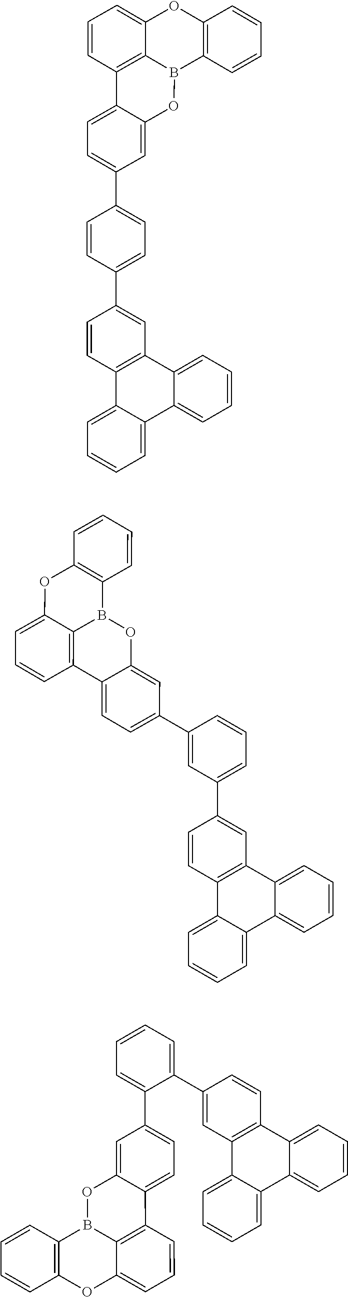

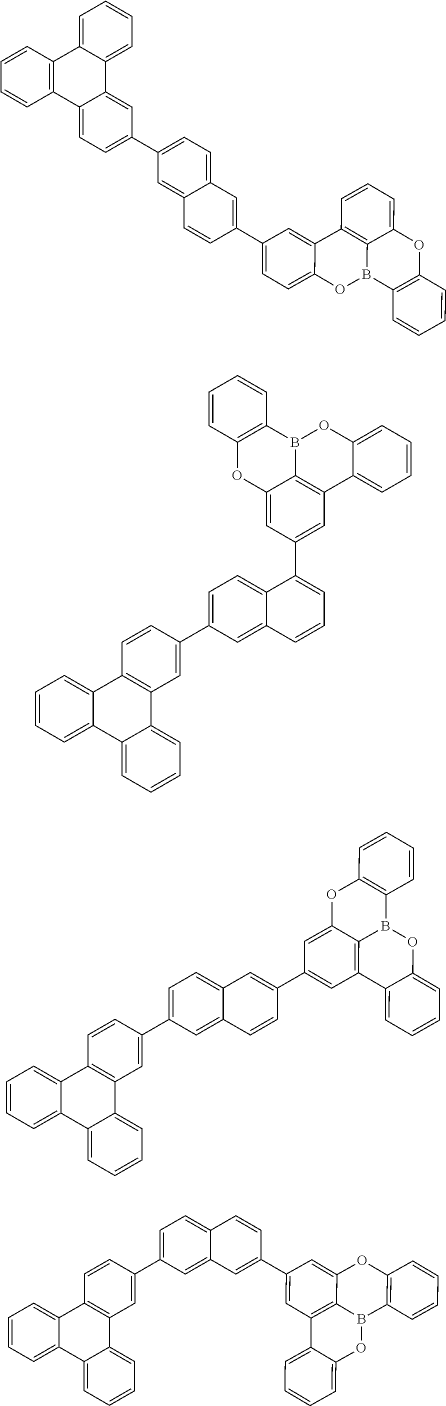 [SMILES: c1ccc2c(c1)Oc1cccc3c1B2Oc1ccc(-c2ccc4cc(-c5ccc6c7ccccc7c7ccccc7c6c5)ccc4c2)cc1-3 ; c1ccc2c(c1)Oc1cc(-c3cccc4cc(-c5ccc6c7ccccc7c7ccccc7c6c5)ccc34)cc3c1B2Oc1ccccc1-3 ; c1ccc2c(c1)Oc1cc(-c3ccc4cc(-c5ccc6c7ccccc7c7ccccc7c6c5)ccc4c3)cc3c1B2Oc1ccccc1-3 ; c1ccc2c(c1)Oc1cc(-c3ccc4ccc(-c5ccc6c7ccccc7c7ccccc7c6c5)cc4c3)cc3c1B2Oc1ccccc1-3]

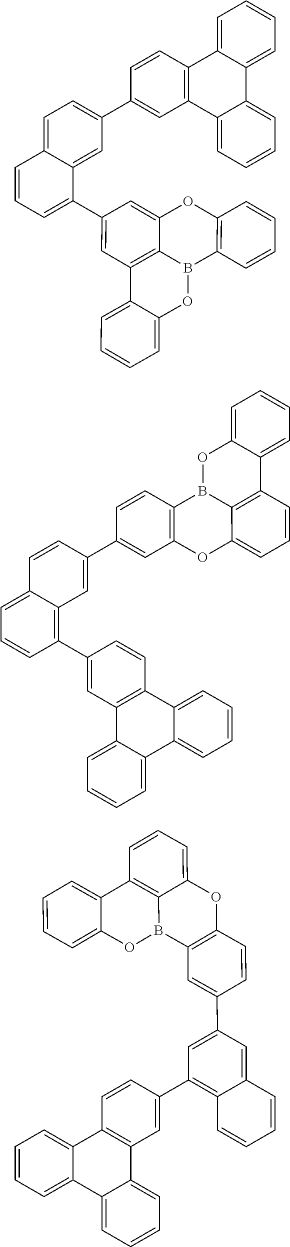

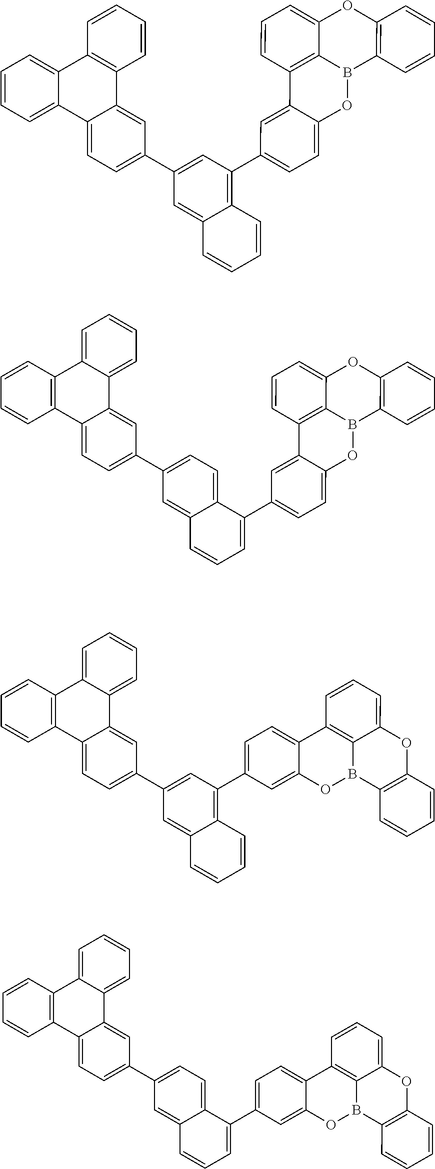 [SMILES: c1ccc2c(c1)Oc1cccc3c1B2Oc1ccc(-c2cc(-c4ccc5c6ccccc6c6ccccc6c5c4)cc4ccccc24)cc1-3 ; c1ccc2c(c1)Oc1cccc3c1B2Oc1ccc(-c2cccc4cc(-c5ccc6c7ccccc7c7ccccc7c6c5)ccc24)cc1-3 ; c1ccc2c(c1)Oc1cccc3c1B2Oc1cc(-c2cc(-c4ccc5c6ccccc6c6ccccc6c5c4)cc4ccccc24)ccc1-3 ; c1ccc2c(c1)Oc1cccc3c1B2Oc1cc(-c2cccc4cc(-c5ccc6c7ccccc7c7ccccc7c6c5)ccc24)ccc1-3]

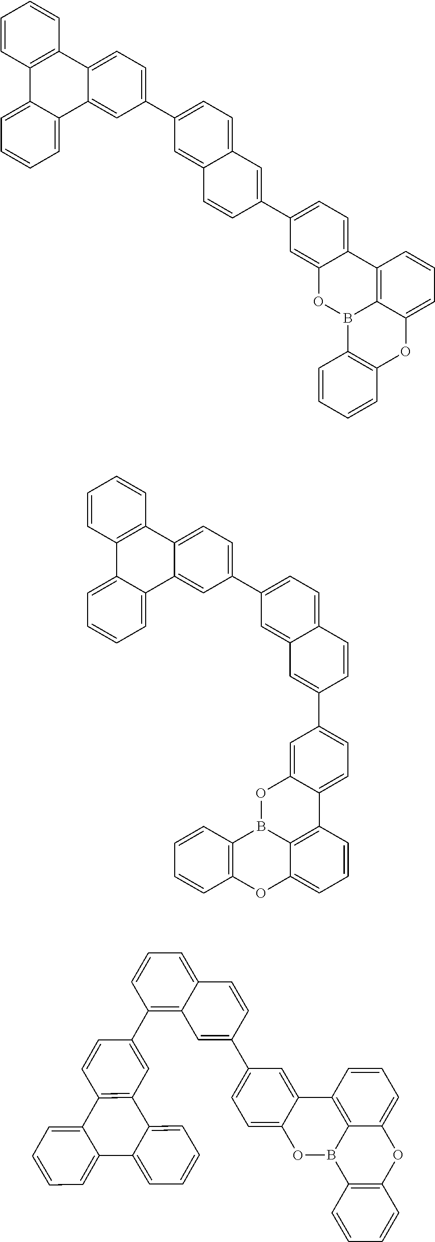 [SMILES: c1ccc2c(c1)Oc1cccc3c1B2Oc1cc(-c2ccc4cc(-c5ccc6c7ccccc7c7ccccc7c6c5)ccc4c2)ccc1-3 ; c1ccc2c(c1)Oc1cccc3c1B2Oc1cc(-c2ccc4ccc(-c5ccc6c7ccccc7c7ccccc7c6c5)cc4c2)ccc1-3 ; c1ccc2c(c1)Oc1cccc3c1B2Oc1ccc(-c2ccc4cccc(-c5ccc6c7ccccc7c7ccccc7c6c5)c4c2)cc1-3]

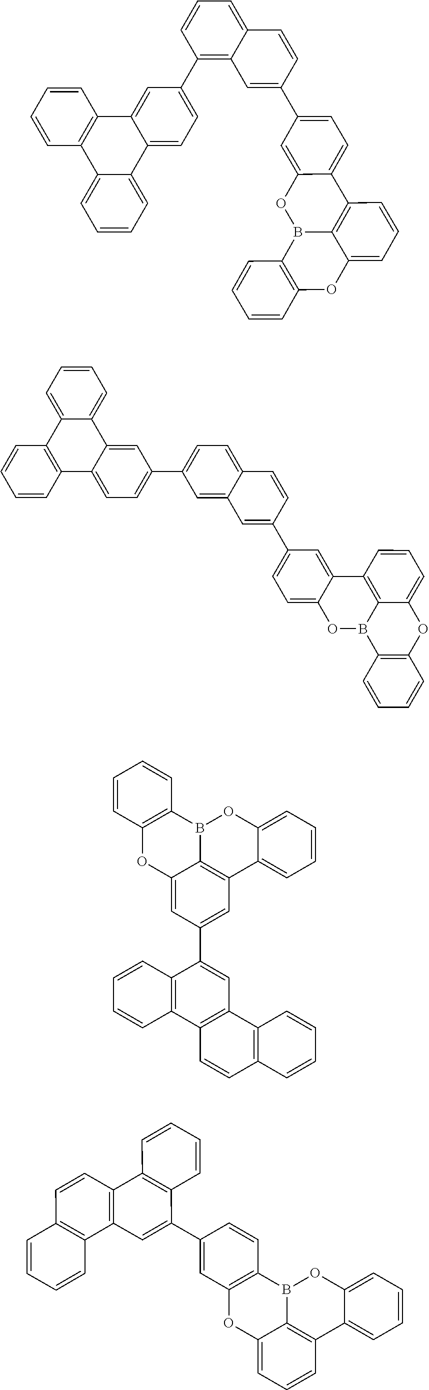 [SMILES: c1ccc2c(c1)Oc1cccc3c1B2Oc1cc(-c2ccc4cccc(-c5ccc6c7ccccc7c7ccccc7c6c5)c4c2)ccc1-3 ; c1ccc2c(c1)Oc1cccc3c1B2Oc1ccc(-c2ccc4ccc(-c5ccc6c7ccccc7c7ccccc7c6c5)cc4c2)cc1-3 ; c1ccc2c(c1)Oc1cc(-c3cc4c5ccccc5ccc4c4ccccc34)cc3c1B2Oc1ccccc1-3 ; c1ccc2c(c1)OB1c3ccc(-c4cc5c6ccccc6ccc5c5ccccc45)cc3Oc3cccc-2c31]

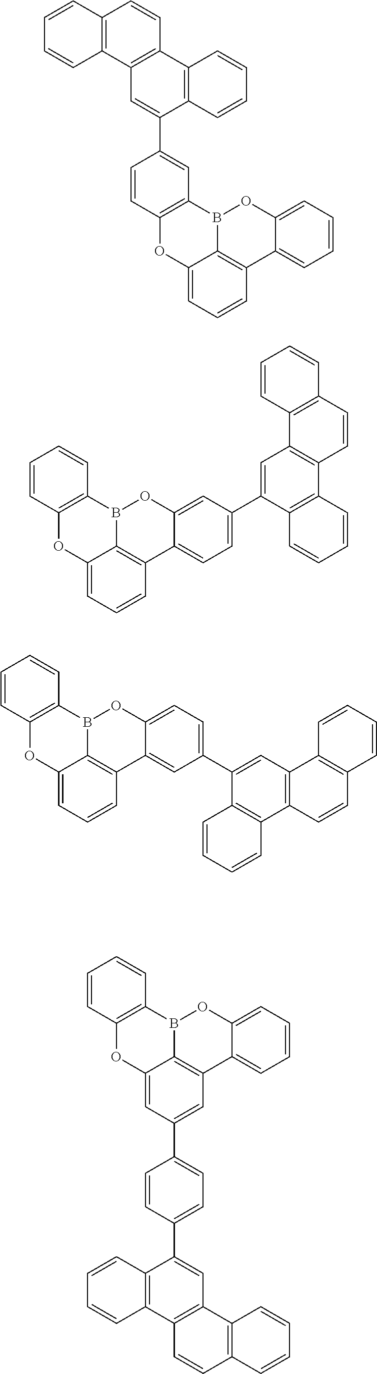 [SMILES: c1ccc2c(c1)OB1c3cc(-c4cc5c6ccccc6ccc5c5ccccc45)ccc3Oc3cccc-2c31 ; c1ccc2c(c1)Oc1cccc3c1B2Oc1cc(-c2cc4c5ccccc5ccc4c4ccccc24)ccc1-3 ; c1ccc2c(c1)Oc1cccc3c1B2Oc1ccc(-c2cc4c5ccccc5ccc4c4ccccc24)cc1-3 ; c1ccc2c(c1)Oc1cc(-c3ccc(-c4cc5c6ccccc6ccc5c5ccccc45)cc3)cc3c1B2Oc1ccccc1-3]

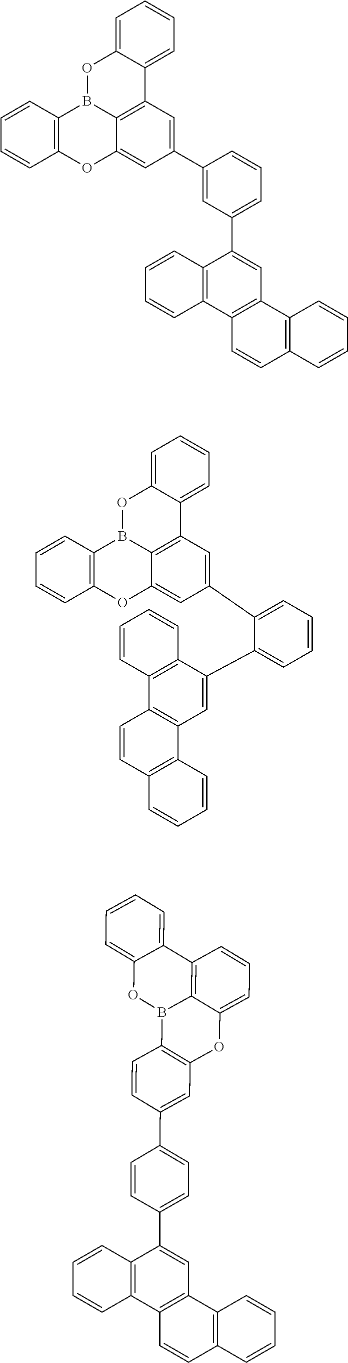 [SMILES: c1cc(-c2cc3c4c(c2)-c2ccccc2OB4c2ccccc2O3)cc(-c2cc3c4ccccc4ccc3c3ccccc23)c1 ; c1ccc2c(c1)Oc1cc(-c3ccccc3-c3cc4c5ccccc5ccc4c4ccccc34)cc3c1B2Oc1ccccc1-3 ; c1ccc2c(c1)OB1c3ccc(-c4ccc(-c5cc6c7ccccc7ccc6c6ccccc56)cc4)cc3Oc3cccc-2c31]

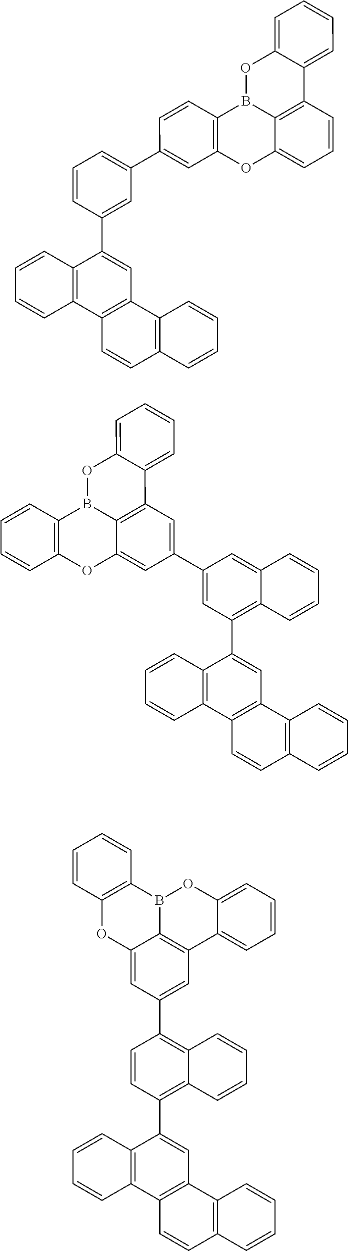

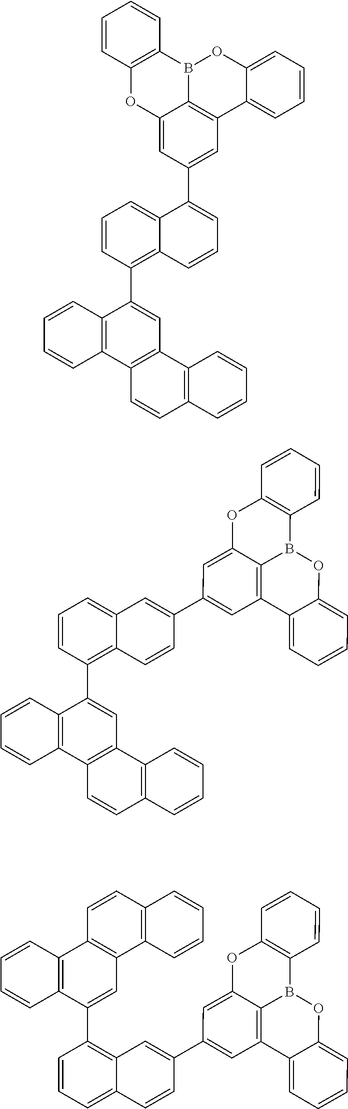 [SMILES: c1ccc2c(c1)Oc1cc(-c3cccc4c(-c5cc6c7ccccc7ccc6c6ccccc56)cccc34)cc3c1B2Oc1ccccc1-3 ; c1ccc2c(c1)Oc1cc(-c3ccc4c(-c5cc6c7ccccc7ccc6c6ccccc56)cccc4c3)cc3c1B2Oc1ccccc1-3 ; c1ccc2c(c1)Oc1cc(-c3ccc4cccc(-c5cc6c7ccccc7ccc6c6ccccc56)c4c3)cc3c1B2Oc1ccccc1-3]

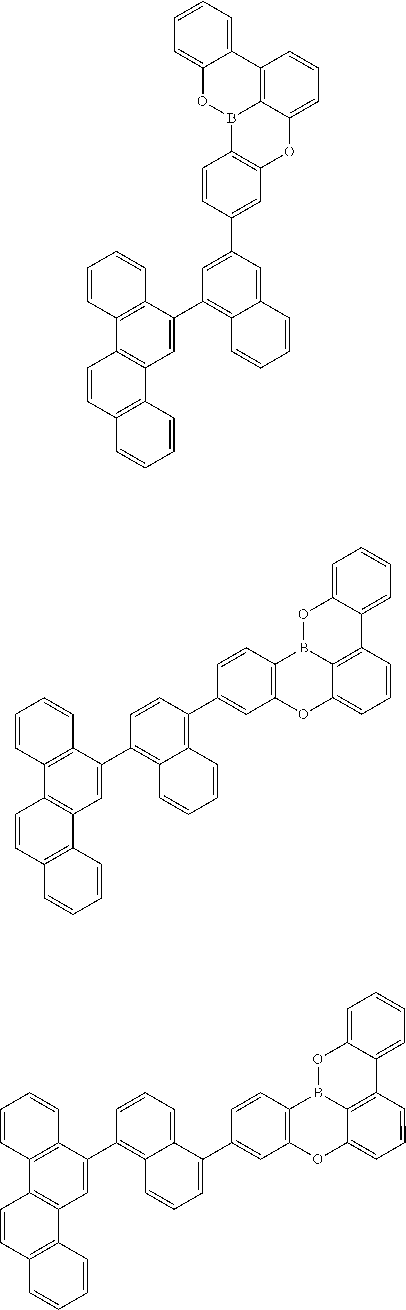 [SMILES: c1ccc2c(c1)OB1c3ccc(-c4cc(-c5cc6c7ccccc7ccc6c6ccccc56)c5ccccc5c4)cc3Oc3cccc-2c31 ; c1ccc2c(c1)OB1c3ccc(-c4ccc(-c5cc6c7ccccc7ccc6c6ccccc56)c5ccccc45)cc3Oc3cccc-2c31 ; c1ccc2c(c1)OB1c3ccc(-c4cccc5c(-c6cc7c8ccccc8ccc7c7ccccc67)cccc45)cc3Oc3cccc-2c31]

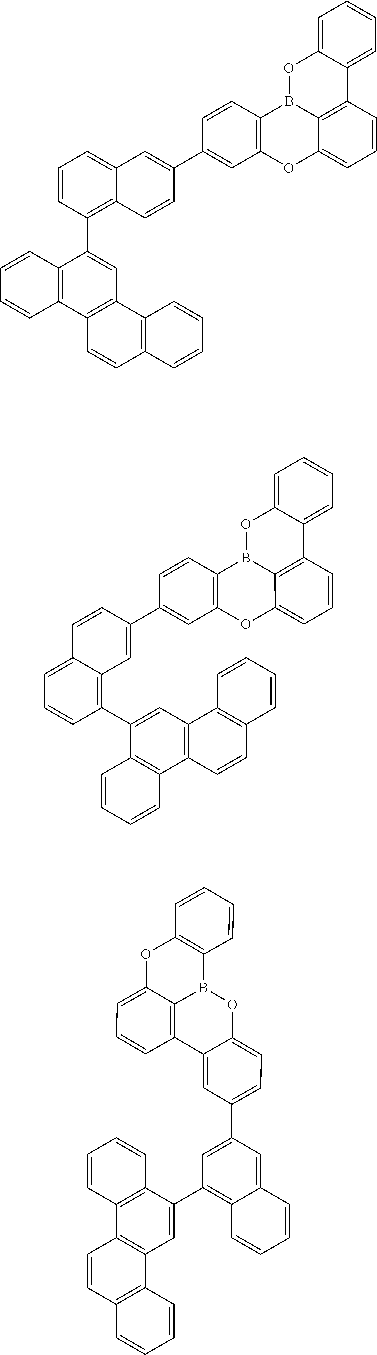 [SMILES: c1ccc2c(c1)OB1c3ccc(-c4ccc5c(-c6cc7c8ccccc8ccc7c7ccccc67)cccc5c4)cc3Oc3cccc-2c31 ; c1ccc2c(c1)OB1c3ccc(-c4ccc5cccc(-c6cc7c8ccccc8ccc7c7ccccc67)c5c4)cc3Oc3cccc-2c31 ; c1ccc2c(c1)Oc1cccc3c1B2Oc1ccc(-c2cc(-c4cc5c6ccccc6ccc5c5ccccc45)c4ccccc4c2)cc1-3]

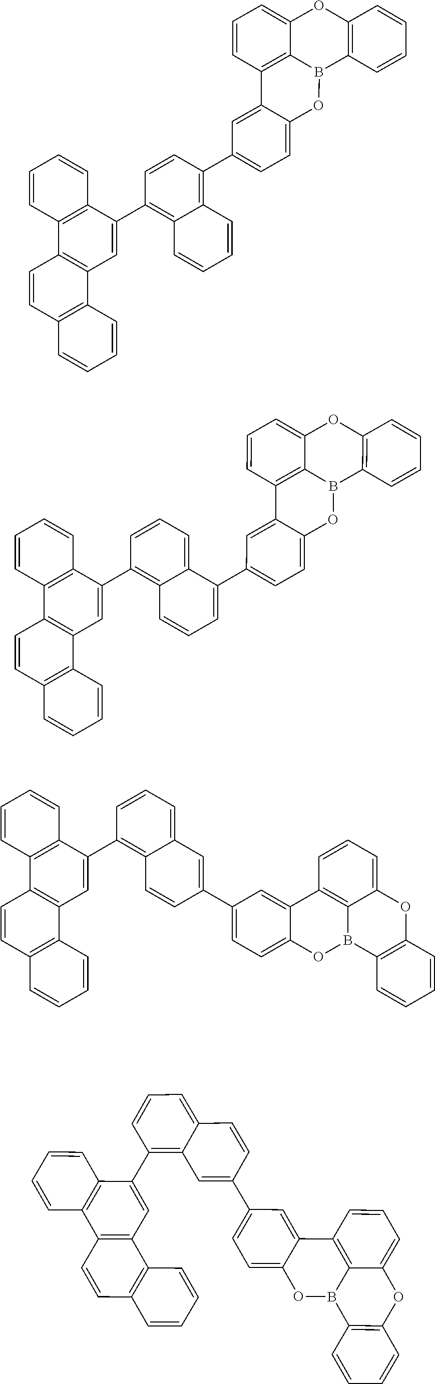 [SMILES: c1ccc2c(c1)Oc1cccc3c1B2Oc1ccc(-c2ccc(-c4cc5c6ccccc6ccc5c5ccccc45)c4ccccc24)cc1-3 ; c1ccc2c(c1)Oc1cccc3c1B2Oc1ccc(-c2cccc4c(-c5cc6c7ccccc7ccc6c6ccccc56)cccc24)cc1-3 ; c1ccc2c(c1)Oc1cccc3c1B2Oc1ccc(-c2ccc4c(-c5cc6c7ccccc7ccc6c6ccccc56)cccc4c2)cc1-3 ; c1ccc2c(c1)Oc1cccc3c1B2Oc1ccc(-c2ccc4cccc(-c5cc6c7ccccc7ccc6c6ccccc56)c4c2)cc1-3]

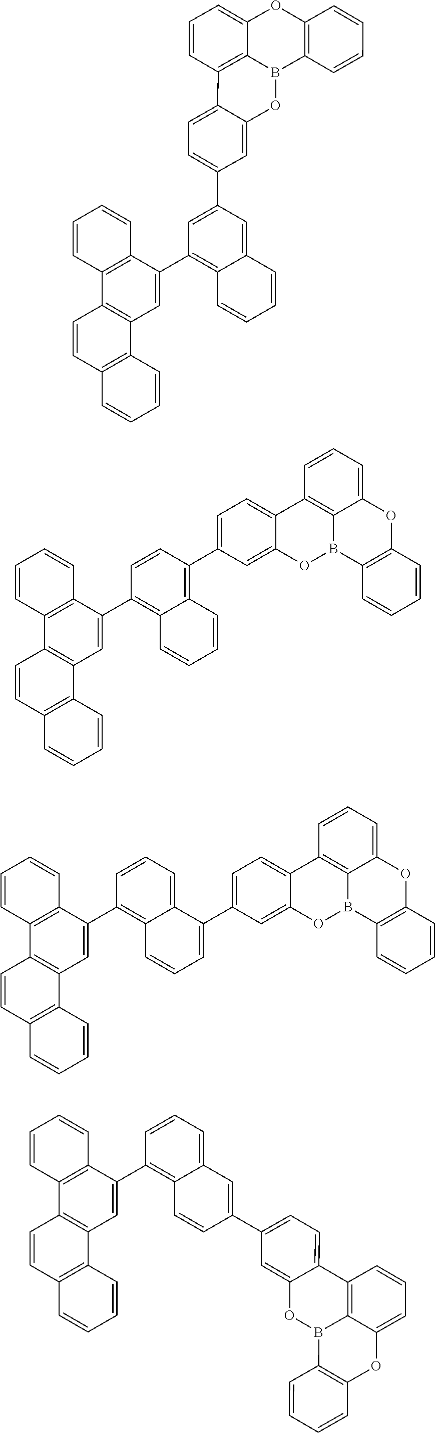

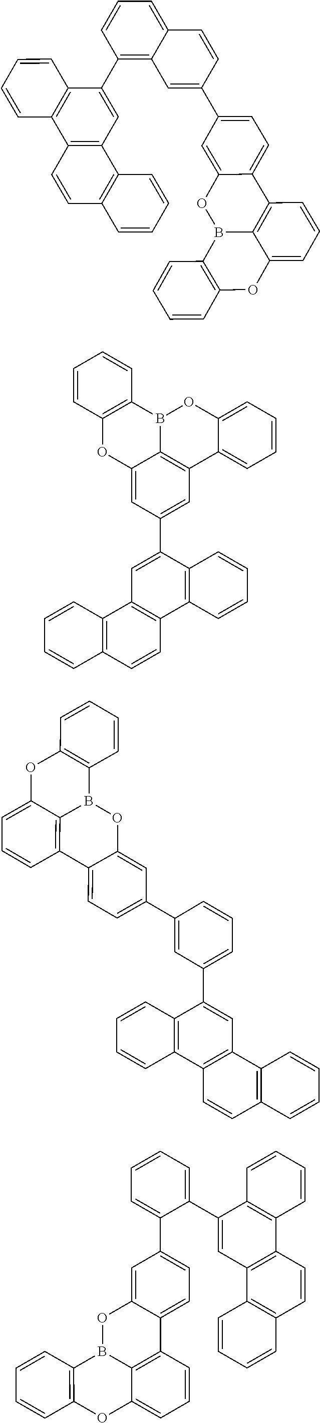

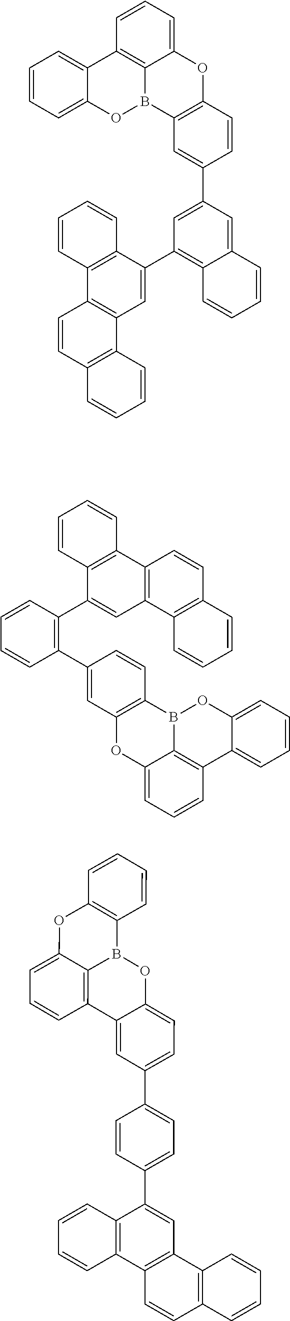 [SMILES: c1ccc2c(c1)OB1c3cc(-c4cc(-c5cc6c7ccccc7ccc6c6ccccc56)c5ccccc5c4)ccc3Oc3cccc-2c31 ; c1ccc2c(c1)OB1c3ccc(-c4ccccc4-c4cc5c6ccccc6ccc5c5ccccc45)cc3Oc3cccc-2c31 ; c1ccc2c(c1)Oc1cccc3c1B2Oc1ccc(-c2ccc(-c4cc5c6ccccc6ccc5c5ccccc45)cc2)cc1-3]

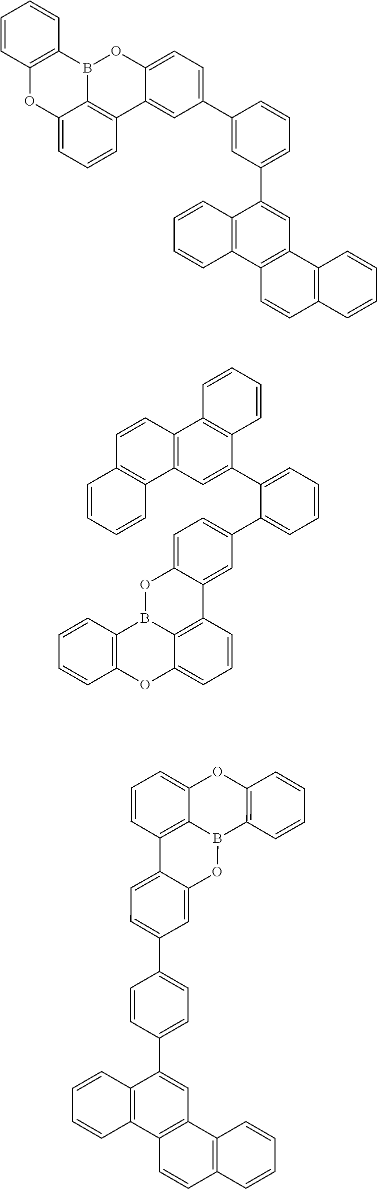 [SMILES: c1cc(-c2ccc3c(c2)-c2cccc4c2B(O3)c2ccccc2O4)cc(-c2cc3c4ccccc4ccc3c3ccccc23)c1 ; c1ccc2c(c1)Oc1cccc3c1B2Oc1ccc(-c2ccccc2-c2cc4c5ccccc5ccc4c4ccccc24)cc1-3 ; c1ccc2c(c1)Oc1cccc3c1B2Oc1cc(-c2ccc(-c4cc5c6ccccc6ccc5c5ccccc45)cc2)ccc1-3]

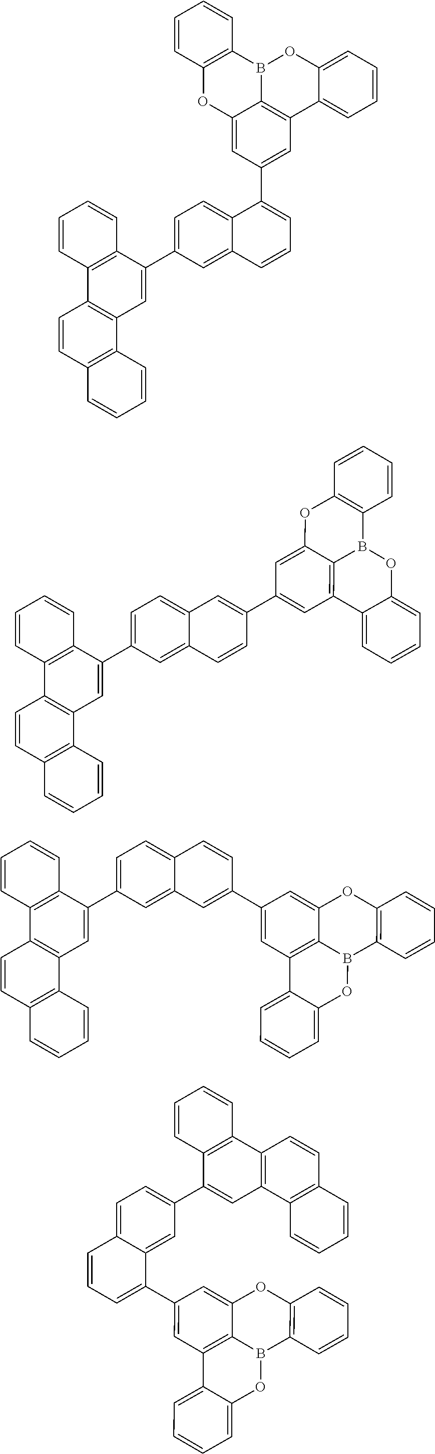 [SMILES: c1ccc2c(c1)Oc1cc(-c3cccc4cc(-c5cc6c7ccccc7ccc6c6ccccc56)ccc34)cc3c1B2Oc1ccccc1-3 ; c1ccc2c(c1)Oc1cc(-c3ccc4cc(-c5cc6c7ccccc7ccc6c6ccccc56)ccc4c3)cc3c1B2Oc1ccccc1-3 ; c1ccc2c(c1)Oc1cc(-c3ccc4ccc(-c5cc6c7ccccc7ccc6c6ccccc56)cc4c3)cc3c1B2Oc1ccccc1-3 ; c1ccc2c(c1)Oc1cc(-c3cccc4ccc(-c5cc6c7ccccc7ccc6c6ccccc56)cc34)cc3c1B2Oc1ccccc1-3]

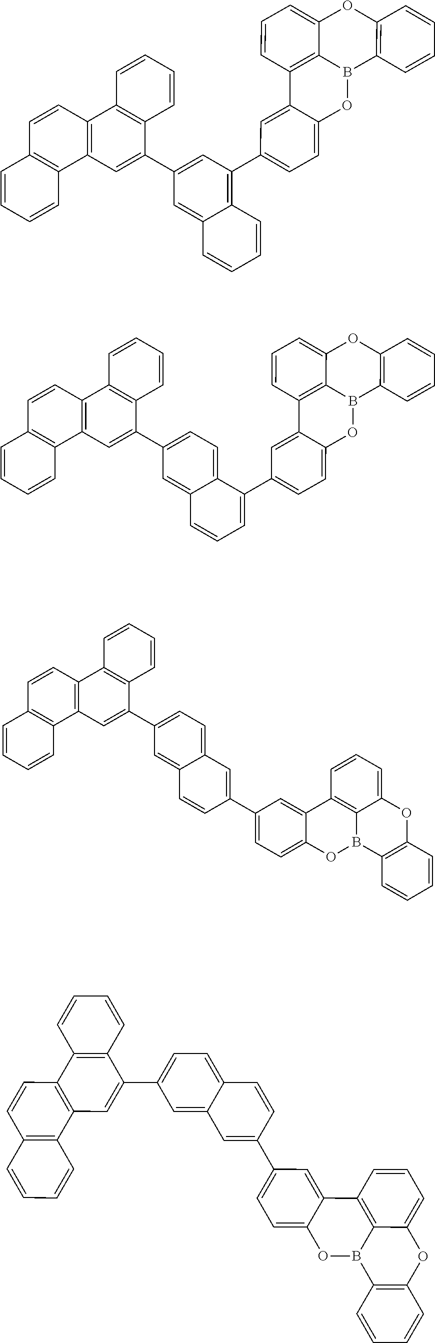 [SMILES: c1ccc2c(c1)Oc1cccc3c1B2Oc1ccc(-c2cc(-c4cc5c6ccccc6ccc5c5ccccc45)cc4ccccc24)cc1-3 ; c1ccc2c(c1)Oc1cccc3c1B2Oc1ccc(-c2cccc4cc(-c5cc6c7ccccc7ccc6c6ccccc56)ccc24)cc1-3 ; c1ccc2c(c1)Oc1cccc3c1B2Oc1ccc(-c2ccc4cc(-c5cc6c7ccccc7ccc6c6ccccc56)ccc4c2)cc1-3 ; c1ccc2c(c1)Oc1cccc3c1B2Oc1ccc(-c2ccc4ccc(-c5cc6c7ccccc7ccc6c6ccccc56)cc4c2)cc1-3]

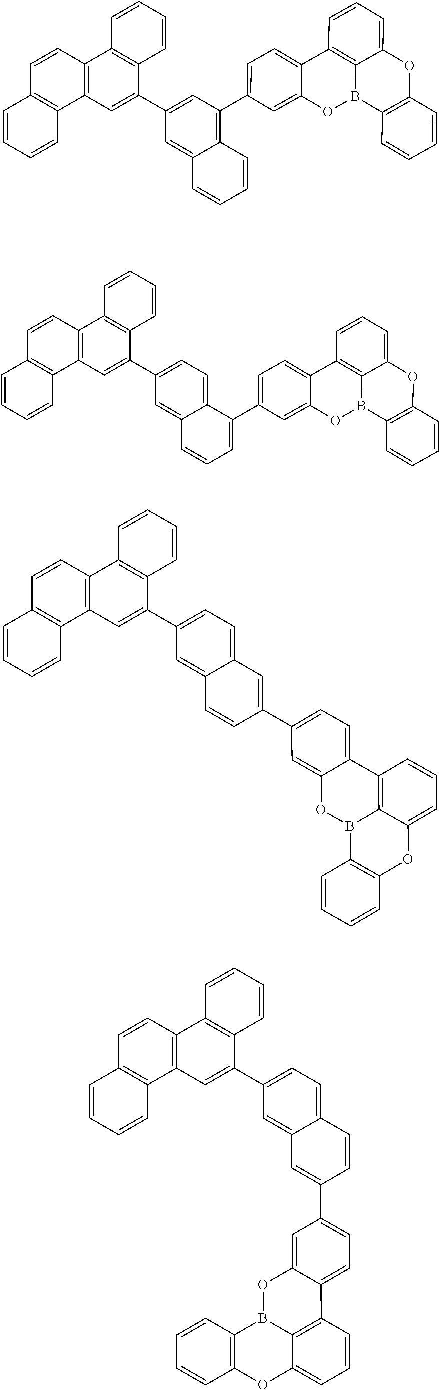 [SMILES: c1ccc2c(c1)Oc1cccc3c1B2Oc1cc(-c2cc(-c4cc5c6ccccc6ccc5c5ccccc45)cc4ccccc24)ccc1-3 ; c1ccc2c(c1)Oc1cccc3c1B2Oc1cc(-c2cccc4cc(-c5cc6c7ccccc7ccc6c6ccccc56)ccc24)ccc1-3 ; c1ccc2c(c1)Oc1cccc3c1B2Oc1cc(-c2ccc4cc(-c5cc6c7ccccc7ccc6c6ccccc56)ccc4c2)ccc1-3 ; c1ccc2c(c1)Oc1cccc3c1B2Oc1cc(-c2ccc4ccc(-c5cc6c7ccccc7ccc6c6ccccc56)cc4c2)ccc1-3]

Hereinafter, the compound represented by Chemical Formula 2 will be described in detail.

In an exemplary embodiment of the present specification, Chemical Formula 2 is represented by the following Chemical Formula 2-1 or 2-2.

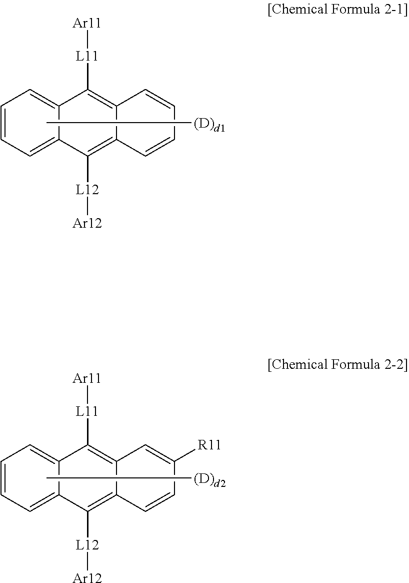

In Chemical Formulae 2-1 and 2-2,
L11, L12, Ar11, Ar12, and R11 are the same as those defined in Chemical Formula 2,
D is deuterium, and
d1 is an integer from 0 to 8, and d2 is an integer from 0 to 7.

In an exemplary embodiment of the present specification, L11 and L12 are the same as or different from each other, and are each independently a direct bond; a substituted or unsubstituted arylene group having 6 to 30 carbon atoms; or a substituted or unsubstituted heteroarylene group having 2 to 30 carbon atoms.

In an exemplary embodiment of the present specification, L11 and L12 are the same as or different from each other, and are independently a direct bond; an arylene group unsubstituted or substituted with one or more selected from the group consisting of deuterium, an aryl group and a heteroaryl group; or a heteroarylene group unsubstituted or substituted with one or more selected from the group consisting of deuterium, an aryl group and a heteroaryl group.

In an exemplary embodiment of the present specification, L11 and L12 are the same as or different from each other, and are each independently a direct bond; an arylene group unsubstituted or substituted with deuterium; or a heteroarylene group unsubstituted or substituted with deuterium.

In an exemplary embodiment of the present specification, L11 and L12 are the same as or different from each other, and are each independently a direct bond; a substituted or unsubstituted phenylene group; a substituted or unsubstituted biphenylylene group; a substituted or unsubstituted naphthylene group; a substituted or unsubstituted divalent furan group; a substituted or unsubstituted divalent benzofuran group; a substituted or unsubstituted divalent dibenzofuran group; a substituted or unsubstituted divalent thiophene group; or a substituted or unsubstituted divalent benzothiophene group; or a substituted or unsubstituted divalent dibenzothiophene group.

In an exemplary embodiment of the present specification, L11 and L12 are the same as or different from each other, and are each independently a direct bond; a substituted or unsubstituted phenylene group; a substituted or unsubstituted naphthylene group; or a substituted or unsubstituted divalent dibenzofuran group.

In an exemplary embodiment of the present specification, L11 and L12 are the same as or different from each other, and are each independently a direct bond; a phenylene group unsubstituted or substituted with deuterium; a naphthylene group unsubstituted or substituted with deuterium; or a divalent dibenzofuran group unsubstituted or substituted with deuterium.

In an exemplary embodiment of the present specification, R11 is hydrogen; deuterium; a substituted or unsubstituted alkyl group having 1 to 30 carbon atoms; a substituted or unsubstituted aryl group having 6 to 30 carbon atoms; or a substituted or unsubstituted heteroaryl group having 2 to 30 carbon atoms.

In an exemplary embodiment of the present specification, R11 is hydrogen; deuterium; an aryl group unsubstituted or substituted with one or more selected from the group consisting of deuterium, an alkyl group and an aryl group; or a heteroaryl group unsubstituted or substituted with one or more selected from the group consisting of deuterium, an alkyl group and an aryl group.

In an exemplary embodiment of the present specification, R11 is hydrogen; deuterium; a substituted or unsubstituted phenyl group; a substituted or unsubstituted biphenyl group; a substituted or unsubstituted naphthyl group; a substituted or unsubstituted dibenzofuran group; or a substituted or unsubstituted dibenzothiophene group.

In an exemplary embodiment of the present specification, R11 is hydrogen; deuterium; a phenyl group unsubstituted or substituted with one or more selected from the group consisting of deuterium, an alkyl group and an aryl group; a biphenyl group unsubstituted or substituted with one or more selected from the group consisting of deuterium, an alkyl group and an aryl group; a naphthyl group unsubstituted or substituted with one or more selected from the group consisting of deuterium, an alkyl group and an aryl group; a dibenzofuran group unsubstituted or substituted with one or more selected from the group consisting of deuterium, an alkyl group and an aryl group; or a dibenzothiophene group unsubstituted or substituted with one or more selected from the group consisting of deuterium, an alkyl group and an aryl group.

In an exemplary embodiment of the present specification, R11 is hydrogen; deuterium; or any one of the following structures, and the structures are unsubstituted or substituted with deuterium.

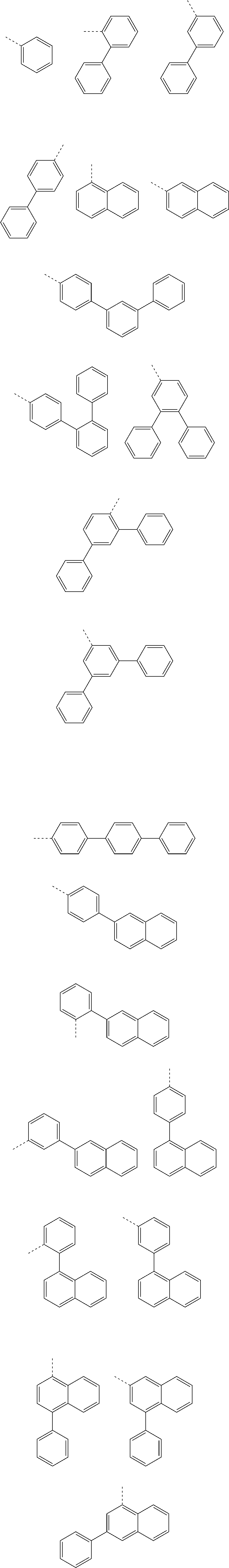

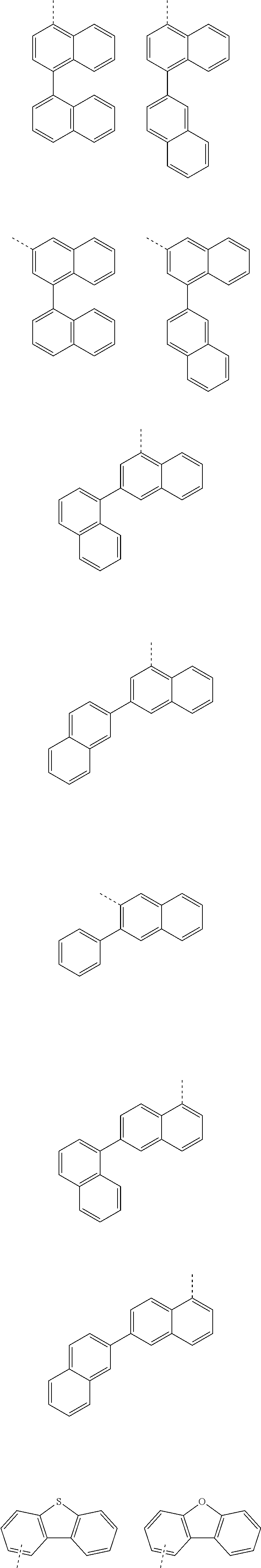

In the structures, - - - - - - is a moiety bonded to Chemical Formula 2.

In an exemplary embodiment of the present specification, Ar11 and Ar12 are the same as or different from each other, and are each independently a substituted or unsubstituted aryl group having 6 to 30 carbon atoms; or a substituted or unsubstituted heteroaryl group having 2 to 30 carbon atoms.

In an exemplary embodiment of the present specification, Ar11 and Ar12 are the same as or different from each other, and are each an aryl group unsubstituted or substituted with one or more selected from the group consisting of deuterium, an alkyl group and an aryl group; or a heteroaryl group unsubstituted or substituted with one or more selected from the group consisting of deuterium, an alkyl group and an aryl group.

In an exemplary embodiment of the present specification, Ar11 and Ar12 are the same as or different from each other, and are each independently a substituted or unsubstituted phenyl group; a substituted or unsubstituted biphenyl group; a substituted or unsubstituted terphenyl group; a substituted or unsubstituted naphthyl group; a substituted or unsubstituted phenanthrene group; a substituted or unsubstituted triphenylene group; a substituted or unsubstituted dibenzofuran group; a substituted or unsubstituted dibenzothiophene group; a substituted or unsubstituted naphthobenzofuran group; a substituted or unsubstituted benzonaphthothiophene group; a substituted or unsubstituted dinaphthofuran group; a substituted or unsubstituted dinaphthothiophene group; or a benzobisbenzofuran group.

In an exemplary embodiment of the present specification, Ar11 and Ar12 are the same as or different from each other, and are each independently a phenyl group unsubstituted or substituted with one or more selected from the group consisting of deuterium and an aryl group; a biphenyl group unsubstituted or substituted with one or more selected from the group consisting of deuterium and an aryl group; a terphenyl group unsubstituted or substituted with one or more selected from the group consisting of deuterium and an aryl group; a naphthyl group unsubstituted or substituted with one or more selected from the group consisting of deuterium and an aryl group; a phenanthrene group unsubstituted or substituted with one or more selected from the group consisting of deuterium and an aryl group; a triphenylene group unsubstituted or substituted with one or more selected from the group consisting of deuterium and an aryl group; a dibenzofuran group unsubstituted or substituted with one or more selected from the group consisting of deuterium and an aryl group; a dibenzothiophene group unsubstituted or substituted with one or more selected from the group consisting of deuterium and an aryl group; a naphthobenzofuran group unsubstituted or substituted with one or more selected from the group consisting of deuterium and an aryl group; a benzonaphthothiophene group unsubstituted or substituted with one or more selected from the group consisting of deuterium and an aryl group; a dinaphthofuran group unsubstituted or substituted with one or more selected from the group consisting of deuterium and an aryl group; a dinaphthothiophene group unsubstituted or substituted with one or more selected from the group consisting of deuterium and an aryl group; or a benzobisbenzofuran group unsubstituted or substituted with one or more selected from the group consisting of deuterium and an aryl group.

In an exemplary embodiment of the present specification, Ar11 and Ar12 are the same as or different from each other, and are each independently any one of the following structures, and the following structures are unsubstituted or substituted with deuterium.

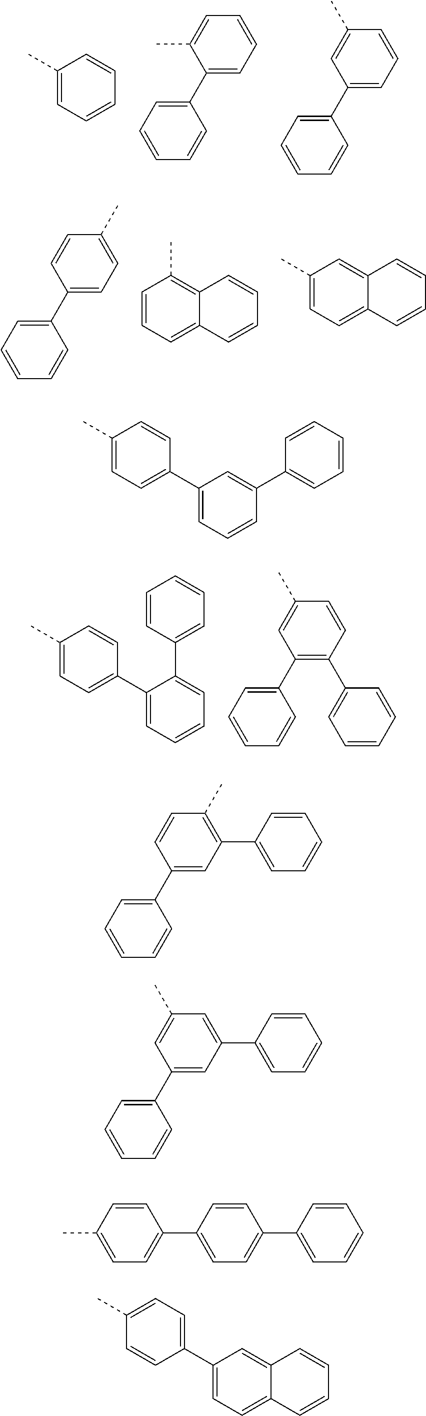

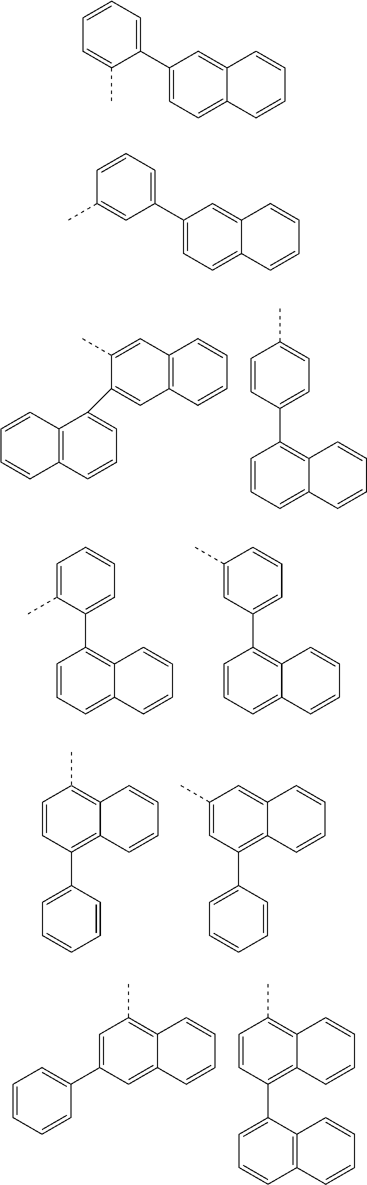

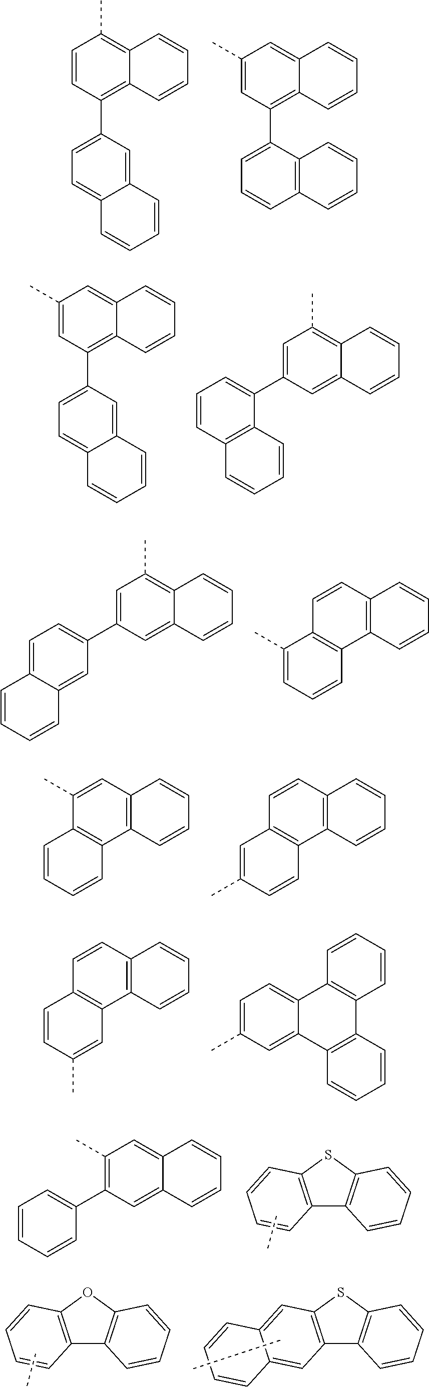

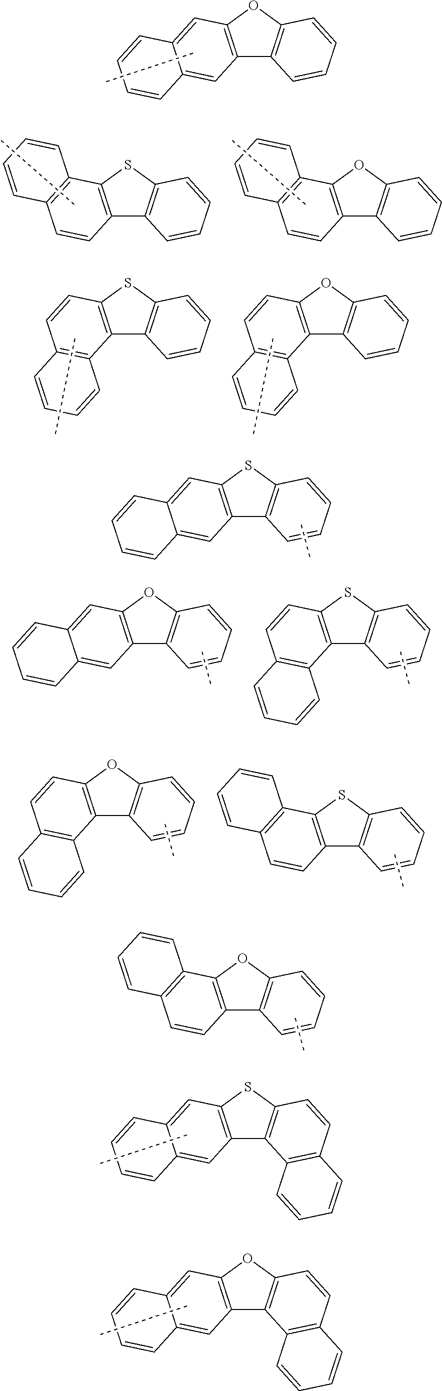

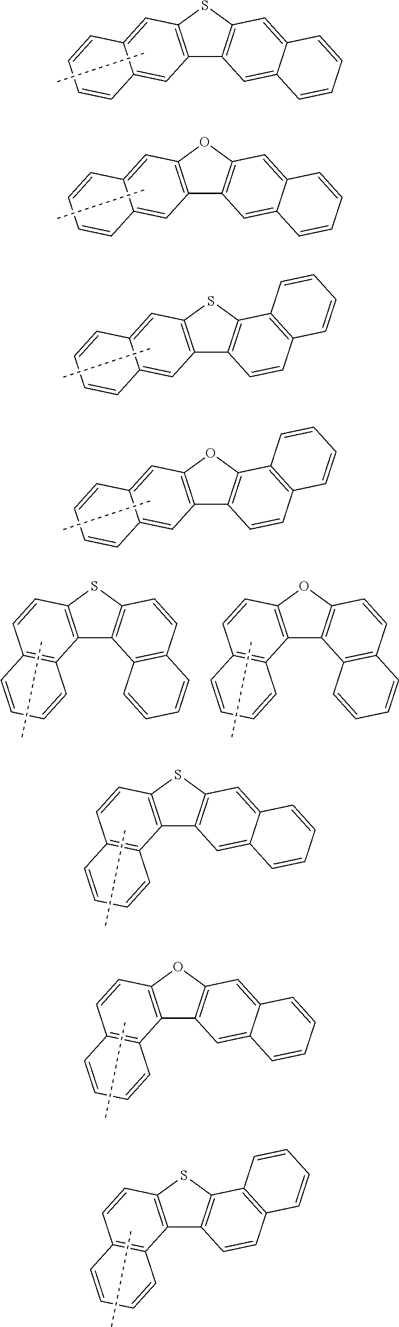

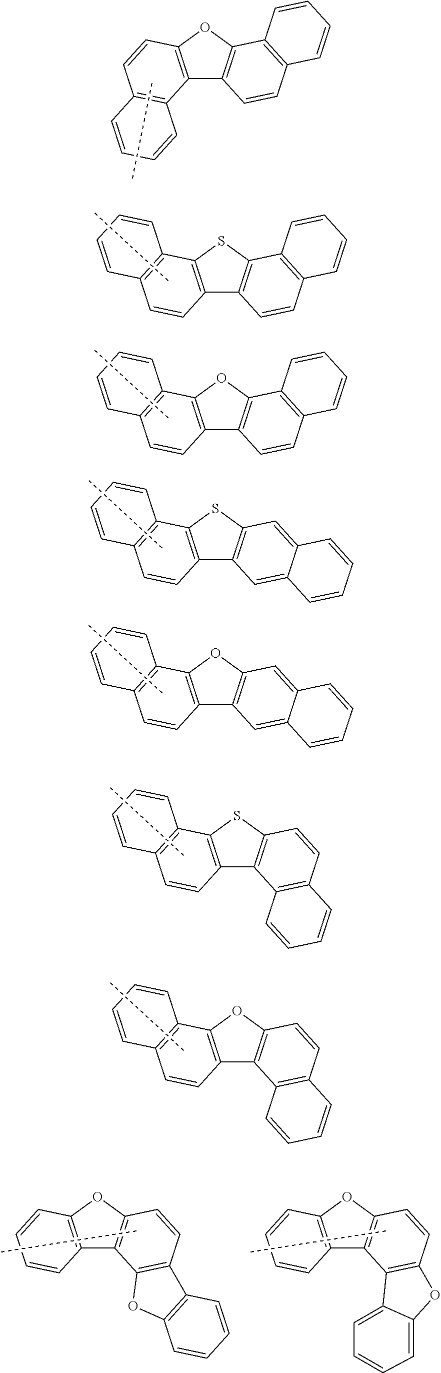

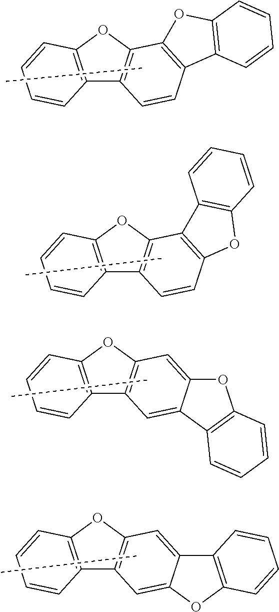

In the structures, - - - - - - is a moiety bonded to Chemical Formula 2.

In an exemplary embodiment of the present specification, the compound represented by Chemical Formula 2 is any one of the following structures.

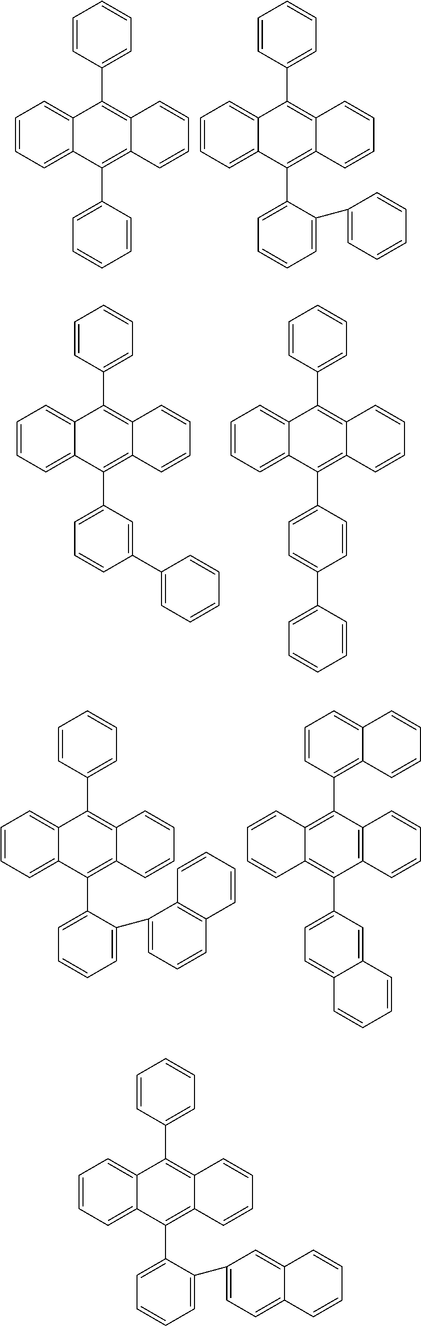

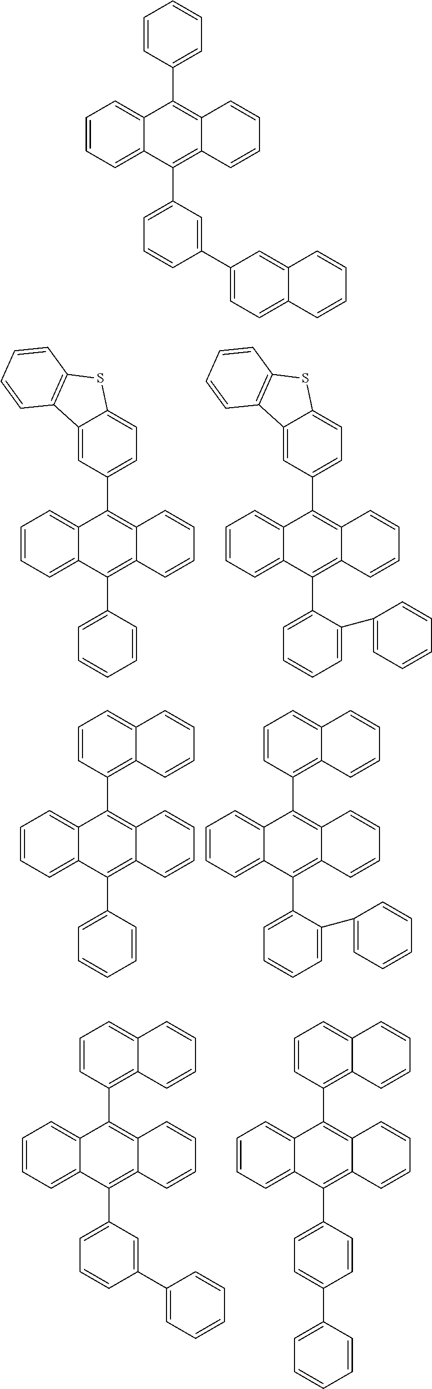

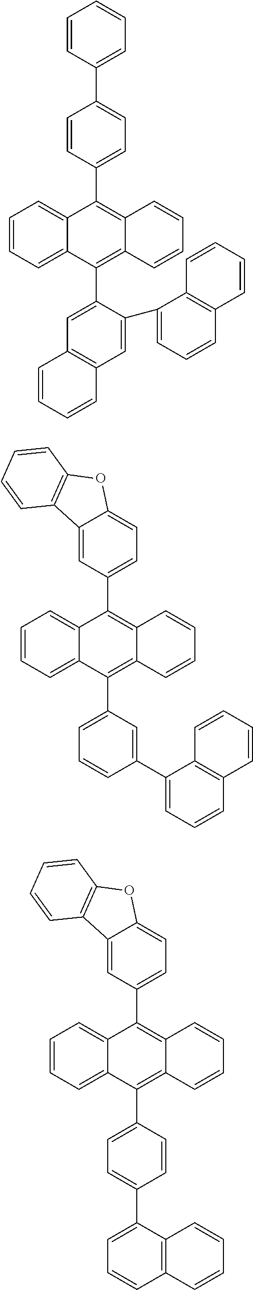

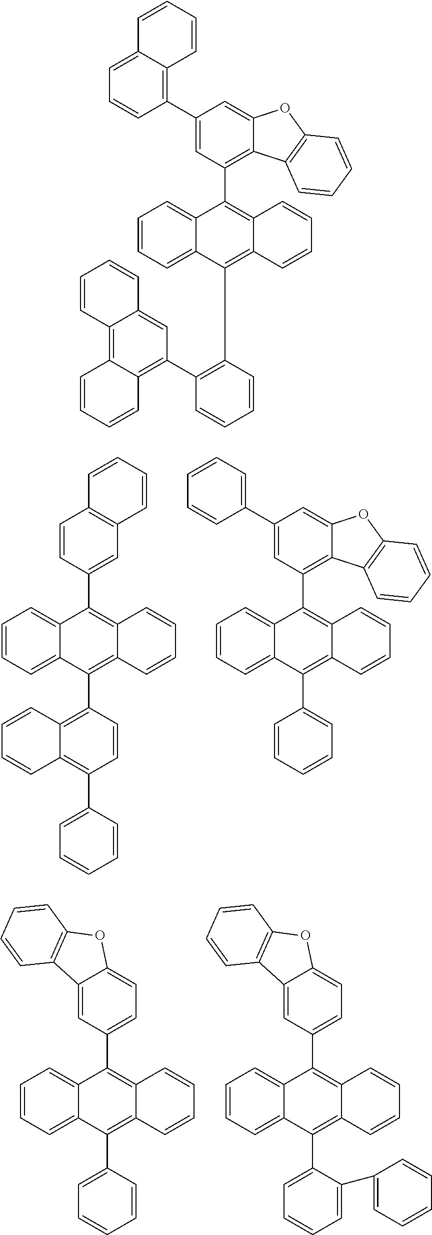

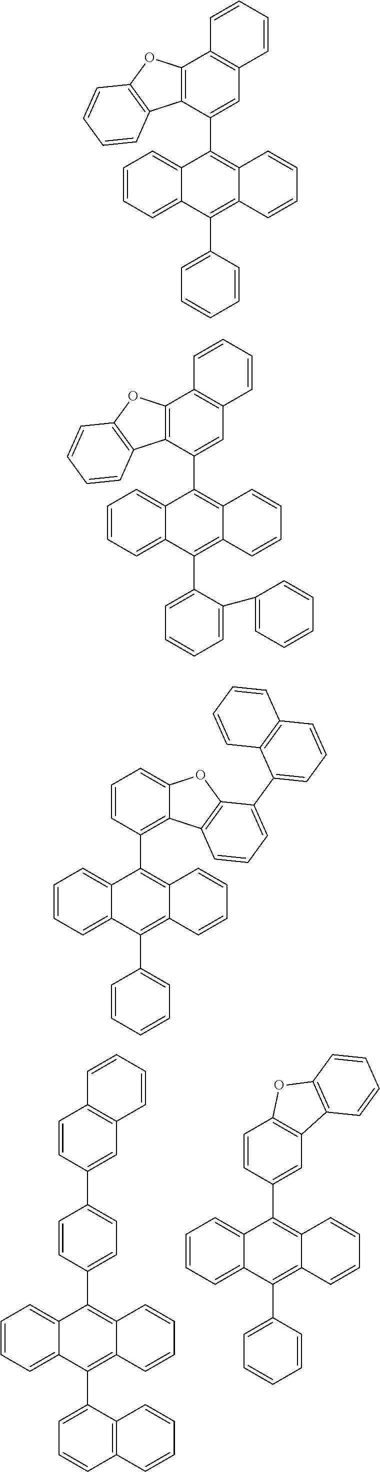

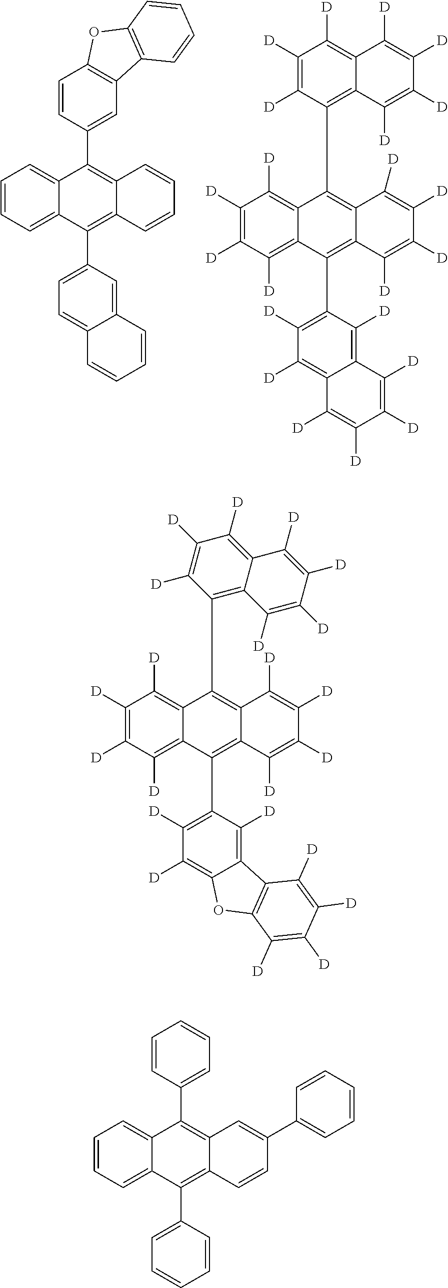

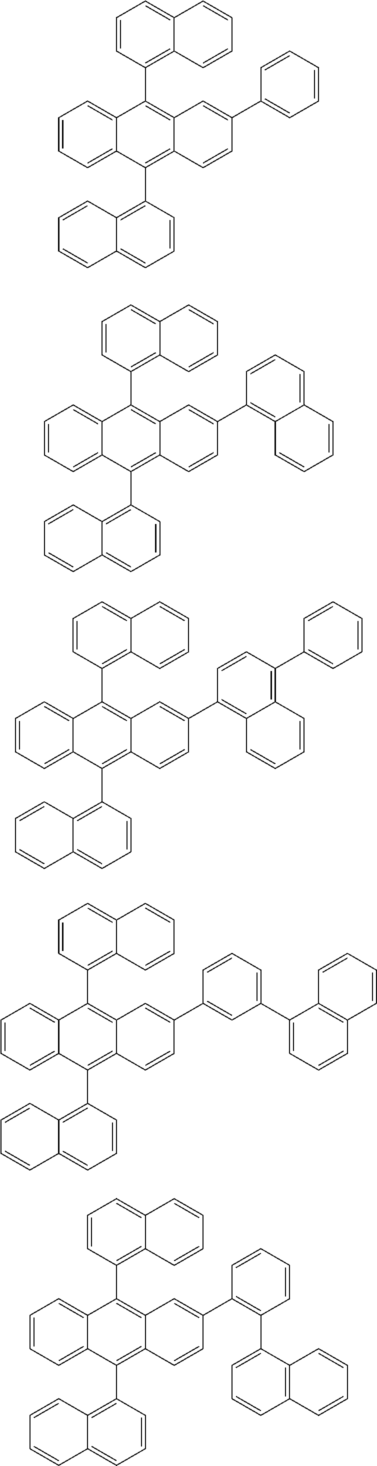

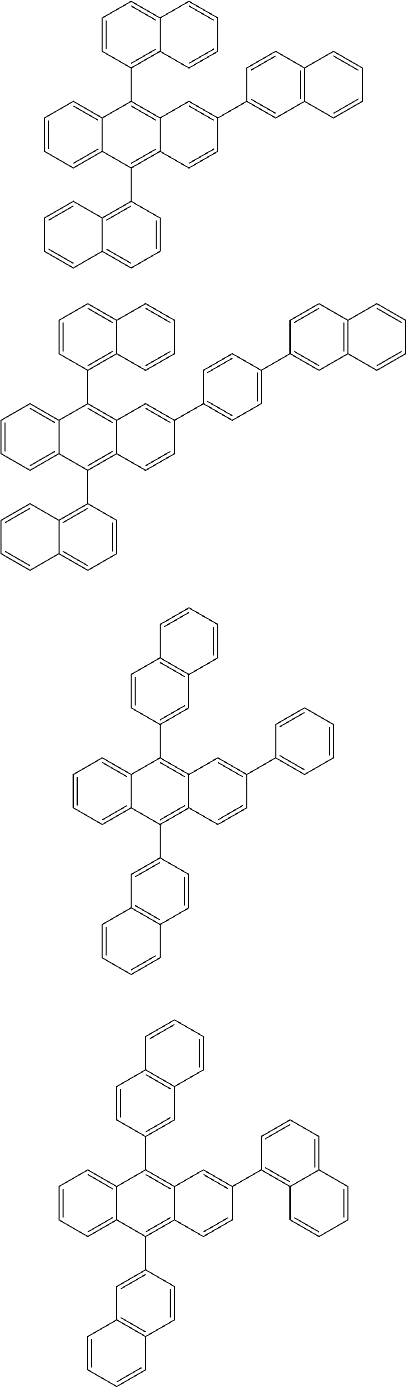

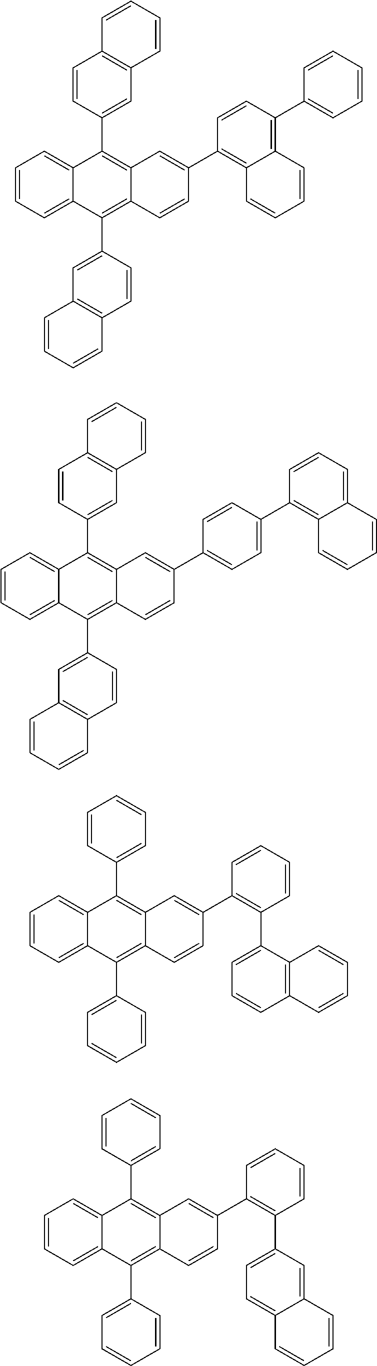

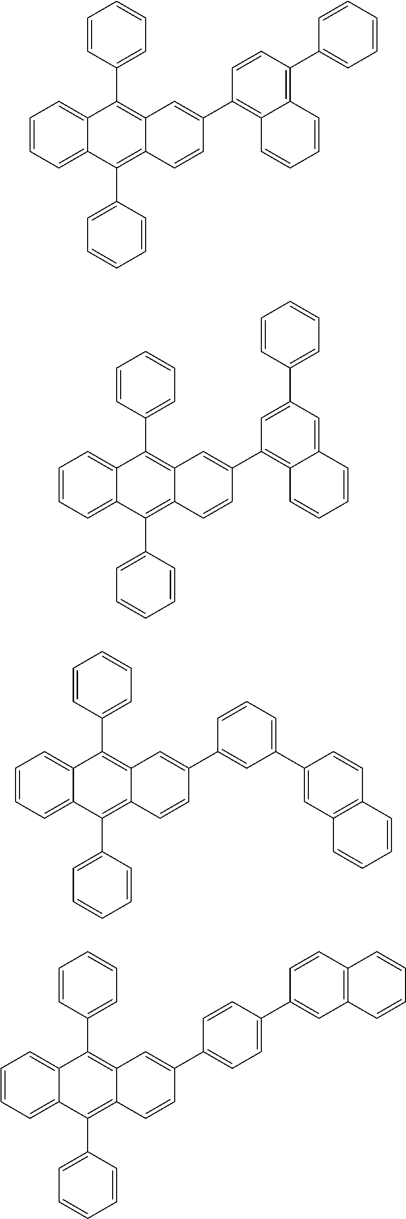

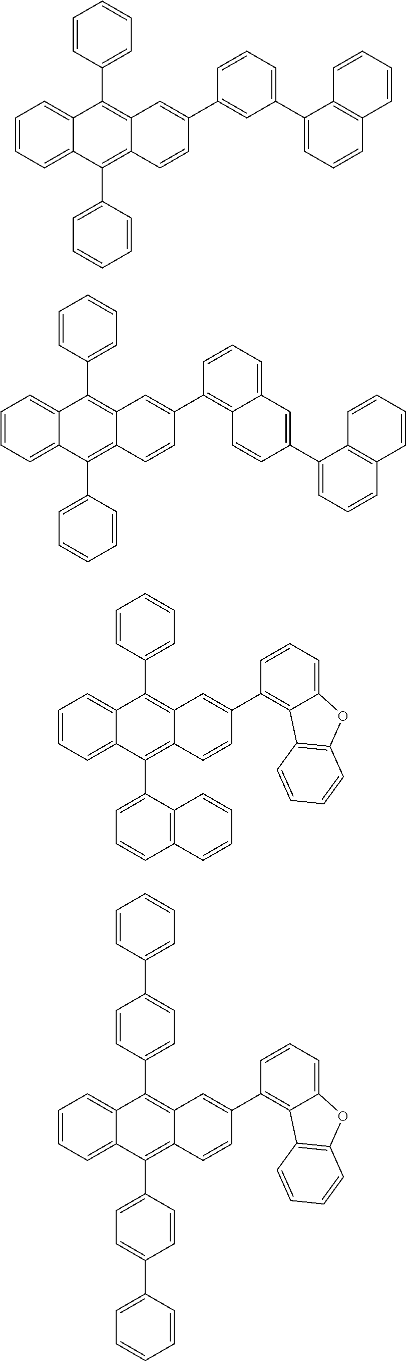

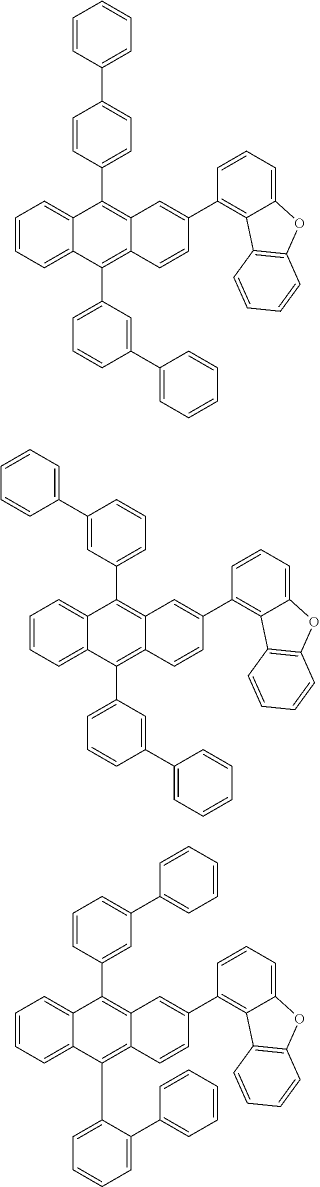

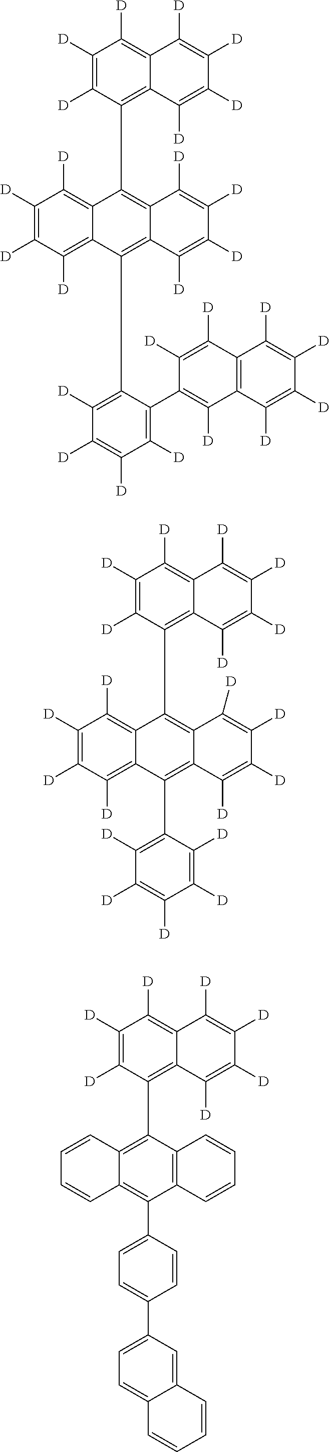 [SMILES: [2H]c1c([2H])c([2H])c(-c2c3c([2H])c([2H])c([2H])c([2H])c3c(-c3c([2H])c([2H])c([2H])c4c([2H])c([2H])c([2H])c([2H])c34)c3c([2H])c([2H])c([2H])c([2H])c23)c(-c2c([2H])c([2H])c3c([2H])c([2H])c([2H])c([2H])c3c2[2H])c1[2H] ; [2H]c1c([2H])c([2H])c(-c2c3c([2H])c([2H])c([2H])c([2H])c3c(-c3c([2H])c([2H])c([2H])c4c([2H])c([2H])c([2H])c([2H])c34)c3c([2H])c([2H])c([2H])c([2H])c23)c([2H])c1[2H] ; [2H]c1c([2H])c([2H])c2c(-c3c4ccccc4c(-c4ccc(-c5ccc6ccccc6c5)cc4)c4ccccc34)c([2H])c([2H])c([2H])c2c1[2H]]

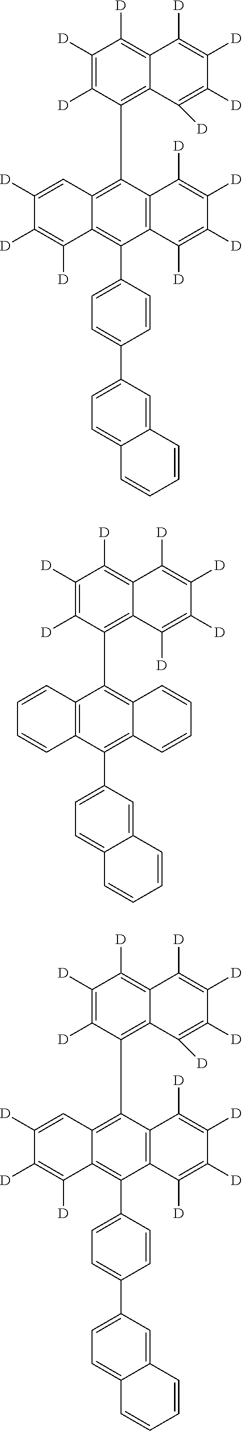

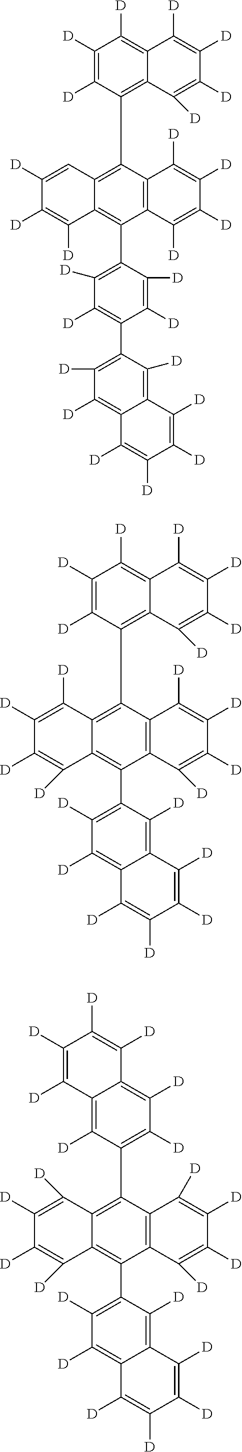

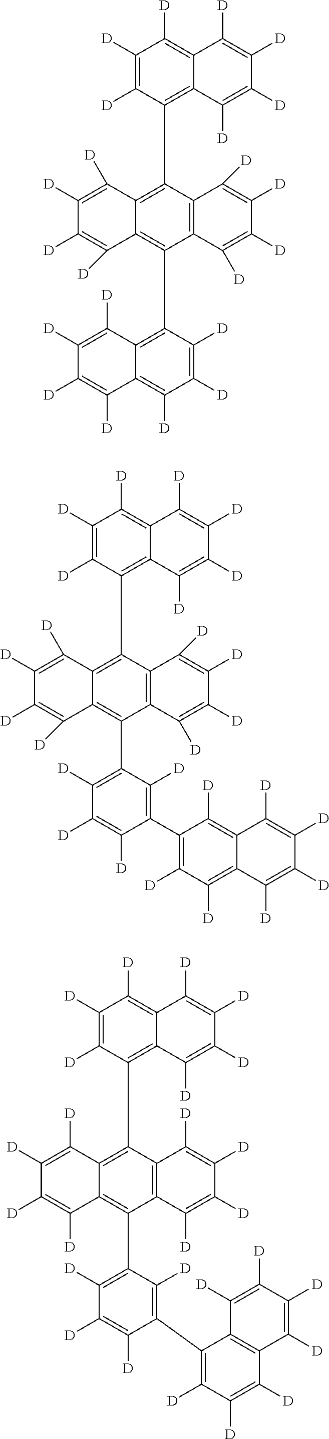

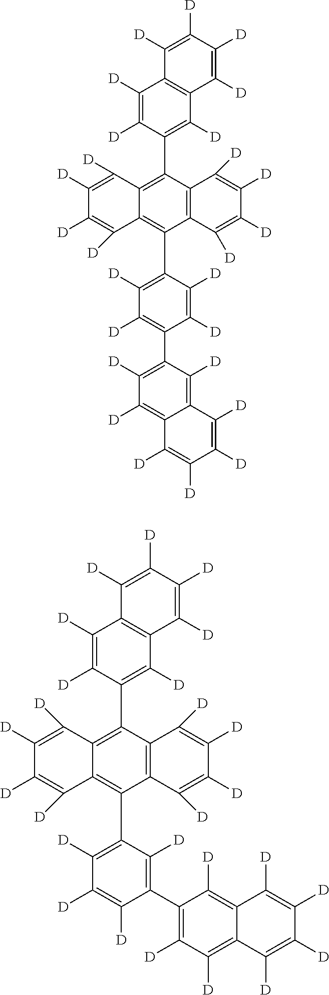 [SMILES: [2H]c1c([2H])c(-c2c3c([2H])c([2H])c([2H])c([2H])c3c(-c3c([2H])c([2H])c4c([2H])c([2H])c([2H])c([2H])c4c3[2H])c3c([2H])c([2H])c([2H])c([2H])c23)c([2H])c([2H])c1-c1c([2H])c([2H])c2c([2H])c([2H])c([2H])c([2H])c2c1[2H] ; [2H]c1c([2H])c(-c2c([2H])c([2H])c3c([2H])c([2H])c([2H])c([2H])c3c2[2H])c([2H])c(-c2c3c([2H])c([2H])c([2H])c([2H])c3c(-c3c([2H])c([2H])c4c([2H])c([2H])c([2H])c([2H])c4c3[2H])c3c([2H])c([2H])c([2H])c([2H])c23)c1[2H]]

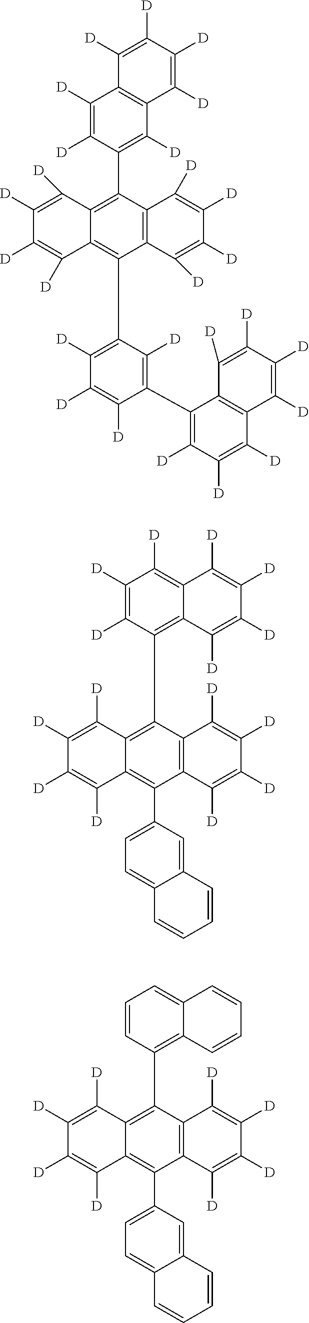

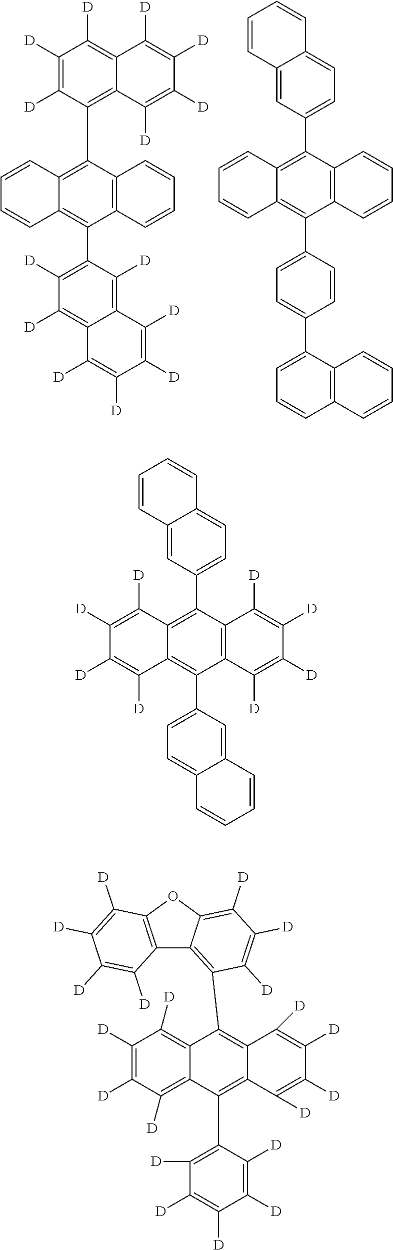

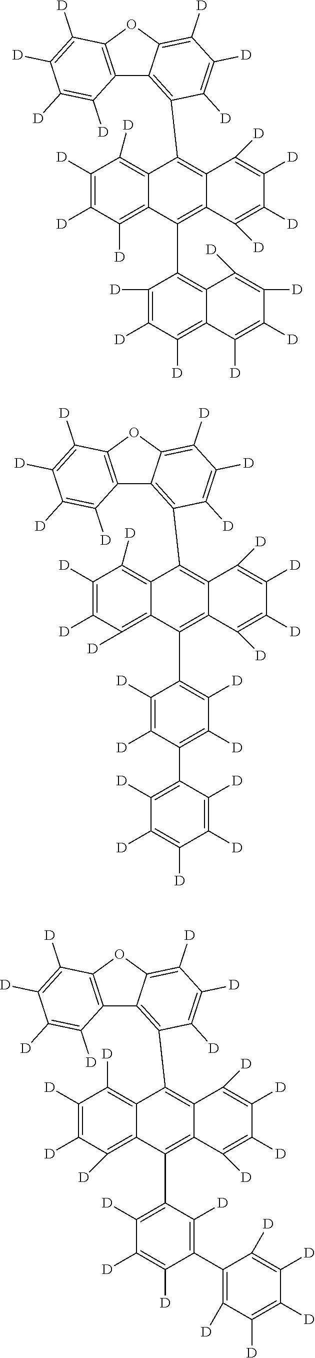

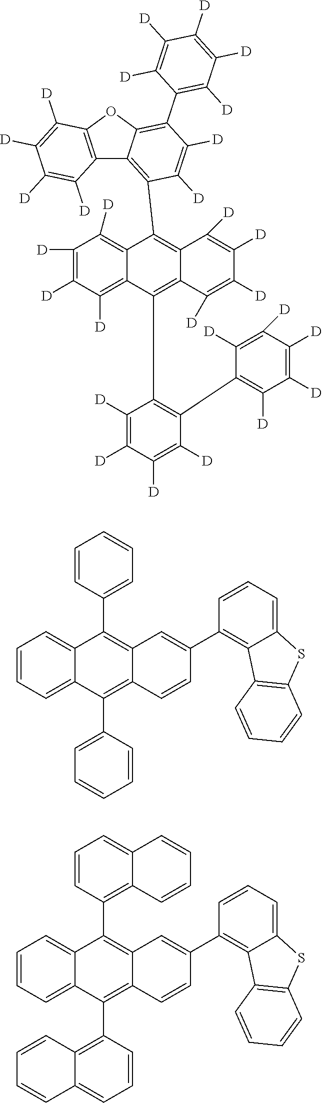

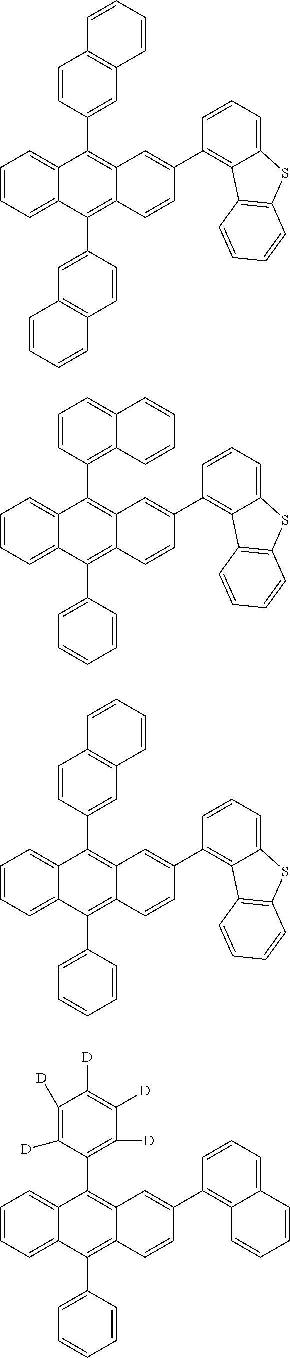

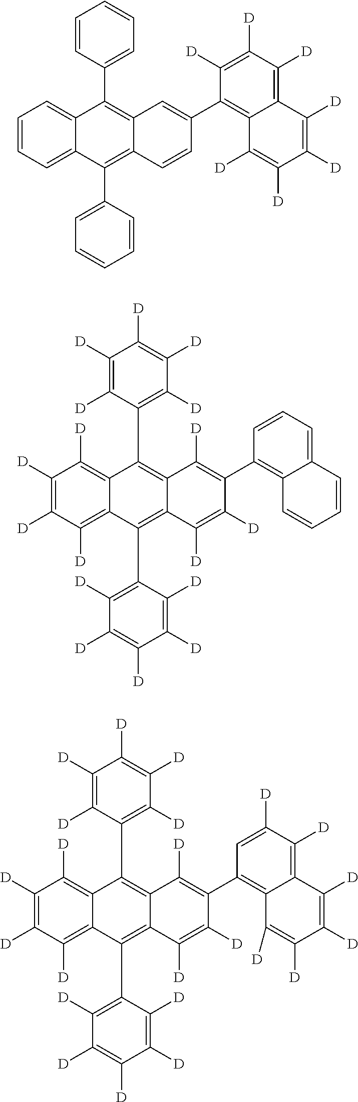

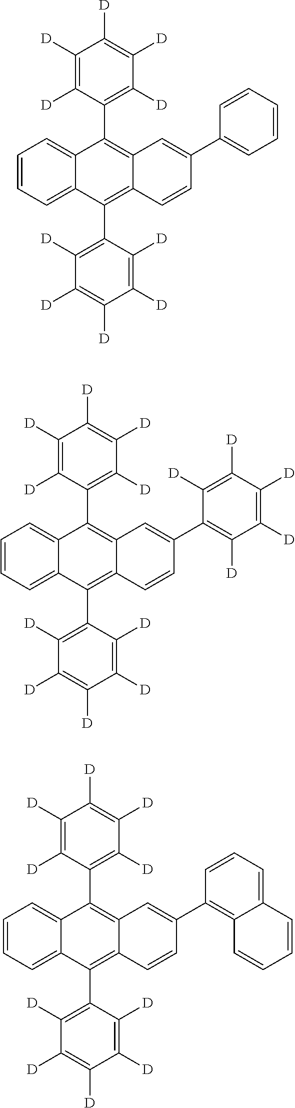

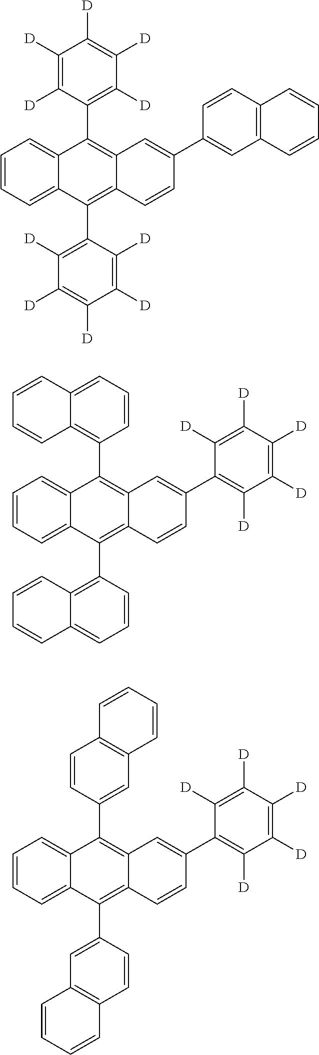

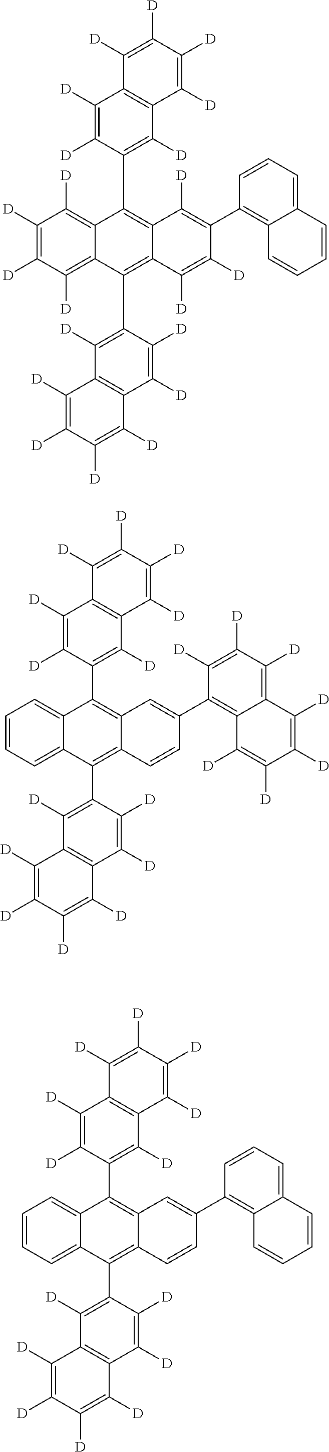

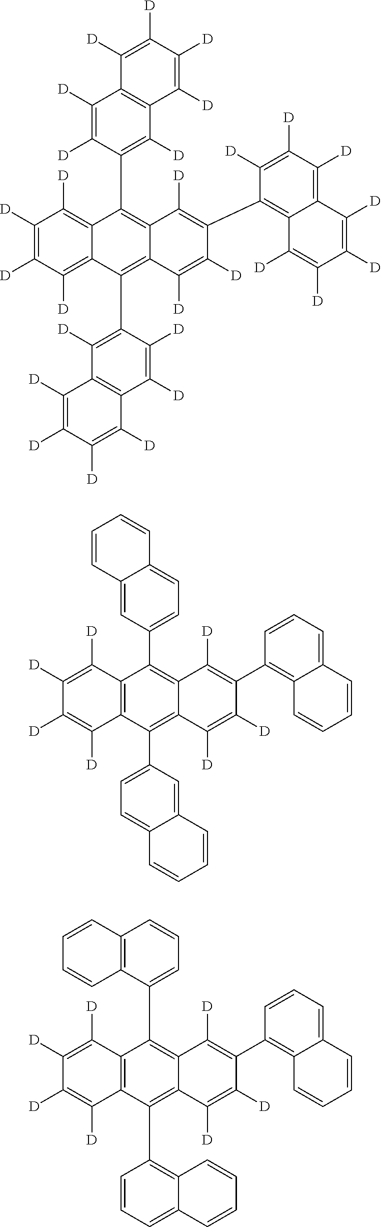

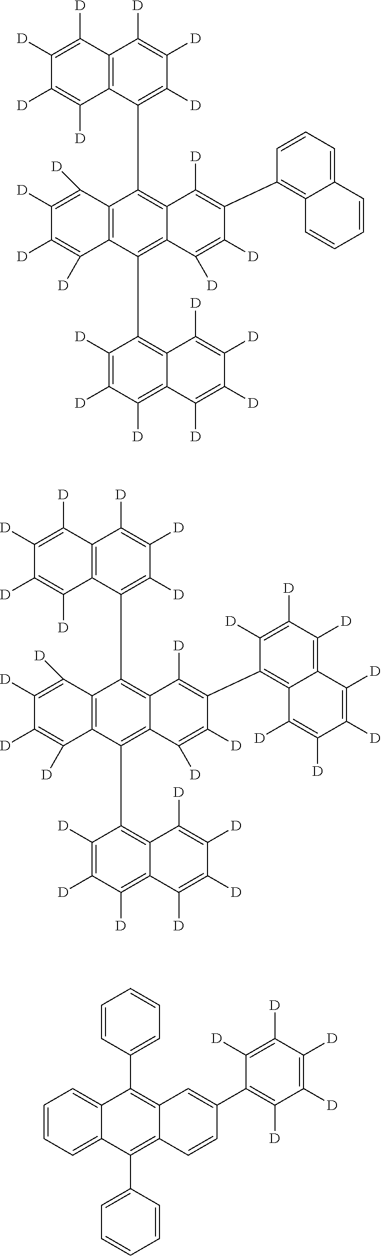

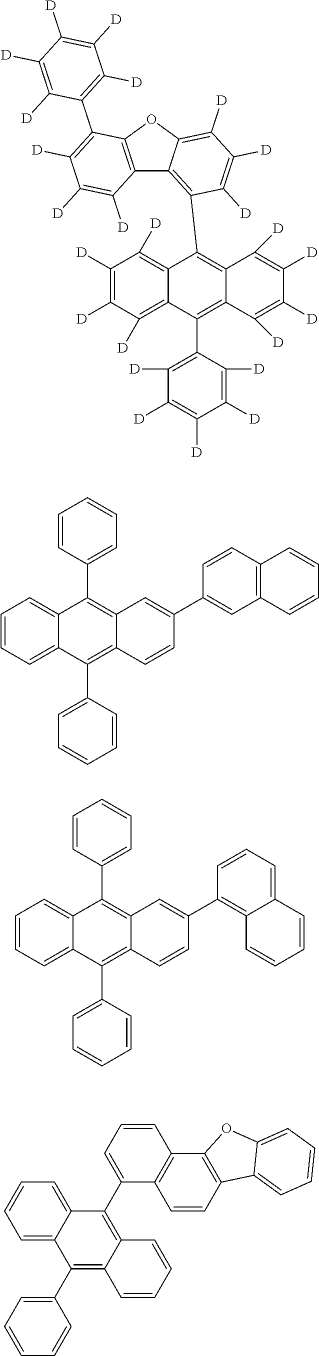

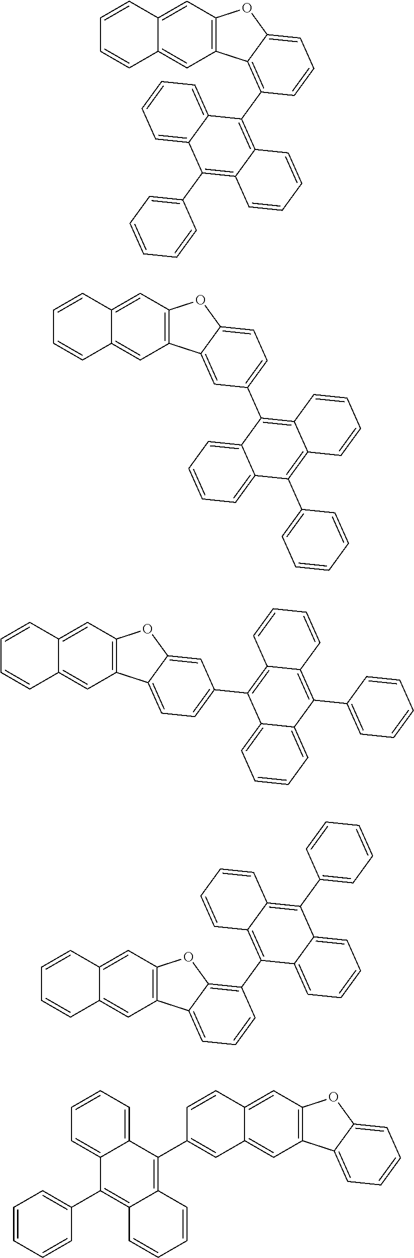

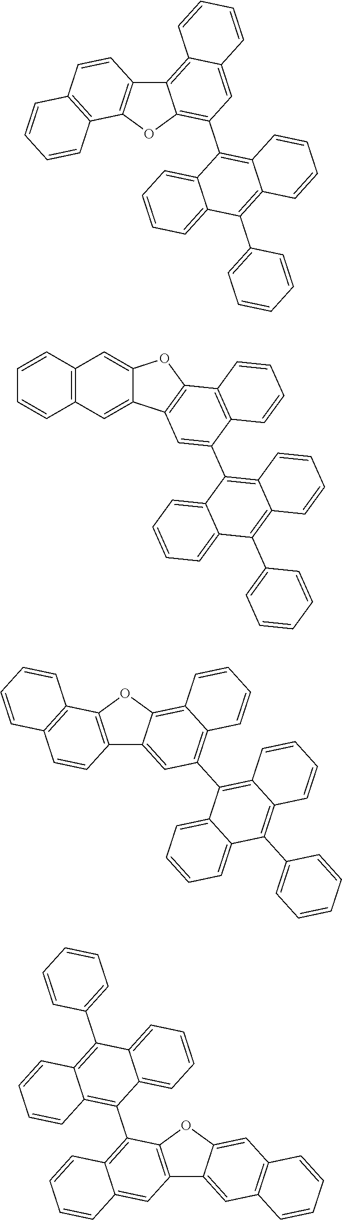 [SMILES: c1ccc(-c2c3ccccc3c(-c3cc4ccccc4c4c3oc3c5ccccc5ccc34)c3ccccc23)cc1 ; c1ccc(-c2c3ccccc3c(-c3cc4c5cc6ccccc6cc5oc4c4ccccc34)c3ccccc23)cc1 ; c1ccc(-c2c3ccccc3c(-c3cc4c5ccc6ccccc6c5oc4c4ccccc34)c3ccccc23)cc1 ; c1ccc(-c2c3ccccc3c(-c3c4ccccc4cc4c3oc3cc5ccccc5cc34)c3ccccc23)cc1]

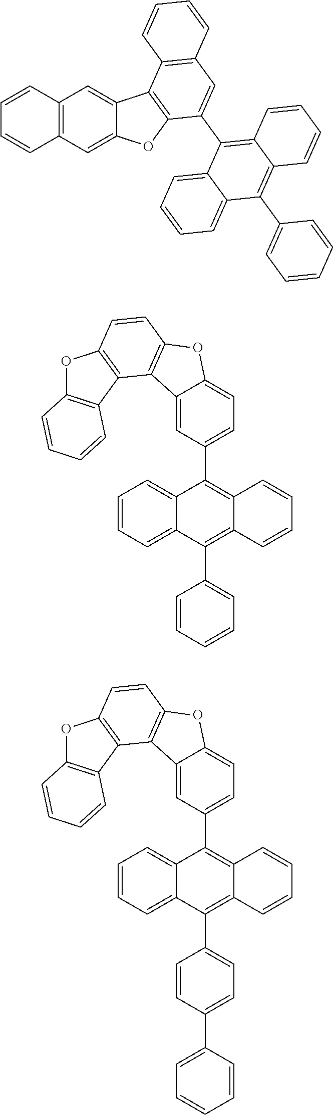 [SMILES: c1ccc(-c2c3ccccc3c(-c3cc4ccccc4c4c3oc3cc5ccccc5cc34)c3ccccc23)cc1 ; c1ccc(-c2c3ccccc3c(-c3ccc4oc5ccc6oc7ccccc7c6c5c4c3)c3ccccc23)cc1 ; c1ccc(-c2ccc(-c3c4ccccc4c(-c4ccc5oc6ccc7oc8ccccc8c7c6c5c4)c4ccccc34)cc2)cc1]

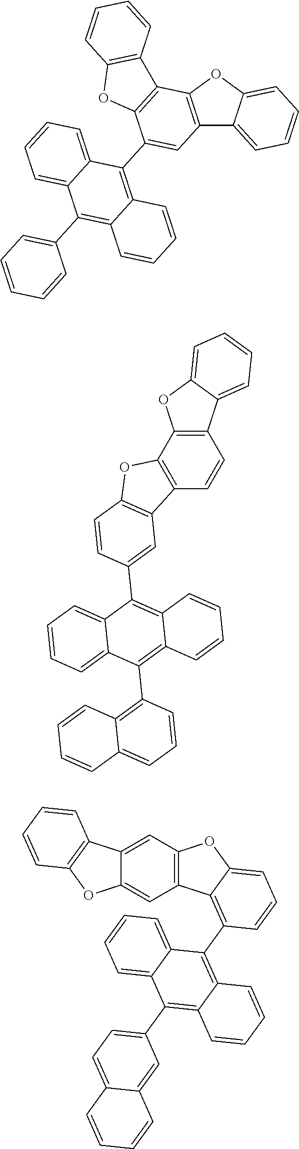

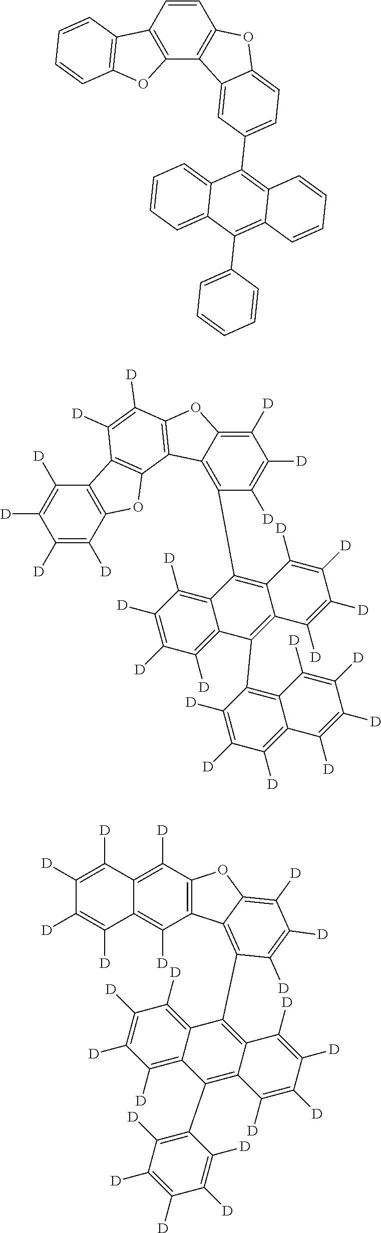 [SMILES: c1ccc(-c2c3ccccc3c(-c3ccc4oc5ccc6c7ccccc7oc6c5c4c3)c3ccccc23)cc1 ; [2H]c1c([2H])c([2H])c2c(oc3c2c([2H])c([2H])c2oc4c([2H])c([2H])c([2H])c(-c5c6c([2H])c([2H])c([2H])c([2H])c6c(-c6c([2H])c([2H])c([2H])c7c([2H])c([2H])c([2H])c([2H])c67)c6c([2H])c([2H])c([2H])c([2H])c56)c4c23)c1[2H] ; [2H]c1c([2H])c([2H])c(-c2c3c([2H])c([2H])c([2H])c([2H])c3c(-c3c([2H])c([2H])c([2H])c4oc5c([2H])c6c([2H])c([2H])c([2H])c([2H])c6c([2H])c5c34)c3c([2H])c([2H])c([2H])c([2H])c23)c([2H])c1[2H]]

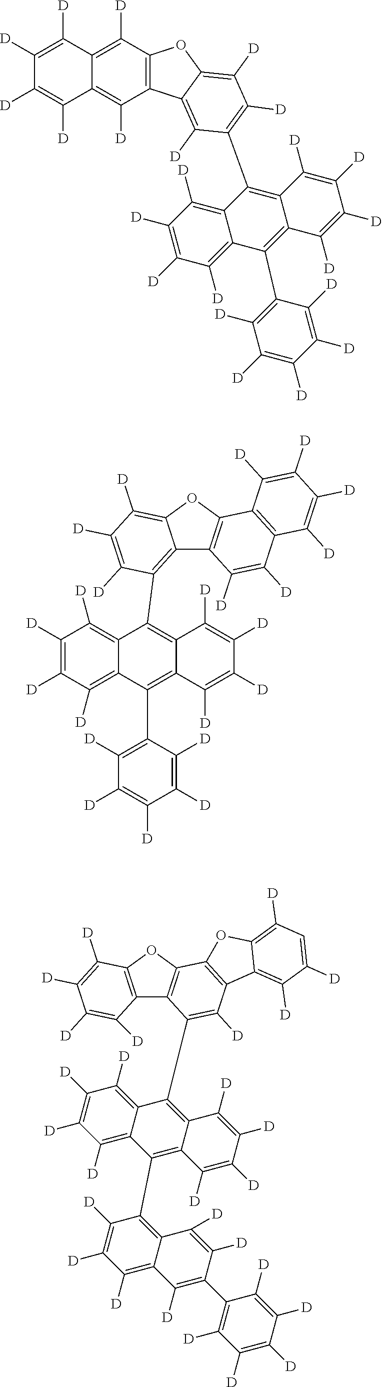

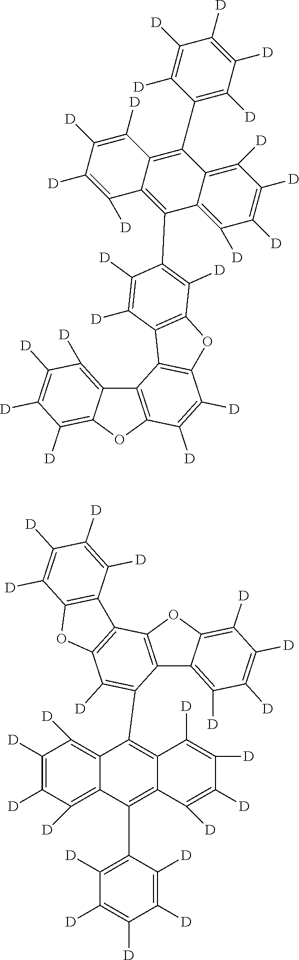 [SMILES: [2H]c1c([2H])c([2H])c(-c2c3c([2H])c([2H])c([2H])c([2H])c3c(-c3c([2H])c([2H])c4c(oc5c([2H])c([2H])c6oc7c([2H])c([2H])c([2H])c([2H])c7c6c54)c3[2H])c3c([2H])c([2H])c([2H])c([2H])c23)c([2H])c1[2H] ; [2H]c1c([2H])c([2H])c(-c2c3c([2H])c([2H])c([2H])c([2H])c3c(-c3c([2H])c4oc5c([2H])c([2H])c([2H])c([2H])c5c4c4oc5c([2H])c([2H])c([2H])c([2H])c5c34)c3c([2H])c([2H])c([2H])c([2H])c23)c([2H])c1[2H]]

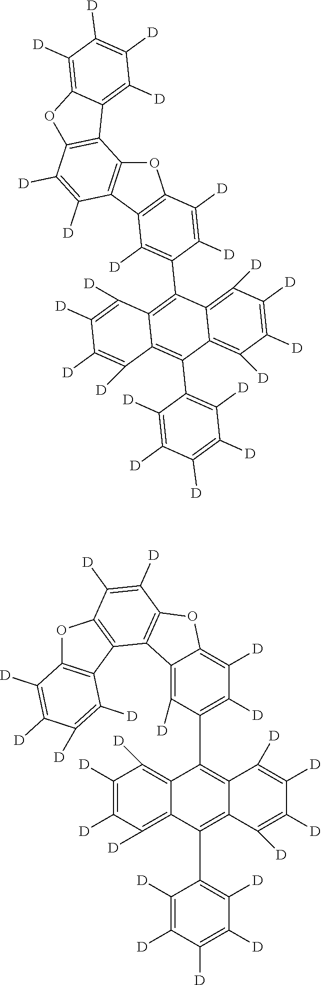 [SMILES: [2H]c1c([2H])c([2H])c(-c2c3c([2H])c([2H])c([2H])c([2H])c3c(-c3c([2H])c([2H])c4oc5c(c([2H])c([2H])c6oc7c([2H])c([2H])c([2H])c([2H])c7c65)c4c3[2H])c3c([2H])c([2H])c([2H])c([2H])c23)c([2H])c1[2H] ; [2H]c1c([2H])c([2H])c(-c2c3c([2H])c([2H])c([2H])c([2H])c3c(-c3c([2H])c([2H])c4oc5c([2H])c([2H])c6oc7c([2H])c([2H])c([2H])c([2H])c7c6c5c4c3[2H])c3c([2H])c([2H])c([2H])c([2H])c23)c([2H])c1[2H]]

The compounds represented by Chemical Formula 1 and Chemical Formula 2 according to an exemplary embodiment of the present specification may be prepared by methods known in the art based on the synthesis examples of the present specification. Further, compounds corresponding to each range of Chemical Formula 1 and Chemical Formula 2 may be synthesized by a synthesis method known in the art using starting materials, intermediate materials, and the like known in the art. In addition, the substituent may be bonded by a method known in the art, and the type and position of the substituent or the number of substituents may be changed according to the technology known in the art, if necessary.

For example, the compounds represented by Chemical Formula 1 and Chemical Formula 2 may be prepared through the following reaction schemes.

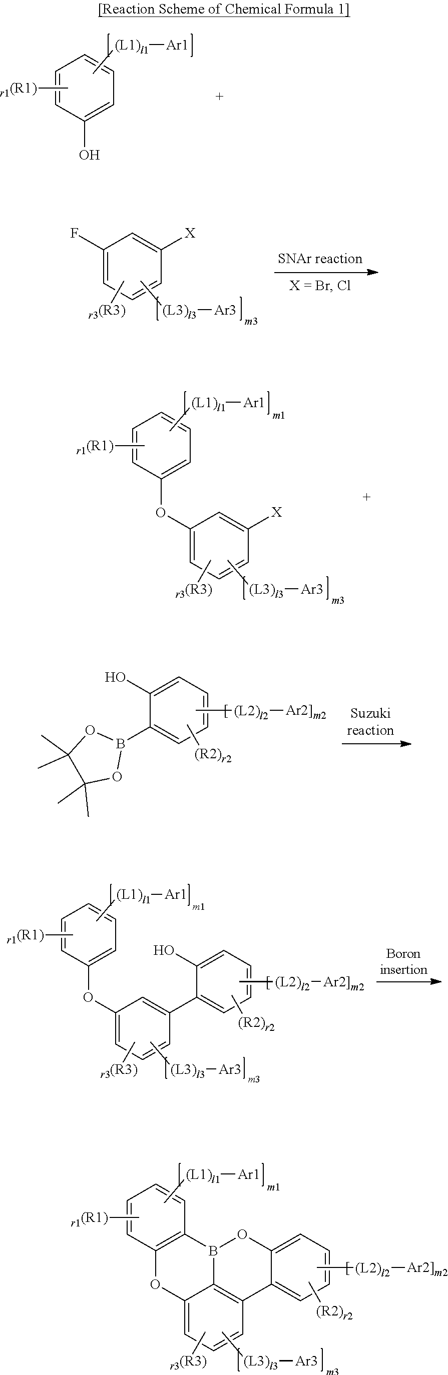

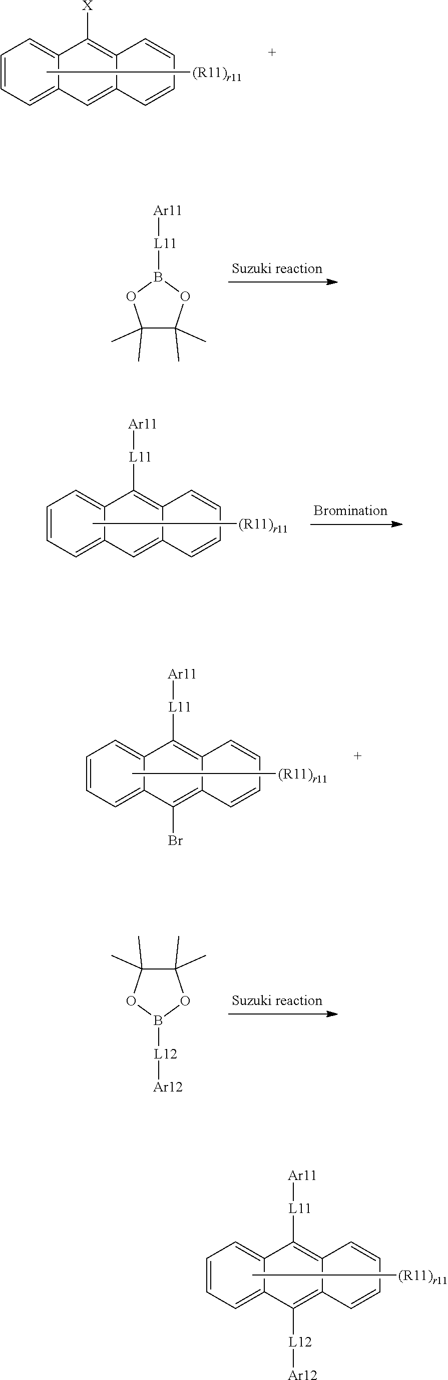

In Reaction Schemes 1 and 2, each substituent is the same as that defined in Chemical Formulae 1 and 2.

In the present specification, compounds having various energy band gaps may be synthesized by introducing various substituents into the core structures of the compounds represented by Chemical Formula 1 and/or Chemical Formula 2. Further, in the present specification, various substituents may be introduced into the core structures having the structure described above to adjust the HOMO and LUMO energy levels of a compound.

In order to understand the distribution of electrons in the molecule and optical properties, a determined structure is required. Furthermore, an electronic structure has different structures in neutral, anionic, and cationic states depending on the charge state of the molecule. In order to drive a device, all the energy levels in the neutral state, the cationic state, and the anionic state are important, and a highest occupied molecular orbital (HOMO) and a lowest unoccupied molecular orbital (LUMO) in the neutral state are representatively recognized as important properties. In order to determine the molecular structure of a chemical material, a structure inputted using a density functional theory (DFT) is optimized.

In an exemplary embodiment of the present specification, in order to calculate a DFT, a BPW91 calculation method (Becke exchange and Perdew correlation-correlation functional) and a double numerical basis set including polarization functional (DNP) basis set may be used. The BPW91 calculation method is published in the paper ‘A. D. Becke, Phys. Rev. A, 38, 3098 (1988)’ and ‘′J. P. Perdew and Y. Wang, Phys. Rev. B, 45, 13244 (1992)’, and the DNP basis set is published in the paper ‘B. Delley, J. Chem. Phys., 92, 508 (1990)’.

In an exemplary embodiment of the present specification, a weight ratio of the compound represented by Chemical Formula 1 and the compound represented by Chemical Formula 2 is 1:99 to 50:50.

When the above-described weight ratio is satisfied, electrons are easily injected into the triplet energy level of the dopant provided by the compound of Chemical Formula 1 while reproducing the low voltage and high efficiency provided by the compound represented by Chemical Formula 2, so that there is an advantage in that the light emitting efficiency is increased because the proportion of excitons formed is increased.

In an exemplary embodiment of the present specification, the sublimation temperature (T_{sub1}) of the compound represented by Chemical Formula 1 and the sublimation temperature (T_{sub2}) of the compound represented by Chemical Formula 2 satisfy the following Equation (1).

$$\vert {T}_{sub 1} - {T}_{sub 2} \vert \leq 20 ° C . \qquad Equation ( 1 )$$

When the above-described sublimation temperature difference is satisfied, electrons are easily injected into the triplet energy level of the dopant provided by the compound of Chemical Formula 1 while reproducing the low voltage and high efficiency provided by the compound represented by Chemical Formula 2, so that there is an advantage in that the light emitting efficiency is increased because the proportion of excitons formed is increased.

In an exemplary embodiment of the present specification, the triplet energy level (Tₕ₁) of the compound represented by Chemical Formula 1 is 2.10 eV or more.

In an exemplary embodiment of the present specification, the triplet energy level (Tₕ₁) of the compound represented by Chemical Formula 1 is 2.10 eV≤Tₕ₁≤2.70 eV.

In an exemplary embodiment of the present specification, the triplet energy level (Tₕ₁) of the compound represented by Chemical Formula 1 is 2.10 eV or more, 2.11 eV or more, or 2.12 eV or more.

In an exemplary embodiment of the present specification, the triplet energy level (Tₕ₁) of the compound represented by Chemical Formula 1 is 2.70 eV or less, 2.65 eV or less, 2.60 eV or less, 2.55 eV or less, 2.50 eV or less, 2.45 eV or less, or 2.40 eV or less.

In an exemplary embodiment of the present specification, the triplet energy level (Tₕ₁) of the compound represented by Chemical Formula 1 is higher than the triplet energy level (Tₕ₂) of the compound represented by Chemical Formula 2.

In an exemplary embodiment of the present specification, the triplet energy level (Tₕ₂) of the compound represented by Chemical Formula 2 is 1.40 eV or more.

In an exemplary embodiment of the present specification, the triplet energy level (Tₕ₂) of the compound represented by Chemical Formula 2 is 1.40 eV≤Tₕ₂≤1.80 eV.

In an exemplary embodiment of the present specification, the triplet energy level (Tₕ₂) of the compound represented by Chemical Formula 2 is 1.40 eV or more, 1.45 eV or more, 1.50 eV or more, or 1.55 eV or more.

In an exemplary embodiment of the present specification, the triplet energy level (Tₕ₂) of the compound represented by Chemical Formula 2 is 1.80 eV or less, 1.75 eV or less, 1.70 eV or less, or 1.65 eV or less.

In the organic light emitting device according to an exemplary embodiment of the present specification, the difference (Δ(Tₕ₁−Tₕ₂)) between the triplet energy level (Tₕ₁) of the compound represented by Chemical Formula 1 and the triplet energy level (Tₕ₂) of the compound represented by Chemical Formula 2 satisfies the following Equation (2).

$$Δ ( {T}_{h 1} - {T}_{h 2} ) \leq 0.9 eV \qquad Equation ( 2 )$$

In an exemplary embodiment of the present specification, the difference (Δ(Tₕ₁−Tₕ₂)) between the triplet energy level (Tₕ₁) of the compound represented by Chemical Formula 1 and the triplet energy level (Tₕ₂) of the compound represented by Chemical Formula 2 is 0.90 eV or less, 0.87 eV or less, 0.85 eV or less, 0.83 eV or less, 0.81 eV or less, 0.79 eV or less, 0.77 eV or less, or 0.75 eV or less.

In an exemplary embodiment of the present specification, the lower limit of the difference (Δ(Tₕ₁−Tₕ₂)) is not limited, but is, for example, 0 eV or more, 0.1 eV or more, 0.15 eV or more, or 0.2 eV or more.

In an exemplary embodiment of the present specification, the triplet energy level (Tₕ₁) of the compound represented by Chemical Formula 1, the triplet energy level (Tₕ₂) of the compound represented by Chemical Formula 2, and the triplet energy level (T_{BD}) of a blue fluorescent dopant satisfy at least one of the following Equations (3) and (4).

$$Δ ( {T}_{BD} - {T}_{h 1} ) \leq 0.4 eV \qquad Equation ( 3 )$$

$$Δ ( {T}_{BD} - {T}_{h 2} ) \geq 0.05 eV \qquad Equation ( 4 )$$

In an exemplary embodiment of the present specification, the difference (Δ(T_{BD}−Tₕ₁)) between the triplet energy level (Tₕ₁) of the compound represented by Chemical Formula 1 and the triplet energy level (T_{BD}) Of the blue fluorescent dopant is 0.40 eV or less, 0.35 eV or less, or 0.30 eV or less.

In an exemplary embodiment of the present specification, the lower limit of the difference (Δ(T_{BD}-Tₕ₁)) is not limited, but is, for example, 0 eV or more, 0.05 eV or more, or 0.1 eV or more.

In an exemplary embodiment of the present specification, the difference (Δ(T_{BD}−Tₕ₂)) between the triplet energy level (Tₕ₂) of the compound represented by Chemical Formula 2 and the triplet energy level (T_{BD}) Of the blue fluorescent dopant is 0.05 eV or more, 0.06 eV or more, or 0.07 eV or more.

In an exemplary embodiment of the present specification, the upper limit of the difference (Δ(T_{BD}−Tₕ₂)) is not limited, but is, for example, 0.5 eV or less, 0.45 eV or less, or 0.4 eV or less.

In an exemplary embodiment of the present specification, the triplet energy level (Tₕ₁) of the compound represented by Chemical Formula 1, the triplet energy level (Tₕ₂) of the compound represented by Chemical Formula 2, and the triplet energy level (T_{BD}) of the blue fluorescent dopant may satisfy both Equations (3) and (4).

When Equation (3) and/or Equation (4) are/is satisfied, electrons are easily injected into the triplet energy level of the dopant, so that the efficiency is increased because the proportion of excitons formed is increased.

In the present specification, the triplet energy level (T) can be measured using a spectroscopic device capable of measuring fluorescence and phosphorescence.

In an exemplary embodiment of the present specification, the triplet energy level can be measured under the following measurement conditions. The triplet energy level is confirmed by preparing a solution at a concentration of 10-6 M with toluene or tetrahydrofuran (THF) as a solvent in an extremely low temperature state using liquid nitrogen, irradiating the solution with a light source at an absorption wavelength band of a material, excluding the singlet light emission from the light emitting spectrum, and analyzing the spectrum emitted at the triplet energy level. When electrons are excited from the light source, two components can be separated from each other in the extremely low temperature state because the time for electrons to stay at the triplet energy level is much longer than the time for the electrons to stay at the singlet energy level.

In an exemplary embodiment of the present specification, the triplet energy level may be calculated using Gaussian 03, a quantum chemical calculation program manufactured by Gaussian, Inc., USA. Specifically, a calculated value of the triplet energy level may be obtained by the time-dependent-density functional theory (TD-DFT) with respect to a structure optimized using B3LYP (Becke, three-parameter, Lee-Yang-Parr) as a functional and 6-31G* as a basis function by using the density functional theory (DFT).

In an exemplary embodiment of the present specification, the triplet energy (Er) may be calculated by the following method. After a sample is cooled to 77 K, the sample for the measurement of phosphorescence is irradiated with excitation light (360 nm), the phosphorescence intensity is measured using a streak camera, and then a tangent to an ascending point of the phosphorescence spectrum is drawn, a wavelength value λedge [nm] at the intersection of the tangent and the x-axis is obtained, and an ET1 value converted into an energy value may be calculated by substituting this wavelength value for the following Equation (5). In this case, the light emitting spectrum was measured using a nitrogen laser (MNL200, manufactured by Lasertechnik Berlin GmbH) and a streak camera (C4334, manufactured by Hamamatsu Photonics K.K.).

$${E}_{T} [ eV ] = 1239.85 / λ edge \qquad Equation ( 5 )$$

In the organic light emitting device according to an exemplary embodiment of the present specification, in the light emitting layer, the maximum light emitting wavelength (λmax) of the compound represented by Chemical Formula 1 and the compound represented by Chemical Formula 2 may each be in a range of 400 nm or more and 500 nm or less.

Preferably, the maximum light emitting wavelength (λmax) of the compound represented by Chemical Formula 1 and the second compound represented by Chemical Formula 2 may each be in a range of 400 nm or more and 485 nm or less, or 400 nm or more and 470 nm or less. When such a configuration is satisfied, the light emitting layer may emit blue light.

Hereinafter, the stacked structure and organic material layer of the organic light emitting device will be described.

The organic light emitting device of the present specification may be manufactured by typical methods and materials for manufacturing an organic light emitting device, except that a light emitting layer is formed using the above-described compound represented by Chemical Formula 1 and the compound represented by Chemical Formula 2.

In an exemplary embodiment of the present specification, the organic light emitting device may be a normal type organic light emitting device in which an anode, a light emitting layer, and a cathode are sequentially stacked on a substrate.

In an exemplary embodiment of the present specification, the organic light emitting device may be an inverted type organic light emitting device in which a cathode, a light emitting layer, and an anode are sequentially stacked on a substrate.

In an exemplary embodiment of the present specification, an organic material layer having one or more layers is further provided between the anode and the cathode, and the organic material layer includes one or more layers of a hole transport layer, a hole injection layer, a hole transport and injection layer, an electron blocking layer, an electron transport layer, an electron injection layer, an electron transport and injection layer and a hole blocking layer.

In an exemplary embodiment of the present specification, the organic material layer includes a hole blocking layer, an electron transport layer or an electron injection layer. In this case, the hole blocking layer, the electron transport layer, and the electron injection layer may or may not include the compound.

In an exemplary embodiment of the present specification, the organic material layer includes a hole injection layer, a hole transport layer, or an electron blocking layer. In this case, the hole blocking layer, the electron transport layer, and the electron injection layer may or may not include the compound.

In an exemplary embodiment of the present specification, the organic light emitting device includes: an anode; a cathode; and a light emitting layer provided between the anode and the cathode, and further includes a single-layered organic material layer between the light emitting layer and the anode.

In an exemplary embodiment of the present specification, the organic light emitting device includes: an anode; a cathode; and a light emitting layer provided between the anode and the cathode, and further includes a multi-layered organic material layer between the light emitting layer and the anode.

In an exemplary embodiment of the present specification, the organic light emitting device includes: an anode; a cathode; and a light emitting layer provided between the anode and the cathode, and further includes one or more layers of a hole injection layer, a hole transport layer, and an electron blocking layer between the light emitting layer and the anode.

In an exemplary embodiment of the present specification, the organic light emitting device includes: an anode; a cathode; and a light emitting layer provided between the anode and the cathode, and further includes a hole injection layer, a hole transport layer, and an electron blocking layer between the light emitting layer and the anode.

In an exemplary embodiment of the present specification, the organic light emitting device has a structure in which an anode; a hole injection layer; a hole transport layer; an electron blocking layer; a light emitting layer; and a cathode are sequentially stacked, and an additional organic material layer may be further provided between each of the layers.

In an exemplary embodiment of the present specification, the organic light emitting device includes: an anode; a cathode; and a light emitting layer provided between the anode and the cathode, and further includes a single-layered organic material layer between the light emitting layer and the cathode.

In an exemplary embodiment of the present specification, the organic light emitting device includes: an anode; a cathode; and a light emitting layer provided between the anode and the cathode, and further includes a multi-layered organic material layer between the light emitting layer and the cathode.

In an exemplary embodiment of the present specification, the organic light emitting device includes: an anode; a cathode; and a light emitting layer provided between the anode and the cathode, and further includes one or more layers of a hole blocking layer an electron injection layer, an electron transport layer, and an electron injection and transport layer between the cathode and the light emitting layer.

In an exemplary embodiment of the present specification, the organic light emitting device includes: an anode; a cathode; and a light emitting layer provided between the anode and the cathode, and includes a hole blocking layer and an electron injection and transport layer between the cathode and the light emitting layer.

In an exemplary embodiment of the present specification, the organic light emitting device has a structure in which an anode; a light emitting layer; a hole blocking layer; an electron injection and transport layer; and a cathode are sequentially stacked, and an additional organic material layer may be further provided between each of the layers.

In an exemplary embodiment of the present specification, the organic light emitting device includes: an anode; a cathode; and a light emitting layer provided between the anode and the cathode, and includes an electron transport layer and an electron injection layer between the cathode and the light emitting layer.

In an exemplary embodiment of the present specification, the organic light emitting device has a structure in which an anode; a light emitting layer; a hole blocking layer; an electron transport layer; an electron injection layer; and a cathode are sequentially stacked, and an additional organic material layer may be further provided between each of the layers.

In an exemplary embodiment of the present specification, the organic light emitting device has a structure in which an anode; a hole injection layer; a hole transport layer; an electron blocking layer; a light emitting layer; a hole blocking layer; an electron injection and transport layer; and a cathode are sequentially stacked.

In an exemplary embodiment of the present specification, the organic light emitting device has a structure in which an anode; a hole injection layer; a hole transport layer; an electron blocking layer; a light emitting layer; an electron transport layer; an electron injection layer; and a cathode are sequentially stacked.

In an exemplary embodiment of the present specification, the light emitting layer may be composed of a single layer, but may also be a plurality of layers having two or more layers.

In an exemplary embodiment of the present specification, the compound represented by Chemical Formula 1 and the compound represented by Chemical Formula 2 are included in the light emitting layer among the organic material layers of the organic light emitting device.

In an exemplary embodiment of the present specification, the light emitting layer includes the compound represented by Chemical Formula 1 and the compound represented by Chemical Formula 2 in a single layer. Such a single-layered light emitting layer may be formed by co-depositing the compound represented by Chemical Formula 1 and the compound represented by Chemical Formula 2.

In an exemplary embodiment of the present specification, the light emitting layer includes a first light emitting layer including one or more of the compound represented by Chemical Formula 1 and the compound represented by Chemical Formula 2; and a second light emitting layer including one or more of the compound represented by Chemical Formula 1, the compound represented by Chemical Formula 2, and a compound different from Chemical Formulae 1 and 2. For example, the light emitting layer includes a first light emitting layer including the compound represented by Chemical Formula 1 and a second light emitting layer including the compound represented by Chemical Formula 2. In this case, the second light emitting layer may be provided between the first light emitting layer and the cathode. The first light emitting layer and the second light emitting layer may be provided in contact with each other.

In an exemplary embodiment of the present specification, the light emitting layer includes: a first light emitting layer including the compound represented by Chemical Formula 1; and a second light emitting layer including the compound represented by Chemical Formula 2.

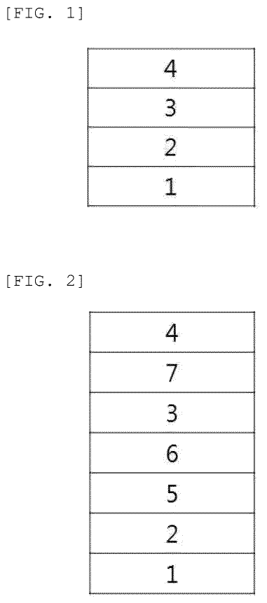

For example, the organic light emitting device of the present specification may have structures illustrated in FIGS. 1 to 4, but is not limited thereto.

FIG. 1 illustrates an example of an organic light emitting device composed of a substrate 1, an anode 2, a light emitting layer 3, and a cathode 4.

FIG. 2 illustrates an example of an organic light emitting device composed of a substrate 1, an anode 2, a hole injection layer 5, a hole transport layer 6, a light emitting layer 3, an electron transport layer 7, and a cathode 4.

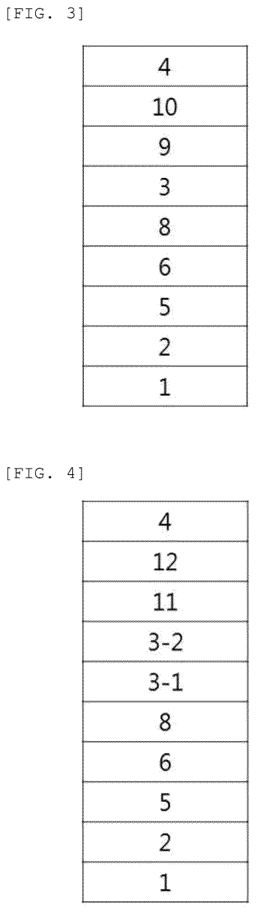

FIG. 3 illustrates an example of an organic light emitting device composed of a substrate 1, an anode 2, a hole injection layer 5, a hole transport layer 6, an electron blocking layer 8, a light emitting layer 3, a hole blocking layer 9, an electron injection and transport layer 10, and a cathode 4.

FIG. 4 illustrates an example of an organic light emitting device composed of a substrate 1, an anode 2, a hole injection layer 5, a hole transport layer 6, an electron blocking layer 8, a first light emitting layer 3-1, a second light emitting layer 3-2, an electron transport layer 11, an electron injection layer 12, and a cathode 4. Specifically, the organic light emitting device may have, for example, the stacking structure described below in addition to the structure shown in the drawings, but the stacking structure is not limited thereto.
(1) Anode/Hole transport layer/Light emitting layer/Cathode
(2) Anode/Hole injection layer/Hole transport layer/Light emitting layer/Cathode
(3) Anode/Hole transport layer/Light emitting layer/Electron transport layer/Cathode
(4) Anode/Hole transport layer/Light emitting layer/Electron transport layer/Electron injection layer/Cathode
(5) Anode/Hole injection layer/Hole transport layer/Light emitting layer/Electron transport layer/Cathode
(6) Anode/Hole injection layer/Hole transport layer/Light emitting layer/Electron transport layer/Electron injection layer/Cathode
(7) Anode/Hole transport layer/Electron blocking layer/Light emitting layer/Electron transport layer/Cathode
(8) Anode/Hole transport layer/Electron blocking layer/Light emitting layer/Electron transport layer/Electron injection layer/Cathode
(9) Anode/Hole injection layer/Hole transport layer/Electron blocking layer/Light emitting layer/Electron transport layer/Cathode
(10) Anode/Hole injection layer/Hole transport layer/Electron blocking layer/Light emitting layer/Electron transport layer/Electron injection layer/Cathode
(11) Anode/Hole transport layer/Light emitting layer/Hole blocking layer/Electron transport layer/Cathode
(12) Anode/Hole transport layer/Light emitting layer/Hole blocking layer/Electron transport layer/Electron injection layer/Cathode
(13) Anode/Hole injection layer/Hole transport layer/Light emitting layer/Hole blocking layer/Electron transport layer/Cathode
(14) Anode/Hole injection layer/Hole transport layer/Light emitting layer/Hole blocking layer/Electron transport layer/Electron injection layer/Cathode
(15) Anode/Hole injection layer/Hole transport layer/Electron blocking layer/Light emitting layer/Hole blocking layer/Electron transport layer/Electron injection layer/Cathode

In an exemplary embodiment of the present specification, the ‘Electron transport layer/Electron injection layer’ may be replaced with an ‘Electron injection and transport layer’ or ‘Layer which injects and transports electrons simultaneously’. For example, number (15) above may be an organic light emitting device having a stacking order of ‘Anode/Hole injection layer/Hole transport layer/Electron blocking layer/Light emitting layer/Hole blocking layer/Electron injection and transport layer/Cathode’.

In an exemplary embodiment of the present specification, the ‘Hole injection layer/Hole transport layer’ may be replaced with an ‘Hole injection and transport layer’ or ‘Layer which injects and transports holes simultaneously’. For example, number (15) above may be an organic light emitting device having a stacking order of ‘Anode/Hole injection and transport layer/Electron blocking layer/Light emitting layer/Hole blocking layer/Electron transport layer/Electron injection layer/Cathode’.

In an exemplary embodiment of the present specification, the ‘light emitting layer’ may be replaced with ‘a first light emitting layer/a second light emitting layer’. For example, number (10) above may be an organic light emitting device having a stacking order of ‘Anode/Hole injection layer/Hole transport layer/Hole blocking layer/First light emitting layer/Second light emitting layer/Electron transport layer/Electron injection layer/Cathode’.

The anode is an electrode which injects holes, and as an anode material, materials having a high work function are usually preferred so as to facilitate the injection of holes into an organic material layer. Specific examples of the anode material which may be used in the present invention include: a metal, such as vanadium, chromium, copper, zinc, and gold, or an alloy thereof; a metal oxide, such as zinc oxide, indium oxide, indium tin oxide (ITO), and indium zinc oxide (IZO); a combination of a metal and an oxide, such as Zno:Al or SnO₂:Sb; a conductive polymer, such as poly(3-methylthiophene), poly[3,4-(ethylene-1,2-dioxy)thiophene] (PEDOT), polypyrrole, and polyaniline; and the like, but are not limited thereto.

The cathode is an electrode which injects electrons, and as a cathode material, materials having a low work function are usually preferred so as to facilitate the injection of electrons into an organic material layer. Specific examples of the cathode material which may be in the present invention include: a metal, such as magnesium, calcium, sodium, potassium, titanium, indium, yttrium, lithium, gadolinium, aluminum, silver, tin, and lead, or an alloy thereof; a multi-layered structural material, such as LiF/Al or LiO₂/Al, and the like, but are not limited thereto.

In an exemplary embodiment of the present specification, the light emitting layer includes the compound of Chemical Formula 1 and the compound of Chemical Formula 2 as hosts.

In an exemplary embodiment of the present specification, the light emitting layer further includes a dopant. Specifically, the light emitting layer further includes a fluorescent dopant or a phosphorescent dopant. In this case, as the dopant, it is possible to use a phosphorescent material such as (4,6-F₂ppy)₂Irpic, or a fluorescent material such as spiro-DPVBi, spiro-6P, distyryl benzene (DSB), distyryl arylene (DSA), a PFO-based polymer, a PPV-based polymer, an anthracene-based compound, a pyrene-based compound, and a boron-based compound, but the dopant is not limited thereto.

In an exemplary embodiment of the present specification, the light emitting layer further includes a blue fluorescent dopant.

In an exemplary embodiment of the present specification, the dopant is represented by the following Chemical Formula D-1.

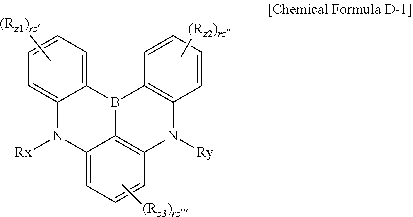

In Chemical Formula D-1,
Rx, Ry, R_{z1}, R_{z2}, and R_{z3} are the same as or different from each other, and are each independently hydrogen; deuterium; a substituted or unsubstituted alkyl group; a substituted or unsubstituted aryl group; or a substituted or unsubstituted heteroaryl group, and
rz′ and rz″ are each an integer from 1 to 4, rz′″ is an integer from 1 to 3, and when rz′, rz″, and rz′″ are each 2 or higher, substituents in each parenthesis are the same as or different from each other.

In an exemplary embodiment of the present specification, Rx, Ry, R_{z1}, R_{z2}, and R_{z3} are the same as or different from each other, and are each independently hydrogen; deuterium; a substituted or unsubstituted alkyl group having 1 to 30 carbon atoms; a substituted or unsubstituted aryl group having 6 to 30 carbon atoms; or a substituted or unsubstituted heteroaryl group having 2 to 30 carbon atoms.

In an exemplary embodiment of the present specification, Rx, Ry, R_{z1}, R_{z2}, and R_{z3} are the same as or different from each other, and are each independently a substituted or unsubstituted alkyl group; or a substituted or unsubstituted aryl group.

In an exemplary embodiment of the present specification, Rx, Ry, R_{z1}, R_{z2}, and R_{z3} are the same as or different from each other, and are each independently an alkyl group; or an aryl group unsubstituted or substituted with an alkyl group.

In an exemplary embodiment of the present specification, Rx, Ry, R_{z1}, R_{z2}, and R_{z3} are the same as or different from each other, and are each independently a straight-chained or branched alkyl group; or an aryl group unsubstituted or substituted with a branched alkyl group.

In an exemplary embodiment of the present specification, Rx and Ry are the same as or different from each other, and are each independently an aryl group unsubstituted or substituted with a branched alkyl group.

In an exemplary embodiment of the present specification, Rx and Ry are the same as or different from each other, and are each independently an aryl group substituted with a branched alkyl group.

In an exemplary embodiment of the present specification, Rx and Ry are the same as or different from each other, and are each independently a phenyl group substituted with a branched alkyl group having 4 to 30 carbon atoms.

In an exemplary embodiment of the present specification, R_{z1}, R_{z2}, and R_{z3} are the same as or different from each other, and are each independently a straight-chained or branched alkyl group.

In an exemplary embodiment of the present specification, R_{z1}, R_{z2}, and R_{z3} are the same as or different from each other, and are each independently a straight-chained alkyl group having 1 to 30 carbon atoms; or a branched alkyl group having 4 to 30 carbon atoms.

In an exemplary embodiment of the present specification, Chemical Formula D-1 is the following structure.

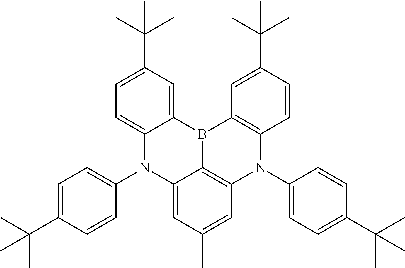 [SMILES: Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1]

In an exemplary embodiment of the present specification, the dopant material may be included in the light emitting layer in an amount of 0.01 parts by weight to 50 parts by weight, and 0.1 parts by weight to 30 parts by weight, 1 part by weight to 10 parts by weight, or 2 parts by weight, based on 100 parts by weight of the light emitting layer (host+dopant). Within the above range, energy transfer from the host to the dopant occurs efficiently.

The hole injection layer may perform a role of smoothly injecting holes from an anode to a light emitting layer. The hole injection material is a material which may proficiently accept holes from an anode at low voltage, and the highest occupied molecular orbital (HOMO) of the hole injection material is preferably a value between the work function of the anode and the HOMO of the neighboring organic material layer. Specific examples of the hole injection material include metal porphyrin, oligothiophene, arylamine-based compounds, hexanitrile hexaazatriphenylene-based compounds, quinacridone-based compounds, perylene derivatives, quinoxaline derivatives, pyrazine derivative, benzonitrile derivatives, anthraquinone, polyaniline-based and polythiophene-based conductive polymers, and the like, but are not limited thereto. Specifically, quinoxaline derivatives or pyrazine derivatives may be used in the hole injection layer. More specifically, a quinoxaline-based compound substituted with a cyano group or a pyrazine-based compound substituted with a cyano group may be used, but the present invention is not limited thereto.

The hole injection layer may have a thickness of 1 nm to 150 nm. When the hole injection layer has a thickness of 1 nm or more, there is an advantage in that it is possible to prevent hole injection characteristics from deteriorating, and when the hole injection layer has a thickness of 150 nm or less, there is an advantage in that it is possible to prevent the driving voltage from being increased in order to improve the movement of holes due to the thick hole injection layer.

In an exemplary embodiment of the present specification, the hole injection layer includes a compound of the following Chemical Formula A-1.

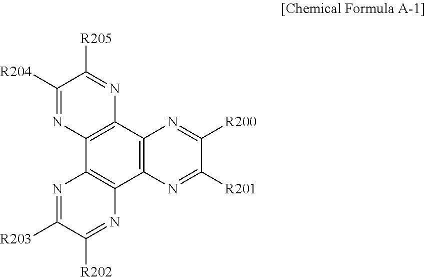

In Chemical Formula A-1,
R200 to R205 are the same as or different from each other, and are each independently hydrogen; deuterium; a cyano group; a substituted or unsubstituted alkyl group; a substituted or unsubstituted aryl group; or a substituted or unsubstituted heteroaryl group, and at least one of R200 to R205 is a cyano group.

In an exemplary embodiment of the present specification, R200 to R205 are each a cyano group.

In an exemplary embodiment of the present specification, Chemical Formula A-1 is the following structure.

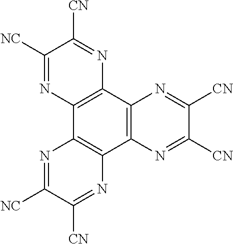 [SMILES: N#Cc1nc2c3nc(C#N)c(C#N)nc3c3nc(C#N)c(C#N)nc3c2nc1C#N]

The hole transport layer may perform a role of smoothly transporting holes. A hole transport material is suitably a material having high hole mobility which may accept holes from an anode or a hole injection layer and transfer the holes to a light emitting layer. Specific examples of the hole transport material include compounds including arylamine, carbazole-based compounds, conductive polymers, block copolymers having both conjugated portions and non-conjugated portions, and the like, but are not limited thereto. Specifically, a compound including carbazole substituted with an arylamine group may be used for the hole transport layer, but the present invention is not limited thereto.

In an exemplary embodiment of the present specification, the hole transport layer includes a compound of the following Chemical Formula B-1.

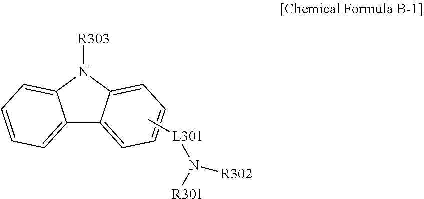

In Chemical Formula B-1,
L301 is a direct bond; or a substituted or unsubstituted arylene group, and
R301 to R303 are the same as or different from each other, and are each independently a substituted or unsubstituted aryl group.

In an exemplary embodiment of the present specification, L301 is a direct bond; a substituted or unsubstituted phenylene group; or a substituted or unsubstituted naphthylene group.

In an exemplary embodiment of the present specification, L301 is a direct bond; or a substituted or unsubstituted phenylene group.

In an exemplary embodiment of the present specification, L301 is a direct bond; or a phenylene group.

In an exemplary embodiment of the present specification, R301 to R303 are the same as or different from each other, and are each independently a substituted or unsubstituted monocyclic aryl group; or a substituted or unsubstituted polycyclic aryl group.

In an exemplary embodiment of the present specification, R301 to R303 are the same as or different from each other, and are each independently a substituted or unsubstituted phenyl group; a substituted or unsubstituted biphenyl group; a substituted or unsubstituted terphenyl group; a substituted or unsubstituted naphthyl group; a substituted or unsubstituted anthracenyl group; a substituted or unsubstituted phenanthrenyl group; a substituted or unsubstituted triphenylenyl group; a substituted or unsubstituted pyrene group; or a substituted or unsubstituted fluorene group.

In an exemplary embodiment of the present specification, R301 to R303 are the same as or different from each other, and are each independently a substituted or unsubstituted phenyl group; a substituted or unsubstituted biphenyl group; or a substituted or unsubstituted fluorene group.

In an exemplary embodiment of the present specification, R301 to R303 are the same as or different from each other, and are each independently a phenyl group; a biphenyl group; or a fluorene group unsubstituted or substituted with one or more selected from the group consisting of an alkyl group and an aryl group.

In an exemplary embodiment of the present specification, R301 to R303 are the same as or different from each other, and are each independently a phenyl group; a biphenyl group; or a fluorene group substituted with an alkyl group and an aryl group.

In an exemplary embodiment of the present specification, Chemical Formula B-1 is any one of the following structures.

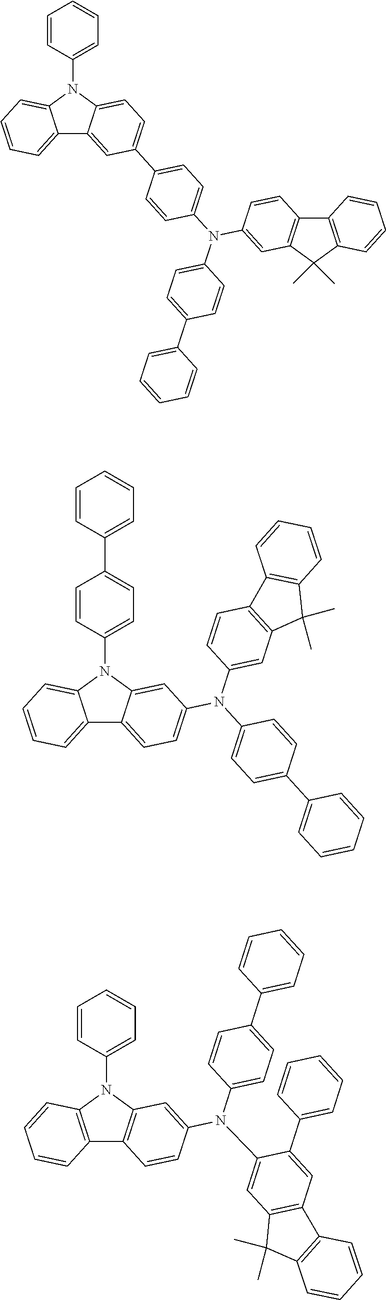 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccc(-c4ccccc4)cc3)c3ccc4c5ccccc5n(-c5ccc(-c6ccccc6)cc5)c4c3)cc21 ; CC1(C)c2ccccc2-c2cc(-c3ccccc3)c(N(c3ccc(-c4ccccc4)cc3)c3ccc4c5ccccc5n(-c5ccccc5)c4c3)cc21]

An electron blocking layer may be provided between the hole transport layer and the light emitting layer. The above-described compound or a material known in the art may be used in the electron blocking layer. Specifically, a carbazole-based compound or an indolocarbazole-based compound may be used for the electron blocking layer.

In an exemplary embodiment of the present specification, the electron blocking layer includes a compound of the following Chemical Formula C-1.

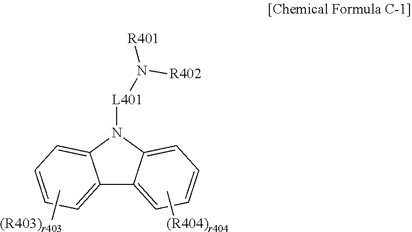

In Chemical Formula C-1,
L401 is a direct bond; or a substituted or unsubstituted arylene group,
R401 and R402 are the same as or different from each other, and are each independently a substituted or unsubstituted aryl group,
R403 and R404 are the same as or different from each other, and are each independently hydrogen; deuterium; a substituted or unsubstituted alkyl group; a substituted or unsubstituted aryl group; or a substituted or unsubstituted heteroaryl group, and
r403 and r404 are each an integer from 1 to 4, and when r403 and r404 are 2 or higher, substituents in each parenthesis are the same as or different from each other.

In an exemplary embodiment of the present specification, L401 is a direct bond; a substituted or unsubstituted phenylene group; a substituted or unsubstituted biphenylene group; or a substituted or unsubstituted naphthylene group.

In an exemplary embodiment of the present specification, L401 is a substituted or unsubstituted biphenylene group.

In an exemplary embodiment of the present specification, L401 is a biphenylene group.

In an exemplary embodiment of the present specification, R401 and R402 are the same as or different from each other, and are each independently a substituted or unsubstituted monocyclic aryl group; or a substituted or unsubstituted polycyclic aryl group.

In an exemplary embodiment of the present specification, R401 and R402 are the same as or different from each other, and are each independently a substituted or unsubstituted phenyl group; a substituted or unsubstituted biphenyl group; a substituted or unsubstituted terphenyl group; a substituted or unsubstituted naphthyl group; a substituted or unsubstituted anthracenyl group; a substituted or unsubstituted phenanthrenyl group; a substituted or unsubstituted triphenylenyl group; a substituted or unsubstituted pyrene group; or a substituted or unsubstituted fluorene group.

In an exemplary embodiment of the present specification, R401 and R402 are the same as or different from each other, and are each independently a substituted or unsubstituted phenyl group; or a substituted or unsubstituted biphenyl group.

In an exemplary embodiment of the present specification, R401 and R402 are the same as or different from each other, and are each independently a phenyl group; a biphenyl group; or a phenyl group substituted with a naphthyl group.

In an exemplary embodiment of the present specification, R403 and R404 are the same as or different from each other, and are each independently hydrogen; deuterium; or a substituted or unsubstituted aryl group.

In an exemplary embodiment of the present specification, R403 and R404 are the same as or different from each other, and are each independently hydrogen; or deuterium.

In an exemplary embodiment of the present specification, Chemical Formula C-1 is the following structure.

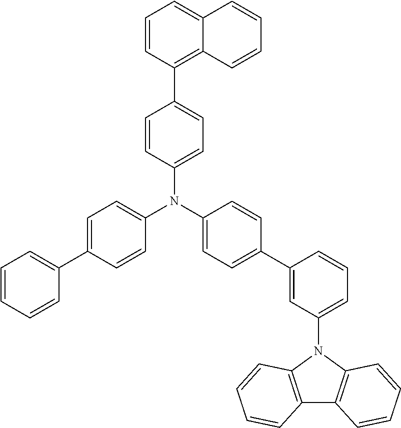 [SMILES: c1ccc(-c2ccc(N(c3ccc(-c4cccc(-n5c6ccccc6c6ccccc65)c4)cc3)c3ccc(-c4cccc5ccccc45)cc3)cc2)cc1]

The light emitting layer may emit red, green, or blue light, and may be composed of a phosphorescent material or a fluorescent material. The light emitting material is a material which may accept holes and electrons from a hole transport layer and an electron transport layer, respectively, and combine the holes and the electrons to emit light in a visible ray region, and is preferably a material having high quantum efficiency to fluorescence or phosphorescence.

According to an exemplary embodiment of the present specification, the light emitting layer includes the compound represented by Chemical Formula 1 and the compound represented by Chemical Formula 2 as hosts of the light emitting layer, and includes the compound of Chemical Formula D-1 as a dopant of the light emitting layer.

A hole blocking layer may be provided between the cathode and the light emitting layer. The hole blocking layer is layer blocking holes from reaching a cathode, and may be generally formed under the same condition as the hole injection layer. Specific examples of the hole blocking material include oxadiazole derivatives, triazole derivatives, triazine derivatives, carbazole derivatives, phenanthroline derivatives, BCP, aluminum complexes, and the like, but are not limited thereto. Specifically, a triazine derivative may be used, but the present invention is not limited thereto.

The electron transport layer may perform a role of smoothly transporting electrons. An electron transport material is suitably a material having high electron mobility which may proficiently accept electrons from a cathode and transfer the electrons to a light emitting layer. For example, examples of the electron transport material include: triazine derivatives, Al complexes of 8-hydroxyquinoline; complexes including Alq₃; organic radical compounds; hydroxyflavone-metal complexes; and the like, but are not limited thereto. Specifically, a triazine derivative may be used, but the present invention is not limited thereto.

The electron transport layer may have a thickness of 1 nm to 50 nm. When the electron transport layer has a thickness of 1 nm or more, there is an advantage in that it is possible to prevent electron transport characteristics from deteriorating, and when the electron transport layer has a thickness of 50 nm or less, there is an advantage in that it is possible to prevent the driving voltage from being increased in order to improve the movement of electrons due to the too thick electron transport layer.

The electron injection layer may perform a role of smoothly injecting electrons. An electron injection material is preferably a compound which has a capability of transporting electrons, an effect of injecting electrons from a cathode, and an excellent effect of injecting electrons into a light emitting layer or a light emitting material, prevents excitons produced from a light emitting layer from moving to a hole injection layer, and is excellent in the ability to form a thin film. For example, specific examples of the electron injection material include fluorenone, anthraquinodimethane, diphenoquinone, thiopyran dioxide, oxazole, oxadiazole, triazole, triazine, imidazole, perylene tetracarboxylic acid, fluorenylidene methane, anthrone or the like, and derivatives thereof, lithium fluoride, metal complex compounds, nitrogen-containing 5-membered ring derivatives, and the like, but are not limited thereto.

Examples of the metal complex compound include tris(8-hydroxyquinolinato)aluminum (Alq₃), bis(8-hydroxyquinolinato)zinc, bis(8-hydroxyquinolinato)copper, bis(8-hydroxyquinolinato)manganese, tris(8-hydroxy-quinolinato)aluminum, tris(2-methyl-8-hydroxyquinolinato)-aluminum, tris(8-hydroxyquinolinato)gallium, bis(10-hydroxybenzo[h]quinolinato)beryllium, bis(10-hydroxybenzo[h]quinolinato)zinc, bis(2-methyl-8-quinolinato)chlorogallium, bis(2-methyl-8-quinolinato)(o-cresolato)gallium, bis(2-methyl-8-quinolinato)(1-naphtholato)aluminum, bis(2-methyl-8-quinolinato)(2-naphtholato)gallium and the like, but are not limited thereto.

The electron transport layer and the electron injection layer may be formed of a single layer. For example, an electron injection and transport layer may be formed by simultaneously vacuum depositing an electron injection material and an electron transport material, or by vacuum depositing a material which simultaneously exhibits electron injection and transport effects.

The electron injection and transport layer may further include a metal complex. Examples of the metal complex include Alq₃, lithium quinolate (Liq), a metal complex compound, and the like, but are not limited thereto. For example, a triazine derivative and Liq may be used for the electron injection and transport layer, but the electron injection and transport layer is not limited thereto.

The organic light emitting device according to the present invention may be a top emission type, a bottom emission type, or a dual emission type according to the material to be used.

Furthermore, the organic light emitting device according to the present specification may be included and used in various electronic devices. For example, the electronic device may be a display panel, a touch panel, a solar module, a lighting device, and the like, and is not limited thereto.

Hereinafter, the present specification will be described in detail with reference to Experimental Examples for specifically describing the present specification. However, the Examples according to the present specification may be modified in various forms, and it is not interpreted that the scope of the present application is limited to the Examples described in detail below. The Examples of the present application are provided to explain the present specification more completely to a person with ordinary skill in the art.

### SYNTHESIS EXAMPLES

### Synthesis Example 1. Synthesis of Compound BH1-1

### (1) Synthesis of Intermediate 1-1

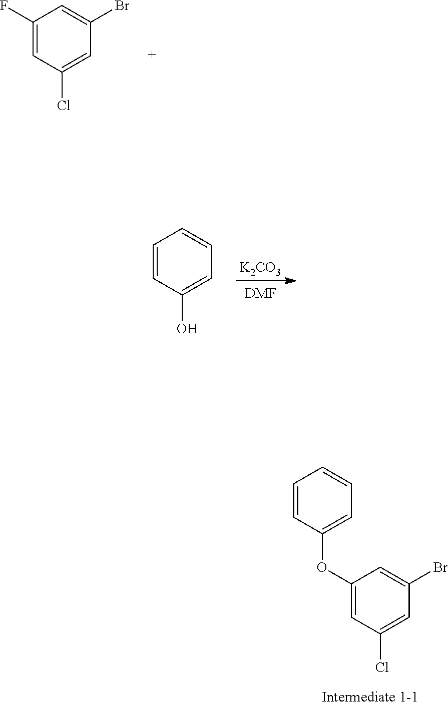

After 50 g of 1-bromo-3-chloro-5-fluorobenzene, 25 g of phenol, 66 g of potassium carbonate (K₂CO₃), and 900 mL of dimethylformamide (DMF) were put into a flask under a nitrogen atmosphere, the resulting mixture was stirred at 160° C. for 3 hours. After the reaction was terminated, the reaction solution was cooled to room temperature, aliquoted by adding water and ethyl acetate thereto, and then filtered by treatment with MgSO₄ (anhydrous). The filtered solution was distilled off under reduced pressure and recrystallized with toluene and hexane, and purified to obtain 56 g of Intermediate 1-1. (Yield 83%, Mass [M⁺]=284)

### (2) Synthesis of Intermediate 1-2

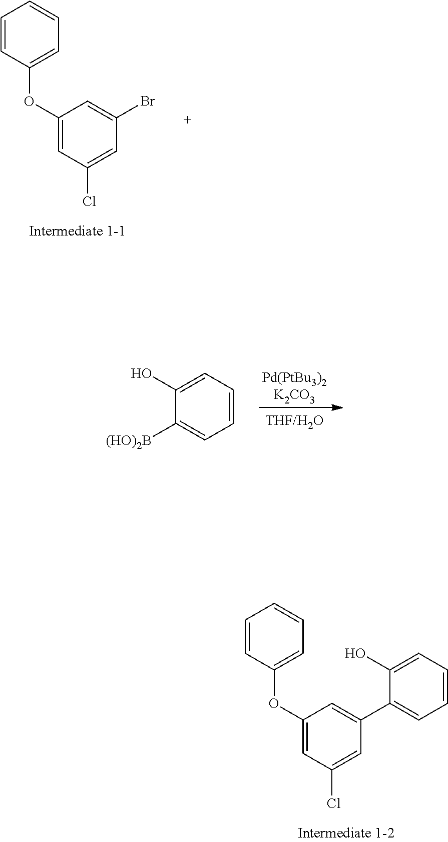

After 56 g of Intermediate 1-1, 33 g of (2-hydroxyphenyl) boronic acid, 82 g of potassium carbonate (K₂CO₃), 650 mL of tetrahydrofuran (THF), and 150 mL of water (H₂O) were put into a flask under a nitrogen atmosphere, 2 g of bis(tri-tert-butylphosphine) palladium (0) (Pd(PtBu₃)₂) was added thereto, and the resulting mixture was stirred at 100° C. for 7 hours. After the reaction was terminated, the reaction solution was cooled to room temperature, aliquoted by adding water and toluene thereto, and then filtered by treatment with MgSO₄ (anhydrous). The filtered solution was distilled off under reduced pressure and recrystallized with toluene and hexane, and purified to obtain 46 g of Intermediate 1-2. (Yield 78%, Mass [M⁺]=297)

### (3) Synthesis of Intermediate 1-3

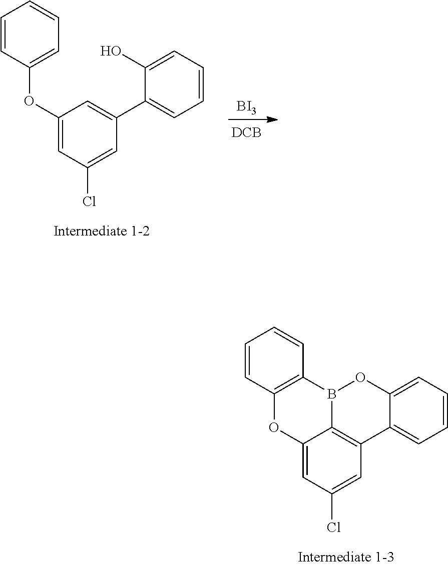

27 g of boron triiodide (BI₃) was put into a flask containing 20 g of Intermediate 1-2 dissolved in 500 mL of 1,2-dichlorobenzene (DCB) under a nitrogen atmosphere, and then the resulting mixture was stirred at 120° C. for 6 hours. After the reaction was terminated, the reaction solution was cooled to room temperature, aliquoted by adding water and a sodium thiosulfate solution thereto, and then filtered by treatment with MgSO₄ (anhydrous). The filtered solution was distilled off under reduced pressure and recrystallized with toluene and hexane, and purified to obtain 10 g of Intermediate 1-3. (Yield 48%, Mass [M⁺]=305),

### (4) Synthesis of Compound BH1-1

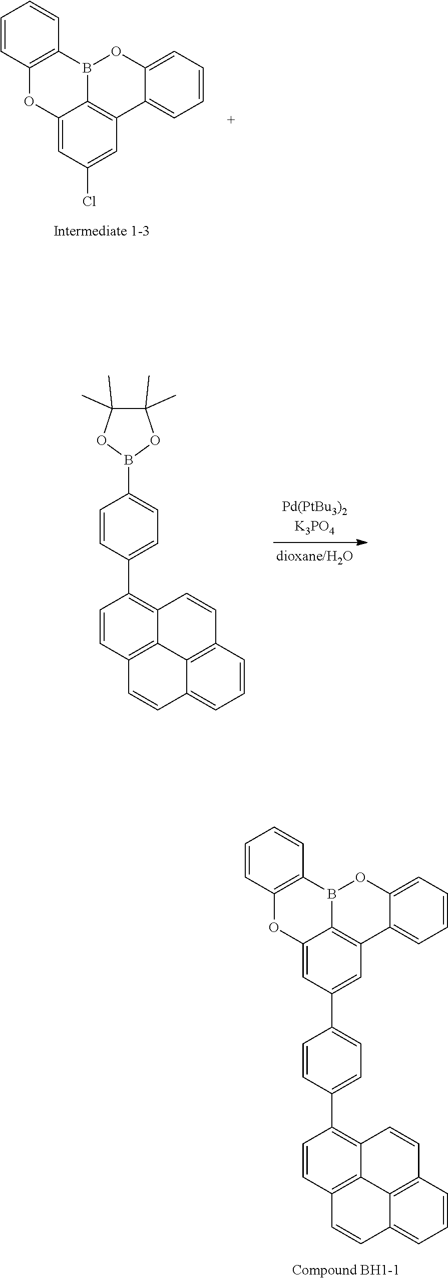 [SMILES: Clc1cc2c3c(c1)-c1ccccc1OB3c1ccccc1O2 ; CC1(C)OB(c2ccc(-c3ccc4ccc5cccc6ccc3c4c56)cc2)OC1(C)C ; c1ccc2c(c1)Oc1cc(-c3ccc(-c4ccc5ccc6cccc7ccc4c5c67)cc3)cc3c1B2Oc1ccccc1-3]

2.5 g of Intermediate 1-3, 3.7 g of 4,4,5,5-tetramethyl-2-(4-(pyren-1-yl)phenyl)-1,3,2-dioxaborolane, 5.2 g of potassium phosphate (K₃PO₄), 65 mL of dioxane, and 15 mL of water were put into a flask under a nitrogen atmosphere. Thereafter, 0.08 g of bis(tri-tert-butylphosphine) palladium (0) (Pd(PtBu₃)₂) was added thereto, and the resulting mixture was stirred at 130° C. for 3 hours. After the reaction was terminated, the reaction solution was cooled to room temperature, aliquoted by adding water and toluene thereto, and then filtered by treatment with MgSO₄ (anhydrous). The filtered solution was distilled off under reduced pressure and recrystallized with toluene and hexane, and purified to obtain 3.5 g of Compound BH1-1. (Yield 78%, Mass [M⁺]=547)

### Synthesis Example 2. Synthesis of Compound BH1-2

### (1) Synthesis of Intermediate 1-4

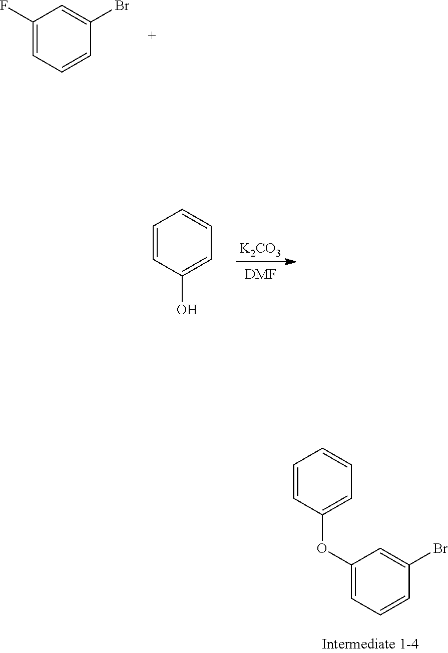

25 g of Intermediate 1-4 was obtained by preparation in the same manner as in (1) of Synthesis Example 1, except that 20 g of 1-bromo-3-fluorobenzene was used instead of 1-bromo-3-chloro-5-fluorobenzene in (1) of Synthesis Example 1. (Yield 88%, Mass [M⁺]=250)

### (2) Synthesis of Intermediate 1-5

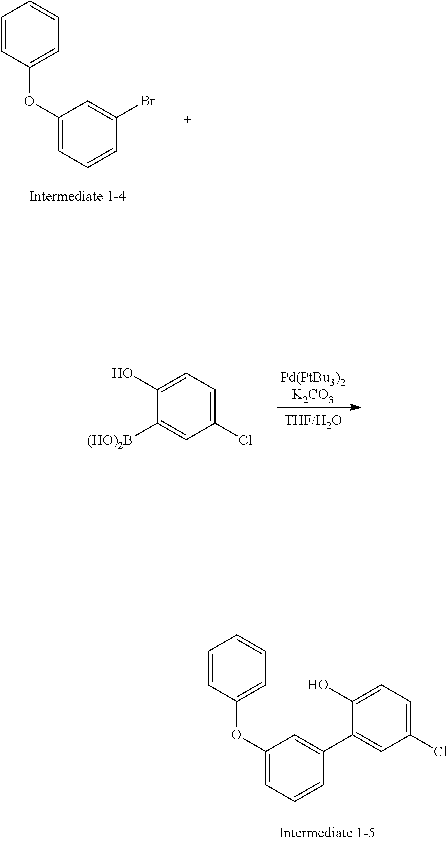 [SMILES: Brc1cccc(Oc2ccccc2)c1 ; OB(O)c1cc(Cl)ccc1O ; "THF/H2O" ; Oc1ccc(Cl)cc1-c1cccc(Oc2ccccc2)c1 ; "Pd(PtBu3)2K2CO3"]

24 g of Intermediate 1-5 was obtained by preparation in the same manner as in (2) of Synthesis Example 1, except that 25 g of Intermediate 1-4 and 21 g of (5-chloro-2-hydroxyphenyl) boronic acid were used instead of Intermediate 1-1 and (2-hydroxyphenyl) boronic acid, respectively, in (2) of Synthesis Example 1. (Yield 81%, Mass [M⁺]=297)

### (3) Synthesis of Intermediate 1-6

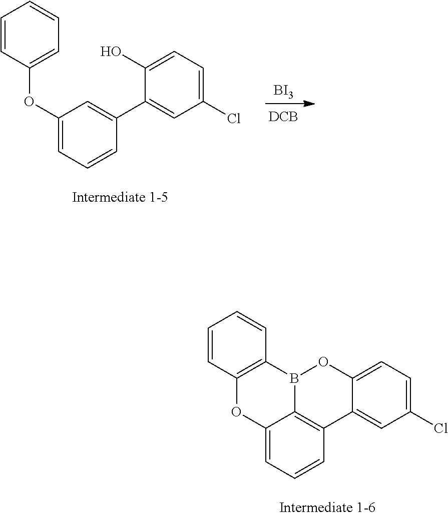

11 g of Intermediate 1-6 was obtained by preparation in the same manner as in (3) of Synthesis Example 1, except that 24 g of Intermediate 1-5 was used instead of Intermediate 1-2 in (3) of Synthesis Example 1. (Yield 45%, Mass [M⁺]=305)

### (4) Synthesis of Compound BH1-2

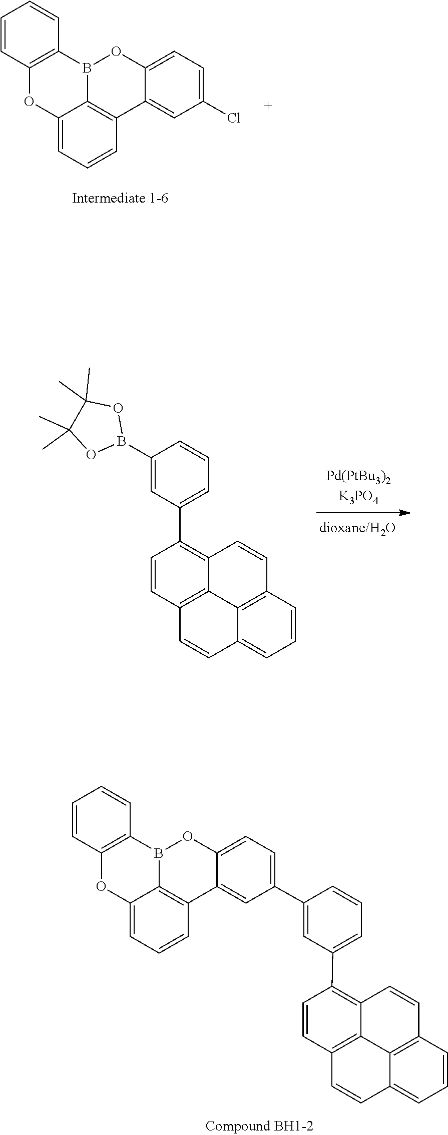 [SMILES: Clc1ccc2c(c1)-c1cccc3c1B(O2)c1ccccc1O3 ; CC1(C)OB(c2cccc(-c3ccc4ccc5cccc6ccc3c4c56)c2)OC1(C)C ; c1cc(-c2ccc3c(c2)-c2cccc4c2B(O3)c2ccccc2O4)cc(-c2ccc3ccc4cccc5ccc2c3c45)c1]

4.1 g of Compound BH1-2 was obtained by preparation in the same manner as in (4) of Synthesis Example 1, except that 3 g of Intermediate 1-6 and 4.4 g of 4,4,5,5-tetramethyl-2-(3-(pyren-1-yl)phenyl)-1,3,2-dioxaborolane were used instead of Intermediate 1-3 and 4,4,5,5-tetramethyl-2-(4-(pyren-1-yl)phenyl)-1,3,2-dioxaborolane, respectively, in (4) of Synthesis Example 1. (Yield 76%, Mass [M⁺]=547)

### Synthesis Example 3. Synthesis of Compound BH1-3

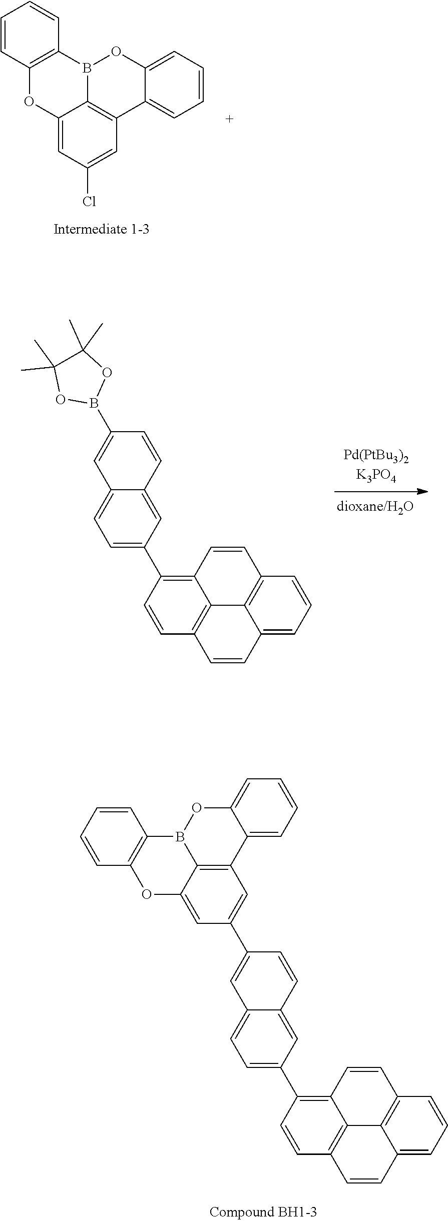 [SMILES: Clc1cc2c3c(c1)-c1ccccc1OB3c1ccccc1O2 ; CC1(C)OB(c2ccc3cc(-c4ccc5ccc6cccc7ccc4c5c67)ccc3c2)OC1(C)C ; c1ccc2c(c1)Oc1cc(-c3ccc4cc(-c5ccc6ccc7cccc8ccc5c6c78)ccc4c3)cc3c1B2Oc1ccccc1-3]

3.3 g of Compound BH1-3 was obtained by preparation in the same manner as in (4) of Synthesis Example 1, except that 4.1 g of 4,4,5,5-tetramethyl-2-(6-(pyren-1-yl) naphthalen-2-yl)-1,3,2-dioxaborolane was used instead of 4,4,5,5-tetramethyl-2-(4-(pyren-1-yl)phenyl)-1,3,2-dioxaborolane in (4) of Synthesis Example 1. (Yield 67%, Mass [M⁺]=597)

### Synthesis Example 4. Synthesis of Compound BH1-4

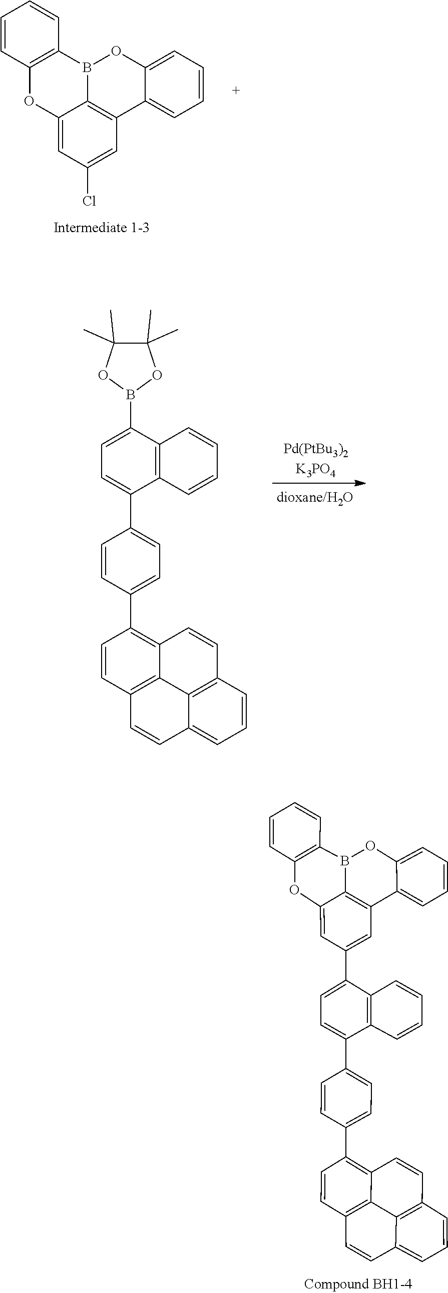 [SMILES: Clc1cc2c3c(c1)-c1ccccc1OB3c1ccccc1O2 ; CC1(C)OB(c2ccc(-c3ccc(-c4ccc5ccc6cccc7ccc4c5c67)cc3)c3ccccc23)OC1(C)C ; c1ccc2c(c1)Oc1cc(-c3ccc(-c4ccc(-c5ccc6ccc7cccc8ccc5c6c78)cc4)c4ccccc34)cc3c1B2Oc1ccccc1-3]

3.7 g of Compound BH1-4 was obtained by preparation in the same manner as in (4) of Synthesis Example 1, except that 4.8 g of 4,4,5,5-tetramethyl-2-(4-(4-(pyren-1-yl)phenyl) naphthalen-1-yl)-1,3,2-dioxaborolane was used instead of 4,4,5,5-tetramethyl-2-(4-(pyren-1-yl)phenyl)-1,3,2-dioxaborolane in (4) of Synthesis Example 1. (Yield 67%, Mass [M⁺]=673)

### Synthesis Example 5. Synthesis of Compound BH1-5

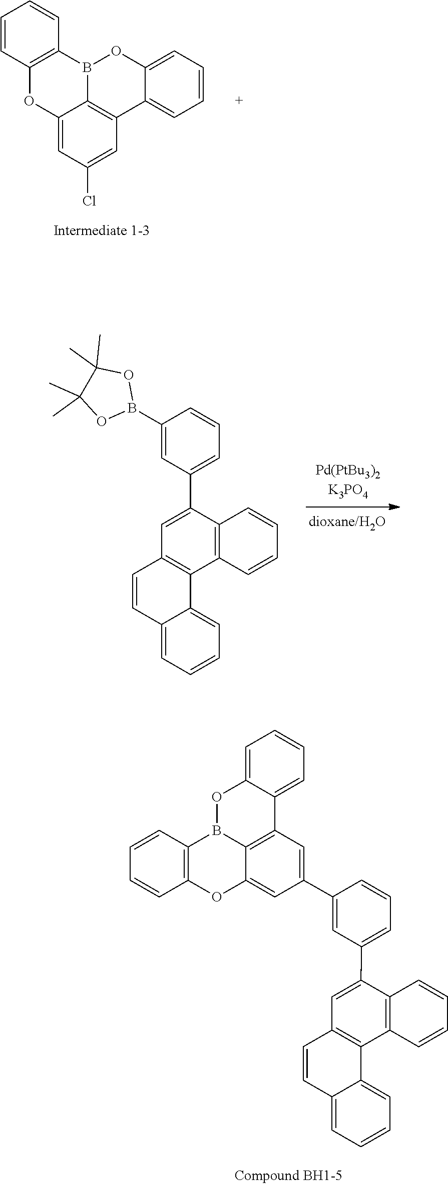 [SMILES: Clc1cc2c3c(c1)-c1ccccc1OB3c1ccccc1O2 ; CC1(C)OB(c2cccc(-c3cc4ccc5ccccc5c4c4ccccc34)c2)OC1(C)C ; c1cc(-c2cc3c4c(c2)-c2ccccc2OB4c2ccccc2O3)cc(-c2cc3ccc4ccccc4c3c3ccccc23)c1]

3.2 g of Compound BH1-5 was obtained by preparation in the same manner as in (4) of Synthesis Example 1, except that 3.9 g of 2-(3-(benzo[c]phenanthren-5-yl)phenyl)-4,4,5,5-tetramethyl-1,3,2-dioxaborolane was used instead of 4,4,5,5-tetramethyl-2-(4-(pyren-1-yl)phenyl)-1,3,2-dioxaborolane in (4) of Synthesis Example 1. (Yield 68%, Mass [M⁺]=573)

### Synthesis Example 6. Synthesis of Compound BH1-6

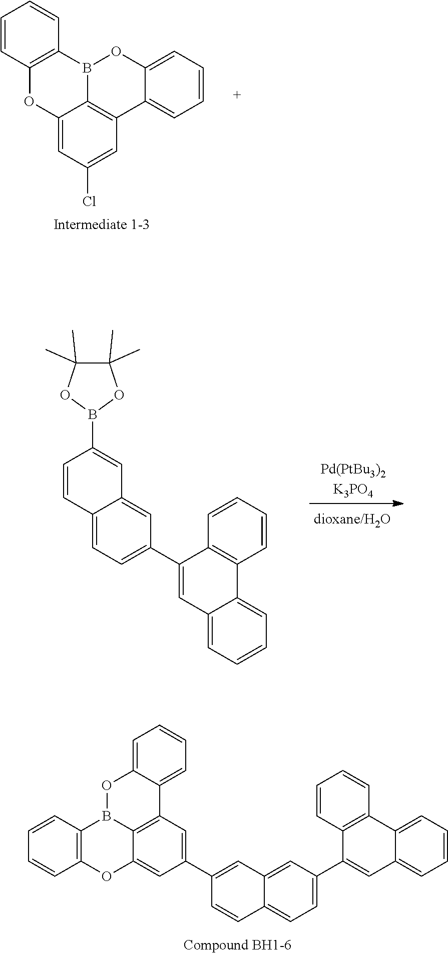 [SMILES: Clc1cc2c3c(c1)-c1ccccc1OB3c1ccccc1O2 ; CC1(C)OB(c2ccc3ccc(-c4cc5ccccc5c5ccccc45)cc3c2)OC1(C)C ; c1ccc2c(c1)Oc1cc(-c3ccc4ccc(-c5cc6ccccc6c6ccccc56)cc4c3)cc3c1B2Oc1ccccc1-3]

2.9 g of Compound BH1-6 was obtained by preparation in the same manner as in (4) of Synthesis Example 1, except that 3.9 g of 4,4,5,5-tetramethyl-2-(7-(phenanthren-9-yl) naphthalen-2-yl)-1,3,2-dioxaborolane was used instead of 4,4,5,5-tetramethyl-2-(4-(pyren-1-yl)phenyl)-1,3,2-dioxaborolane in (4) of Synthesis Example 1. (Yield 62%, Mass [M⁺]=573)

### Synthesis Example 7. Synthesis of Compound BH1-7

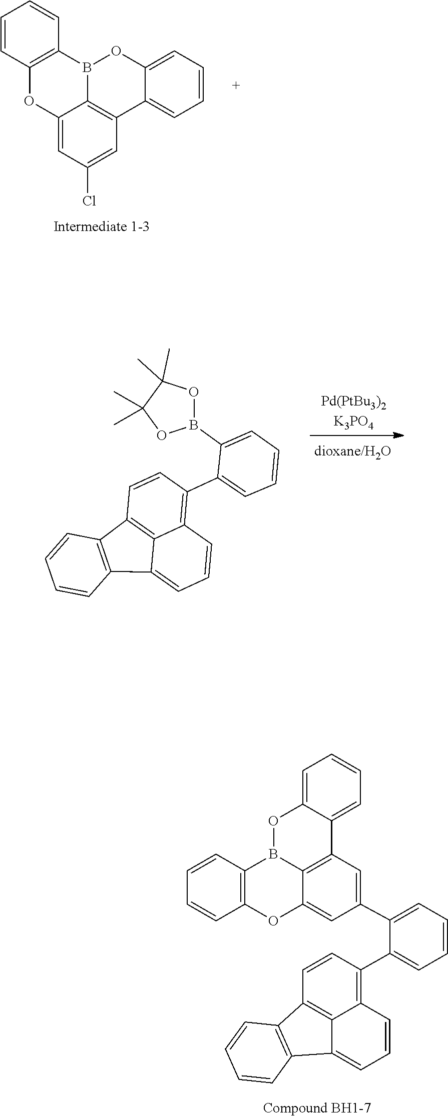 [SMILES: Clc1cc2c3c(c1)-c1ccccc1OB3c1ccccc1O2 ; CC1(C)OB(c2ccccc2-c2ccc3c4c(cccc24)-c2ccccc2-3)OC1(C)C ; c1ccc2c(c1)Oc1cc(-c3ccccc3-c3ccc4c5c(cccc35)-c3ccccc3-4)cc3c1B2Oc1ccccc1-3]

2.7 g of Compound BH1-7 was obtained by preparation in the same manner as in (4) of Synthesis Example 1, except that 3.7 g of 2-(2-(fluoranthen-3-yl)phenyl)-4,4,5,5-tetramethyl-1,3,2-dioxaborolane was used instead of 4,4,5,5-tetramethyl-2-(4-(pyren-1-yl)phenyl)-1,3,2-dioxaborolane in (4) of Synthesis Example 1. (Yield 60%, Mass [M⁺]=547)

### Synthesis Example 8. Synthesis of Compound BH1-8

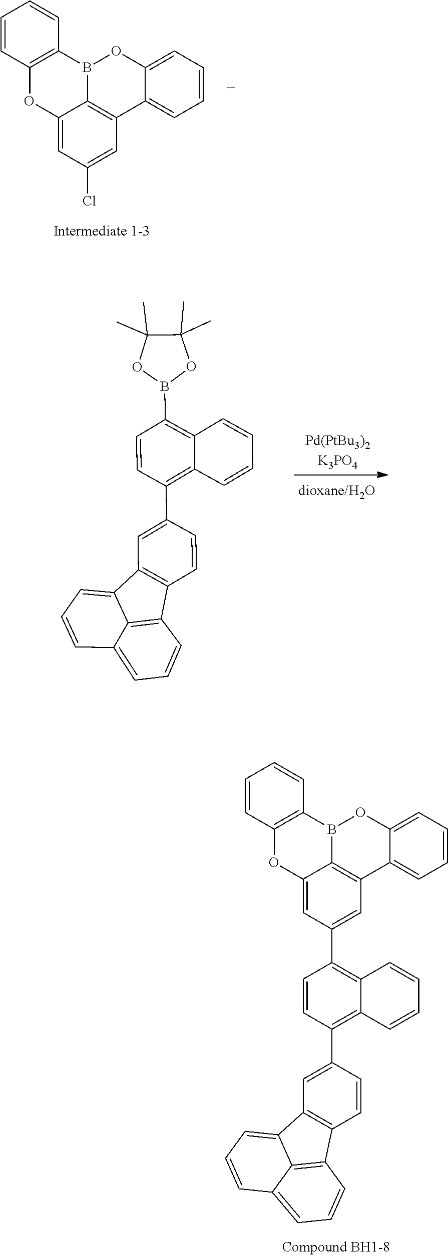 [SMILES: Clc1cc2c3c(c1)-c1ccccc1OB3c1ccccc1O2 ; CC1(C)OB(c2ccc(-c3ccc4c(c3)-c3cccc5cccc-4c35)c3ccccc23)OC1(C)C ; c1ccc2c(c1)Oc1cc(-c3ccc(-c4ccc5c(c4)-c4cccc6cccc-5c46)c4ccccc34)cc3c1B2Oc1ccccc1-3]

3.2 g of Compound BH1-8 was obtained by preparation in the same manner as in (4) of Synthesis Example 1, except that 4.1 g of 2-(4-(fluoranthen-8-yl) naphthalen-1-yl)-4,4,5,5-tetramethyl-1,3,2-dioxaborolane was used instead of 4,4,5,5-tetramethyl-2-(4-(pyren-1-yl)phenyl)-1,3,2-dioxaborolane in (4) of Synthesis Example 1. (Yield 65%, Mass [M⁺]=597)

### Synthesis Example 9. Synthesis of Compound BH1-9

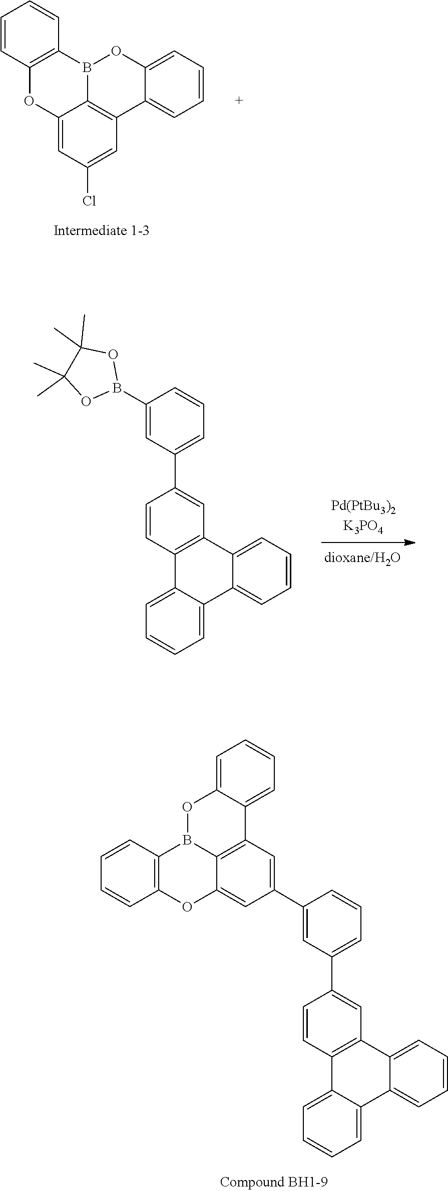 [SMILES: Clc1cc2c3c(c1)-c1ccccc1OB3c1ccccc1O2 ; CC1(C)OB(c2cccc(-c3ccc4c5ccccc5c5ccccc5c4c3)c2)OC1(C)C ; c1cc(-c2cc3c4c(c2)-c2ccccc2OB4c2ccccc2O3)cc(-c2ccc3c4ccccc4c4ccccc4c3c2)c1]

2.8 g of Compound BH1-9 was obtained by preparation in the same manner as in (4) of Synthesis Example 1, except that 3.9 g of 4,4,5,5-tetramethyl-2-(3-(triphenylen-2-yl)phenyl)-1,3,2-dioxaborolane was used instead of 4,4,5,5-tetramethyl-2-(4-(pyren-1-yl)phenyl)-1,3,2-dioxaborolane in (4) of Synthesis Example 1. (Yield 60%, Mass [M⁺]=573)

### Synthesis Example 10. Synthesis of Compound BH1-10

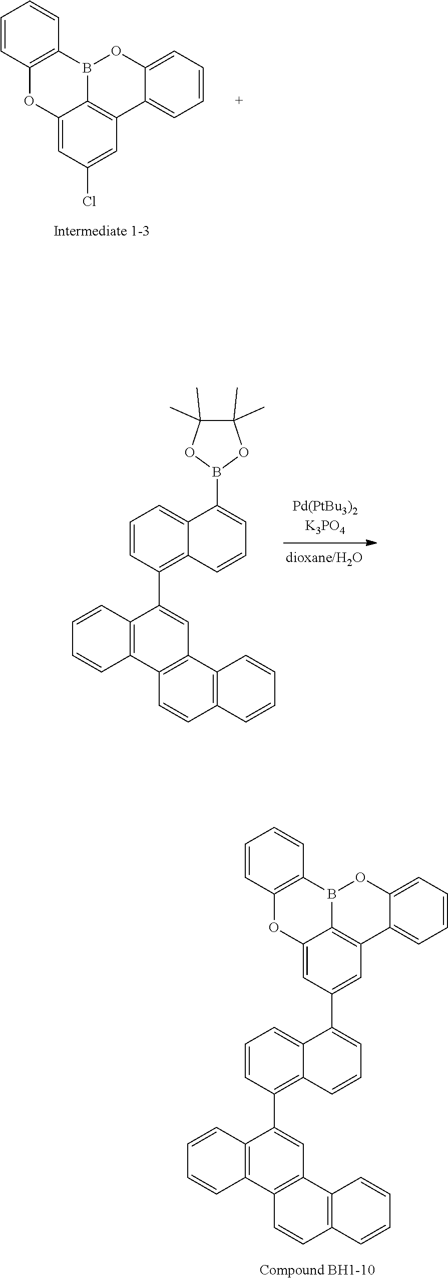 [SMILES: Clc1cc2c3c(c1)-c1ccccc1OB3c1ccccc1O2 ; CC1(C)OB(c2cccc3c(-c4cc5c6ccccc6ccc5c5ccccc45)cccc23)OC1(C)C ; c1ccc2c(c1)Oc1cc(-c3cccc4c(-c5cc6c7ccccc7ccc6c6ccccc56)cccc34)cc3c1B2Oc1ccccc1-3]

3 g of Compound BH1-10 was obtained by preparation in the same manner as in (4) of Synthesis Example 1, except that 4.3 g of 2-(5-(chrysen-6-yl) naphthalen-1-yl)-4,4,5,5-tetramethyl-1,3,2-dioxaborolane was used instead of 4,4,5,5-tetramethyl-2-(4-(pyren-1-yl)phenyl)-1,3,2-dioxaborolane in (4) of Synthesis Example 1. (Yield 59%, Mass [M⁺]=623)

### Synthesis Example 11. Synthesis of Compound BH2-1

### (1) Synthesis of Intermediate 2-1

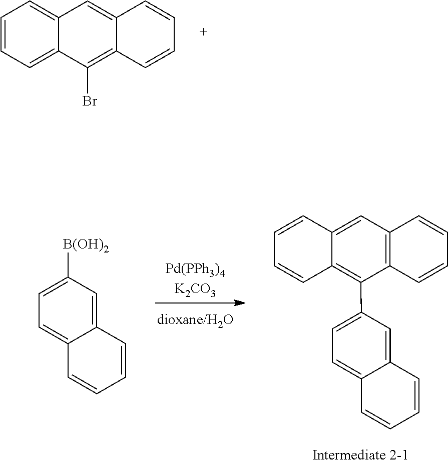

10 g of 9-bromoanthracene, 7.4 g of naphthalen-2-ylboronic acid, 10.7 g of potassium carbonate (K₂CO₃), 320 mL of dioxane, and 80 mL of water were put into a flask under a nitrogen atmosphere. Thereafter, 0.9 g of tetrakis(triphenylphosphine)palladium (0) (Pd(PPh₃)₄) was added thereto, and the resulting mixture was stirred at 100° C. for 5 hours. After the reaction was terminated, the reaction solution was cooled to room temperature, aliquoted by adding water and toluene thereto, and then filtered by treatment with MgSO₄ (anhydrous). The filtered solution was distilled off under reduced pressure and purified by column chromatography to obtain 8.8 g of Intermediate 2-1. (Yield 74%, Mass [M⁺]=305)

### (2) Synthesis of Intermediate 2-2

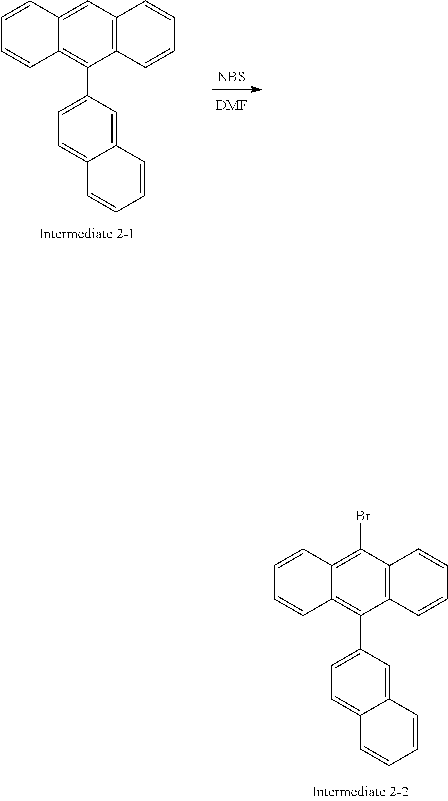

8.8 g of Intermediate 2-1, 5.2 g of N-bromosuccinimide (NBS), and 250 mL of dimethylformamide (DMF) were put into a flask under a nitrogen atmosphere, and the resulting mixture was stirred at room temperature for 10 hours. After the reaction was terminated, the reaction solution was transferred to a separatory funnel, aliquoted by adding water and ethyl acetate thereto, and then filtered by treatment with MgSO₄ (anhydrous). The filtered solution was distilled off under reduced pressure and purified by column chromatography to obtain 7.8 g of Intermediate 2-2. (Yield 70%, Mass [M⁺]=384)

### (3) Synthesis of Compound BH2-1

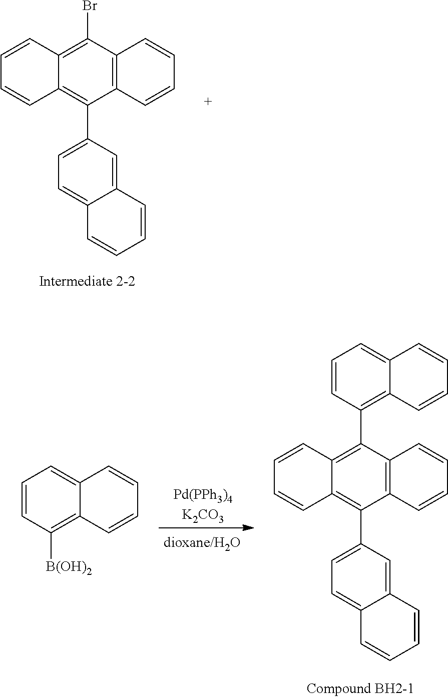

7.8 g of Intermediate 2-2, 3.9 g of naphthalen-1-ylboronic acid, 5.6 g of potassium carbonate (K₂CO₃), 160 mL of dioxane, and 40 mL of water were put into a flask under a nitrogen atmosphere. Thereafter, 0.47 g of tetrakis(triphenylphosphine)palladium (0) (Pd(PPh₃)₄) was added thereto, and the resulting mixture was stirred at 130° C. for 8 hours. After the reaction was terminated, the reaction solution was cooled to room temperature, aliquoted by adding water and toluene thereto, and then filtered by treatment with MgSO₄ (anhydrous). The filtered solution was distilled off under reduced pressure and purified with recrystallization (toluene/hexane) to obtain 5.7 g of Compound BH2-1. (Yield 65%, Mass [M⁺]=431)

### Synthesis Example 12. Synthesis of Compound BH2-2

### (1) Synthesis of Intermediate 2-3

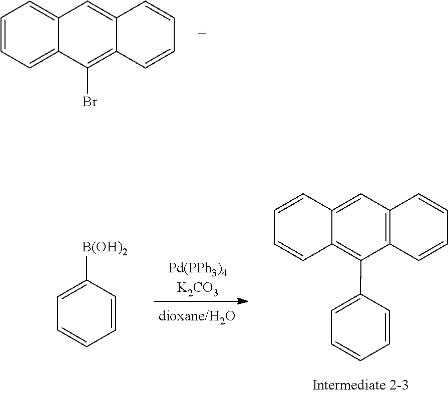

7.8 g of Intermediate 2-3 was obtained by preparation in the same manner as in (1) of Synthesis Example 11, except that 5.2 g of phenyl boronic acid was used instead of naphthalen-2-ylboronic acid in (1) of Synthesis Example 11. (Yield 79%, Mass [M⁺]=255)

### (2) Synthesis of Intermediate 2-4

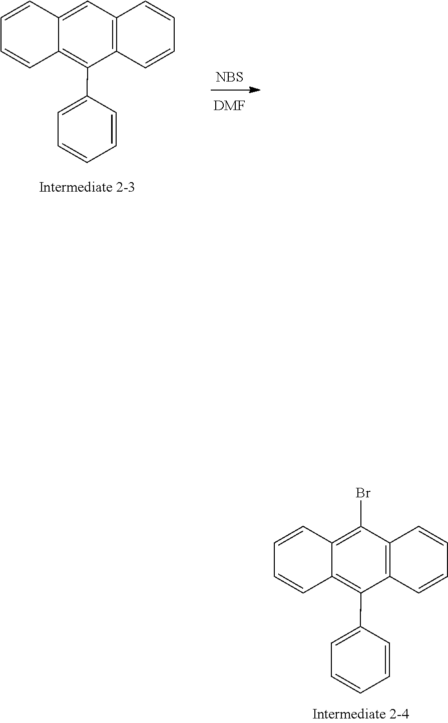

6.8 g of Intermediate 2-4 was obtained by preparation in the same manner as in (2) of Synthesis Example 11, except that 7.8 g of Intermediate 2-3 was used instead of Intermediate 2-1 in (2) of Synthesis Example 11. (Yield 67%, Mass [M⁺]=334)

### (3) Synthesis of Compound BH2-2

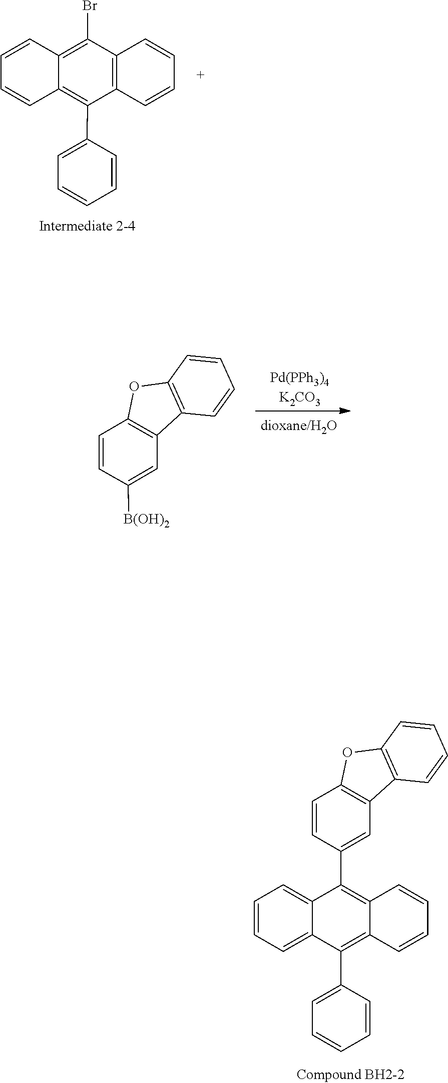 [SMILES: Brc1c2ccccc2c(-c2ccccc2)c2ccccc12 ; OB(O)c1ccc2oc3ccccc3c2c1 ; c1ccc(-c2c3ccccc3c(-c3ccc4oc5ccccc5c4c3)c3ccccc23)cc1]

6.2 g of Compound BH2-2 was obtained by preparation in the same manner as in (3) of Synthesis Example 11, except that 6.8 g of Intermediate 2-4 and 4.8 g of dibenzo[b,d]furan-2-ylboronic acid were used instead of Intermediate 2-2 and naphthalen-1-ylboronic acid, respectively, in (3) of Synthesis Example 11. (Yield 72%, Mass [M⁺]=421)

### Synthesis Example 13. Synthesis of Compound BH2-3

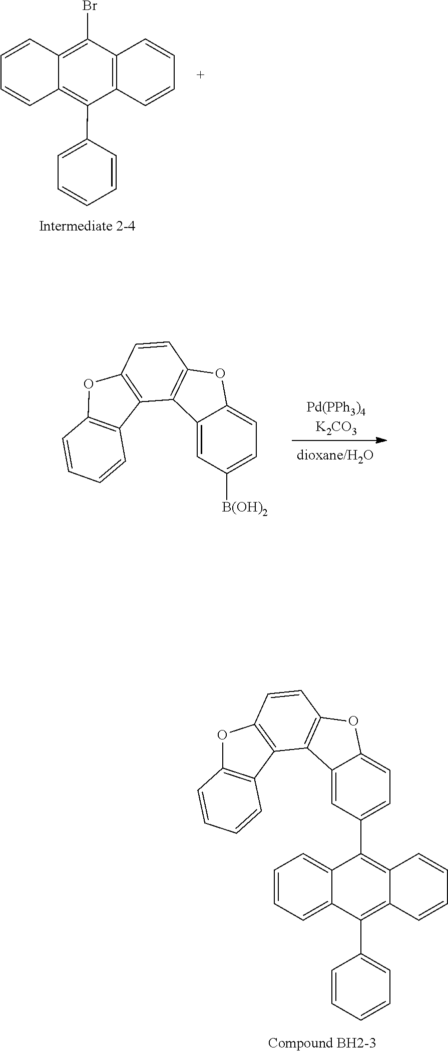 [SMILES: Brc1c2ccccc2c(-c2ccccc2)c2ccccc12 ; OB(O)c1ccc2oc3ccc4oc5ccccc5c4c3c2c1 ; c1ccc(-c2c3ccccc3c(-c3ccc4oc5ccc6oc7ccccc7c6c5c4c3)c3ccccc23)cc1]

4.2 g of Compound BH2-3 was obtained by preparation in the same manner as in (3) of Synthesis Example 11, except that 4 g of Intermediate 2-4 and 4.0 g of benzofurodibenzofuryl boronic acid were used instead of Intermediate 2-2 and naphthalen-1-ylboronic acid, respectively, in (3) of Synthesis Example 11. (Yield 69%, Mass [M⁺]=511)

### EXAMPLES

### Example 1

A substrate on which indium tin oxide (ITO)/Ag/ITO were deposited to have a thickness of 70 Å/1000 Å/70 Å as an anode was cut into a size of 50 mm×50 mm×0.5 mm, put in distilled water in which a dispersant was dissolved, and ultrasonically cleaned. A product manufactured by Fischer Co., was used as the detergent, and distilled water twice filtered using a filter manufactured by Millipore Co., was used as the distilled water. After the substrate was washed for 30 minutes, ultrasonic washing was conducted twice repeatedly using distilled water for 10 minutes. After washing with distilled water, the substrate was washed with ultrasonic waves using the solvents of isopropyl alcohol, acetone, and methanol in this order, and then dried.

HI-1 was vacuum deposited to a thickness of 50 Å on the anode, thereby forming a hole injection layer, and HT-1 was vacuum deposited to a thickness of 1100 Å thereon, thereby forming a hole transport layer. Then, EB-1 (150 Å°) was vacuum deposited, thereby forming an electron blocking layer. Subsequently, BD-1 (dopant, 2 wt % with respect to 100 wt % of the entire light emitting layer) and Compounds BH1-1 and BH2-1 (hosts, the weight ratio of Compounds BH1-1 and BH2-1 is 20:80, and the sum of the hosts is 98 wt % with respect to 100 wt % of the entire light emitting layer) were deposited by a method of co-deposition, thereby forming a light emitting layer having a thickness of 200 Å. HB-1 was vacuum deposited to a thickness of 50 Å on the light emitting layer, thereby forming a hole blocking layer. Subsequently, ET-1 and lithium quinolate (liq) were vacuum deposited at a weight ratio of 1:1 on the hole blocking layer, thereby forming an electron injection and transport layer having a thickness of 310 Å. Lithium fluoride (LiF) and aluminum were sequentially deposited on the electron injection and transport layer to a thickness of 5 Å and 1,000 Å, respectively, thereby forming a cathode.

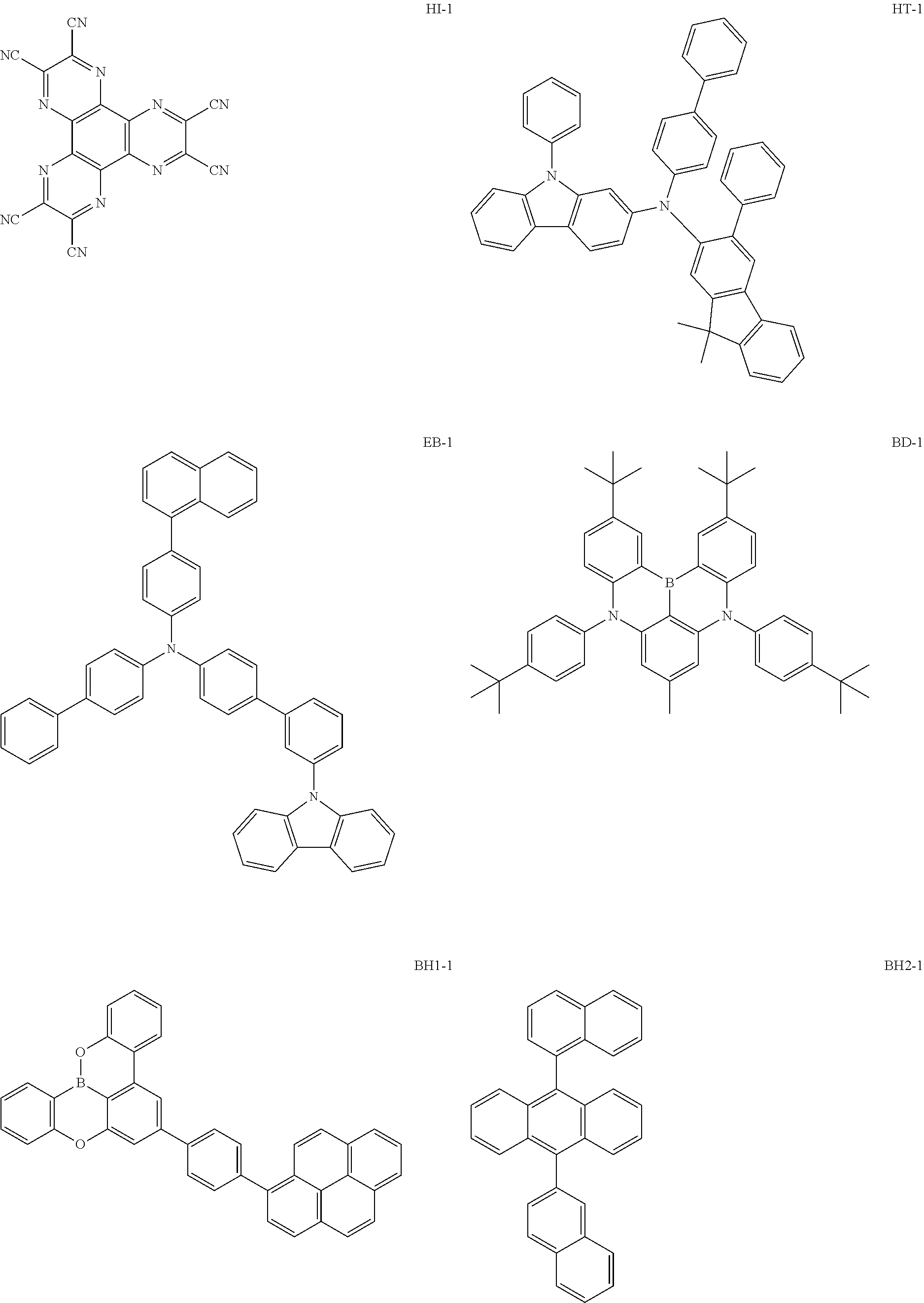

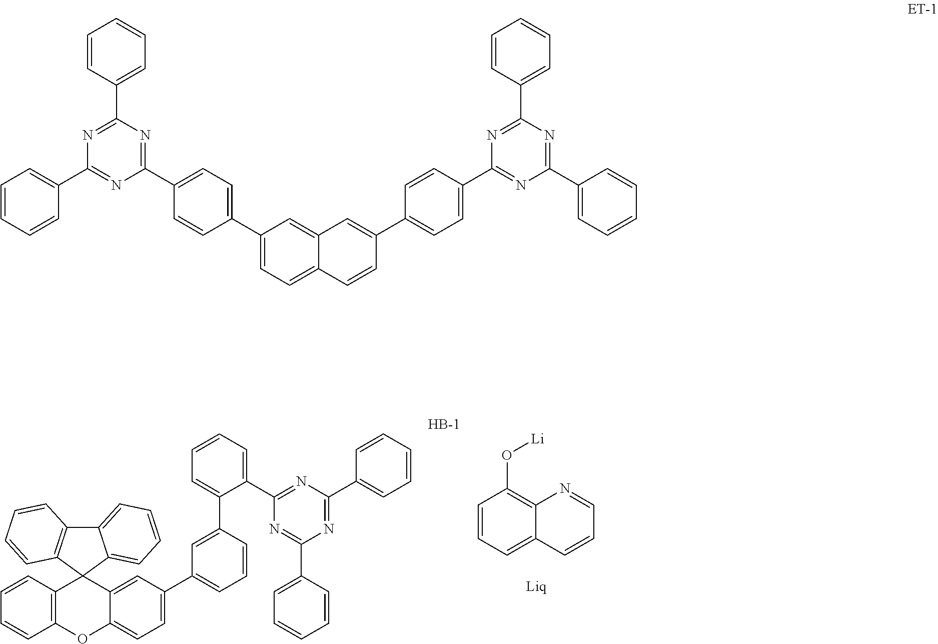

In the aforementioned procedure, the deposition rate of the organic material was maintained at 0.4 Å/sec to 0.7 Å/sec, the deposition rates of lithium fluoride and aluminum of the cathode were maintained at 0.3 Å/sec and at 2 Å/sec, respectively, and the degree of vacuum during the deposition was maintained at 5×10⁻⁶ to 2×10⁻⁷ torr, thereby manufacturing an organic light emitting device.

### Examples 2 to 21

Organic light emitting devices were manufactured in the same manner as in Example 1, except that compounds described in the following Table 1 were used instead of Compounds BH1-1 and BH2-1 and each proportion was changed in Example 1.

### Comparative Examples 1 to 5

Organic light emitting devices were manufactured in the same manner as in Example 1, except that compounds described in the following Table 1 were used instead of Compounds BH1-1 and BH2-1 in Example 1.

### Comparative Example 6

An organic light emitting device was manufactured in the same manner as in Example 1, except that Compound BH1-6 was used during the preparation of the hole transport layer and Compound BH2-3 was used during the preparation of the light emitting layer in Example 1.

### Comparative Example 7

An organic light emitting device was manufactured in the same manner as in Example 1, except that Compound BH1-8 was used during the preparation of the electron transport layer and Compound BH2-1 was used during the preparation of the light emitting layer in Example 1.

Comparative Examples 1 and 2 are comparative examples in which other compounds were applied instead of Compound 1 during the preparation of the light emitting layer, Comparative Example 3 is a comparative example in which another compound was applied instead of Compound 2 during the preparation of the light emitting layer, Comparative Examples 4 and 5 are comparative examples in which one type of host (Chemical Formula 1 or 2) was used during the preparation of the light emitting layer, Comparative Example 6 is a comparative example in which the compound of Chemical Formula 1 was applied not to the light emitting layer but to the hole transport layer, and Comparative Example 7 is a comparative example in which the compound of Chemical Formula 1 was applied not to the light emitting layer but to the electron transport layer.

The structures of Compounds BH1-1 to BH1-8 prepared in Synthesis Examples 1 to 10 and used in the Examples and Comparative Examples are as follows.

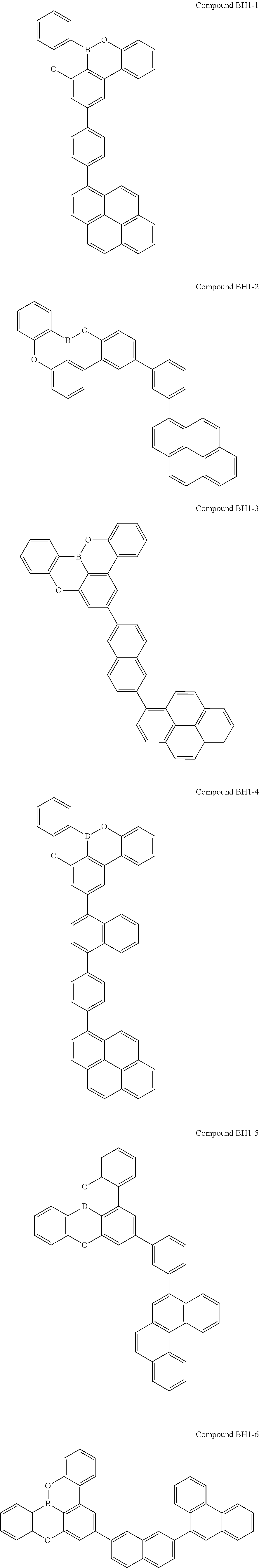 [SMILES: c1ccc2c(c1)Oc1cc(-c3ccc(-c4ccc5ccc6cccc7ccc4c5c67)cc3)cc3c1B2Oc1ccccc1-3 ; c1cc(-c2ccc3c(c2)-c2cccc4c2B(O3)c2ccccc2O4)cc(-c2ccc3ccc4cccc5ccc2c3c45)c1 ; c1ccc2c(c1)Oc1cc(-c3ccc4cc(-c5ccc6ccc7cccc8ccc5c6c78)ccc4c3)cc3c1B2Oc1ccccc1-3 ; c1ccc2c(c1)Oc1cc(-c3ccc(-c4ccc(-c5ccc6ccc7cccc8ccc5c6c78)cc4)c4ccccc34)cc3c1B2Oc1ccccc1-3 ; c1cc(-c2cc3c4c(c2)-c2ccccc2OB4c2ccccc2O3)cc(-c2cc3ccc4ccccc4c3c3ccccc23)c1 ; c1ccc2c(c1)Oc1cc(-c3ccc4ccc(-c5cc6ccccc6c6ccccc56)cc4c3)cc3c1B2Oc1ccccc1-3]

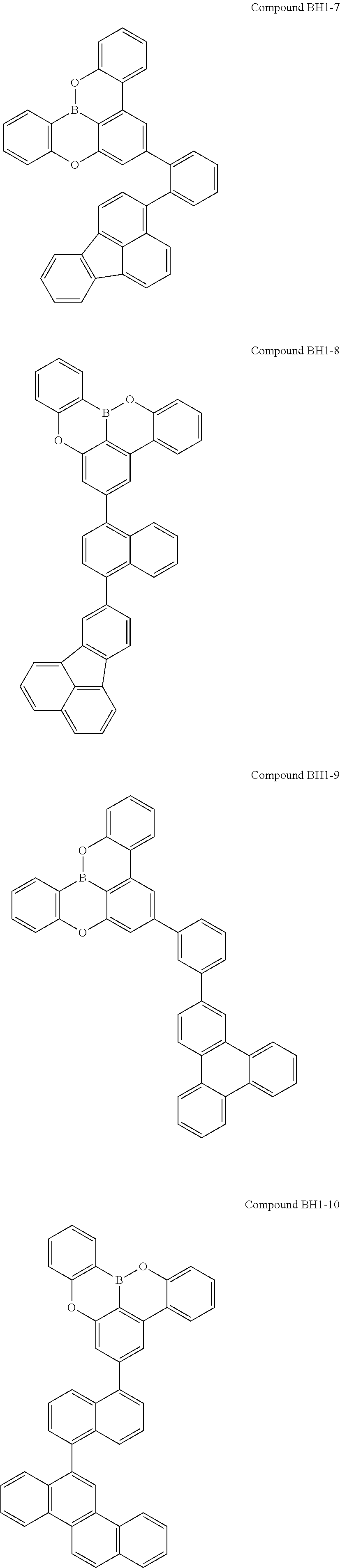 [SMILES: c1ccc2c(c1)Oc1cc(-c3ccccc3-c3ccc4c5c(cccc35)-c3ccccc3-4)cc3c1B2Oc1ccccc1-3 ; c1ccc2c(c1)Oc1cc(-c3ccc(-c4ccc5c(c4)-c4cccc6cccc-5c46)c4ccccc34)cc3c1B2Oc1ccccc1-3 ; c1cc(-c2cc3c4c(c2)-c2ccccc2OB4c2ccccc2O3)cc(-c2ccc3c4ccccc4c4ccccc4c3c2)c1 ; c1ccc2c(c1)Oc1cc(-c3cccc4c(-c5cc6c7ccccc7ccc6c6ccccc56)cccc34)cc3c1B2Oc1ccccc1-3]

The structures of Compounds BH2-1 to BH2-3 prepared in Synthesis Examples 11 to 13 and used in the Examples and Comparative Examples are as follows.

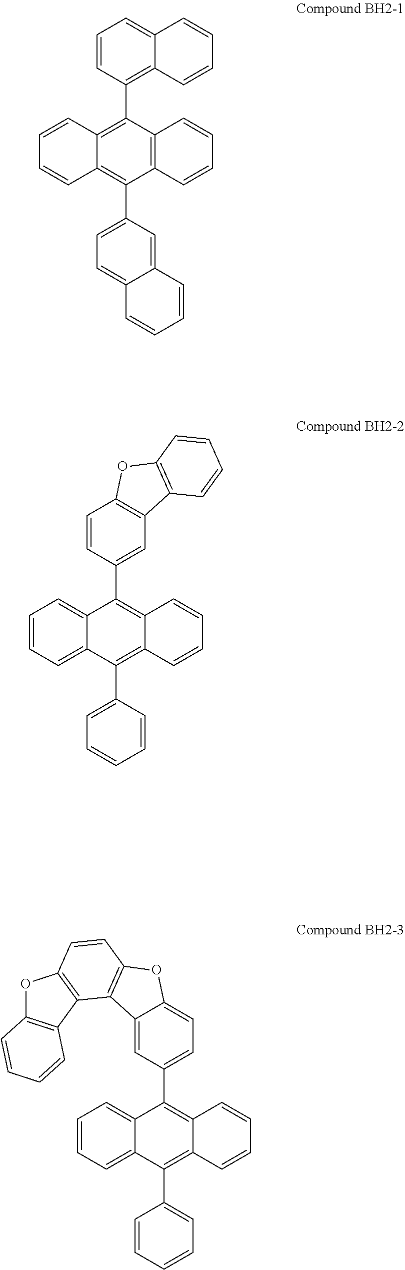

The compounds of BH-A to BH-C used in the Comparative Examples are as follows.

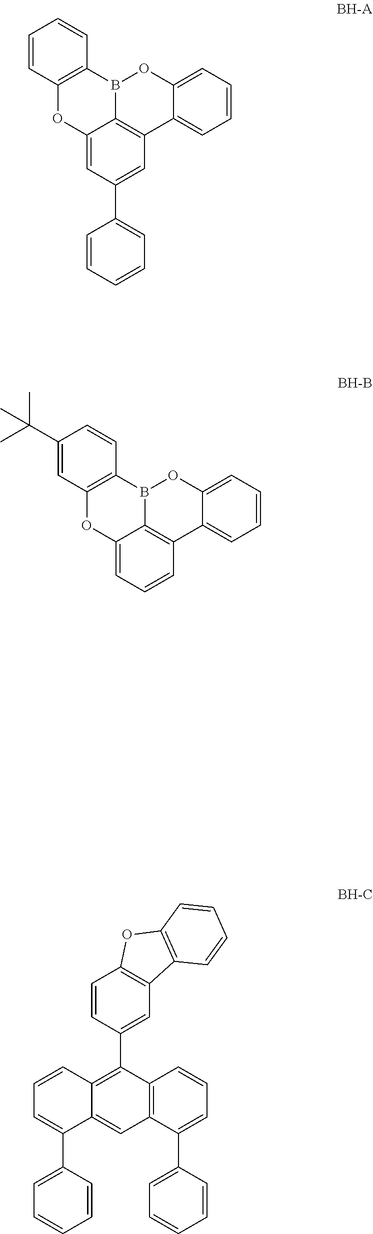 [SMILES: c1ccc(-c2cc3c4c(c2)-c2ccccc2OB4c2ccccc2O3)cc1 ; CC(C)(C)c1ccc2c(c1)Oc1cccc3c1B2Oc1ccccc1-3 ; c1ccc(-c2cccc3c(-c4ccc5oc6ccccc6c5c4)c4cccc(-c5ccccc5)c4cc23)cc1]

For the organic light emitting devices manufactured by Examples 1 to 21 and Comparative Examples 1 to 7, the driving voltage (V) and the light emitting efficiency (EQE) were measured at a current density of 10 mA/cm², and a time (T97) for reaching a 97% value compared to the initial luminance was measured at a current density of 20 mA/cm². The results are shown in the following Table 1.

TABLE 1

| | Light emitting layer | | | | |
|---|---|---|---|---|---|
| | Host | Host | Voltage (V) | EQE | T97 (h) |
| | BH1 | BH2 | (@10 mA/ | (@10 mA/ | (@20 mA/ |
| | (Weight ratio) | | cm²) | cm²) | cm²) |
| Example 1 | BH1-1 | BH2-1 | 3.59 | 6.94 | 110 |
| | 20:80 | | | | |
| Example 2 | BH1-1 | BH2-1 | 3.56 | 7.08 | 116 |
| | 30:70 | | | | |
| Example 3 | BH1-1 | BH2-2 | 3.52 | 6.85 | 126 |
| | 20:80 | | | | |
| Example 4 | BH1-1 | BH2-3 | 3.45 | 6.74 | 115 |
| | 30:70 | | | | |
| Example 5 | BH1-2 | BH2-1 | 3.71 | 6.87 | 109 |
| | 30:70 | | | | |
| Example 6 | BH1-2 | BH2-2 | 3.63 | 6.70 | 123 |
| | 30:70 | | | | |
| Example 7 | BH1-2 | BH2-3 | 3.55 | 6.53 | 109 |
| | 20:80 | | | | |
| Example 8 | BH1-3 | BH2-1 | 3.67 | 6.92 | 107 |
| | 10:90 | | | | |
| Example 9 | BH1-3 | BH2-2 | 3.59 | 6.76 | 114 |
| | 10:90 | | | | |
| Example 10 | BH1-3 | BH2-3 | 3.62 | 6.65 | 110 |
| | 10:90 | | | | |
| Example 11 | BH1-4 | BH2-1 | 3.67 | 6.97 | 121 |
| | 10:90 | | | | |
| Example 12 | BH1-4 | BH2-2 | 3.59 | 6.80 | 115 |
| | 10:90 | | | | |
| Example 13 | BH1-4 | BH2-3 | 3.62 | 6.69 | 117 |
| | 10:90 | | | | |
| Example 14 | BH1-5 | BH2-1 | 3.63 | 6.82 | 106 |
| | 30:70 | | | | |
| Example 15 | BH1-5 | BH2-2 | 3.56 | 6.77 | 113 |
| | 20:80 | | | | |
| Example 16 | BH1-5 | BH2-3 | 3.52 | 6.54 | 115 |
| | 20:80 | | | | |
| Example 17 | BH1-6 | BH2-1 | 3.71 | 6.76 | 109 |
| | 20:80 | | | | |
| Example 18 | BH1-7 | BH2-1 | 3.67 | 6.70 | 107 |
| | 20:80 | | | | |
| Example 19 | BH1-7 | BH2-3 | 3.52 | 6.66 | 110 |
| | 10:90 | | | | |
| Example 20 | BH1-8 | BH2-1 | 3.71 | 6.87 | 108 |
| | 10:90 | | | | |
| Example 21 | BH1-8 | BH2-2 | 3.56 | 6.89 | 119 |
| | 20:80 | | | | |
| Comparative | BH-A | BH2-1 | 3.92 | 4.65 | 45 |
| Example 1 | 20:80 | | | | |
| Comparative | BH-B | BH2-2 | 4.04 | 4.40 | 34 |
| Example 2 | 20:80 | | | | |
| Comparative | BH1-5 | BH-C | 4.12 | 4.08 | 42 |
| Example 3 | 20:80 | | | | |
| Comparative | BH1-3 | | 4.29 | 3.86 | 15 |
| Example 4 | | | | | |
| Comparative | BH2-1 | | 3.88 | 6.35 | 88 |
| Example 5 | | | | | |
| Comparative | BH1-6 | BH2-3 | 5.22 | 2.95 | 28 |
| Example 6 | (Hole | | | | |
| | transport | | | | |
| | layer) | | | | |
| Comparative | BH1-8 | BH2-1 | 5.15 | 3.02 | 31 |
| Example 7 | (Electron | | | | |
| | transport | | | | |
| | layer) | | | | |

Through Table 1, it can be seen that when the light emitting layer includes both the compounds of Chemical Formulae 1 and 2 (Examples 1 to 21), the characteristics of low voltage, high efficiency, and long service life of the device are enhanced compared to when the light emitting layer includes only any one of Chemical Formulae 1 and 2,

### Example 22

A substrate on which indium tin oxide (ITO)/Ag/ITO were deposited to have a thickness of 70 Å/1000 Å/70 Å as an anode was cut into a size of 50 mm×50 mm×0.5 mm, put in distilled water in which a dispersant was dissolved, and ultrasonically cleaned. A product manufactured by Fischer Co., was used as the detergent, and distilled water twice filtered using a filter manufactured by Millipore Co., was used as the distilled water. After the substrate was washed for 30 minutes, ultrasonic washing was conducted twice repeatedly using distilled water for 10 minutes. After washing with distilled water, the substrate was washed with ultrasonic waves using the solvents of isopropyl alcohol, acetone, and methanol in this order, and then dried.

HI-1 was vacuum deposited to a thickness of 50 Å on the anode, thereby forming a hole injection layer, and HT-1 was vacuum deposited to a thickness of 1100 Å thereon, thereby forming a hole transport layer. Then, EB-1 (100 Å′) was vacuum deposited, thereby forming an electron blocking layer. Subsequently, BD-1 (dopant, 2 wt % with respect to 100 wt % of the entire first light emitting layer) and BH1-1 (host, 98 wt % with respect to 100 wt % of the entire first light emitting layer) were deposited by a method of co-deposition, thereby forming a first light emitting layer having a thickness of 100 Å. Subsequently, BD-1 (dopant, 2 wt % with respect to 100 wt % of the entire second light emitting layer) and BH2-1 (host, 98 wt % with respect to 100 wt % of the entire second light emitting layer) were deposited on the first light emitting layer by a method of co-deposition, thereby depositing a second light emitting layer having a thickness of 100 Å. ET-1 was vacuum deposited to a thickness of 100 Å on the light emitting layer, thereby forming an electron transport layer. LiF was vacuum deposited on the electron transport layer to a thickness of 5 Å, thereby forming an electron injection layer. Subsequently, aluminum was deposited to a thickness of 1000 Å to form a cathode, thereby manufacturing an organic light emitting device.

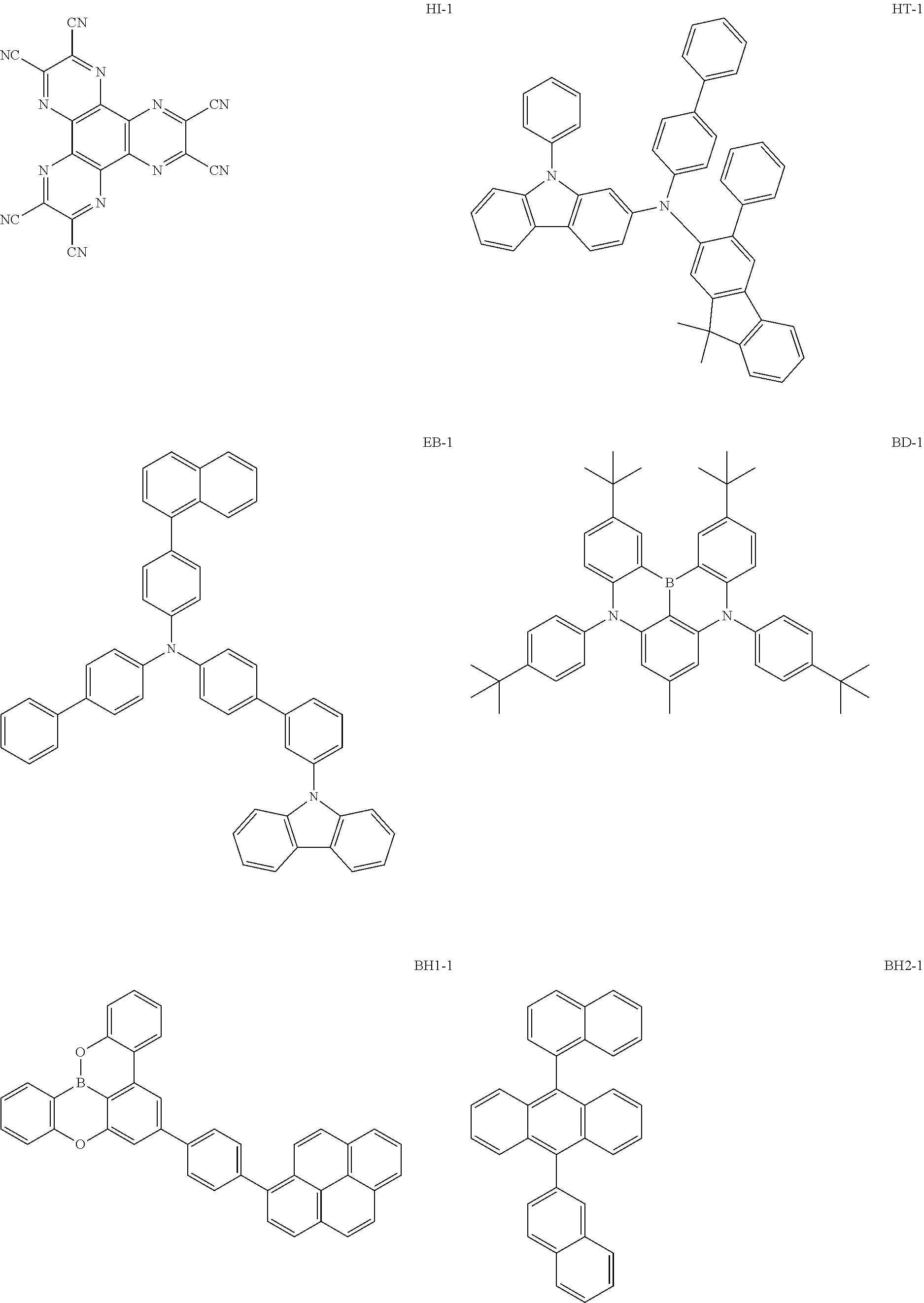

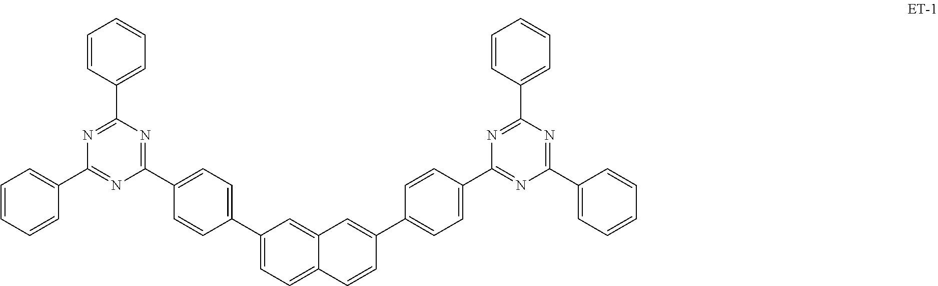 [SMILES: c1ccc(-c2nc(-c3ccccc3)nc(-c3ccc(-c4ccc5ccc(-c6ccc(-c7nc(-c8ccccc8)nc(-c8ccccc8)n7)cc6)cc5c4)cc3)n2)cc1]

In the aforementioned procedure, the deposition rate of the organic material was maintained at 0.4 Å/sec to 0.7 Å/sec, the deposition rates of lithium fluoride and aluminum of the cathode were maintained at 0.3 Å/sec and at 2 Å/sec, respectively, and the degree of vacuum during the deposition was maintained at 2×10⁻⁷ to 5×10⁻⁶ torr, thereby manufacturing an organic light emitting device.

### Examples 23 to 29

Organic light emitting devices were manufactured in the same manner as in Example 22, except that compounds described in the following Table 2 were used instead of Compounds BH1-1 and BH2-1 in Example 22.

### Comparative Examples 8 to 11

Organic light emitting devices were manufactured in the same manner as in Example 22, except that compounds described in the following Table 2 were used instead of Compounds BH1-1 and BH2-1 in Example 22. Specifically, in Comparative Examples 8 to 11, only a light emitting layer having one layer was used, to which only one of the compounds of Chemical Formula 1 or 2 was applied.

In the following Table 2, ‘-’ means that the corresponding layer is not formed. For example, in Comparative Example 8, only the first light emitting layer was formed, and the second light emitting layer was not formed.

TABLE 2

| | Light emitting layer | | | | |
|---|---|---|---|---|---|
| | First | Second | | | |
| | light | light | Voltage (V) | EQE | T97 (h) |
| | emitting | emitting | (@10 mA/ | (@10 mA/ | (@20 mA/ |
| | layer | layer | cm2) | cm2) | cm2) |
| Example 22 | BH1-1 | BH2-1 | 3.65 | 6.91 | 116 |
| Example 23 | BH1-3 | BH2-2 | 3.59 | 6.76 | 131 |
| Example 24 | BH1-4 | BH2-2 | 3.61 | 6.72 | 122 |
| Example 25 | BH1-6 | BH2-3 | 3.52 | 6.82 | 112 |
| Example 26 | BH1-9 | BH2-3 | 3.55 | 6.85 | 121 |
| Example 27 | BH1-9 | BH2-2 | 3.64 | 6.79 | 127 |
| Example 28 | BH1-10 | BH2-1 | 3.69 | 6.94 | 109 |
| Example 29 | BH1-10 | BH2-2 | 3.60 | 6.75 | 118 |
| Comparative | BH1-6 | — | 5.15 | 3.91 | 25 |
| Example 8 | | | | | |
| Comparative | BH1-9 | — | 4.88 | 3.72 | 30 |
| Example 9 | | | | | |
| Comparative | — | BH2-2 | 3.87 | 6.24 | 76 |
| Example 10 | | | | | |
| Comparative | — | BH2-3 | 3.82 | 6.38 | 81 |
| Example 11 | | | | | |

From Table 2, it can be seen that even when a device is manufactured by constructing a light emitting layer having two layers, the device exhibits characteristics of low voltage, high efficiency, and long service life, similar to when using a light emitting layer having one layer by co-deposition.

### DESCRIPTION OF SYMBOLS

1: substrate
2: anode
3: light emitting layer
3-1: a first light emitting layer
3-2: a second light emitting layer
4: cathode
5: hole injection layer
6: hole transport layer
7: electron transport layer
8: electron blocking layer
9: hole blocking layer
10: electron injection and transport layer
11: electron transport layer
12: electron injection layer

1. An organic light emitting device comprising:
an anode;
a cathode; and
a light emitting layer provided between the anode and the cathode,
wherein the light emitting layer comprises a compound represented by the following Chemical Formula 1 and a compound represented by the following Chemical Formula 2: 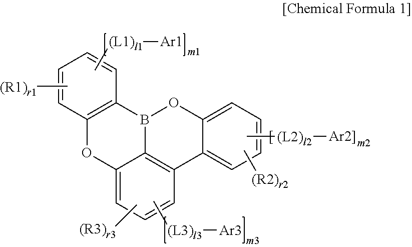
in Chemical Formula 1,
L1 to L3 are the same as or different from each other, and are each independently a direct bond; or a substituted or unsubstituted arylene group,
Ar1 to Ar3 are the same as or different from each other, and are each independently a substituted or unsubstituted polycyclic aryl group,
R1 to R3 are the same as or different from each other, and are each independently hydrogen; deuterium; a substituted or unsubstituted alkyl group; a substituted or unsubstituted aryl group; or a substituted or unsubstituted heteroaryl group,
l1 to l3 are each an integer from 1 to 3, and when l1 to l3 are each 2 or higher, structures in each parenthesis are the same as or different from each other,
m1 to m3 are each an integer of 0 or 1, and m1+m2+m3 is an integer from 1 to 3,
r1 and r2 are each an integer from 1 to 4, and when r1 and r2 are 2 or higher, structures in each parenthesis are the same as or different from each other, r3 is 1 or 2, and when r3 is 2, structures in the parenthesis are the same as or different from each other, r1+m1 is an integer from 1 to 4, r2+m2 is an integer from 1 to 4, and r3+m3 is an integer from 1 to 3, 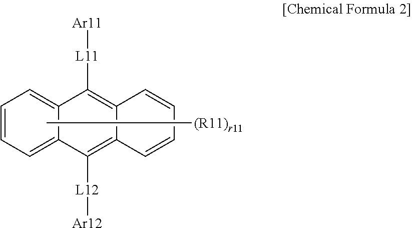
in Chemical Formula 2,
L11 and L12 are the same as or different from each other, and are each independently a direct bond; a substituted or unsubstituted arylene group; or a substituted or unsubstituted heteroarylene group,
Ar11 and Ar12 are the same as or different from each other, and are each independently a substituted or unsubstituted aryl group; or a substituted or unsubstituted heteroaryl group,
R11 is hydrogen; deuterium; a substituted or unsubstituted alkyl group; a substituted or unsubstituted aryl group; or a substituted or unsubstituted heteroaryl group, and
r11 is an integer from 1 to 8, and when r11 is 2 or higher, two or more R11's are the same as or different from each other.

2. The organic light emitting device of claim 1, wherein Chemical Formula 1 is any one of the following Chemical Formulae 1-1 to 1-3: 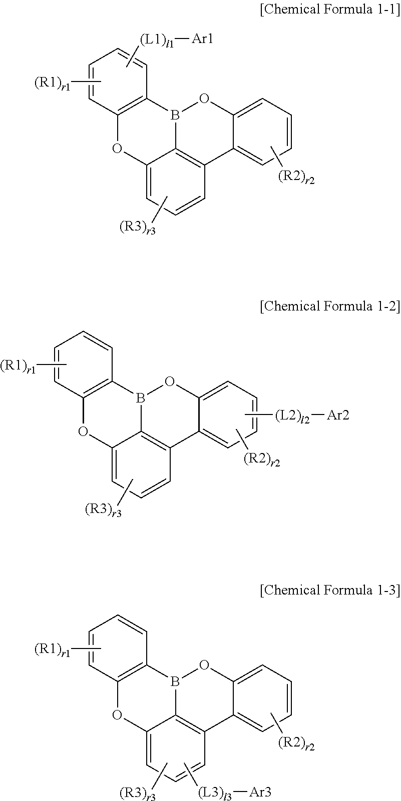
in Chemical Formulae 1-1 to 1-3,
R1 to R3, r1 to r3, L1 to L3, 11 to 13, and Ar1 to Ar3 are the same as those defined in Chemical Formula 1.

3. The organic light emitting device of claim 1, wherein Ar1 to Ar3 are the same as or different from each other, are each independently substituted or unsubstituted, and are a fused aryl group in which two or more hydrocarbon rings are fused.

4. The organic light emitting device of claim 1, wherein Ar1 to Ar3 are the same as or different from each other, and are each independently a substituted or unsubstituted pyrene group; a substituted or unsubstituted benzophenanthrene group; a substituted or unsubstituted phenanthrene group; a substituted or unsubstituted fluoranthene group; a substituted or unsubstituted triphenylene group; or a substituted or unsubstituted chrysene group.

5. The organic light emitting device of claim 1, wherein Chemical Formula 2 is the following Chemical Formula 2-1 or 2-2: 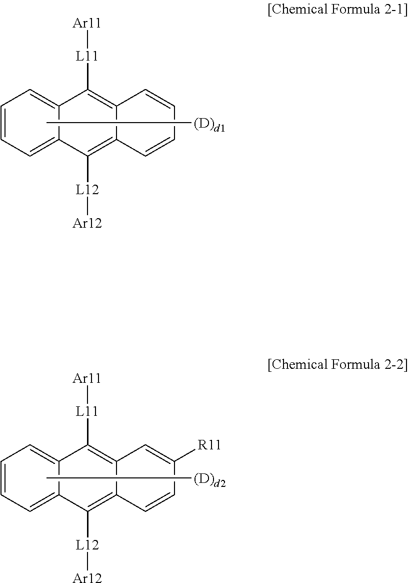
in Chemical Formulae 2-1 and 2-2,
L11, L12, Ar11, Ar12, and R11 are the same as those defined in Chemical Formula 2,
D is deuterium, and
d1 is an integer from 0 to 8, and d2 is an integer from 0 to 7.

6. The organic light emitting device of claim 1, wherein L11 and L12 are the same as or different from each other, and are each independently a direct bond; a substituted or unsubstituted phenylene group; a substituted or unsubstituted biphenylylene group; a substituted or unsubstituted naphthylene group; a substituted or unsubstituted divalent furan group; a substituted or unsubstituted divalent benzofuran group; a substituted or unsubstituted divalent dibenzofuran group; a substituted or unsubstituted divalent thiophene group; or a substituted or unsubstituted divalent benzothiophene group; or a substituted or unsubstituted divalent dibenzothiophene group.

7. The organic light emitting device of claim 1, wherein Ar11 and Ar12 are the same as or different from each other, and are each independently a substituted or unsubstituted phenyl group; a substituted or unsubstituted biphenyl group; a substituted or unsubstituted terphenyl group; a substituted or unsubstituted naphthyl group; a substituted or unsubstituted phenanthrene group; a substituted or unsubstituted triphenylene group; a substituted or unsubstituted dibenzofuran group; a substituted or unsubstituted dibenzothiophene group; a substituted or unsubstituted naphthobenzofuran group; a substituted or unsubstituted benzonaphthothiophene group; a substituted or unsubstituted dinaphthofuran group; a substituted or unsubstituted dinaphthothiophene group; or a benzobisbenzofuran group.

8. The organic light emitting device of claim 1, wherein the compound represented by Chemical Formula 1 is any one of the following structures:

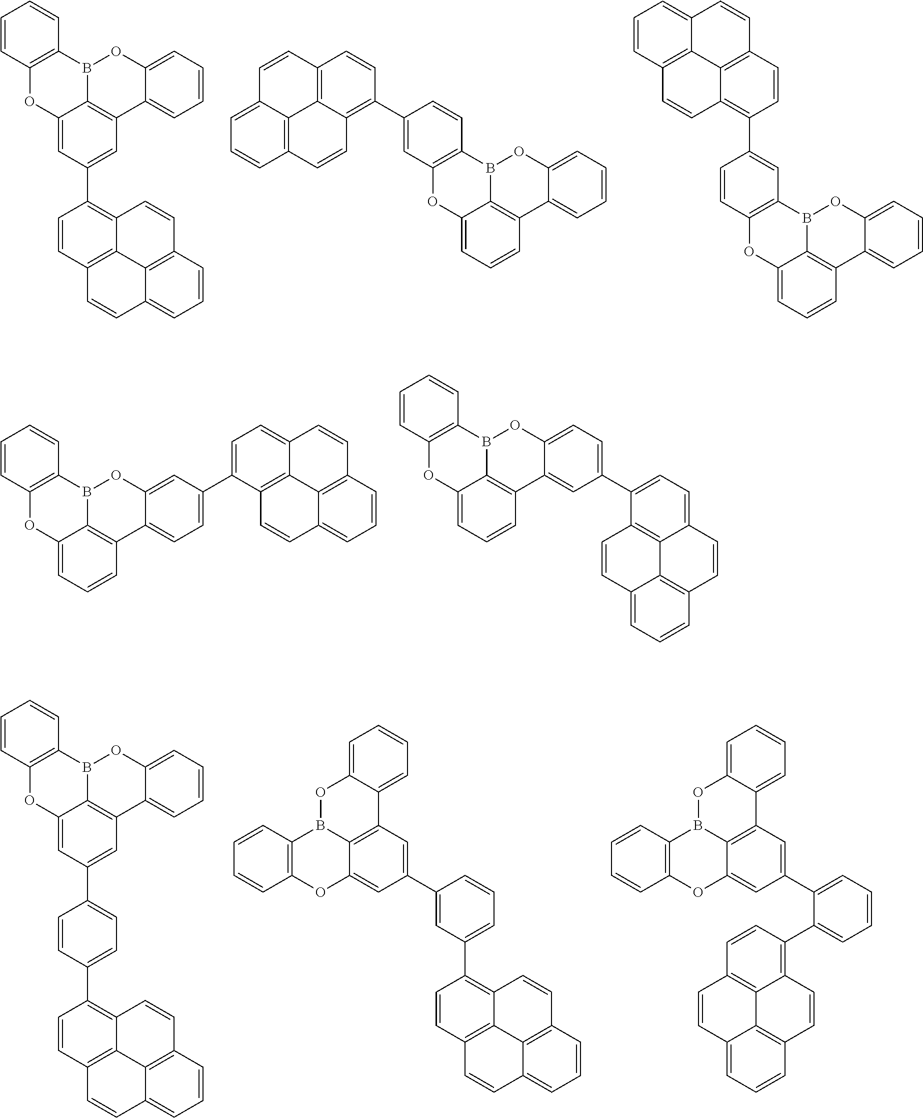

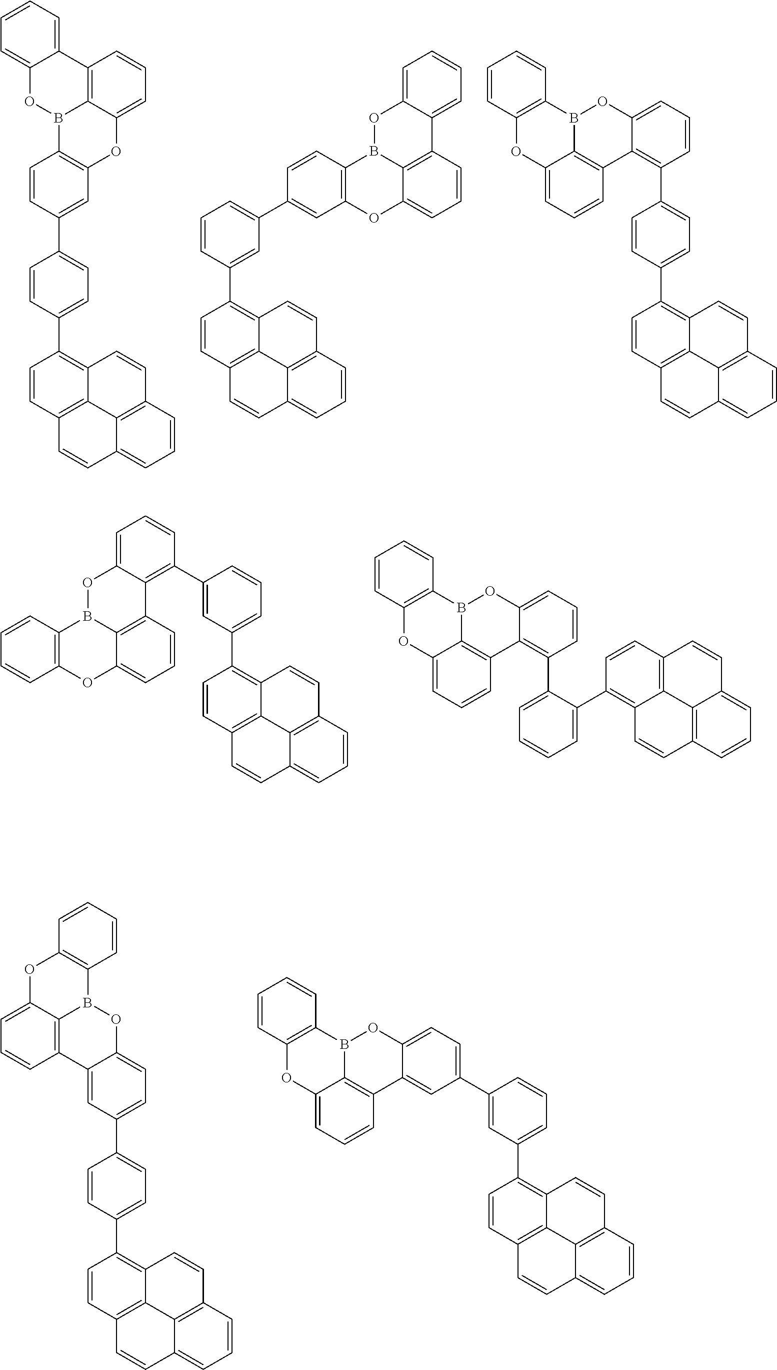

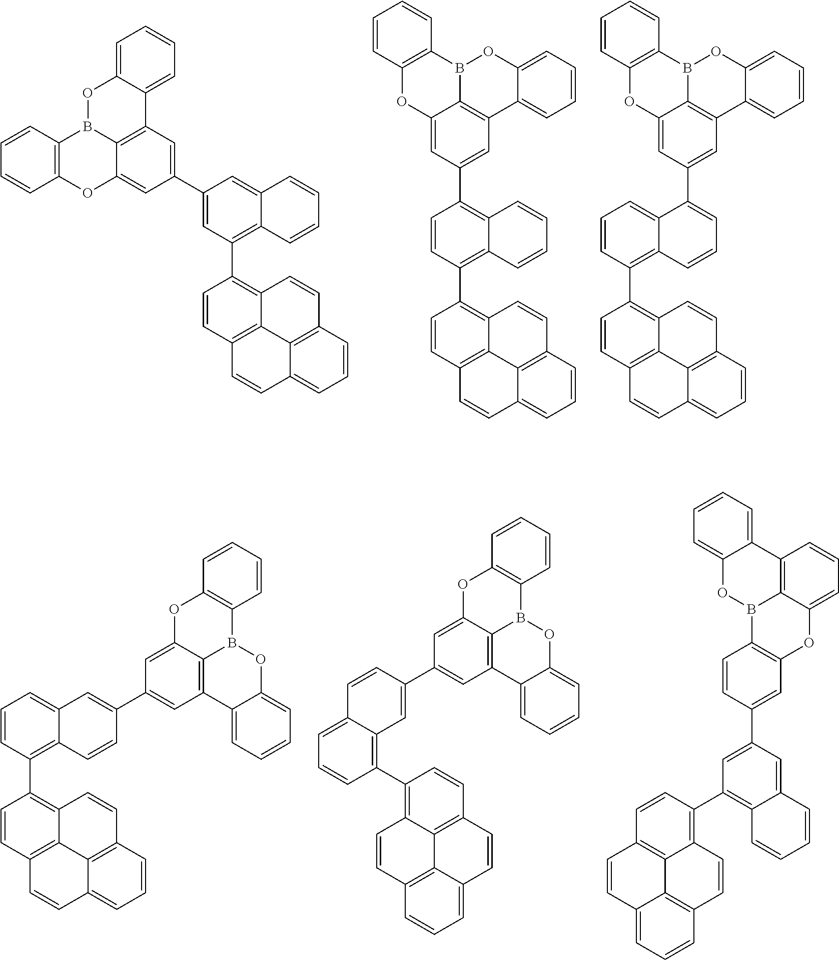

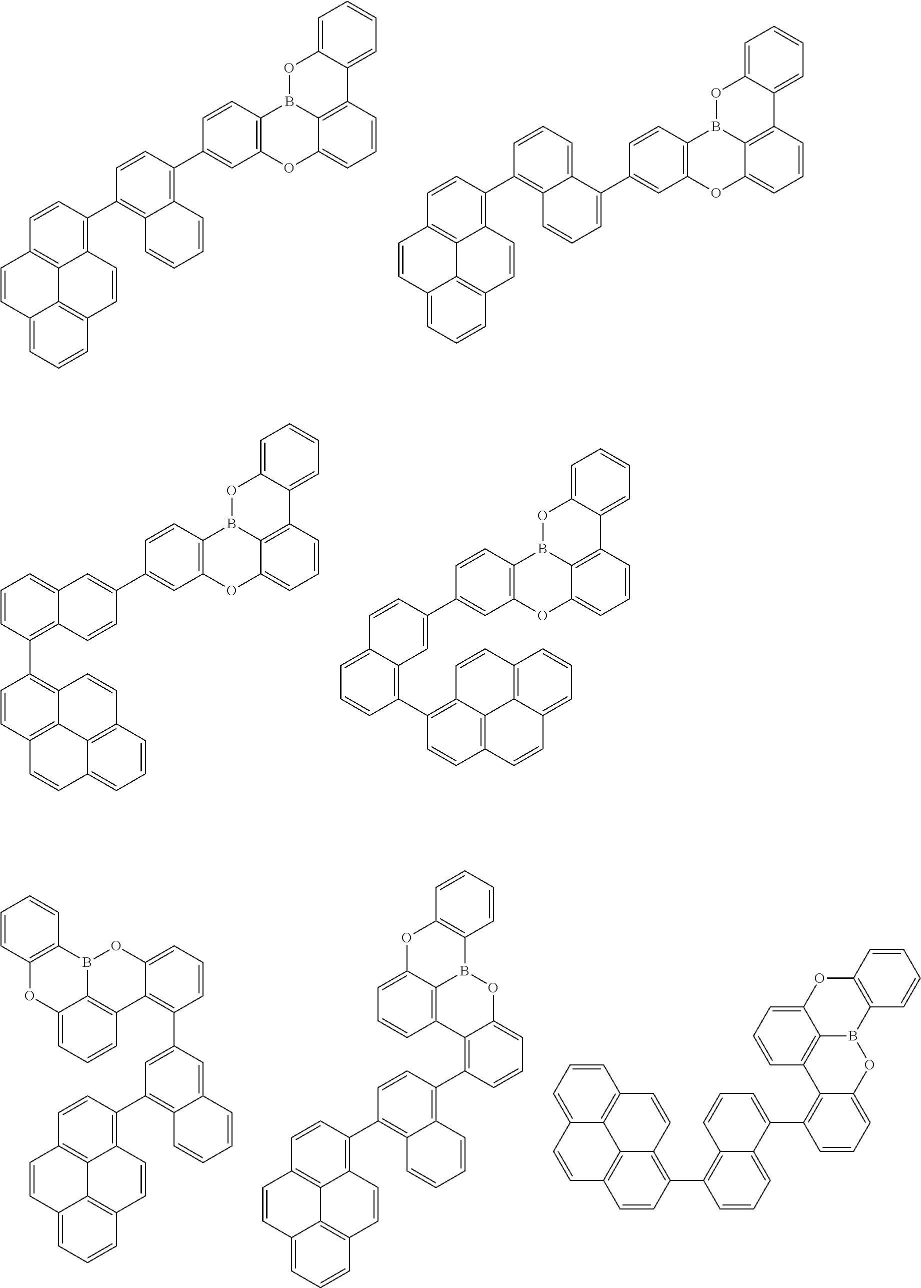

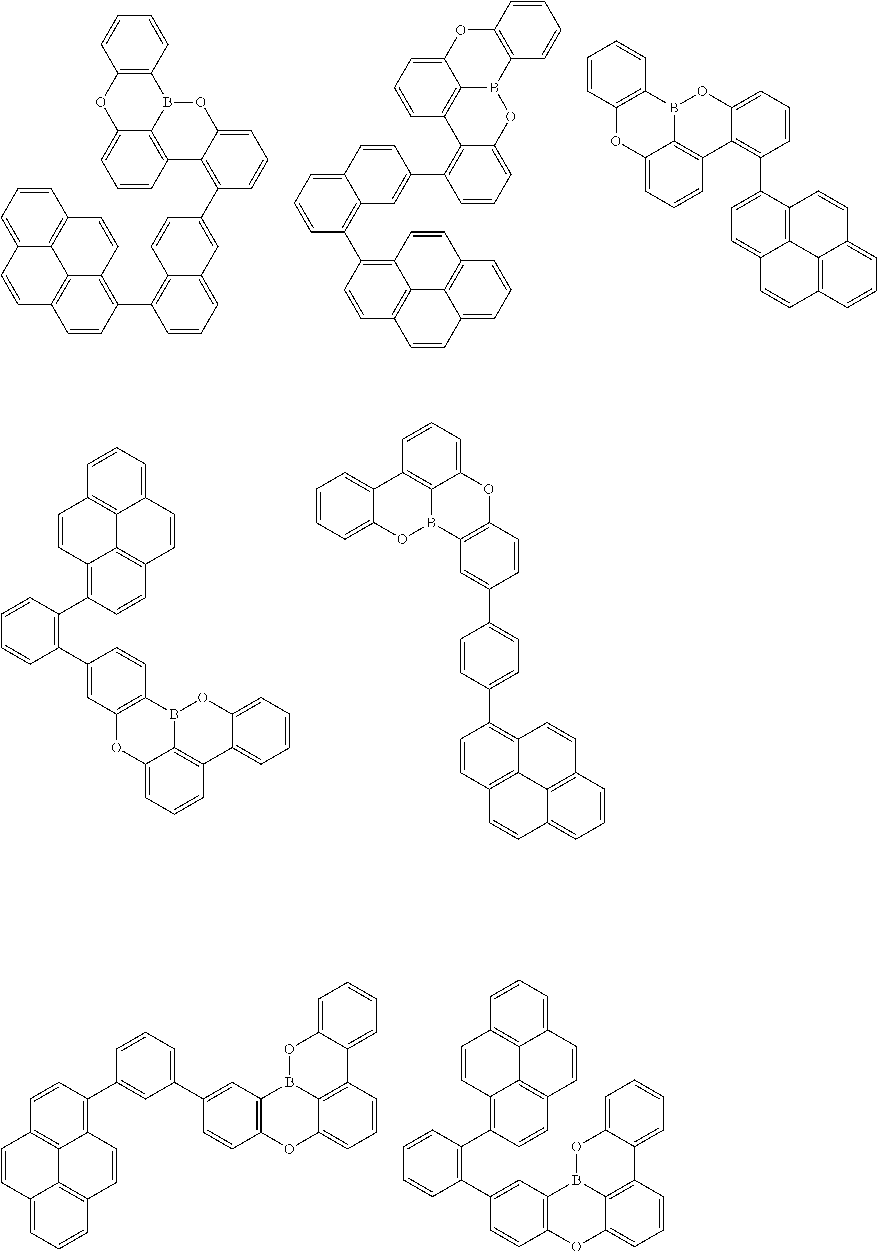

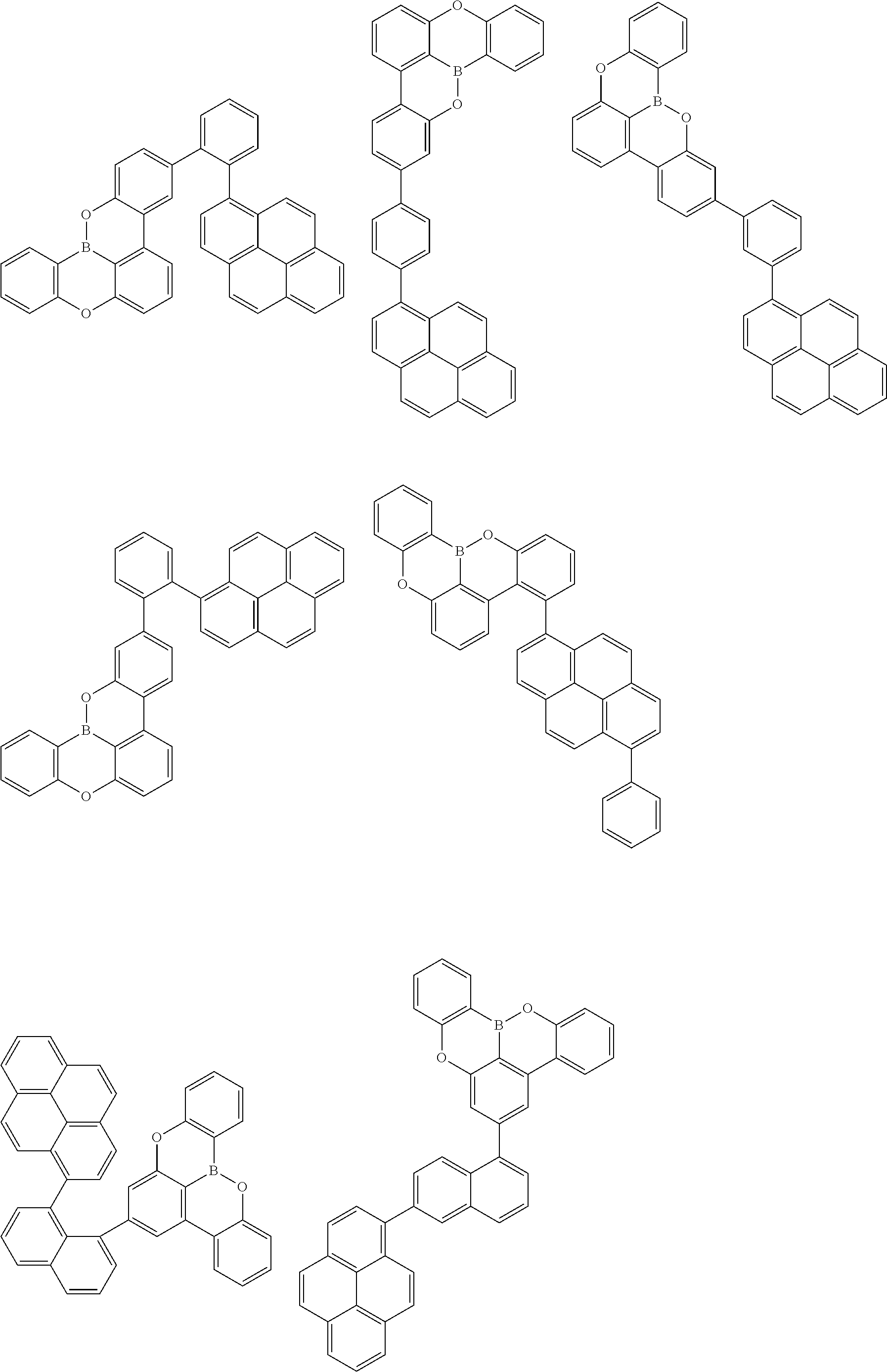

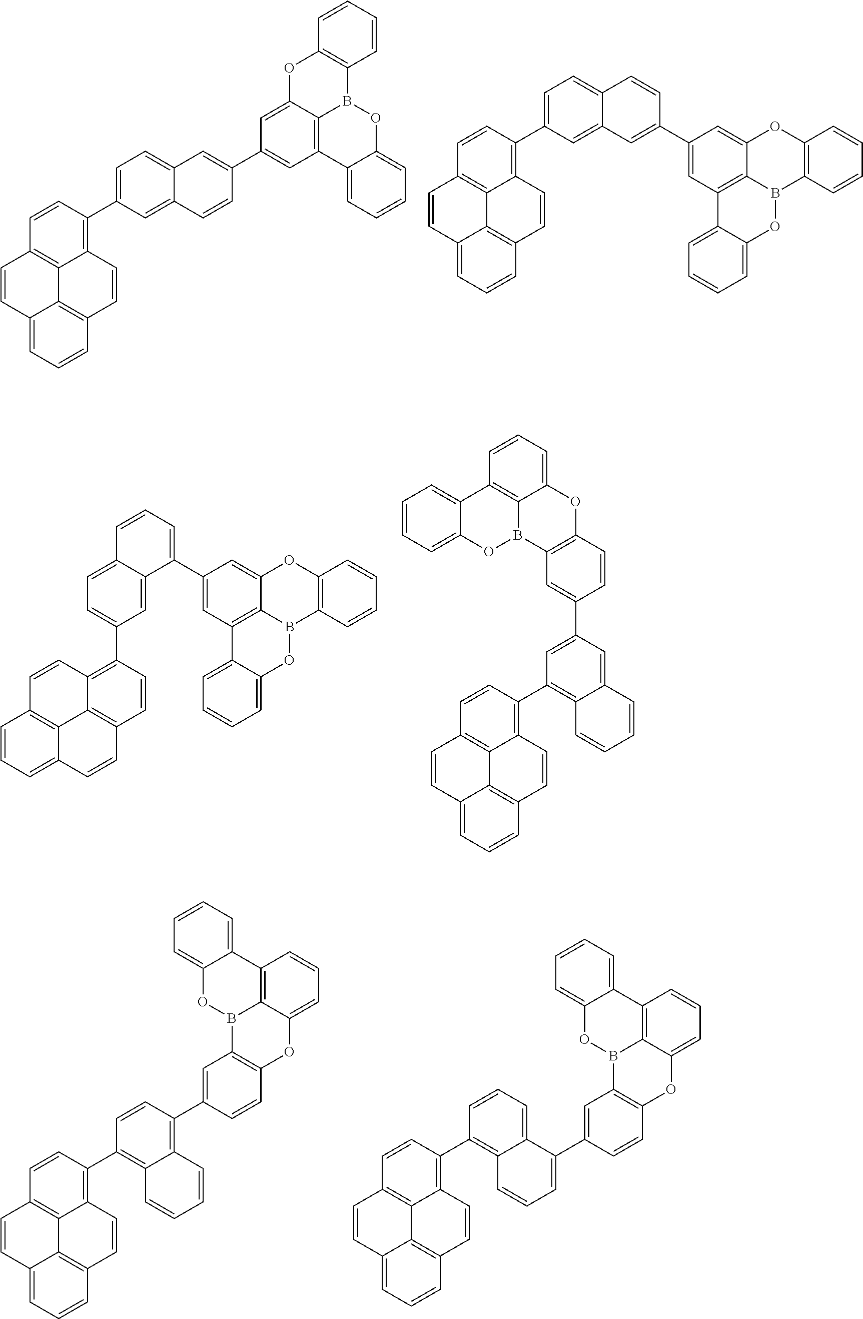

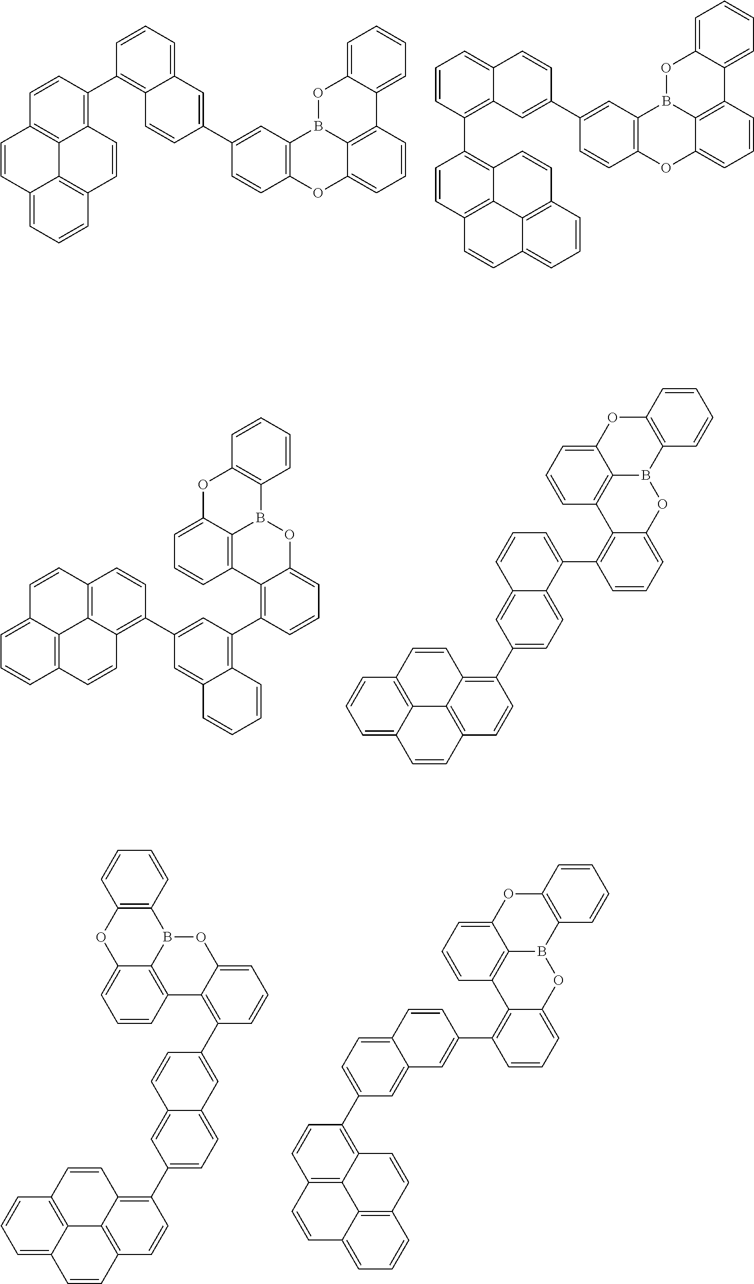

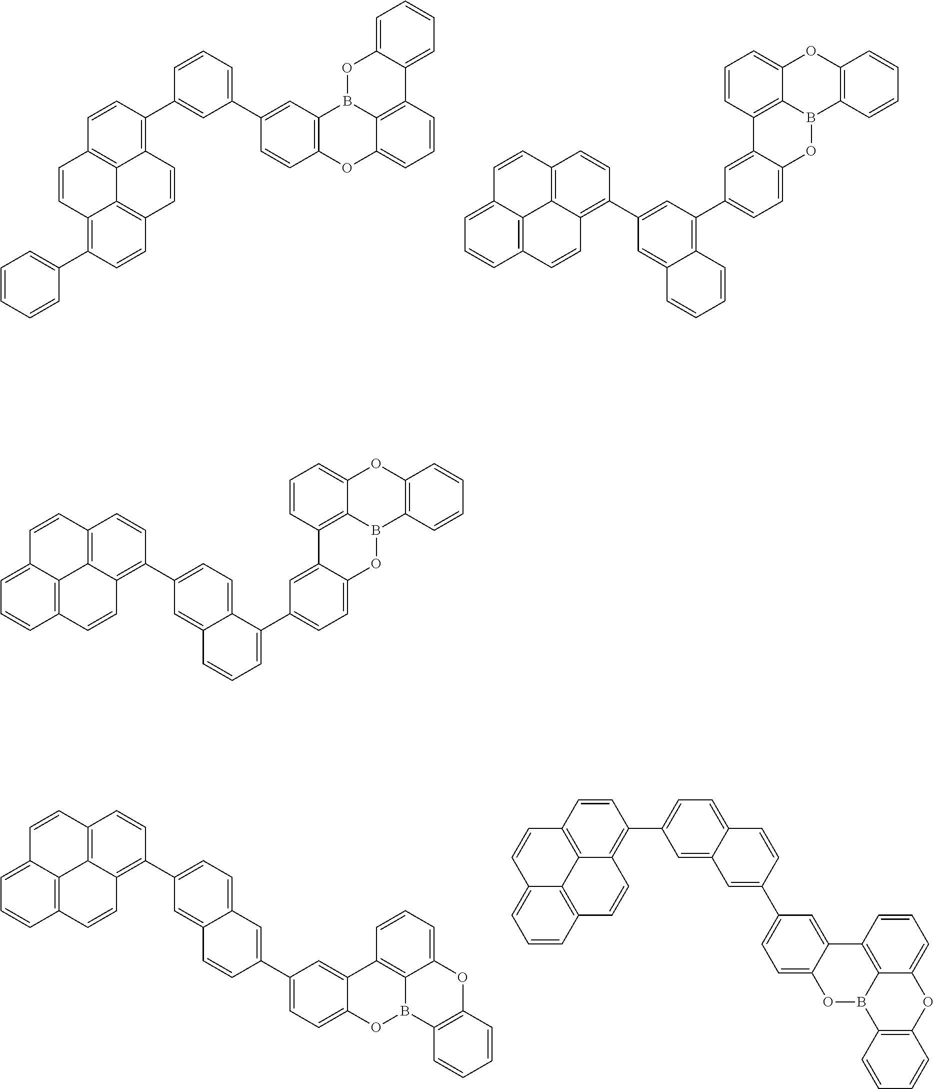

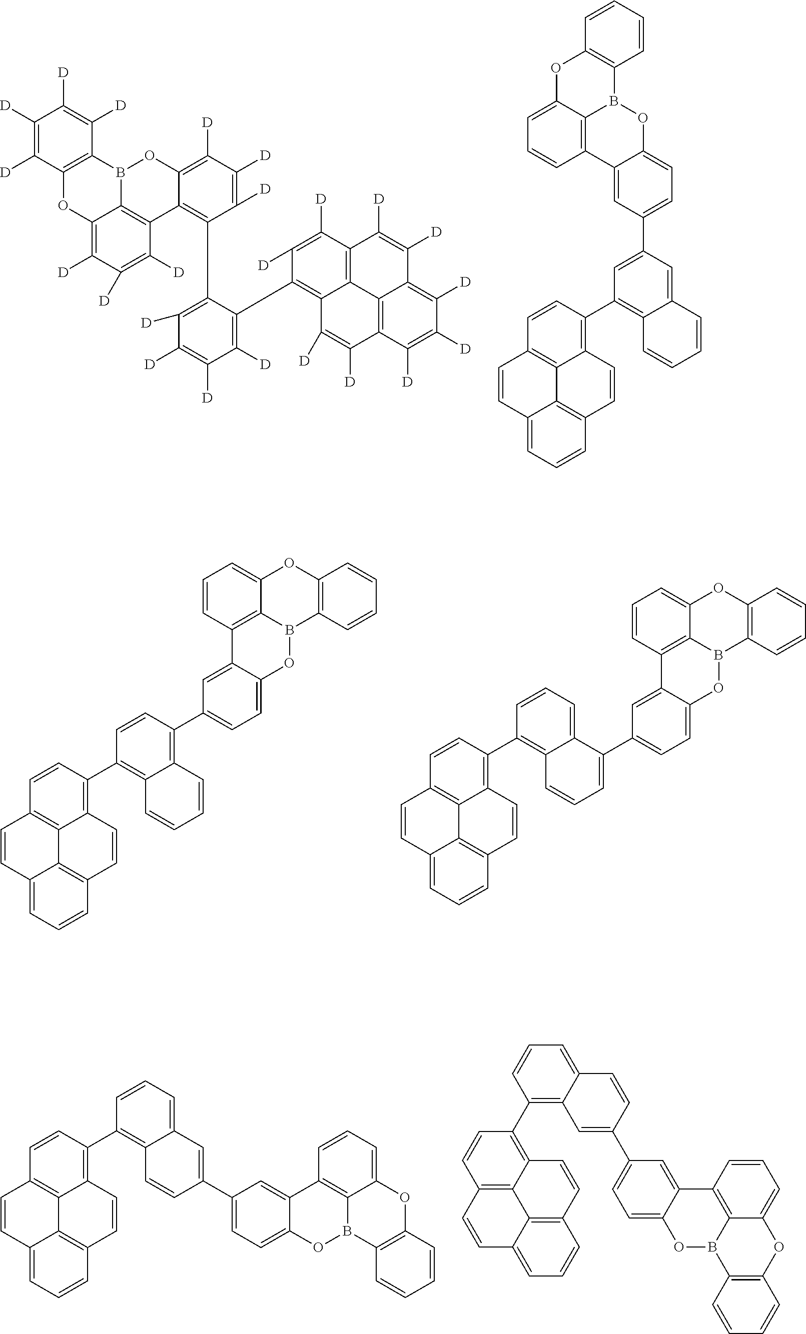

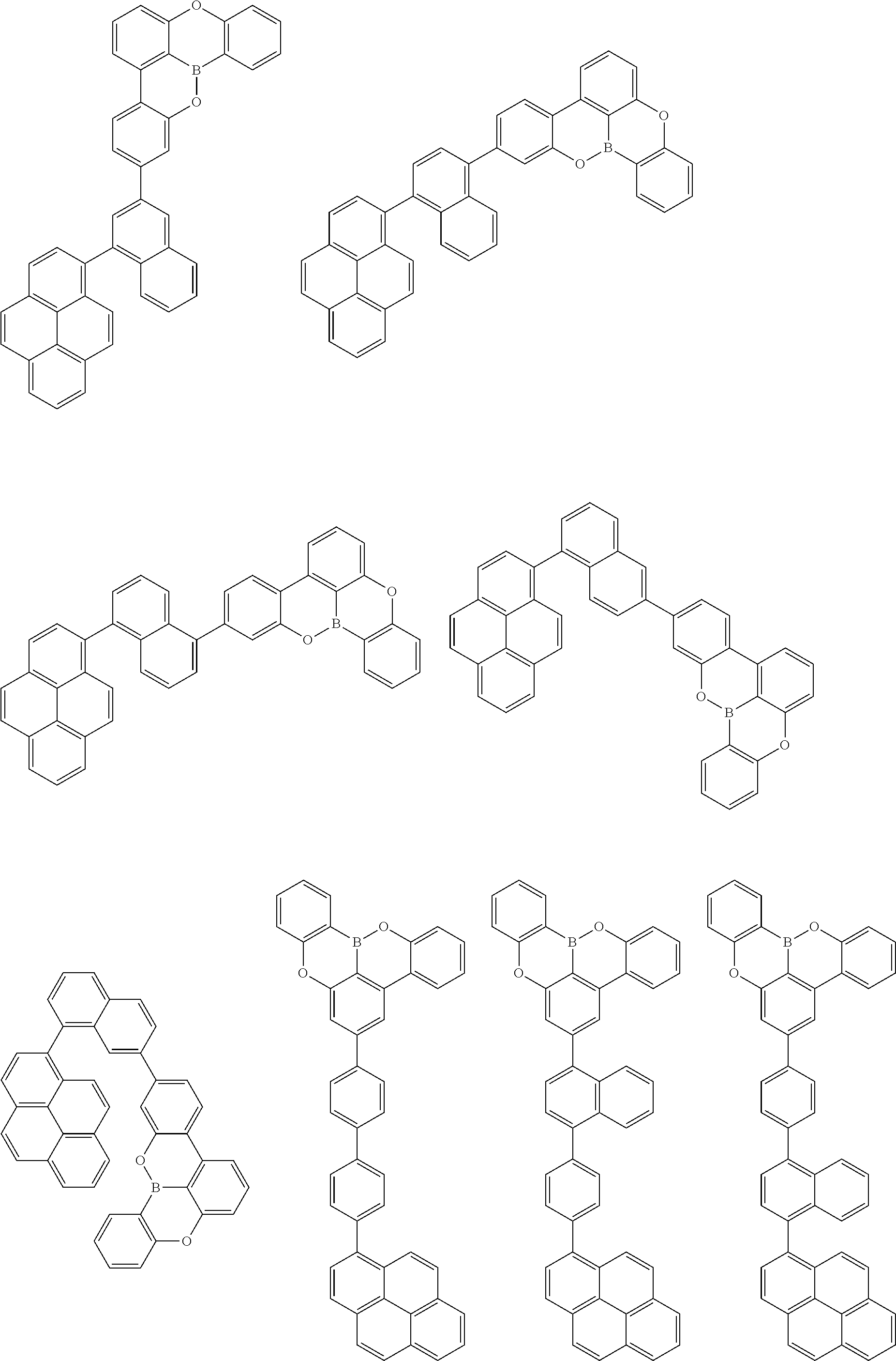

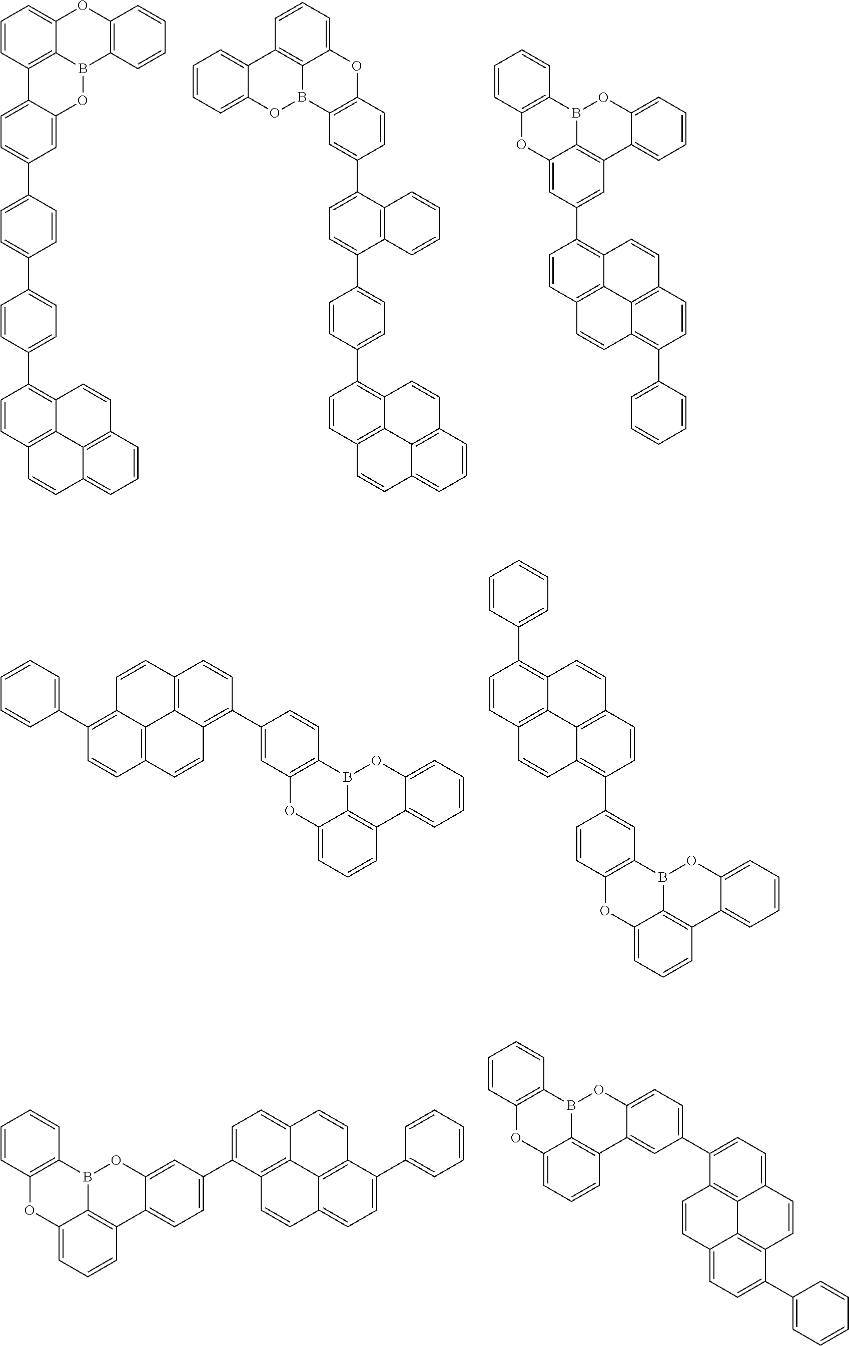

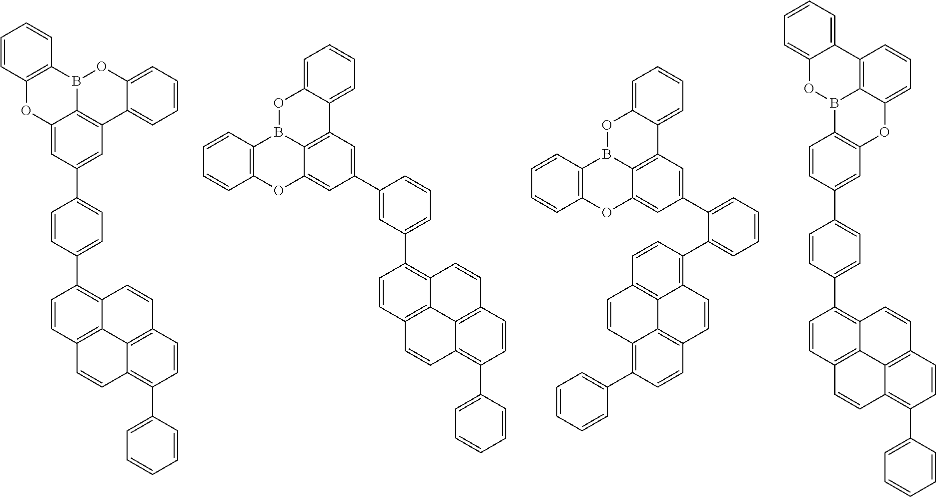 [SMILES: c1ccc(-c2ccc3ccc4c(-c5ccc(-c6cc7c8c(c6)-c6ccccc6OB8c6ccccc6O7)cc5)ccc5ccc2c3c54)cc1 ; c1ccc(-c2ccc3ccc4c(-c5cccc(-c6cc7c8c(c6)-c6ccccc6OB8c6ccccc6O7)c5)ccc5ccc2c3c54)cc1 ; c1ccc(-c2ccc3ccc4c(-c5ccccc5-c5cc6c7c(c5)-c5ccccc5OB7c5ccccc5O6)ccc5ccc2c3c54)cc1 ; c1ccc(-c2ccc3ccc4c(-c5ccc(-c6ccc7c(c6)Oc6cccc8c6B7Oc6ccccc6-8)cc5)ccc5ccc2c3c54)cc1]

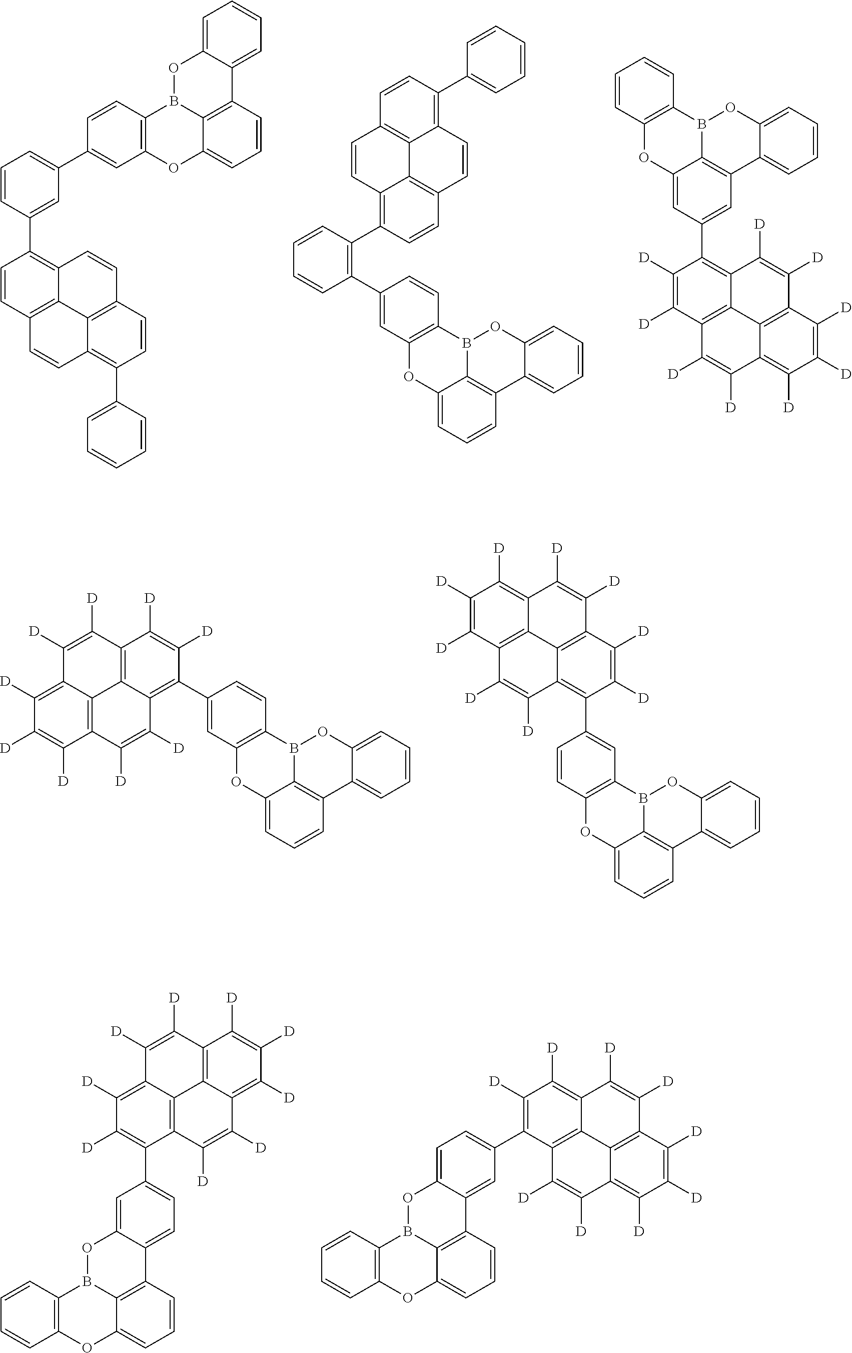

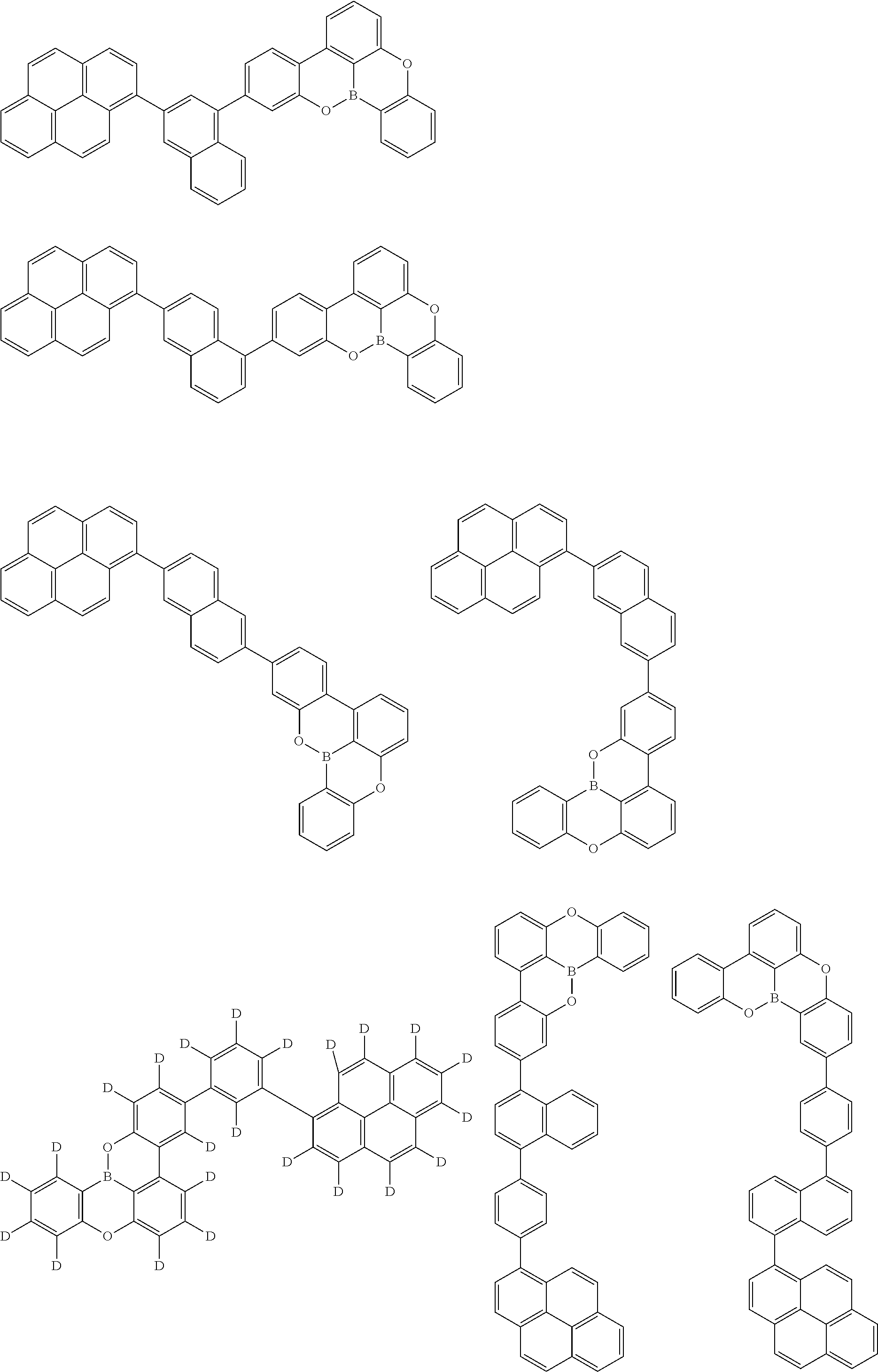

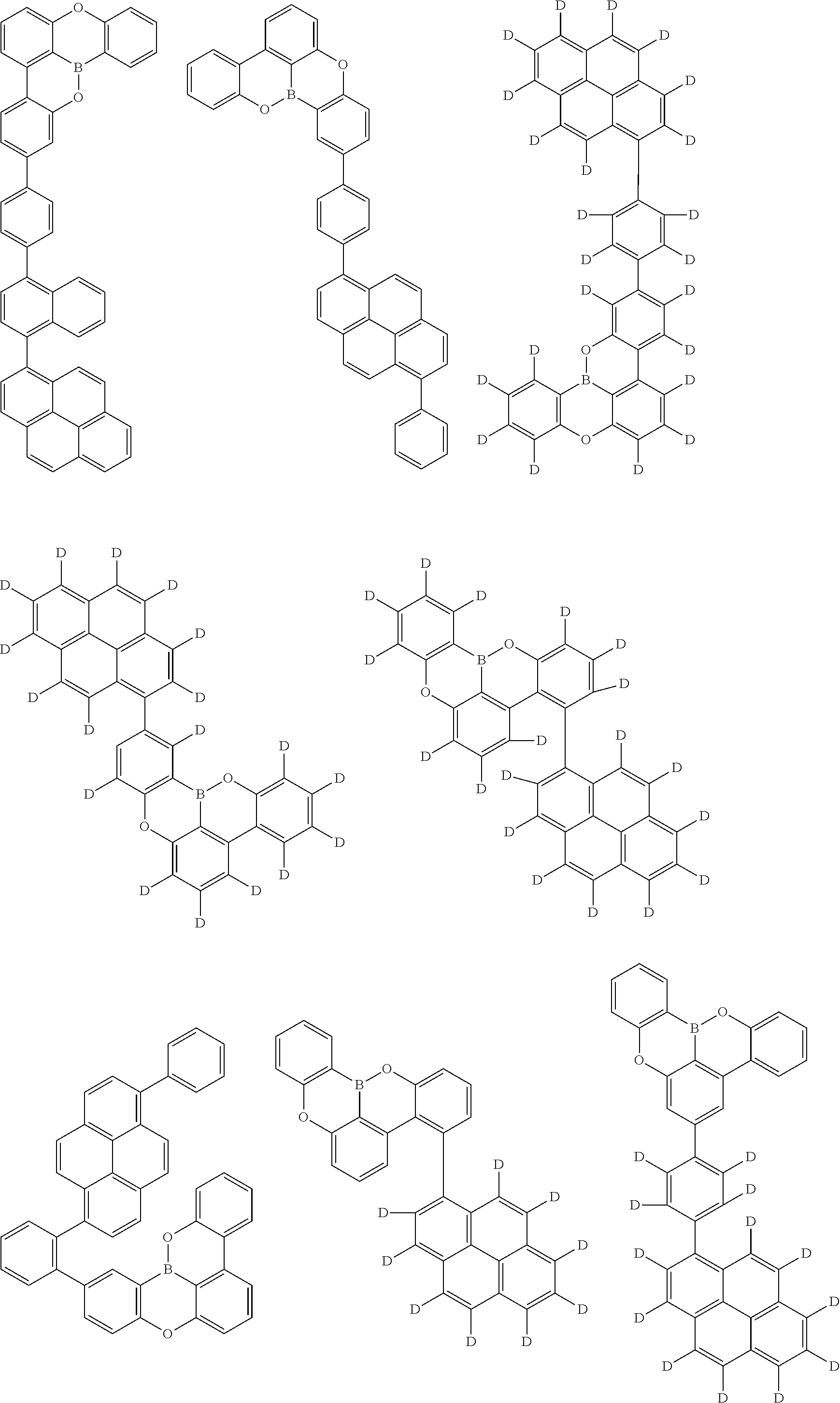

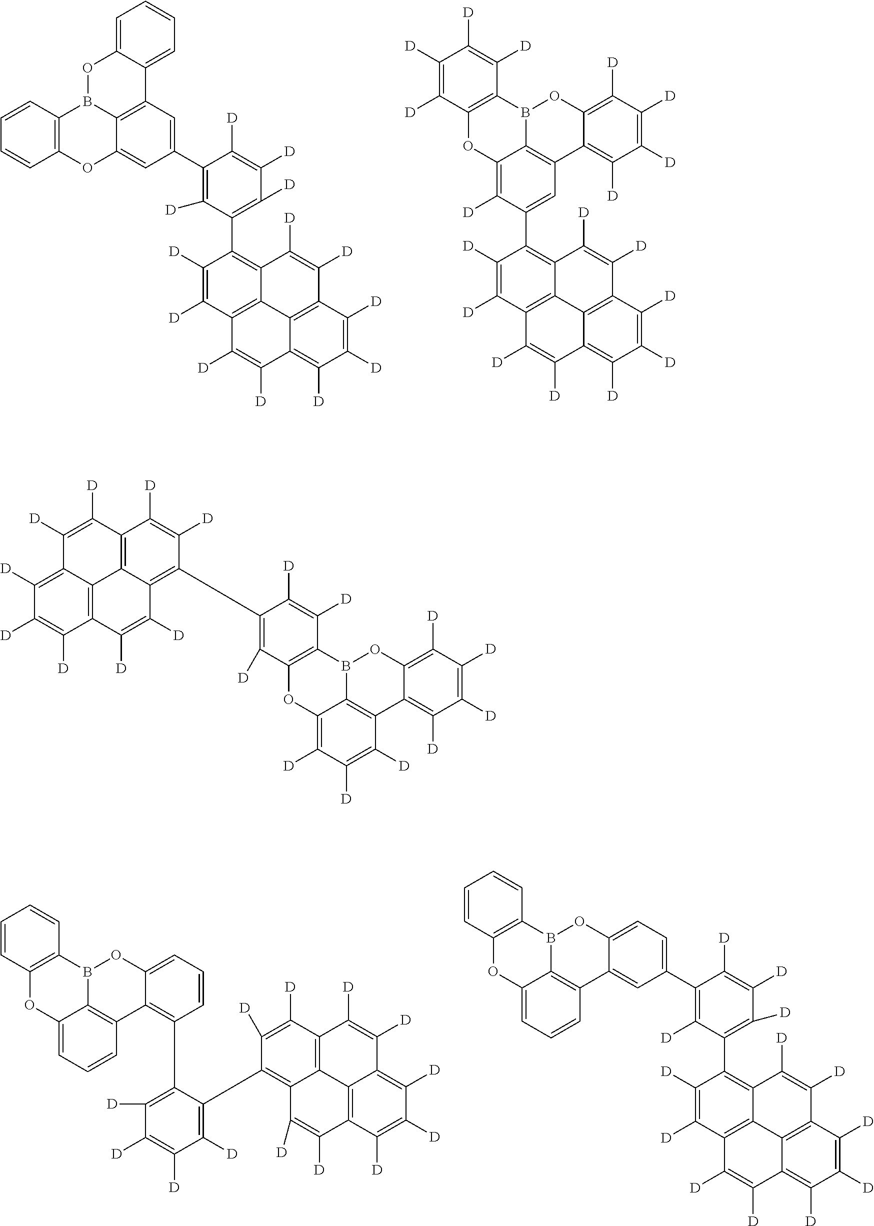

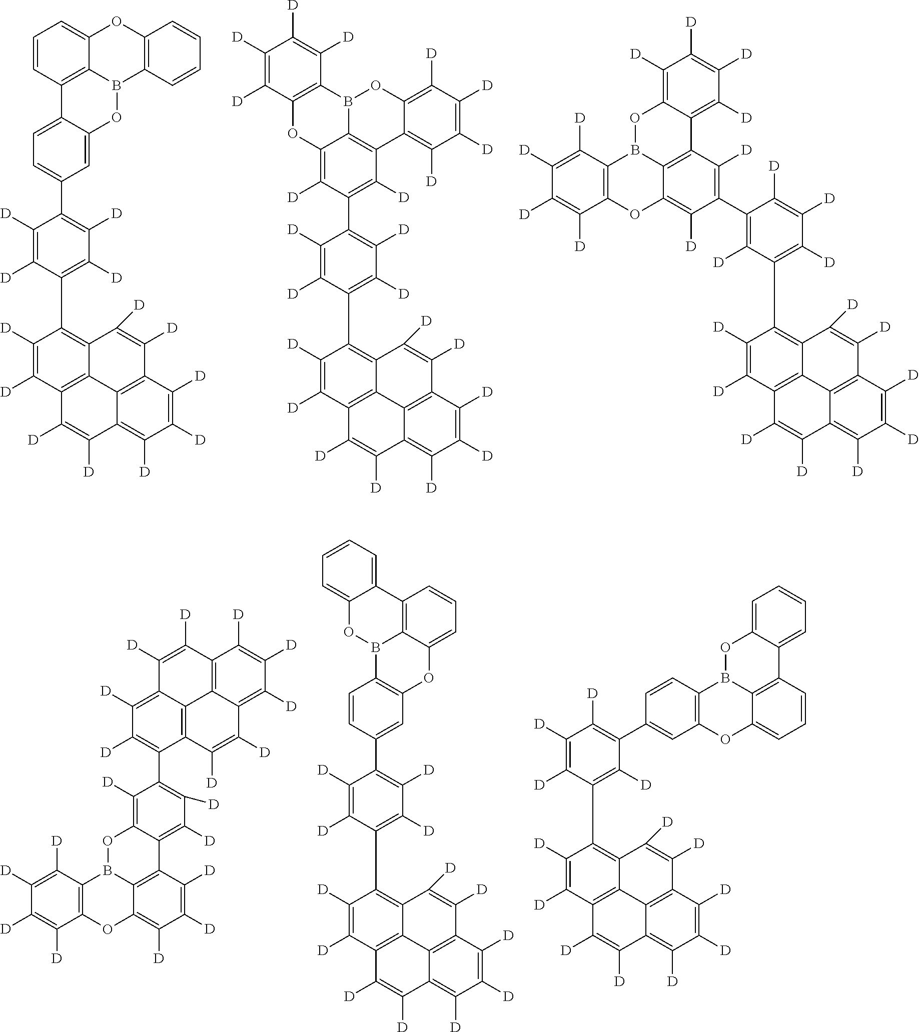

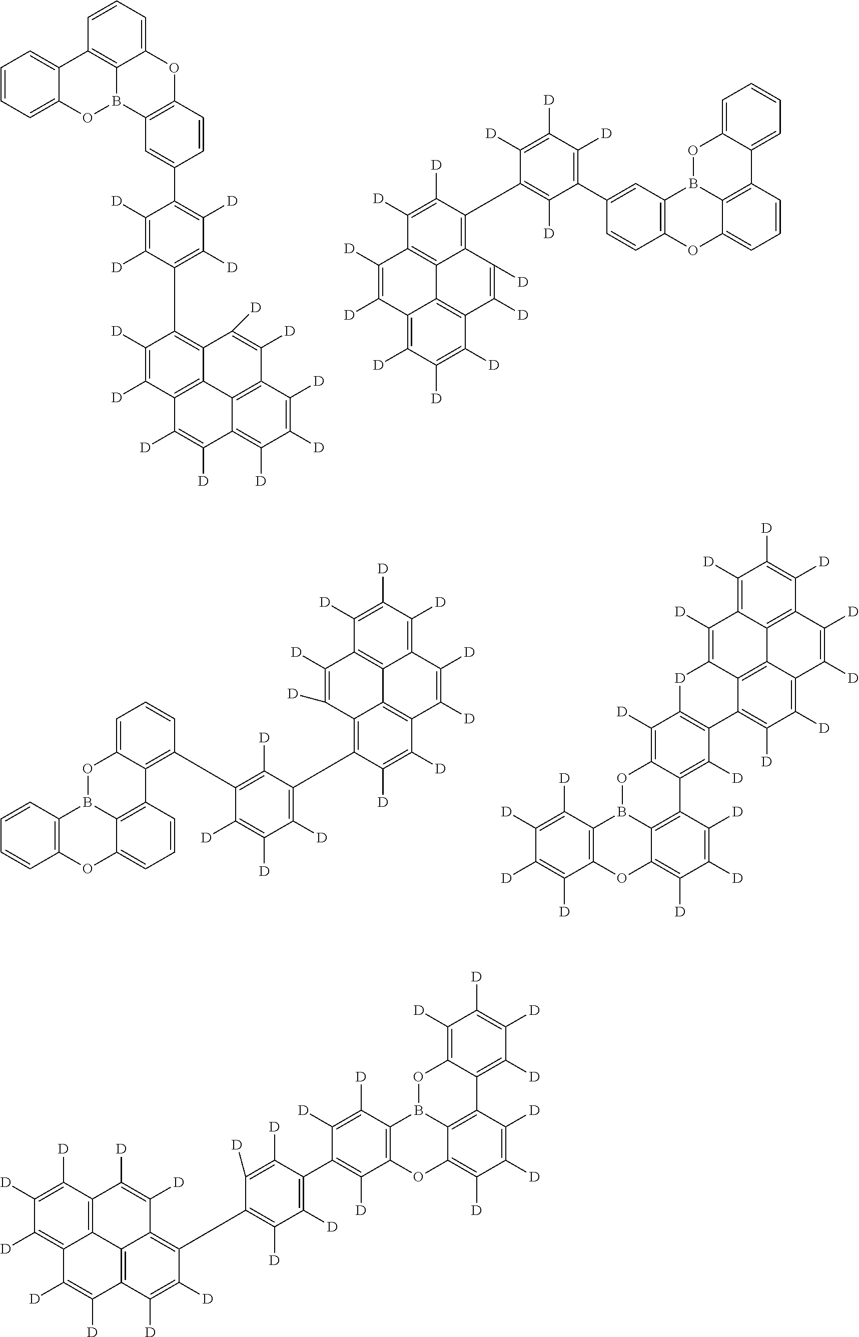

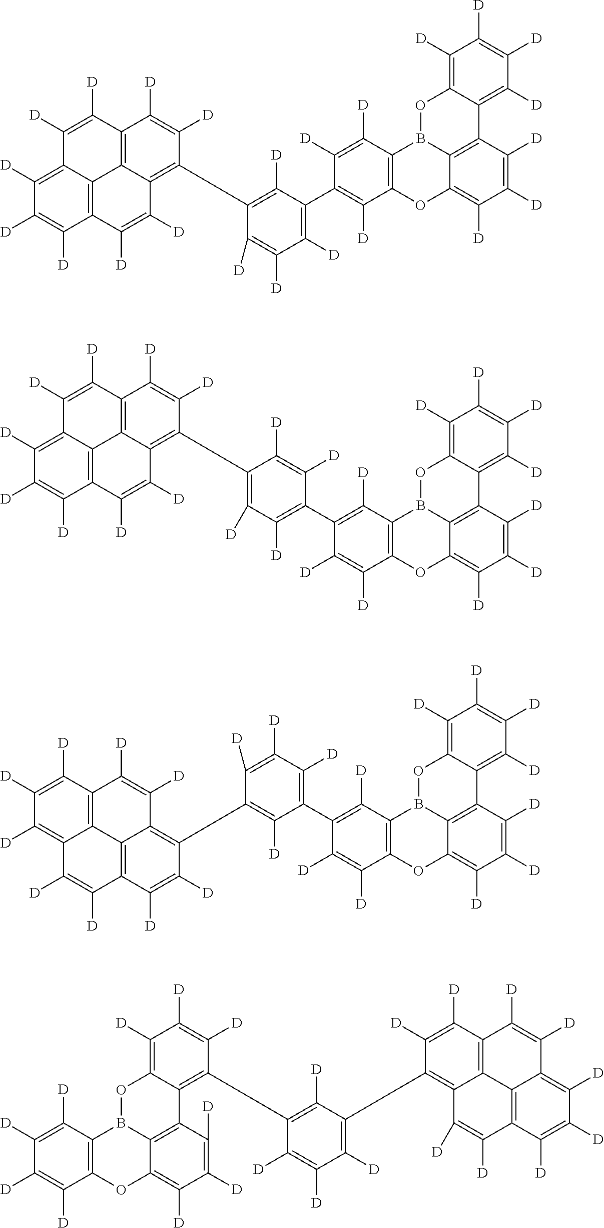

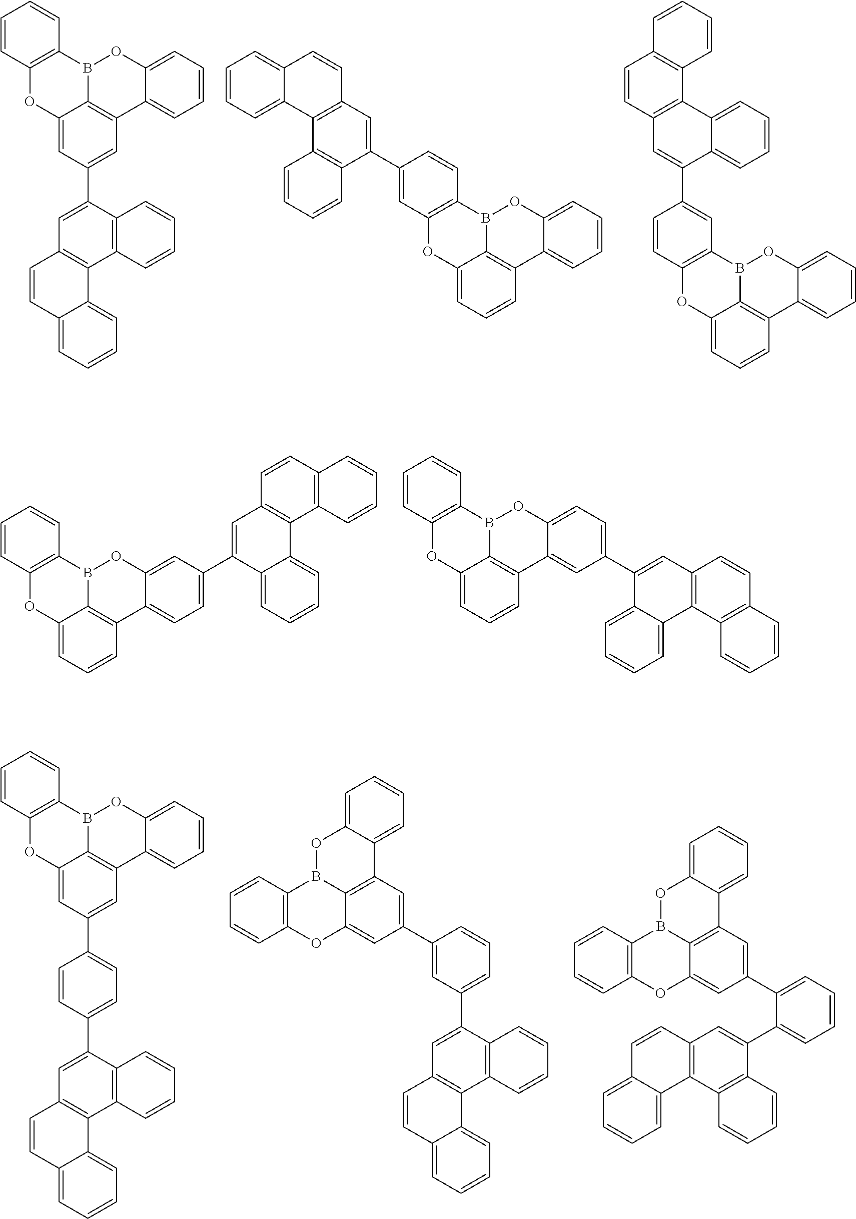

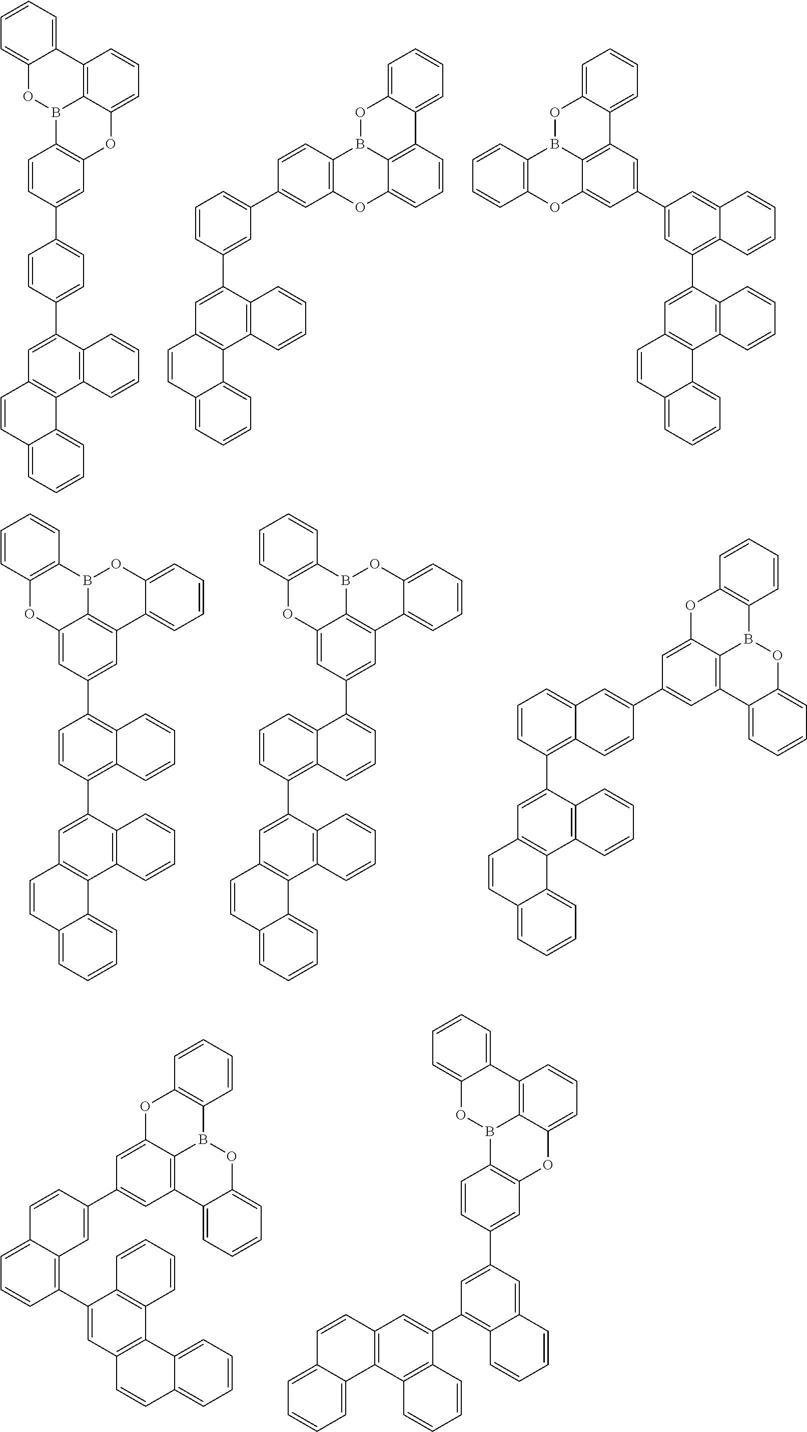

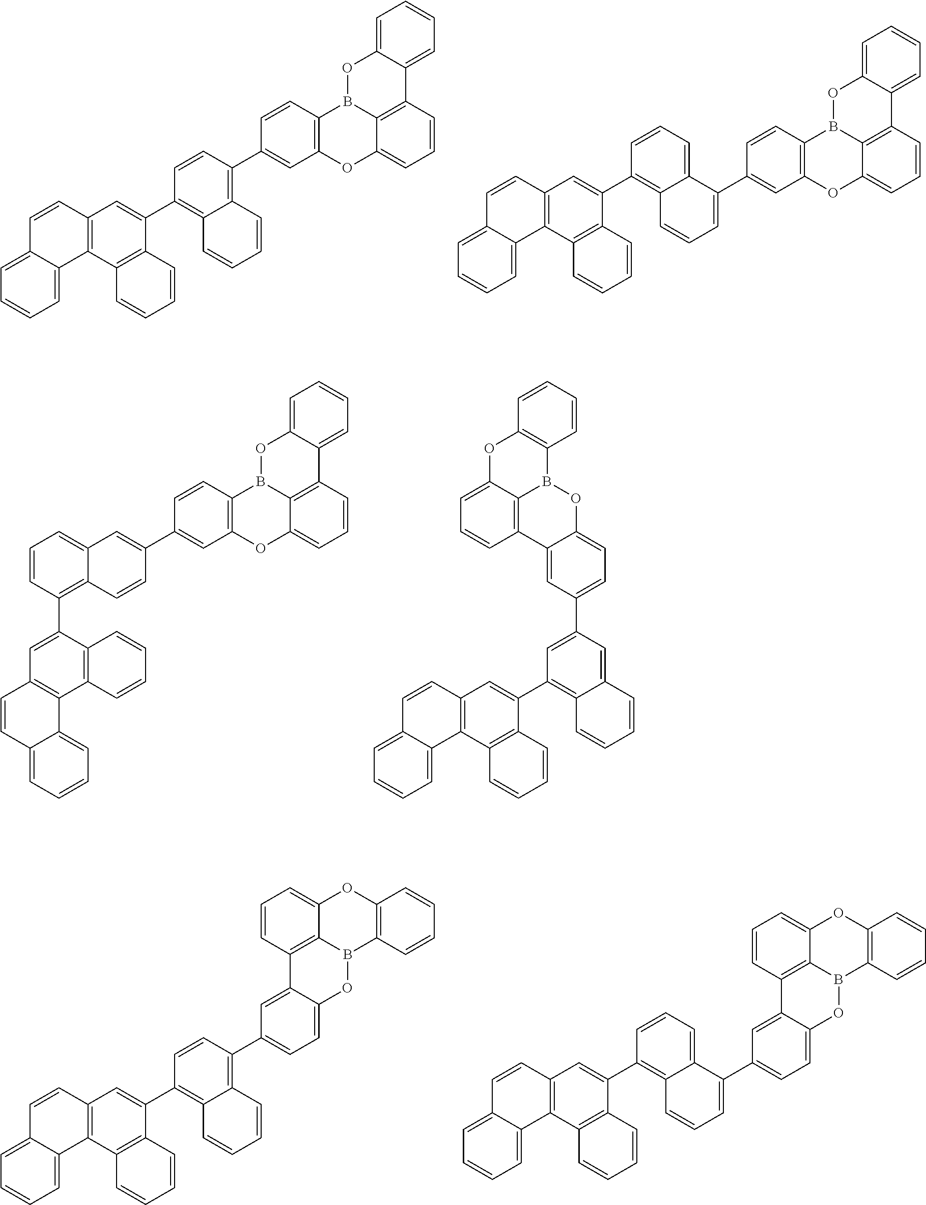 [SMILES: c1ccc2c(c1)OB1c3ccc(-c4ccc(-c5cc6ccc7ccccc7c6c6ccccc56)c5ccccc45)cc3Oc3cccc-2c31 ; c1ccc2c(c1)OB1c3ccc(-c4cccc5c(-c6cc7ccc8ccccc8c7c7ccccc67)cccc45)cc3Oc3cccc-2c31 ; c1ccc2c(c1)OB1c3ccc(-c4ccc5c(-c6cc7ccc8ccccc8c7c7ccccc67)cccc5c4)cc3Oc3cccc-2c31 ; c1ccc2c(c1)Oc1cccc3c1B2Oc1ccc(-c2cc(-c4cc5ccc6ccccc6c5c5ccccc45)c4ccccc4c2)cc1-3 ; c1ccc2c(c1)Oc1cccc3c1B2Oc1ccc(-c2ccc(-c4cc5ccc6ccccc6c5c5ccccc45)c4ccccc24)cc1-3 ; c1ccc2c(c1)Oc1cccc3c1B2Oc1ccc(-c2cccc4c(-c5cc6ccc7ccccc7c6c6ccccc56)cccc24)cc1-3]

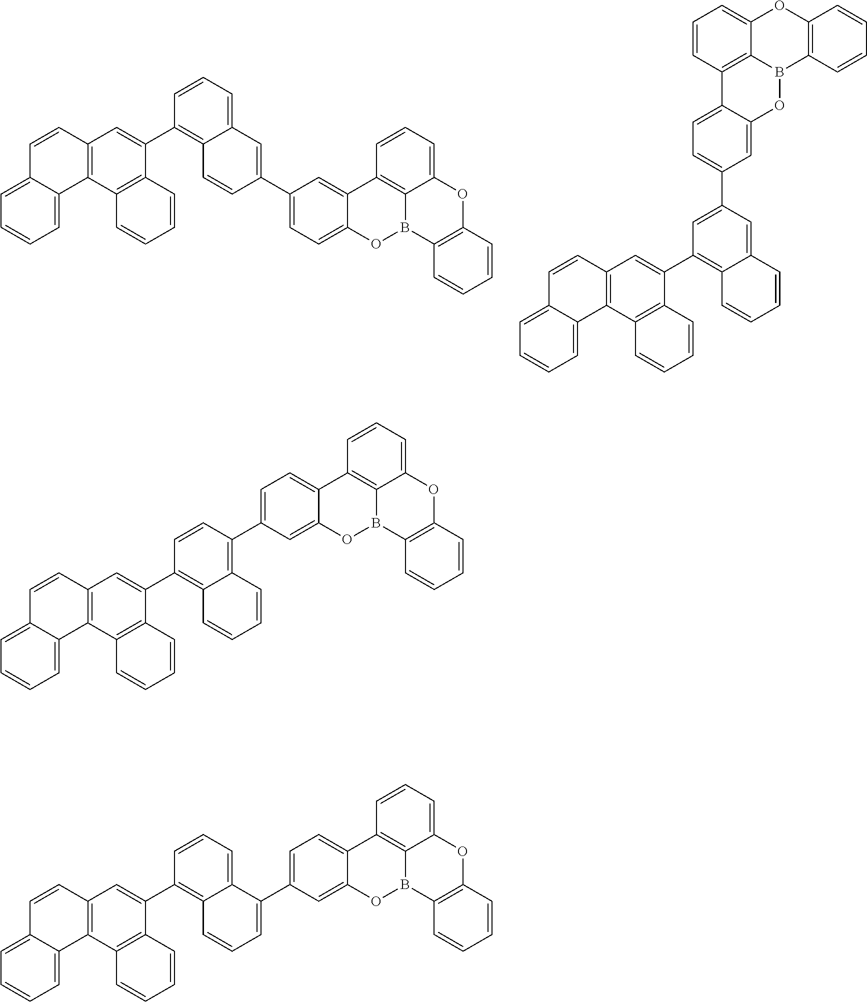 [SMILES: c1ccc2c(c1)Oc1cccc3c1B2Oc1ccc(-c2ccc4c(-c5cc6ccc7ccccc7c6c6ccccc56)cccc4c2)cc1-3 ; c1ccc2c(c1)Oc1cccc3c1B2Oc1cc(-c2cc(-c4cc5ccc6ccccc6c5c5ccccc45)c4ccccc4c2)ccc1-3 ; c1ccc2c(c1)Oc1cccc3c1B2Oc1cc(-c2ccc(-c4cc5ccc6ccccc6c5c5ccccc45)c4ccccc24)ccc1-3 ; c1ccc2c(c1)Oc1cccc3c1B2Oc1cc(-c2cccc4c(-c5cc6ccc7ccccc7c6c6ccccc56)cccc24)ccc1-3]

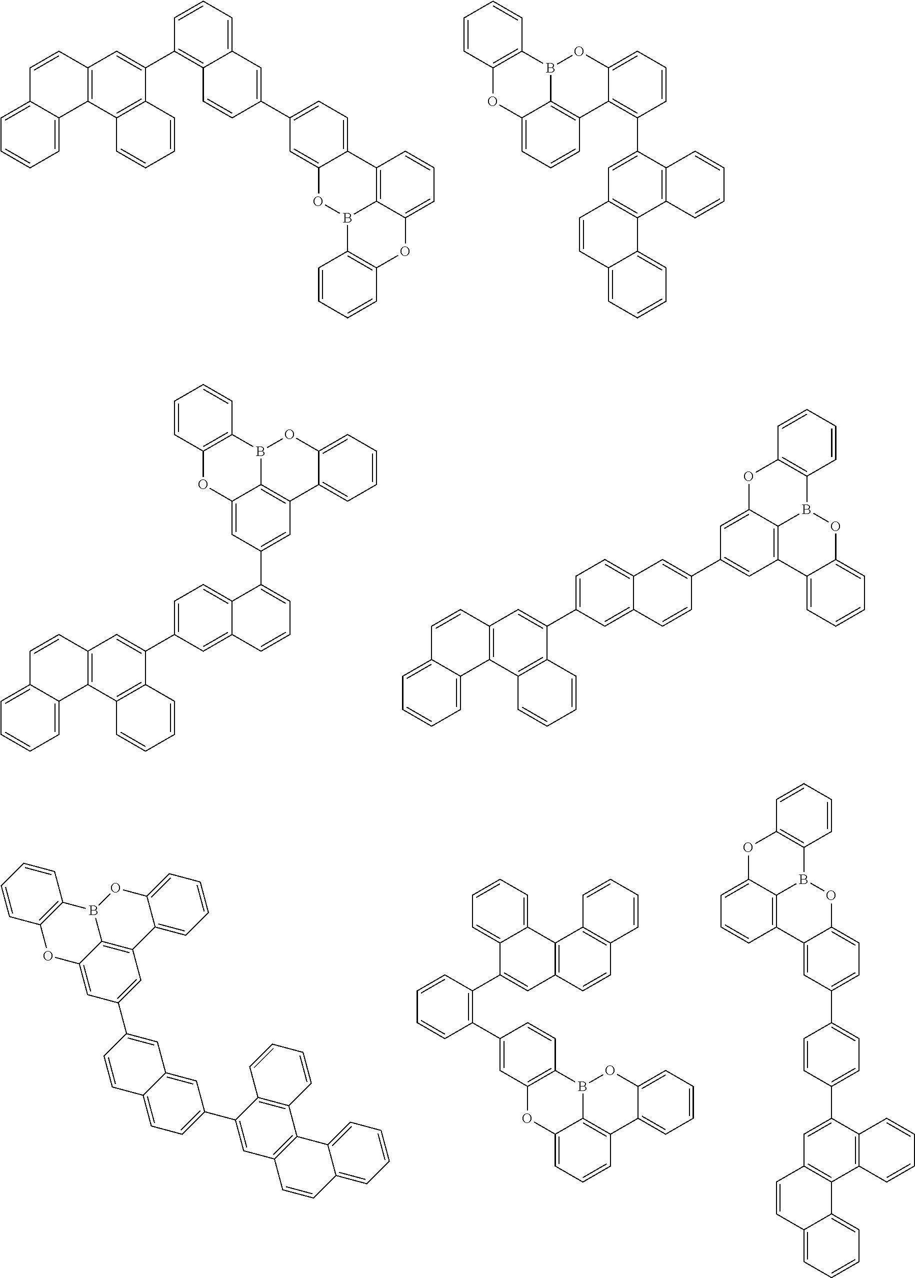

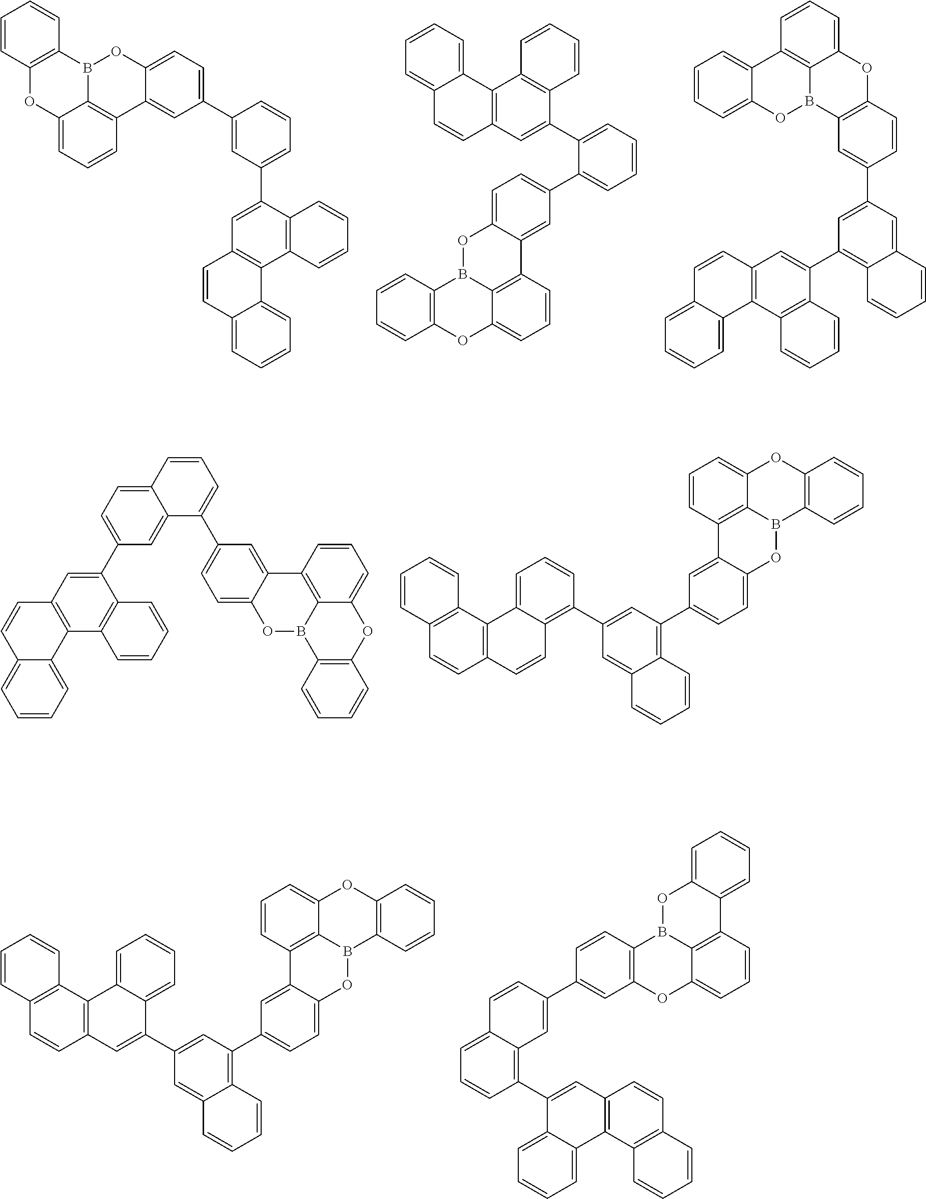

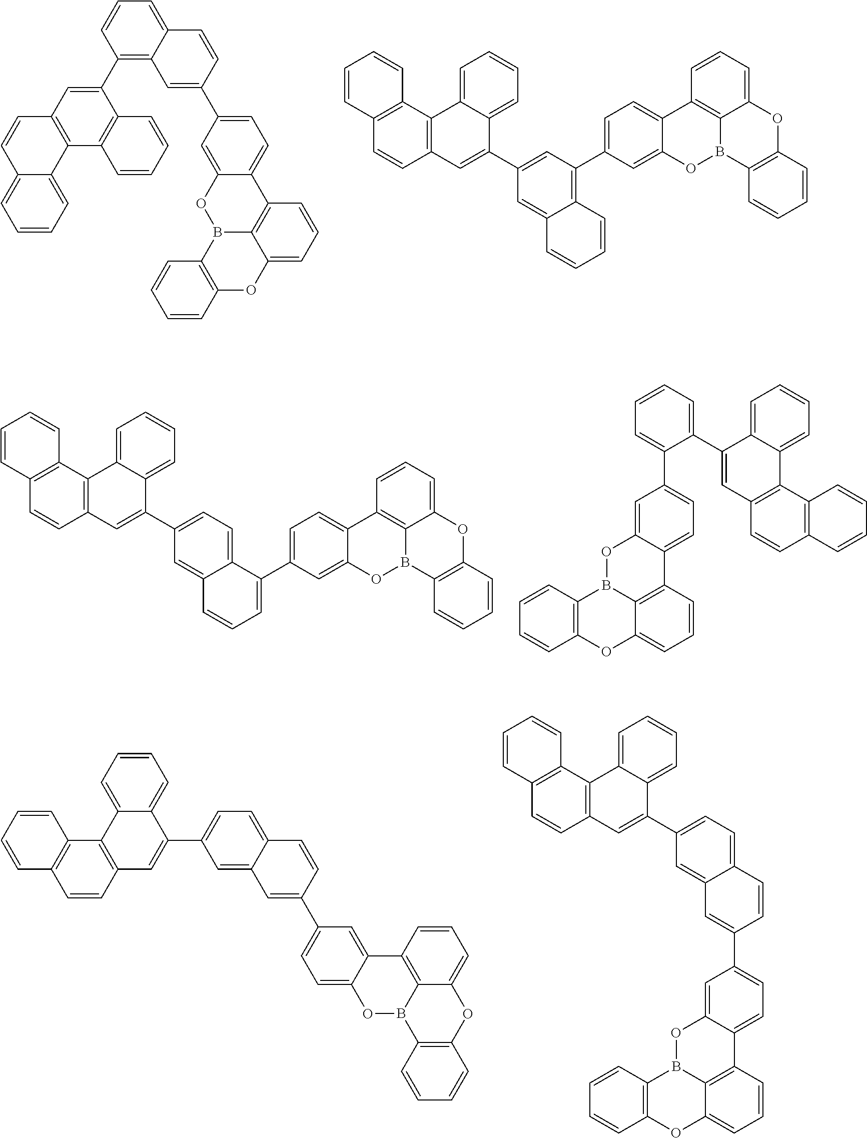

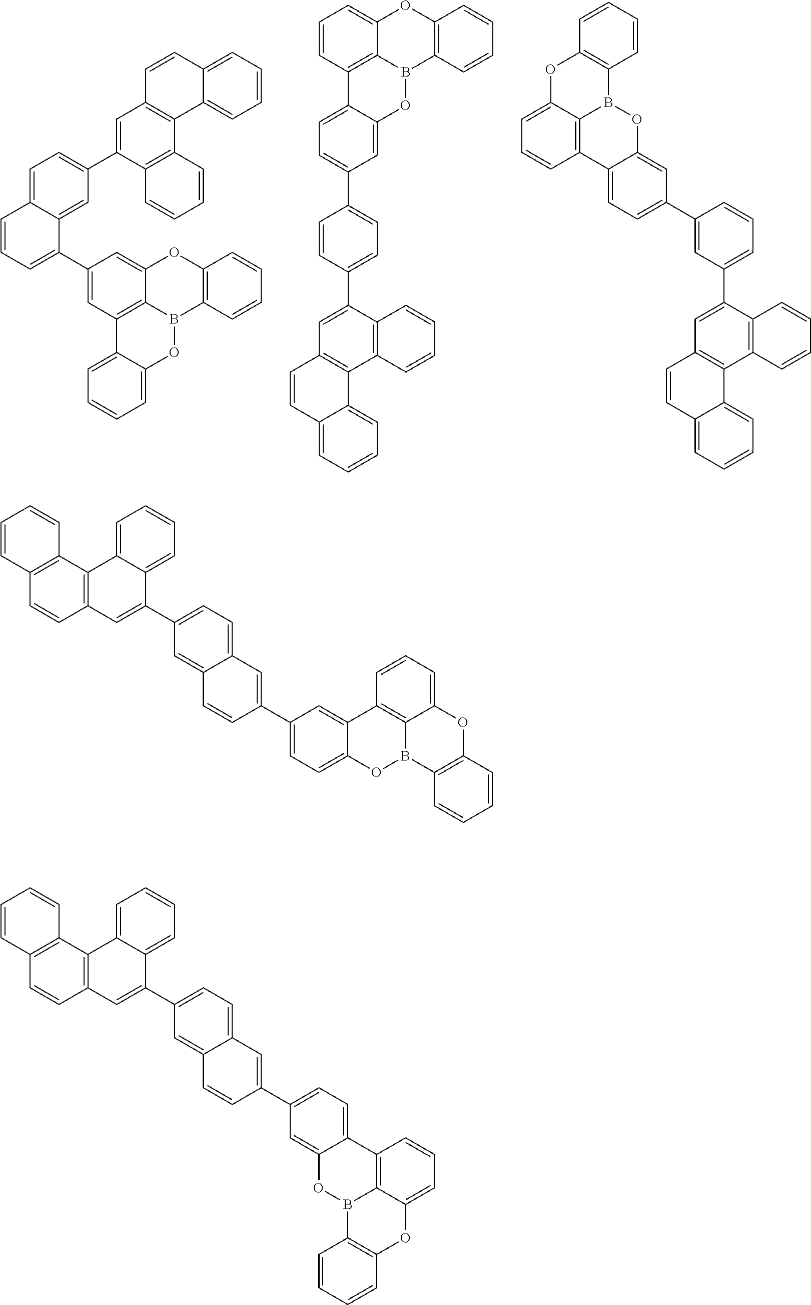 [SMILES: c1ccc2c(c1)Oc1cc(-c3cccc4ccc(-c5cc6ccc7ccccc7c6c6ccccc56)cc34)cc3c1B2Oc1ccccc1-3 ; c1ccc2c(c1)Oc1cccc3c1B2Oc1cc(-c2ccc(-c4cc5ccc6ccccc6c5c5ccccc45)cc2)ccc1-3 ; c1cc(-c2ccc3c(c2)OB2c4ccccc4Oc4cccc-3c42)cc(-c2cc3ccc4ccccc4c3c3ccccc23)c1 ; c1ccc2c(c1)Oc1cccc3c1B2Oc1ccc(-c2ccc4cc(-c5cc6ccc7ccccc7c6c6ccccc56)ccc4c2)cc1-3 ; c1ccc2c(c1)Oc1cccc3c1B2Oc1cc(-c2ccc4cc(-c5cc6ccc7ccccc7c6c6ccccc56)ccc4c2)ccc1-3]

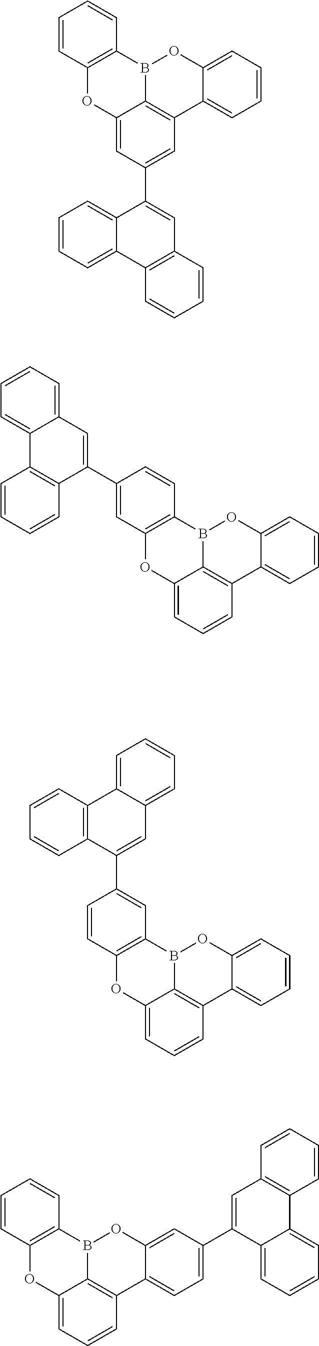 [SMILES: c1ccc2c(c1)Oc1cc(-c3cc4ccccc4c4ccccc34)cc3c1B2Oc1ccccc1-3 ; c1ccc2c(c1)OB1c3ccc(-c4cc5ccccc5c5ccccc45)cc3Oc3cccc-2c31 ; c1ccc2c(c1)OB1c3cc(-c4cc5ccccc5c5ccccc45)ccc3Oc3cccc-2c31 ; c1ccc2c(c1)Oc1cccc3c1B2Oc1cc(-c2cc4ccccc4c4ccccc24)ccc1-3]

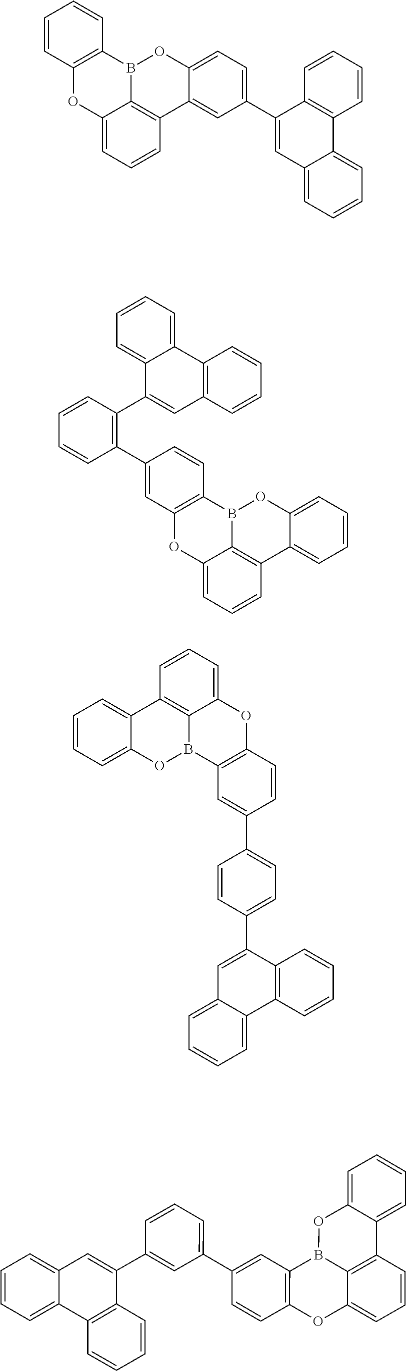 [SMILES: c1ccc2c(c1)Oc1cccc3c1B2Oc1ccc(-c2cc4ccccc4c4ccccc24)cc1-3 ; c1ccc2c(c1)OB1c3ccc(-c4ccccc4-c4cc5ccccc5c5ccccc45)cc3Oc3cccc-2c31 ; c1ccc2c(c1)OB1c3cc(-c4ccc(-c5cc6ccccc6c6ccccc56)cc4)ccc3Oc3cccc-2c31 ; c1cc(-c2ccc3c(c2)B2Oc4ccccc4-c4cccc(c42)O3)cc(-c2cc3ccccc3c3ccccc23)c1]

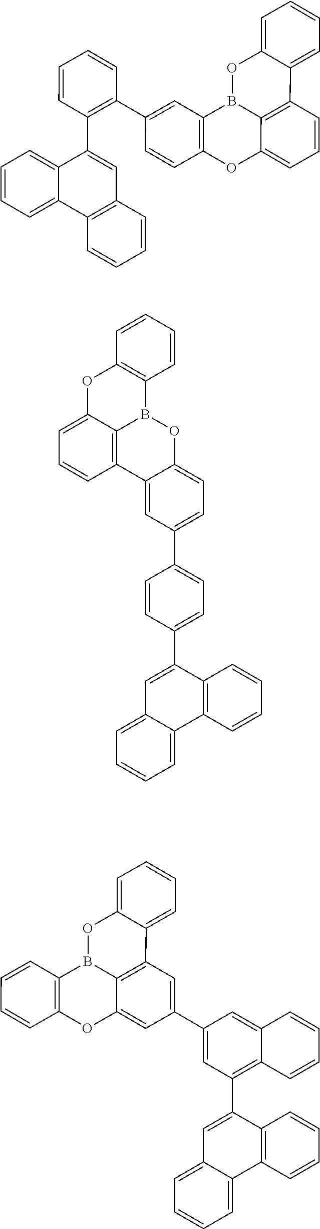 [SMILES: c1ccc2c(c1)OB1c3cc(-c4ccccc4-c4cc5ccccc5c5ccccc45)ccc3Oc3cccc-2c31 ; c1ccc2c(c1)Oc1cccc3c1B2Oc1ccc(-c2ccc(-c4cc5ccccc5c5ccccc45)cc2)cc1-3 ; c1ccc2c(c1)Oc1cc(-c3cc(-c4cc5ccccc5c5ccccc45)c4ccccc4c3)cc3c1B2Oc1ccccc1-3]

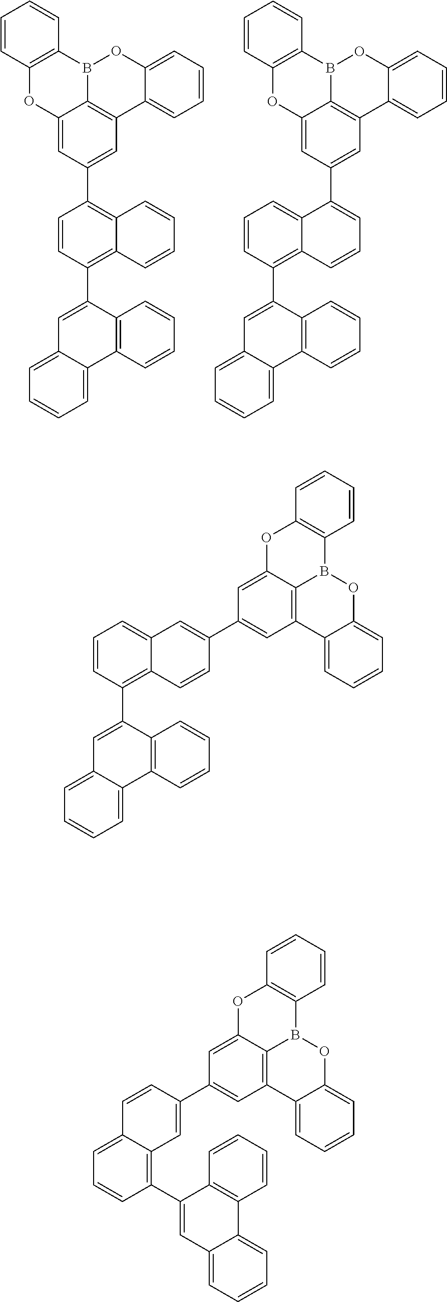

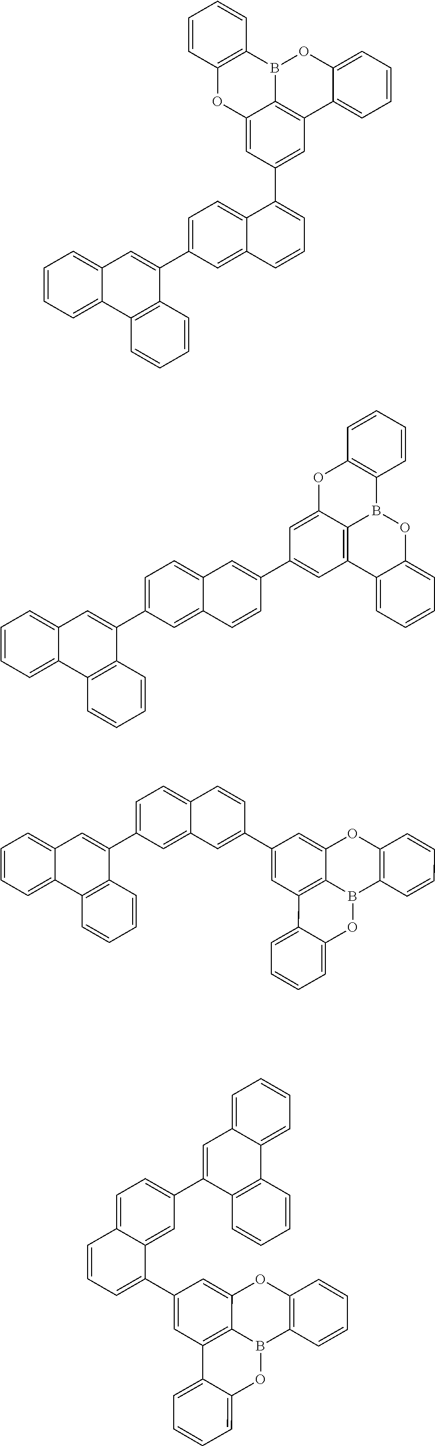 [SMILES: c1ccc2c(c1)Oc1cc(-c3cccc4cc(-c5cc6ccccc6c6ccccc56)ccc34)cc3c1B2Oc1ccccc1-3 ; c1ccc2c(c1)Oc1cc(-c3ccc4cc(-c5cc6ccccc6c6ccccc56)ccc4c3)cc3c1B2Oc1ccccc1-3 ; c1ccc2c(c1)Oc1cc(-c3ccc4ccc(-c5cc6ccccc6c6ccccc56)cc4c3)cc3c1B2Oc1ccccc1-3 ; c1ccc2c(c1)Oc1cc(-c3cccc4ccc(-c5cc6ccccc6c6ccccc56)cc34)cc3c1B2Oc1ccccc1-3]

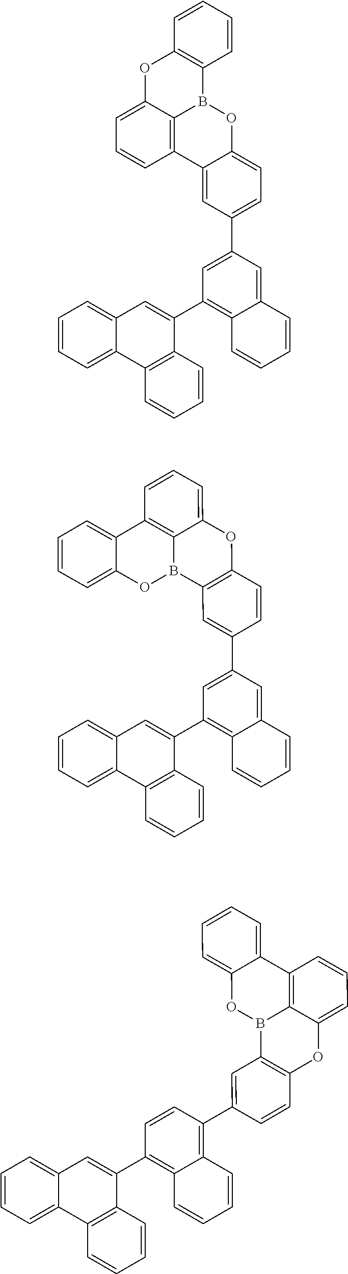 [SMILES: c1ccc2c(c1)Oc1cccc3c1B2Oc1ccc(-c2cc(-c4cc5ccccc5c5ccccc45)c4ccccc4c2)cc1-3 ; c1ccc2c(c1)OB1c3cc(-c4cc(-c5cc6ccccc6c6ccccc56)c5ccccc5c4)ccc3Oc3cccc-2c31 ; c1ccc2c(c1)OB1c3cc(-c4ccc(-c5cc6ccccc6c6ccccc56)c5ccccc45)ccc3Oc3cccc-2c31]

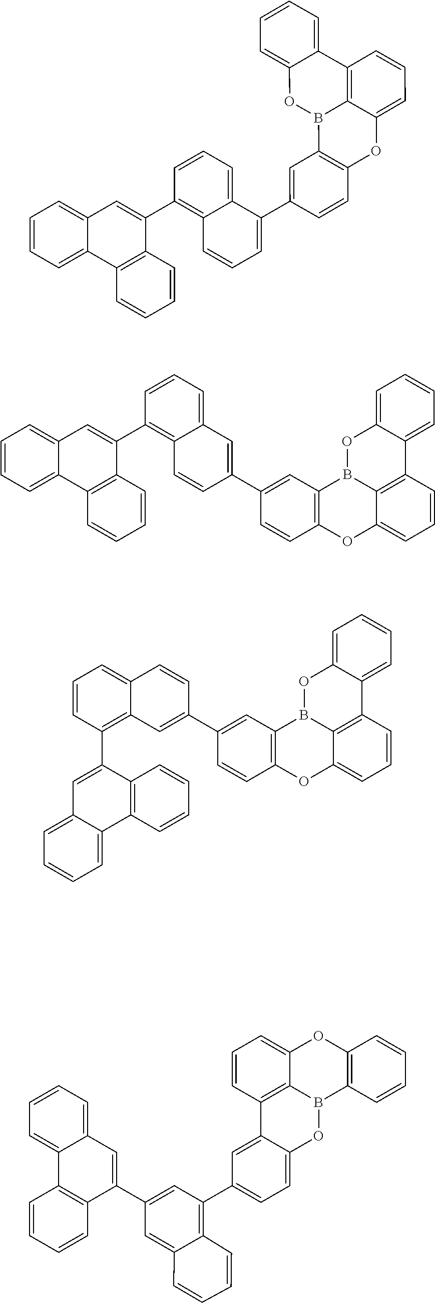 [SMILES: c1ccc2c(c1)OB1c3cc(-c4cccc5c(-c6cc7ccccc7c7ccccc67)cccc45)ccc3Oc3cccc-2c31 ; c1ccc2c(c1)OB1c3cc(-c4ccc5c(-c6cc7ccccc7c7ccccc67)cccc5c4)ccc3Oc3cccc-2c31 ; c1ccc2c(c1)OB1c3cc(-c4ccc5cccc(-c6cc7ccccc7c7ccccc67)c5c4)ccc3Oc3cccc-2c31 ; c1ccc2c(c1)Oc1cccc3c1B2Oc1ccc(-c2cc(-c4cc5ccccc5c5ccccc45)cc4ccccc24)cc1-3]

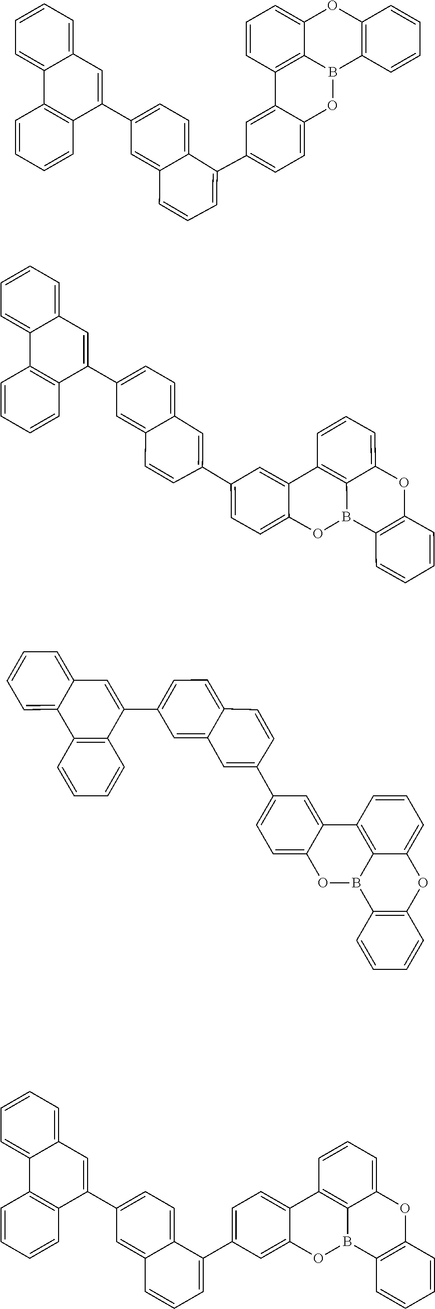 [SMILES: c1ccc2c(c1)Oc1cccc3c1B2Oc1ccc(-c2cccc4cc(-c5cc6ccccc6c6ccccc56)ccc24)cc1-3 ; c1ccc2c(c1)Oc1cccc3c1B2Oc1ccc(-c2ccc4cc(-c5cc6ccccc6c6ccccc56)ccc4c2)cc1-3 ; c1ccc2c(c1)Oc1cccc3c1B2Oc1ccc(-c2ccc4ccc(-c5cc6ccccc6c6ccccc56)cc4c2)cc1-3 ; c1ccc2c(c1)Oc1cccc3c1B2Oc1cc(-c2cccc4cc(-c5cc6ccccc6c6ccccc56)ccc24)ccc1-3]

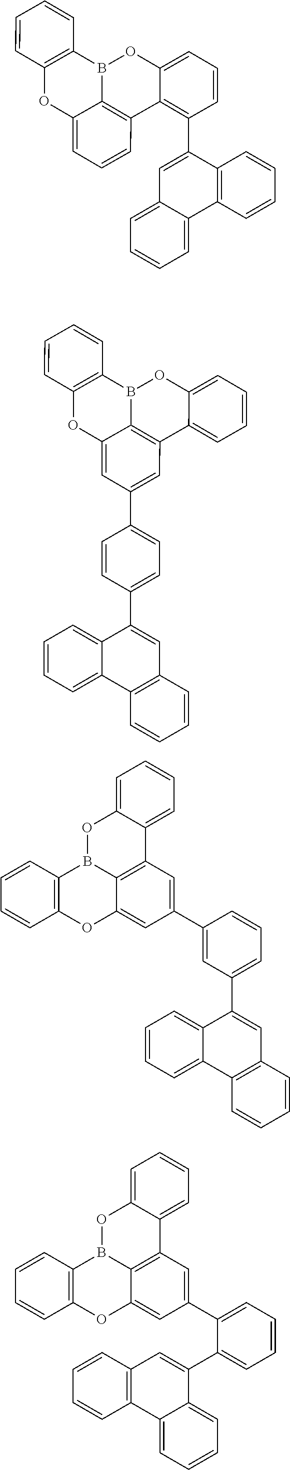

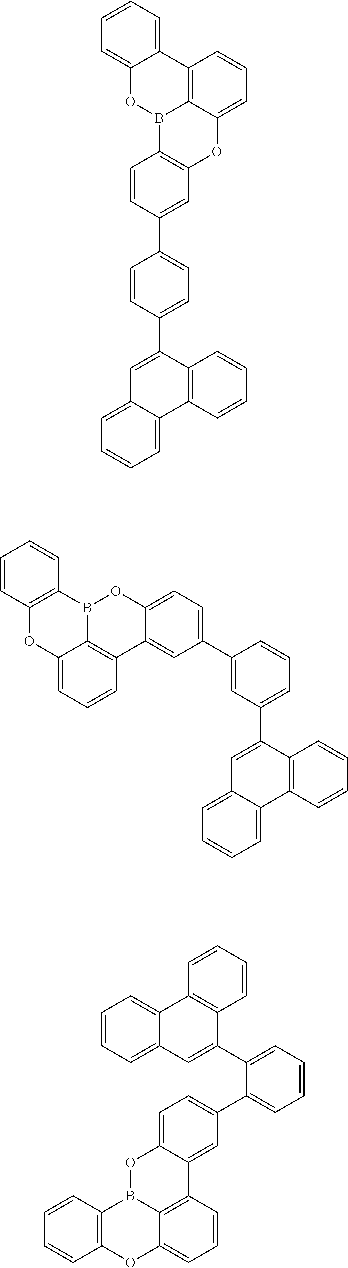 [SMILES: c1ccc2c(c1)OB1c3ccc(-c4ccc(-c5cc6ccccc6c6ccccc56)cc4)cc3Oc3cccc-2c31 ; c1cc(-c2ccc3c(c2)-c2cccc4c2B(O3)c2ccccc2O4)cc(-c2cc3ccccc3c3ccccc23)c1 ; c1ccc2c(c1)Oc1cccc3c1B2Oc1ccc(-c2ccccc2-c2cc4ccccc4c4ccccc24)cc1-3]

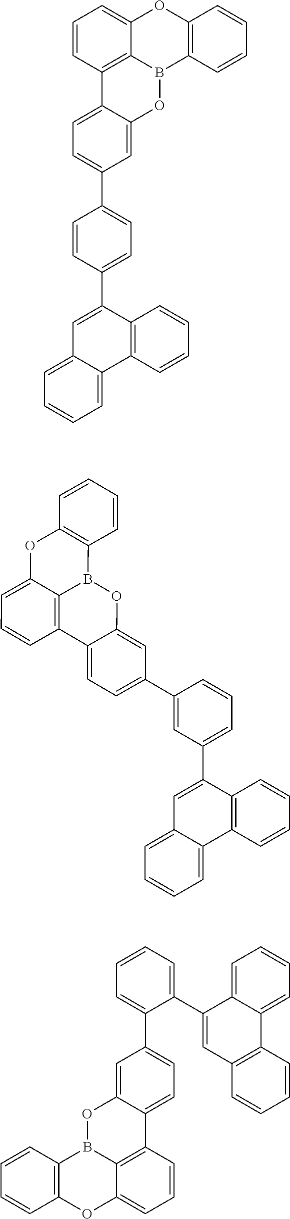 [SMILES: c1ccc2c(c1)Oc1cccc3c1B2Oc1cc(-c2ccc(-c4cc5ccccc5c5ccccc45)cc2)ccc1-3 ; c1cc(-c2ccc3c(c2)OB2c4ccccc4Oc4cccc-3c42)cc(-c2cc3ccccc3c3ccccc23)c1 ; c1ccc2c(c1)Oc1cccc3c1B2Oc1cc(-c2ccccc2-c2cc4ccccc4c4ccccc24)ccc1-3]

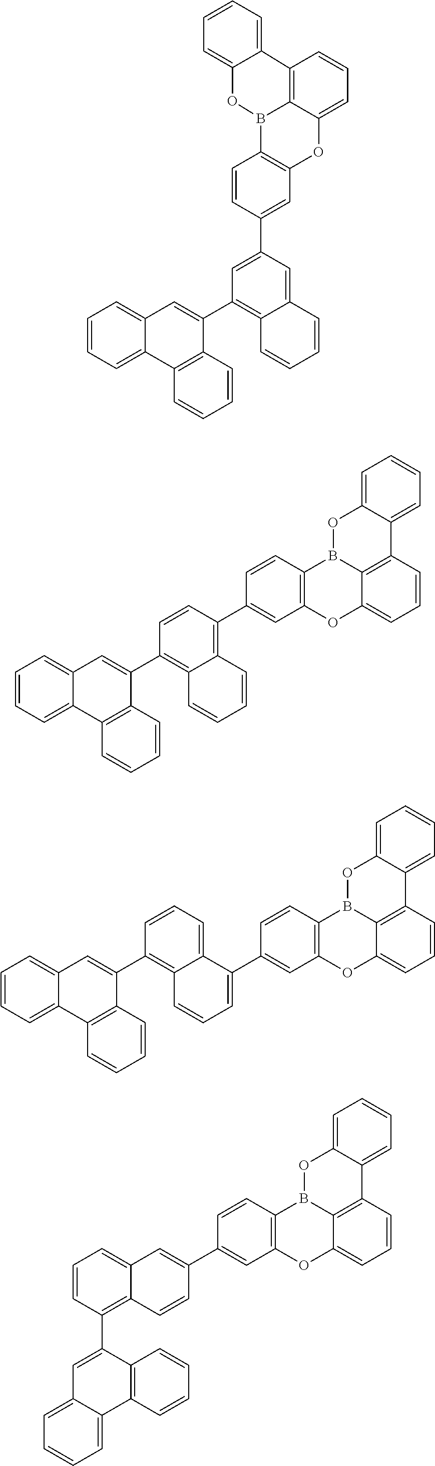 [SMILES: c1ccc2c(c1)OB1c3ccc(-c4cc(-c5cc6ccccc6c6ccccc56)c5ccccc5c4)cc3Oc3cccc-2c31 ; c1ccc2c(c1)OB1c3ccc(-c4ccc(-c5cc6ccccc6c6ccccc56)c5ccccc45)cc3Oc3cccc-2c31 ; c1ccc2c(c1)OB1c3ccc(-c4cccc5c(-c6cc7ccccc7c7ccccc67)cccc45)cc3Oc3cccc-2c31 ; c1ccc2c(c1)OB1c3ccc(-c4ccc5c(-c6cc7ccccc7c7ccccc67)cccc5c4)cc3Oc3cccc-2c31]

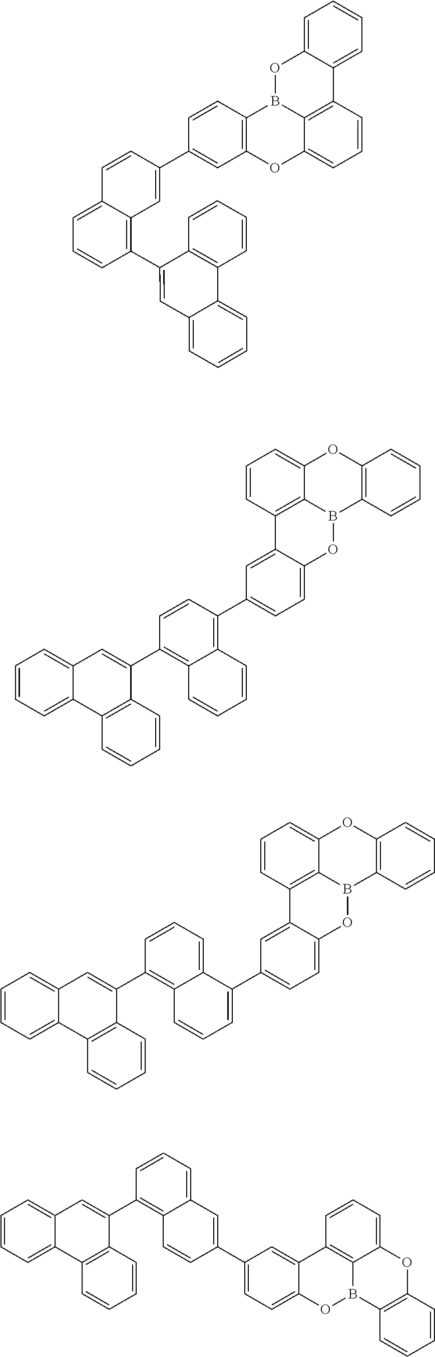

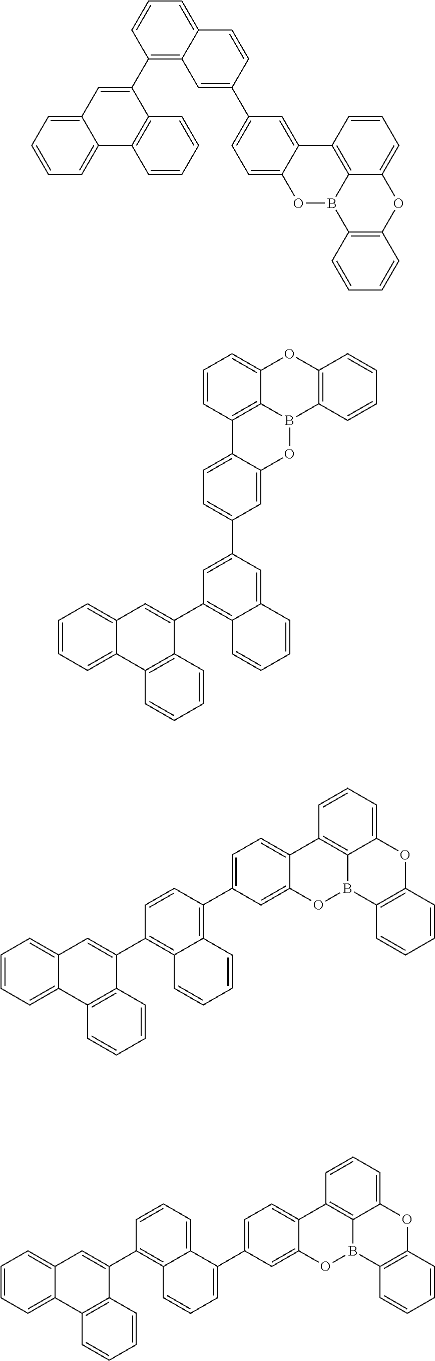 [SMILES: c1ccc2c(c1)Oc1cccc3c1B2Oc1ccc(-c2ccc4cccc(-c5cc6ccccc6c6ccccc56)c4c2)cc1-3 ; c1ccc2c(c1)Oc1cccc3c1B2Oc1cc(-c2cc(-c4cc5ccccc5c5ccccc45)c4ccccc4c2)ccc1-3 ; c1ccc2c(c1)Oc1cccc3c1B2Oc1cc(-c2ccc(-c4cc5ccccc5c5ccccc45)c4ccccc24)ccc1-3 ; c1ccc2c(c1)Oc1cccc3c1B2Oc1cc(-c2cccc4c(-c5cc6ccccc6c6ccccc56)cccc24)ccc1-3]

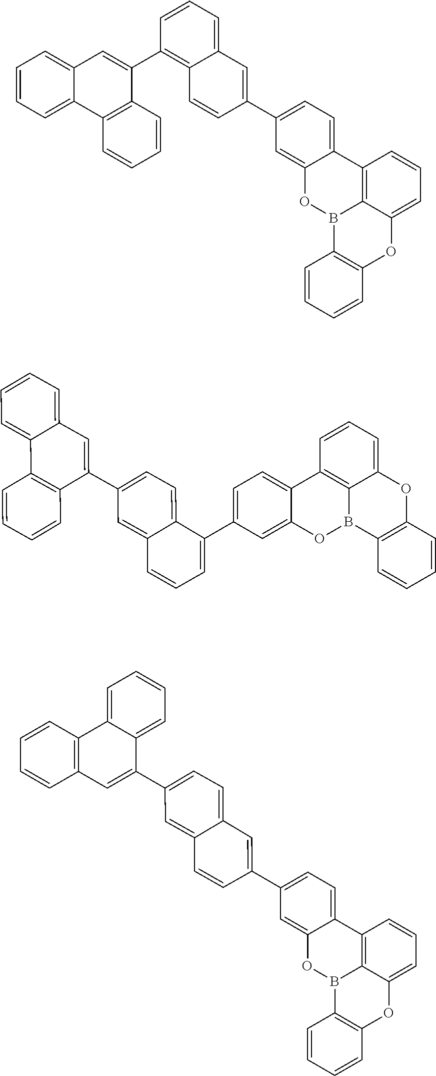 [SMILES: c1ccc2c(c1)Oc1cccc3c1B2Oc1cc(-c2ccc4c(-c5cc6ccccc6c6ccccc56)cccc4c2)ccc1-3 ; c1ccc2c(c1)Oc1cccc3c1B2Oc1cc(-c2cccc4cc(-c5cc6ccccc6c6ccccc56)ccc24)ccc1-3 ; c1ccc2c(c1)Oc1cccc3c1B2Oc1cc(-c2ccc4cc(-c5cc6ccccc6c6ccccc56)ccc4c2)ccc1-3]

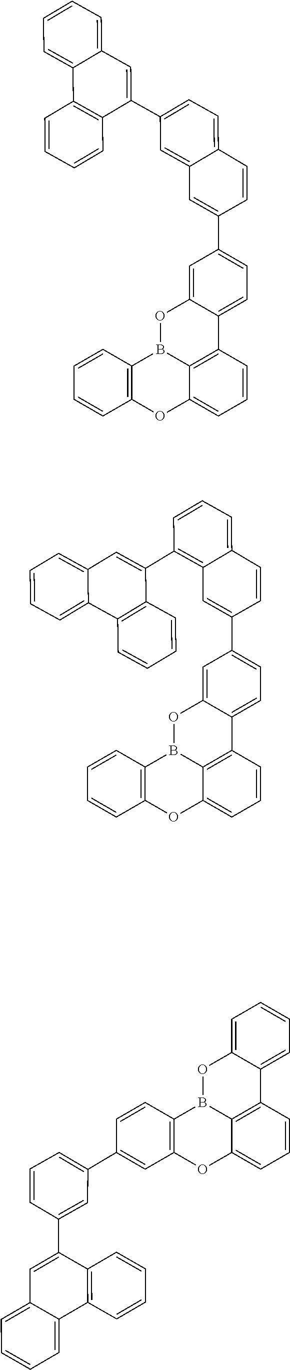 [SMILES: c1ccc2c(c1)Oc1cccc3c1B2Oc1cc(-c2ccc4ccc(-c5cc6ccccc6c6ccccc56)cc4c2)ccc1-3 ; c1ccc2c(c1)Oc1cccc3c1B2Oc1cc(-c2ccc4cccc(-c5cc6ccccc6c6ccccc56)c4c2)ccc1-3 ; c1cc(-c2ccc3c(c2)Oc2cccc4c2B3Oc2ccccc2-4)cc(-c2cc3ccccc3c3ccccc23)c1]

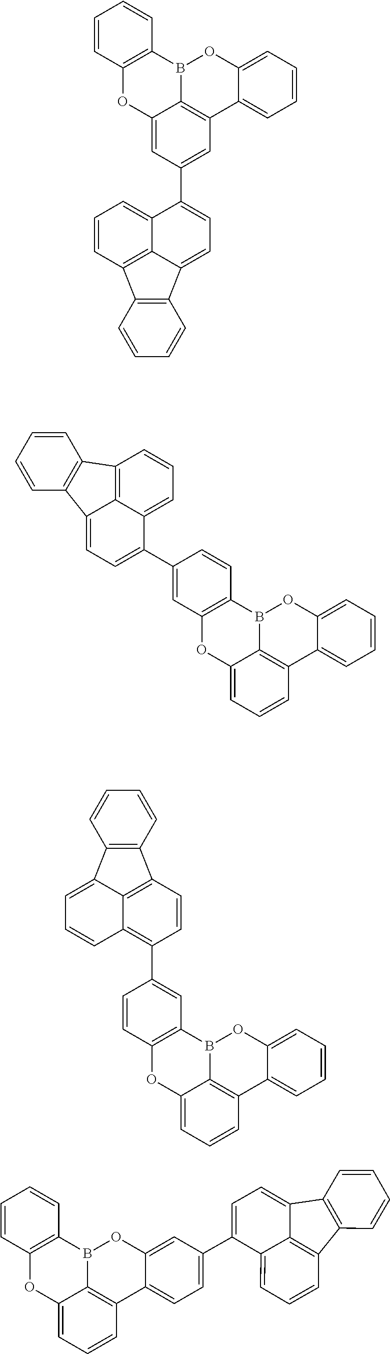 [SMILES: c1ccc2c(c1)Oc1cc(-c3ccc4c5c(cccc35)-c3ccccc3-4)cc3c1B2Oc1ccccc1-3 ; c1ccc2c(c1)OB1c3ccc(-c4ccc5c6c(cccc46)-c4ccccc4-5)cc3Oc3cccc-2c31 ; c1ccc2c(c1)OB1c3cc(-c4ccc5c6c(cccc46)-c4ccccc4-5)ccc3Oc3cccc-2c31 ; c1ccc2c(c1)Oc1cccc3c1B2Oc1cc(-c2ccc4c5c(cccc25)-c2ccccc2-4)ccc1-3]

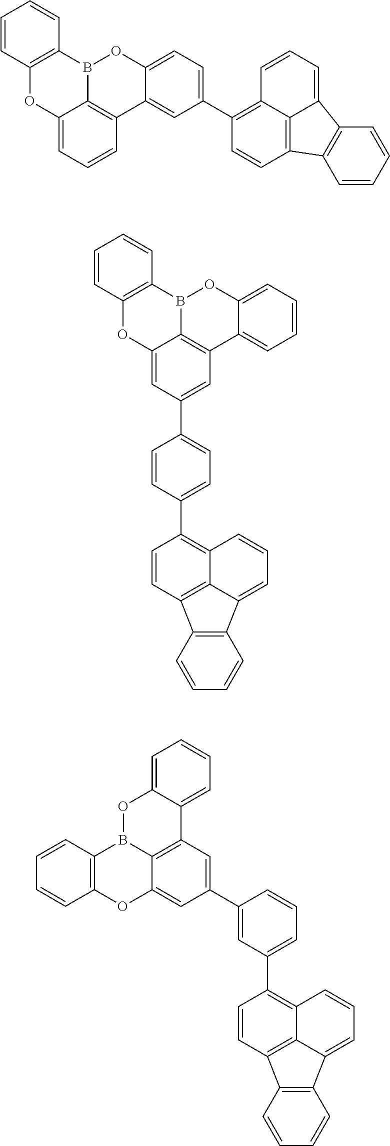 [SMILES: c1ccc2c(c1)Oc1cccc3c1B2Oc1ccc(-c2ccc4c5c(cccc25)-c2ccccc2-4)cc1-3 ; c1ccc2c(c1)Oc1cc(-c3ccc(-c4ccc5c6c(cccc46)-c4ccccc4-5)cc3)cc3c1B2Oc1ccccc1-3 ; c1cc(-c2cc3c4c(c2)-c2ccccc2OB4c2ccccc2O3)cc(-c2ccc3c4c(cccc24)-c2ccccc2-3)c1]

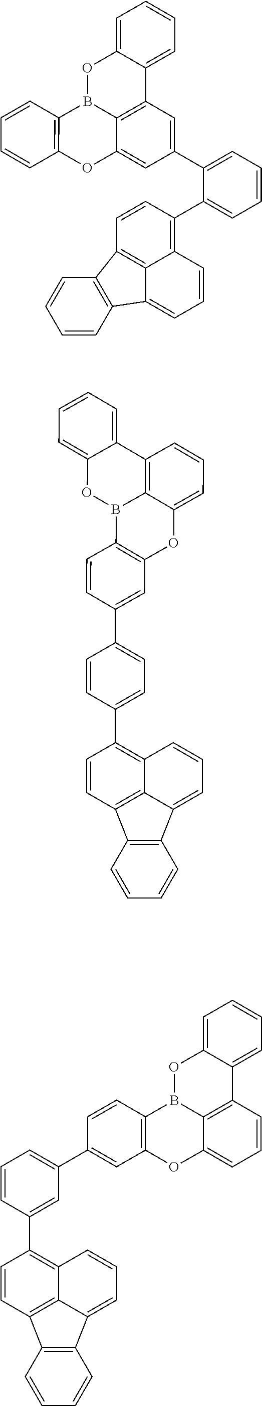 [SMILES: c1ccc2c(c1)Oc1cc(-c3ccccc3-c3ccc4c5c(cccc35)-c3ccccc3-4)cc3c1B2Oc1ccccc1-3 ; c1ccc2c(c1)OB1c3ccc(-c4ccc(-c5ccc6c7c(cccc57)-c5ccccc5-6)cc4)cc3Oc3cccc-2c31 ; c1cc(-c2ccc3c(c2)Oc2cccc4c2B3Oc2ccccc2-4)cc(-c2ccc3c4c(cccc24)-c2ccccc2-3)c1]

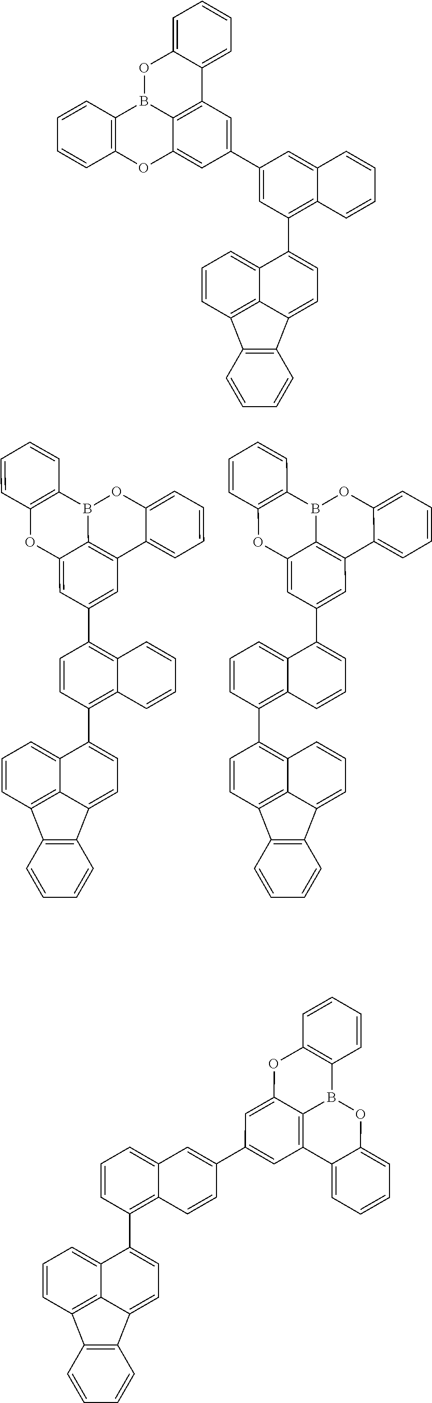

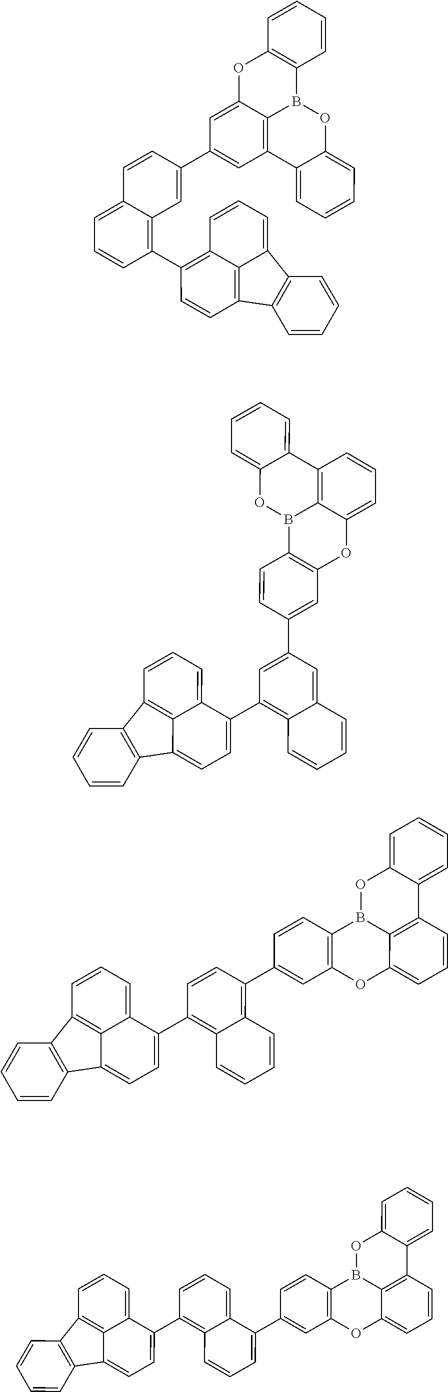 [SMILES: c1ccc2c(c1)Oc1cc(-c3ccc4cccc(-c5ccc6c7c(cccc57)-c5ccccc5-6)c4c3)cc3c1B2Oc1ccccc1-3 ; c1ccc2c(c1)OB1c3ccc(-c4cc(-c5ccc6c7c(cccc57)-c5ccccc5-6)c5ccccc5c4)cc3Oc3cccc-2c31 ; c1ccc2c(c1)OB1c3ccc(-c4ccc(-c5ccc6c7c(cccc57)-c5ccccc5-6)c5ccccc45)cc3Oc3cccc-2c31 ; c1ccc2c(c1)OB1c3ccc(-c4cccc5c(-c6ccc7c8c(cccc68)-c6ccccc6-7)cccc45)cc3Oc3cccc-2c31]

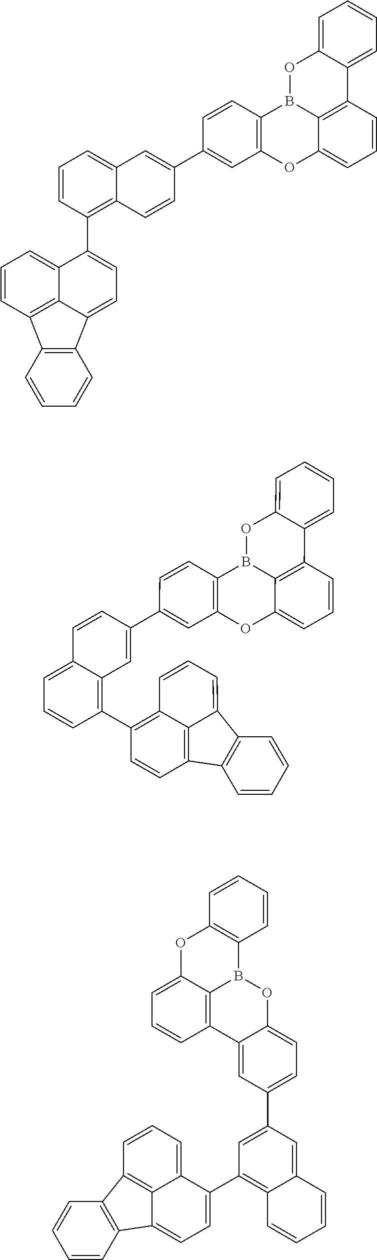 [SMILES: c1ccc2c(c1)OB1c3ccc(-c4ccc5c(-c6ccc7c8c(cccc68)-c6ccccc6-7)cccc5c4)cc3Oc3cccc-2c31 ; c1ccc2c(c1)OB1c3ccc(-c4ccc5cccc(-c6ccc7c8c(cccc68)-c6ccccc6-7)c5c4)cc3Oc3cccc-2c31 ; c1ccc2c(c1)Oc1cccc3c1B2Oc1ccc(-c2cc(-c4ccc5c6c(cccc46)-c4ccccc4-5)c4ccccc4c2)cc1-3]

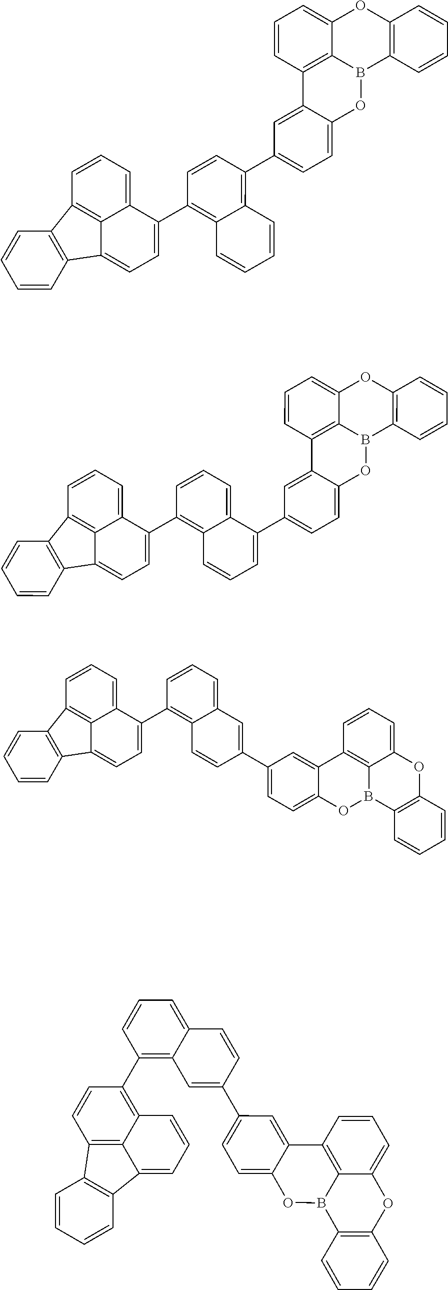 [SMILES: c1ccc2c(c1)Oc1cccc3c1B2Oc1ccc(-c2ccc(-c4ccc5c6c(cccc46)-c4ccccc4-5)c4ccccc24)cc1-3 ; c1ccc2c(c1)Oc1cccc3c1B2Oc1ccc(-c2cccc4c(-c5ccc6c7c(cccc57)-c5ccccc5-6)cccc24)cc1-3 ; c1ccc2c(c1)Oc1cccc3c1B2Oc1ccc(-c2ccc4c(-c5ccc6c7c(cccc57)-c5ccccc5-6)cccc4c2)cc1-3 ; c1ccc2c(c1)Oc1cccc3c1B2Oc1ccc(-c2ccc4cccc(-c5ccc6c7c(cccc57)-c5ccccc5-6)c4c2)cc1-3]

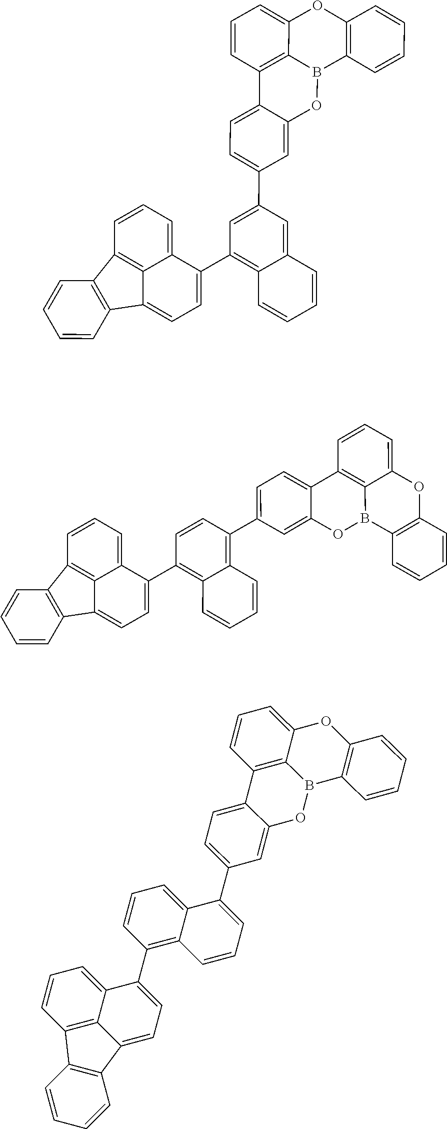 [SMILES: c1ccc2c(c1)Oc1cccc3c1B2Oc1cc(-c2cc(-c4ccc5c6c(cccc46)-c4ccccc4-5)c4ccccc4c2)ccc1-3 ; c1ccc2c(c1)Oc1cccc3c1B2Oc1cc(-c2ccc(-c4ccc5c6c(cccc46)-c4ccccc4-5)c4ccccc24)ccc1-3 ; c1ccc2c(c1)Oc1cccc3c1B2Oc1cc(-c2cccc4c(-c5ccc6c7c(cccc57)-c5ccccc5-6)cccc24)ccc1-3]

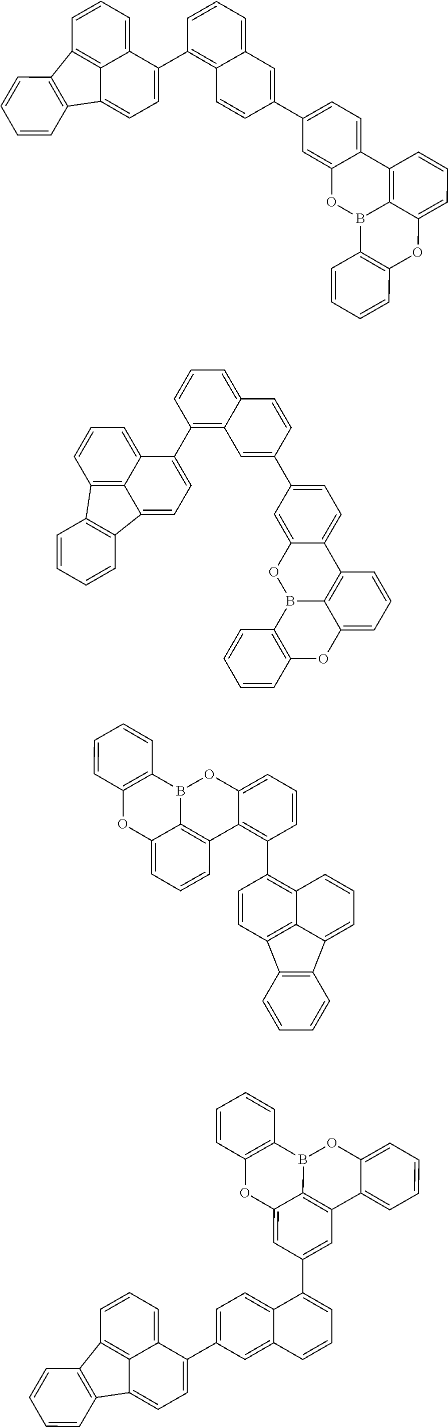 [SMILES: c1ccc2c(c1)Oc1cccc3c1B2Oc1cc(-c2ccc4c(-c5ccc6c7c(cccc57)-c5ccccc5-6)cccc4c2)ccc1-3 ; c1ccc2c(c1)Oc1cccc3c1B2Oc1cc(-c2ccc4cccc(-c5ccc6c7c(cccc57)-c5ccccc5-6)c4c2)ccc1-3 ; c1ccc2c(c1)Oc1cccc3c1B2Oc1cccc(-c2ccc4c5c(cccc25)-c2ccccc2-4)c1-3 ; c1ccc2c(c1)Oc1cc(-c3cccc4cc(-c5ccc6c7c(cccc57)-c5ccccc5-6)ccc34)cc3c1B2Oc1ccccc1-3]

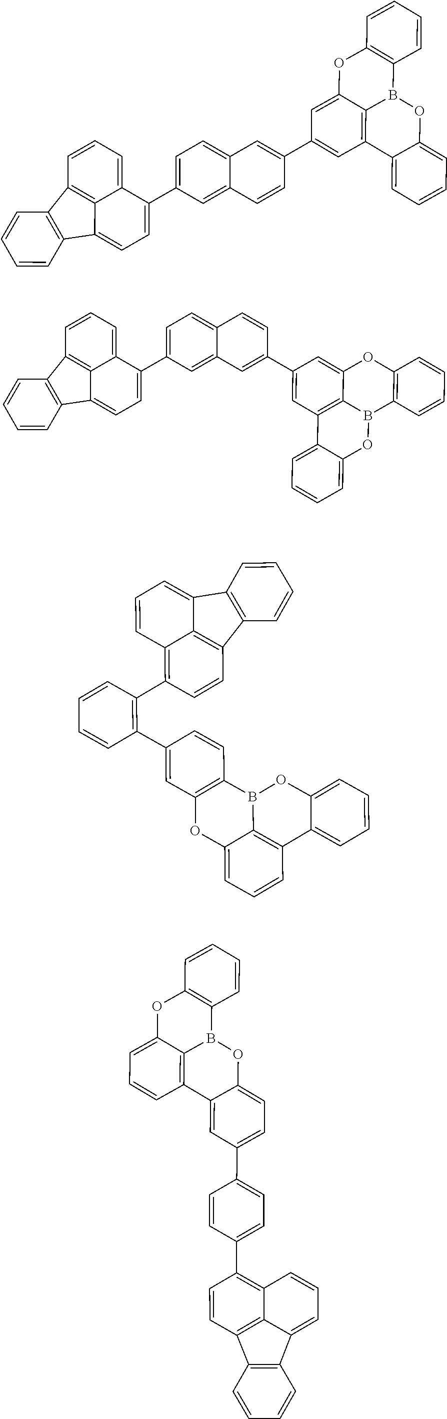 [SMILES: c1ccc2c(c1)Oc1cc(-c3ccc4cc(-c5ccc6c7c(cccc57)-c5ccccc5-6)ccc4c3)cc3c1B2Oc1ccccc1-3 ; c1ccc2c(c1)Oc1cc(-c3ccc4ccc(-c5ccc6c7c(cccc57)-c5ccccc5-6)cc4c3)cc3c1B2Oc1ccccc1-3 ; c1ccc2c(c1)OB1c3ccc(-c4ccccc4-c4ccc5c6c(cccc46)-c4ccccc4-5)cc3Oc3cccc-2c31 ; c1ccc2c(c1)Oc1cccc3c1B2Oc1ccc(-c2ccc(-c4ccc5c6c(cccc46)-c4ccccc4-5)cc2)cc1-3]

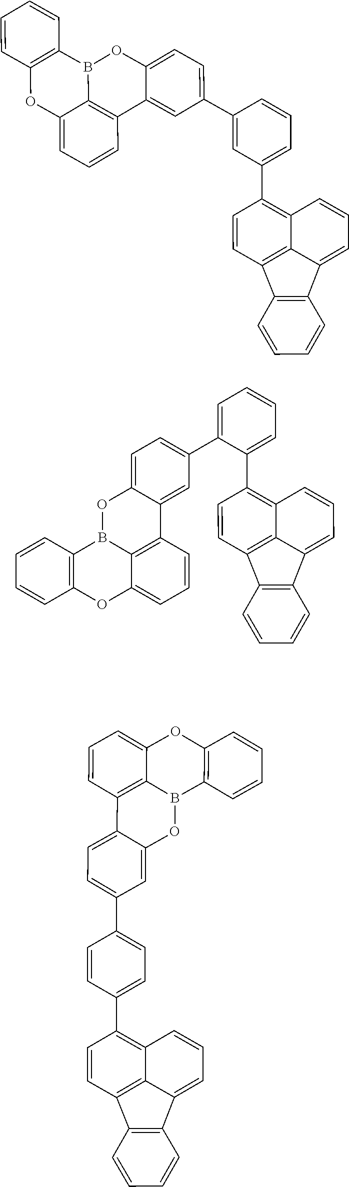

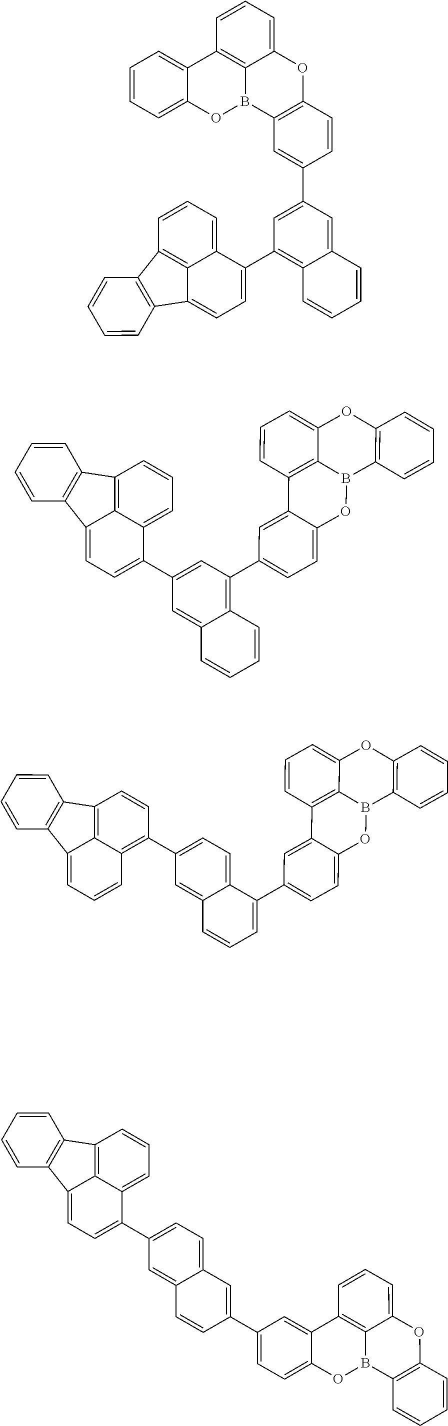 [SMILES: c1ccc2c(c1)OB1c3cc(-c4cc(-c5ccc6c7c(cccc57)-c5ccccc5-6)c5ccccc5c4)ccc3Oc3cccc-2c31 ; c1ccc2c(c1)Oc1cccc3c1B2Oc1ccc(-c2cc(-c4ccc5c6c(cccc46)-c4ccccc4-5)cc4ccccc24)cc1-3 ; c1ccc2c(c1)Oc1cccc3c1B2Oc1ccc(-c2cccc4cc(-c5ccc6c7c(cccc57)-c5ccccc5-6)ccc24)cc1-3 ; c1ccc2c(c1)Oc1cccc3c1B2Oc1ccc(-c2ccc4cc(-c5ccc6c7c(cccc57)-c5ccccc5-6)ccc4c2)cc1-3]

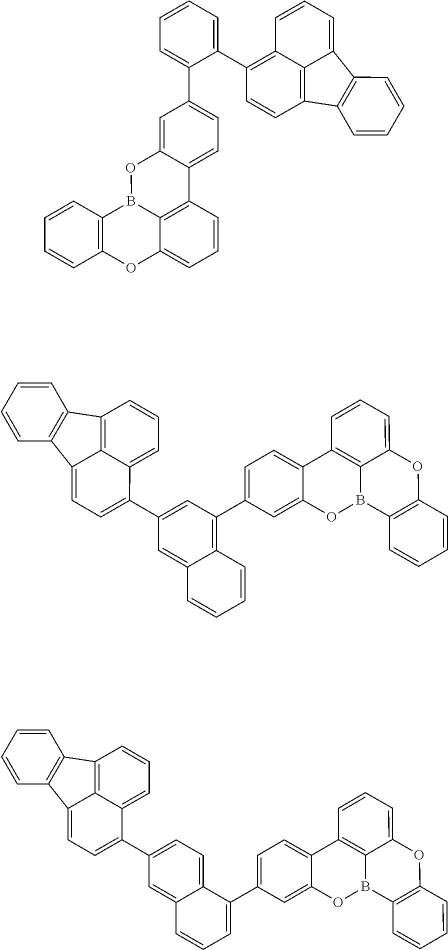 [SMILES: c1ccc2c(c1)Oc1cccc3c1B2Oc1cc(-c2ccccc2-c2ccc4c5c(cccc25)-c2ccccc2-4)ccc1-3 ; c1ccc2c(c1)Oc1cccc3c1B2Oc1cc(-c2cc(-c4ccc5c6c(cccc46)-c4ccccc4-5)cc4ccccc24)ccc1-3 ; c1ccc2c(c1)Oc1cccc3c1B2Oc1cc(-c2cccc4cc(-c5ccc6c7c(cccc57)-c5ccccc5-6)ccc24)ccc1-3]

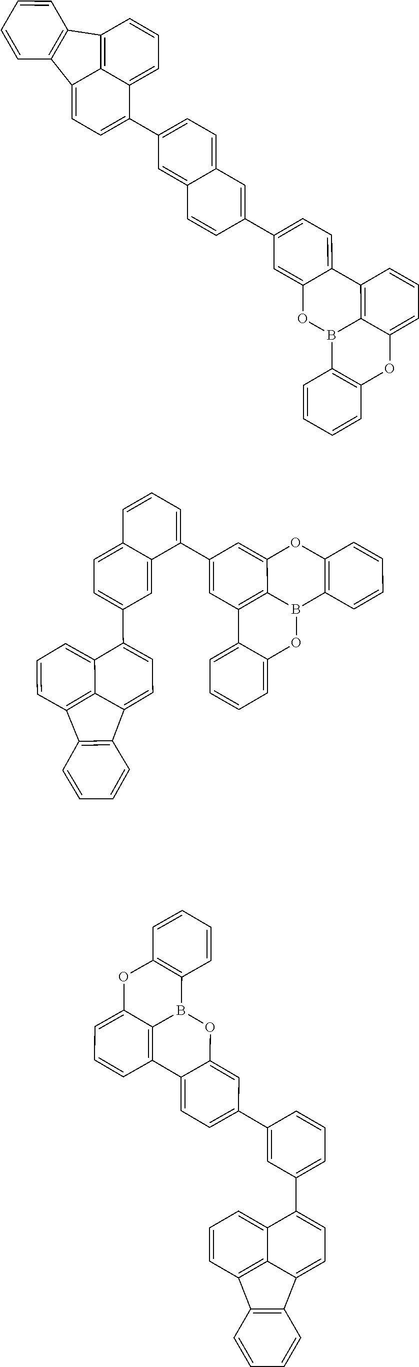 [SMILES: c1ccc2c(c1)Oc1cccc3c1B2Oc1cc(-c2ccc4cc(-c5ccc6c7c(cccc57)-c5ccccc5-6)ccc4c2)ccc1-3 ; c1ccc2c(c1)Oc1cc(-c3cccc4ccc(-c5ccc6c7c(cccc57)-c5ccccc5-6)cc34)cc3c1B2Oc1ccccc1-3 ; c1cc(-c2ccc3c(c2)OB2c4ccccc4Oc4cccc-3c42)cc(-c2ccc3c4c(cccc24)-c2ccccc2-3)c1]

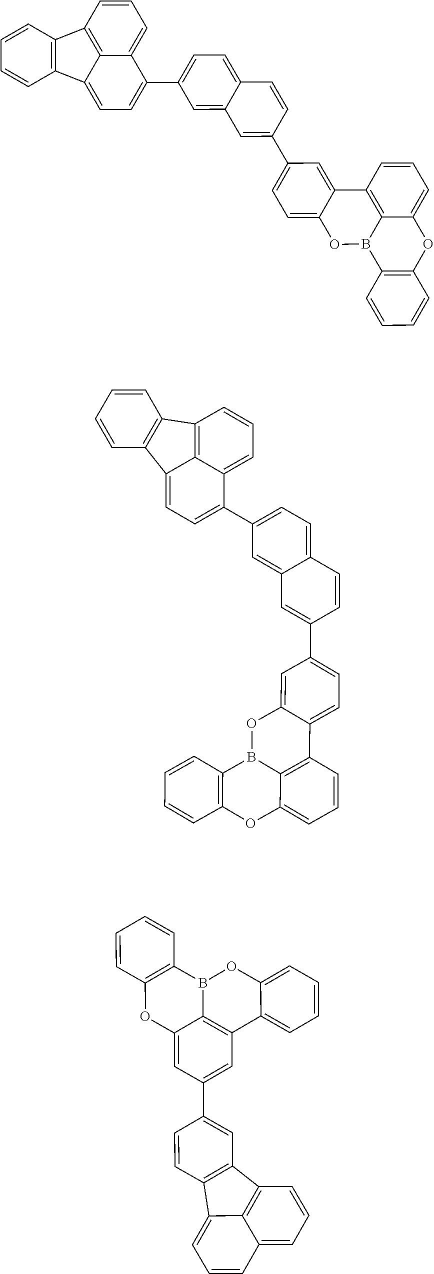 [SMILES: c1ccc2c(c1)Oc1cccc3c1B2Oc1ccc(-c2ccc4ccc(-c5ccc6c7c(cccc57)-c5ccccc5-6)cc4c2)cc1-3 ; c1ccc2c(c1)Oc1cccc3c1B2Oc1cc(-c2ccc4ccc(-c5ccc6c7c(cccc57)-c5ccccc5-6)cc4c2)ccc1-3 ; c1ccc2c(c1)Oc1cc(-c3ccc4c(c3)-c3cccc5cccc-4c35)cc3c1B2Oc1ccccc1-3]

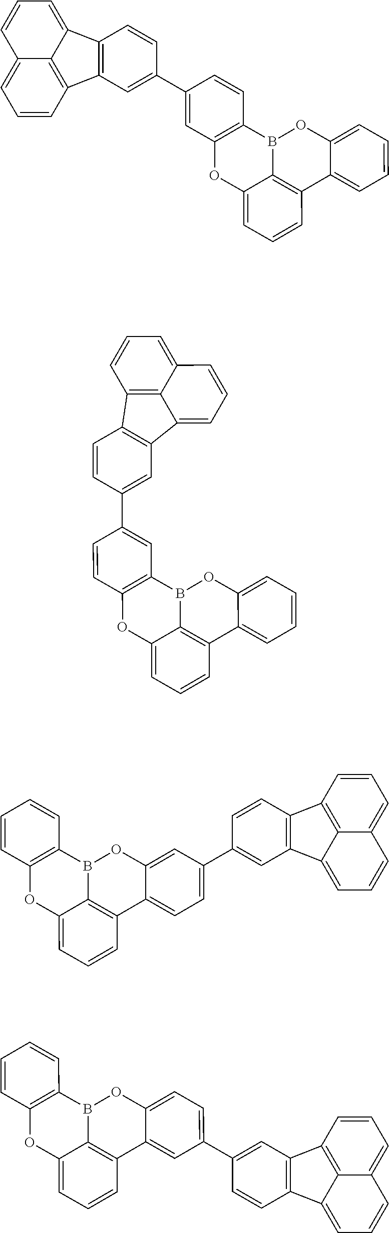 [SMILES: c1ccc2c(c1)OB1c3ccc(-c4ccc5c(c4)-c4cccc6cccc-5c46)cc3Oc3cccc-2c31 ; c1ccc2c(c1)OB1c3cc(-c4ccc5c(c4)-c4cccc6cccc-5c46)ccc3Oc3cccc-2c31 ; c1ccc2c(c1)Oc1cccc3c1B2Oc1cc(-c2ccc4c(c2)-c2cccc5cccc-4c25)ccc1-3 ; c1ccc2c(c1)Oc1cccc3c1B2Oc1ccc(-c2ccc4c(c2)-c2cccc5cccc-4c25)cc1-3]

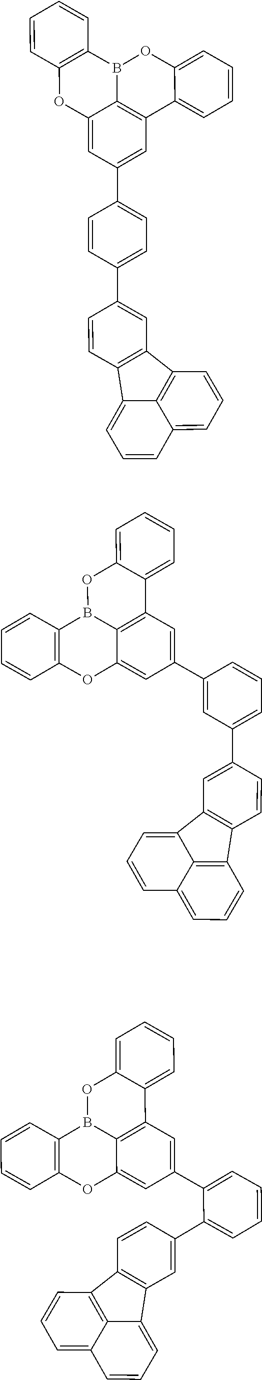 [SMILES: c1ccc2c(c1)Oc1cc(-c3ccc(-c4ccc5c(c4)-c4cccc6cccc-5c46)cc3)cc3c1B2Oc1ccccc1-3 ; c1cc(-c2ccc3c(c2)-c2cccc4cccc-3c24)cc(-c2cc3c4c(c2)-c2ccccc2OB4c2ccccc2O3)c1 ; c1ccc2c(c1)Oc1cc(-c3ccccc3-c3ccc4c(c3)-c3cccc5cccc-4c35)cc3c1B2Oc1ccccc1-3]

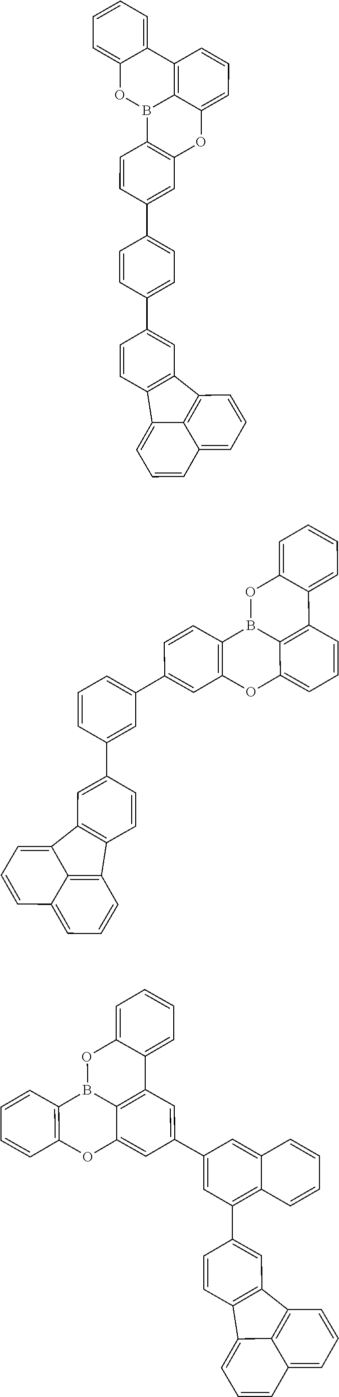 [SMILES: c1ccc2c(c1)OB1c3ccc(-c4ccc(-c5ccc6c(c5)-c5cccc7cccc-6c57)cc4)cc3Oc3cccc-2c31 ; c1cc(-c2ccc3c(c2)Oc2cccc4c2B3Oc2ccccc2-4)cc(-c2ccc3c(c2)-c2cccc4cccc-3c24)c1 ; c1ccc2c(c1)Oc1cc(-c3cc(-c4ccc5c(c4)-c4cccc6cccc-5c46)c4ccccc4c3)cc3c1B2Oc1ccccc1-3]

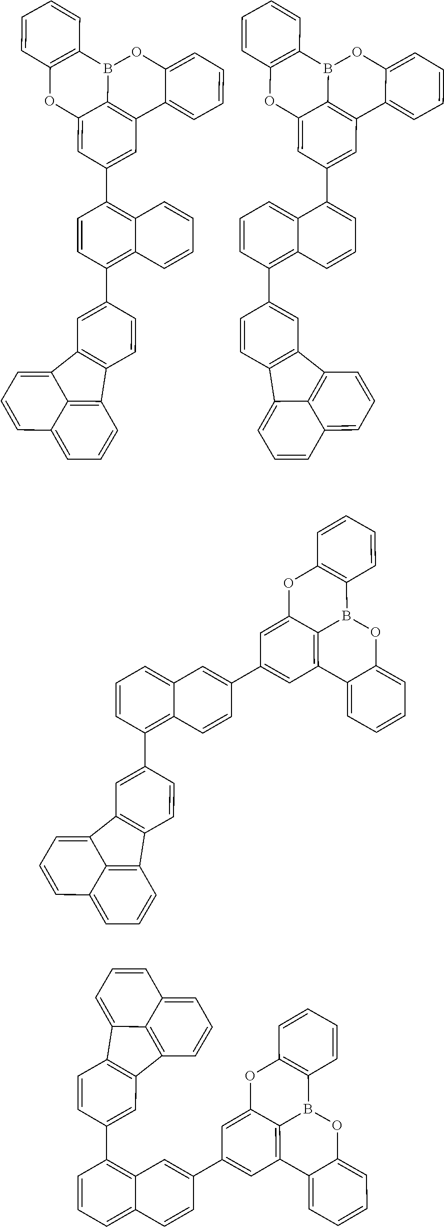

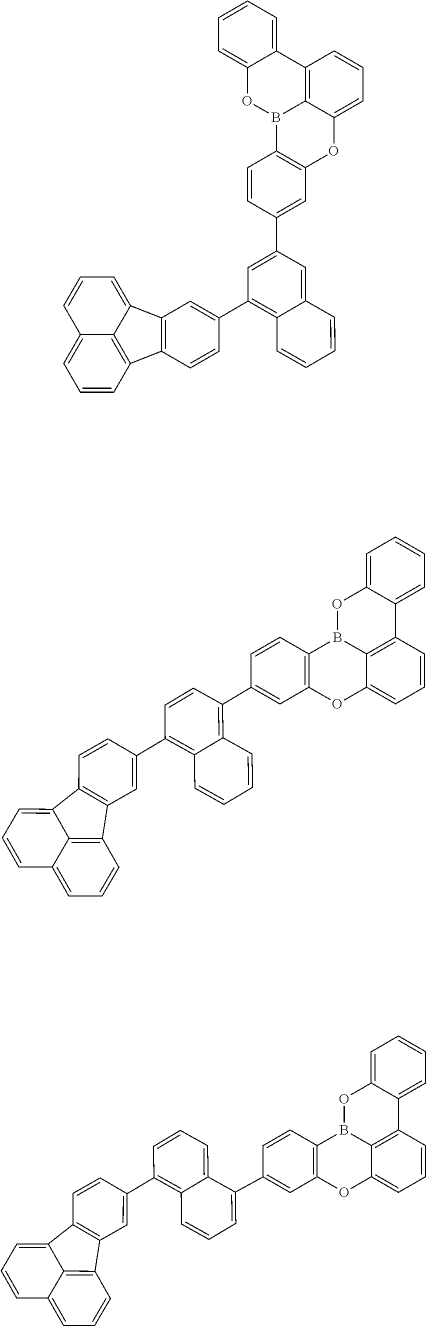 [SMILES: c1ccc2c(c1)OB1c3ccc(-c4cc(-c5ccc6c(c5)-c5cccc7cccc-6c57)c5ccccc5c4)cc3Oc3cccc-2c31 ; c1ccc2c(c1)OB1c3ccc(-c4ccc(-c5ccc6c(c5)-c5cccc7cccc-6c57)c5ccccc45)cc3Oc3cccc-2c31 ; c1ccc2c(c1)OB1c3ccc(-c4cccc5c(-c6ccc7c(c6)-c6cccc8cccc-7c68)cccc45)cc3Oc3cccc-2c31]

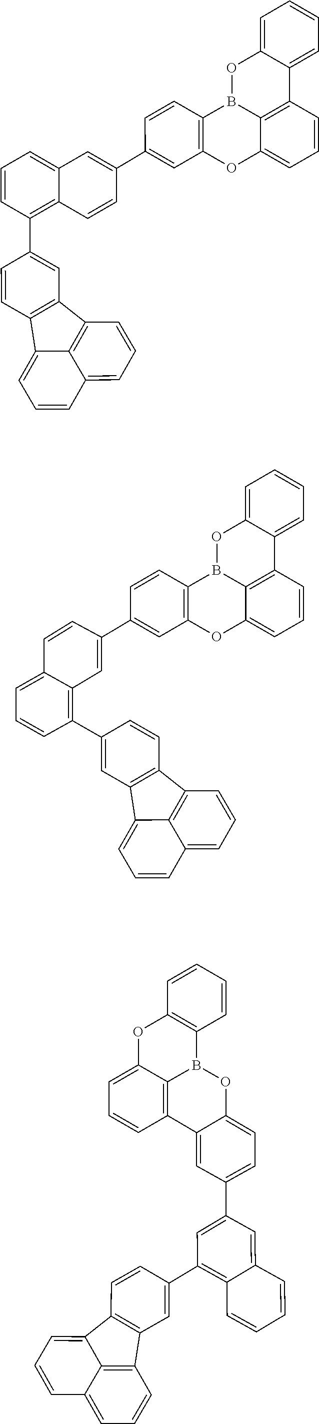 [SMILES: c1ccc2c(c1)OB1c3ccc(-c4ccc5c(-c6ccc7c(c6)-c6cccc8cccc-7c68)cccc5c4)cc3Oc3cccc-2c31 ; c1ccc2c(c1)OB1c3ccc(-c4ccc5cccc(-c6ccc7c(c6)-c6cccc8cccc-7c68)c5c4)cc3Oc3cccc-2c31 ; c1ccc2c(c1)Oc1cccc3c1B2Oc1ccc(-c2cc(-c4ccc5c(c4)-c4cccc6cccc-5c46)c4ccccc4c2)cc1-3]

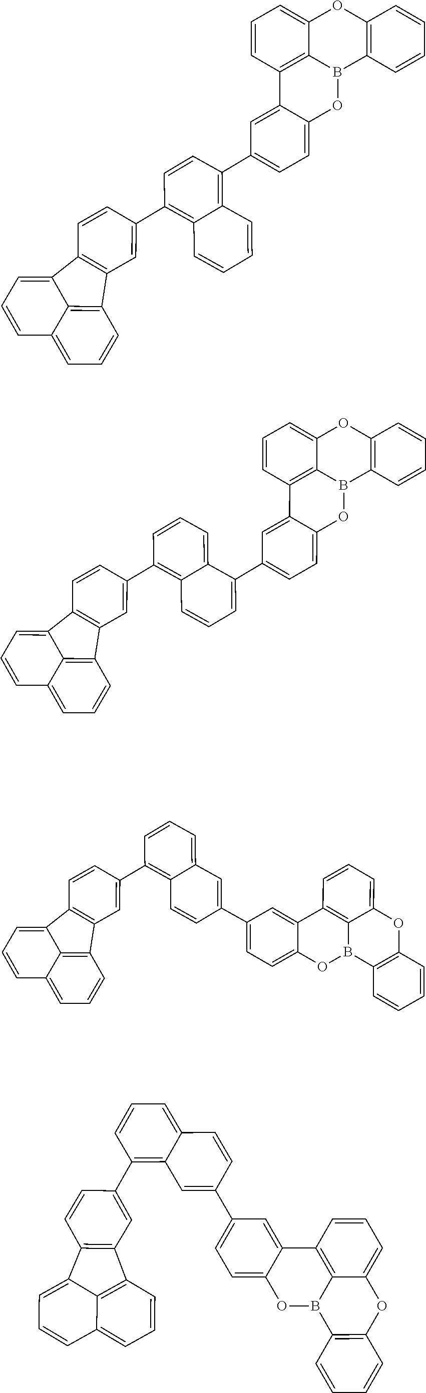 [SMILES: c1ccc2c(c1)Oc1cccc3c1B2Oc1ccc(-c2ccc(-c4ccc5c(c4)-c4cccc6cccc-5c46)c4ccccc24)cc1-3 ; c1ccc2c(c1)Oc1cccc3c1B2Oc1ccc(-c2cccc4c(-c5ccc6c(c5)-c5cccc7cccc-6c57)cccc24)cc1-3 ; c1ccc2c(c1)Oc1cccc3c1B2Oc1ccc(-c2ccc4c(-c5ccc6c(c5)-c5cccc7cccc-6c57)cccc4c2)cc1-3 ; c1ccc2c(c1)Oc1cccc3c1B2Oc1ccc(-c2ccc4cccc(-c5ccc6c(c5)-c5cccc7cccc-6c57)c4c2)cc1-3]

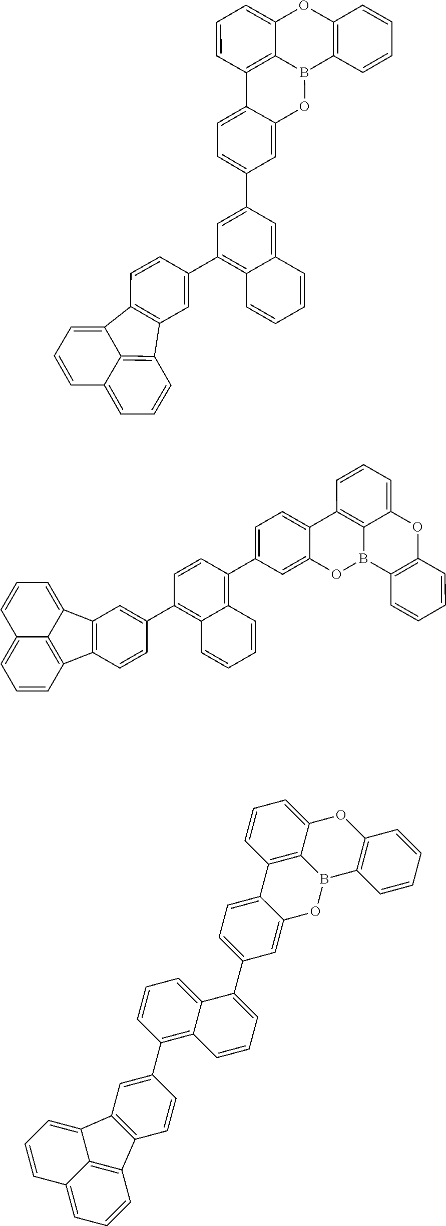 [SMILES: c1ccc2c(c1)Oc1cccc3c1B2Oc1cc(-c2cc(-c4ccc5c(c4)-c4cccc6cccc-5c46)c4ccccc4c2)ccc1-3 ; c1ccc2c(c1)Oc1cccc3c1B2Oc1cc(-c2ccc(-c4ccc5c(c4)-c4cccc6cccc-5c46)c4ccccc24)ccc1-3 ; c1ccc2c(c1)Oc1cccc3c1B2Oc1cc(-c2cccc4c(-c5ccc6c(c5)-c5cccc7cccc-6c57)cccc24)ccc1-3]

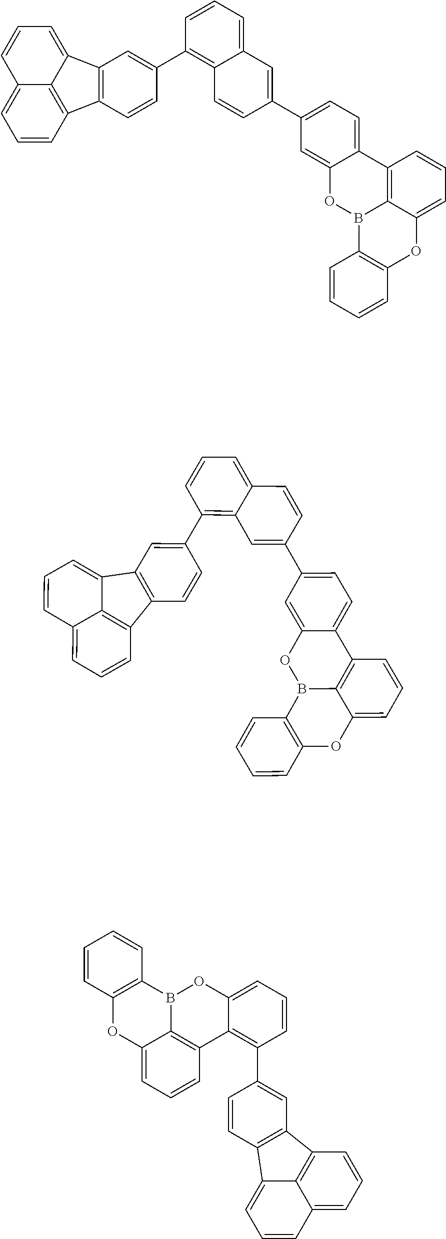

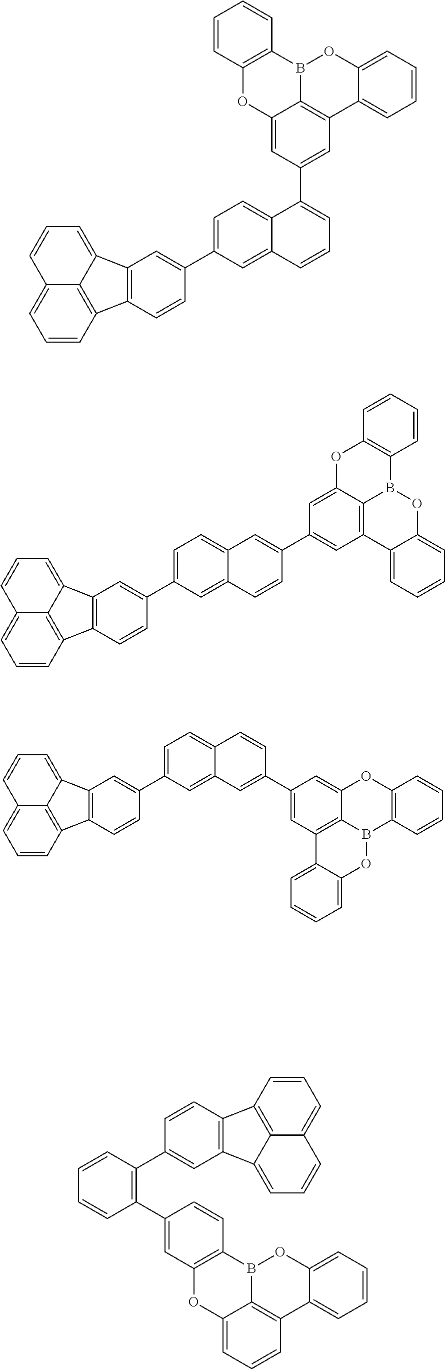 [SMILES: c1ccc2c(c1)Oc1cc(-c3cccc4cc(-c5ccc6c(c5)-c5cccc7cccc-6c57)ccc34)cc3c1B2Oc1ccccc1-3 ; c1ccc2c(c1)Oc1cc(-c3ccc4cc(-c5ccc6c(c5)-c5cccc7cccc-6c57)ccc4c3)cc3c1B2Oc1ccccc1-3 ; c1ccc2c(c1)Oc1cc(-c3ccc4ccc(-c5ccc6c(c5)-c5cccc7cccc-6c57)cc4c3)cc3c1B2Oc1ccccc1-3 ; c1ccc2c(c1)OB1c3ccc(-c4ccccc4-c4ccc5c(c4)-c4cccc6cccc-5c46)cc3Oc3cccc-2c31]

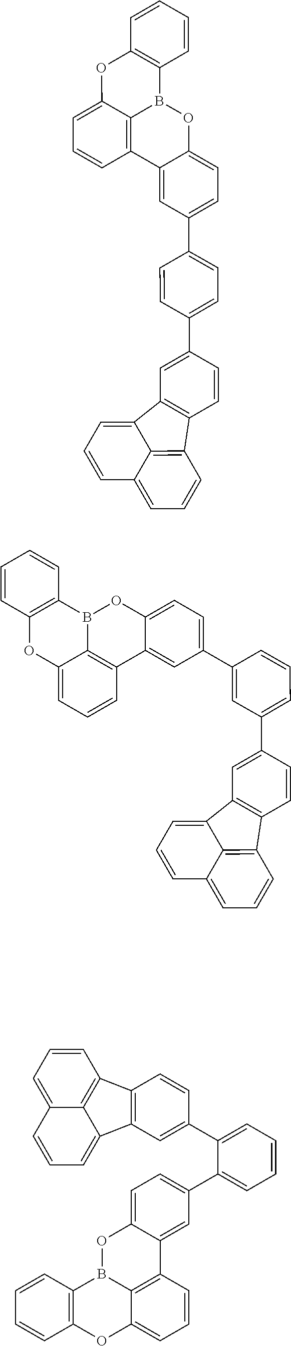

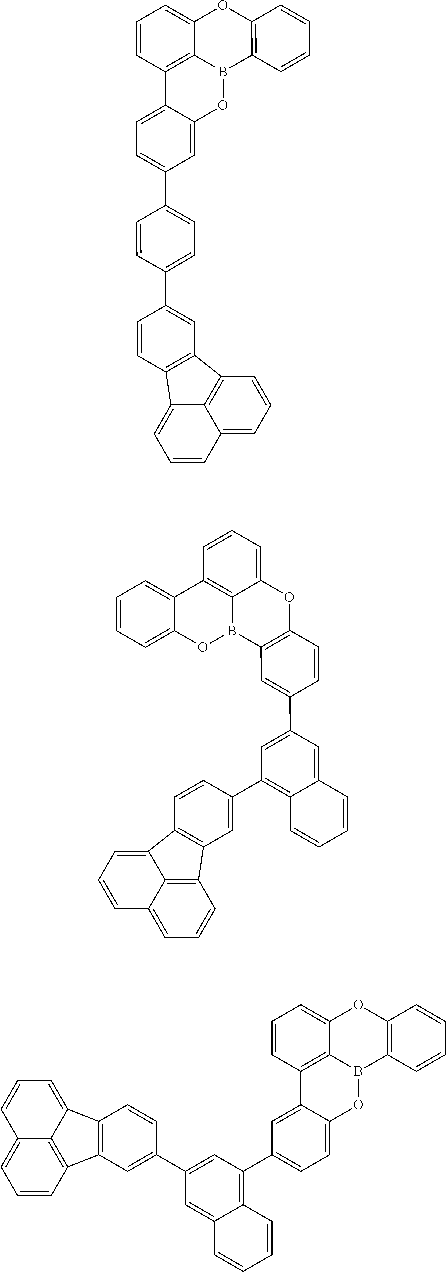

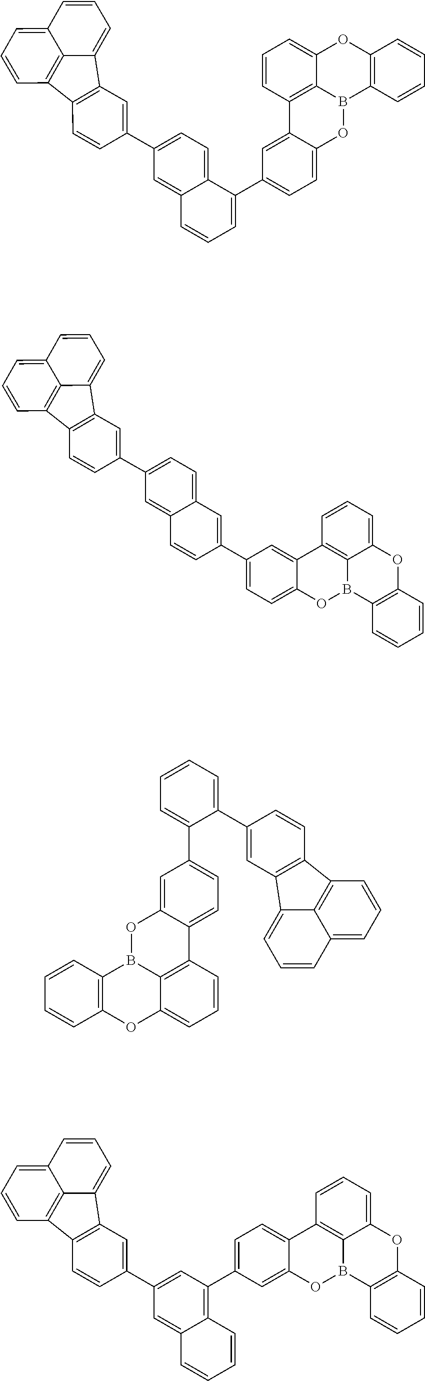

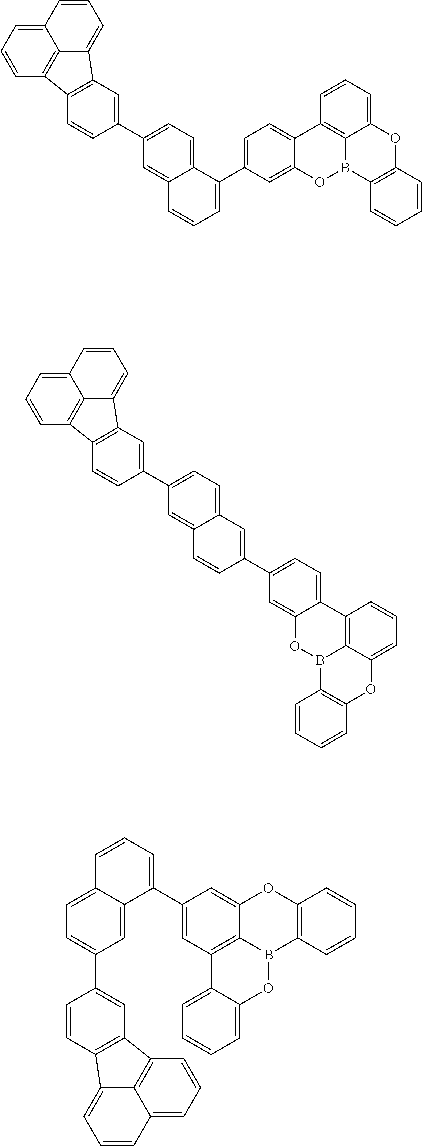

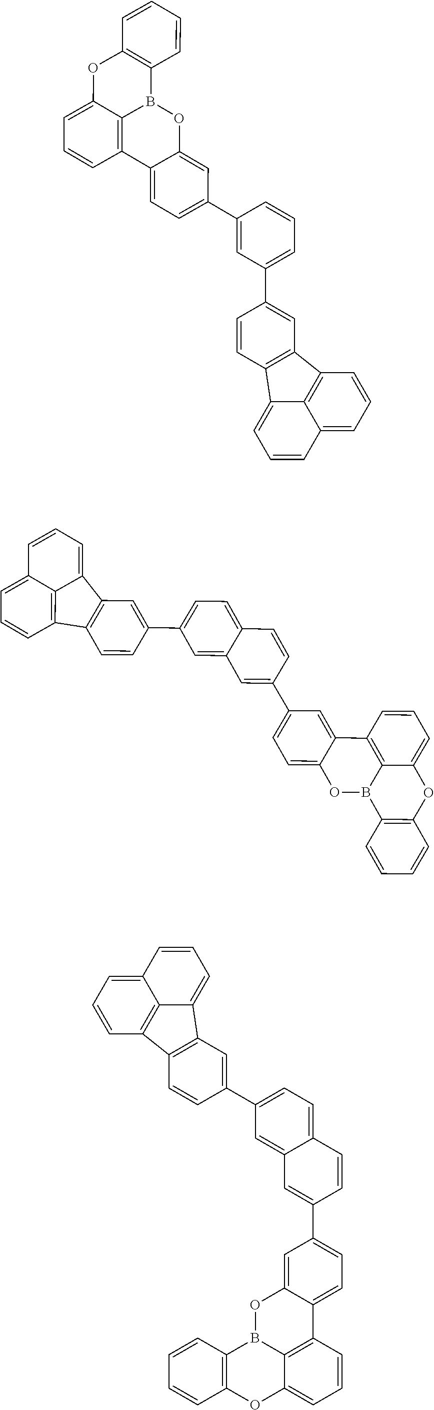

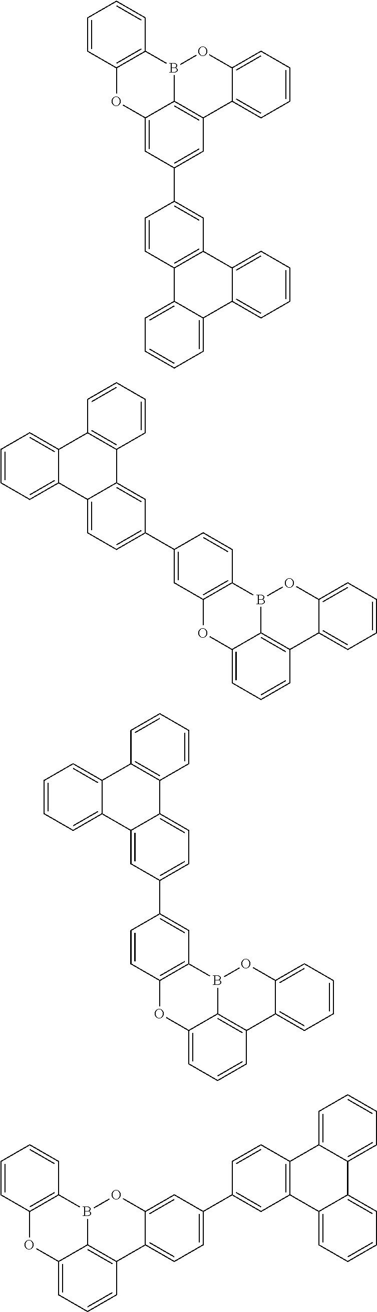

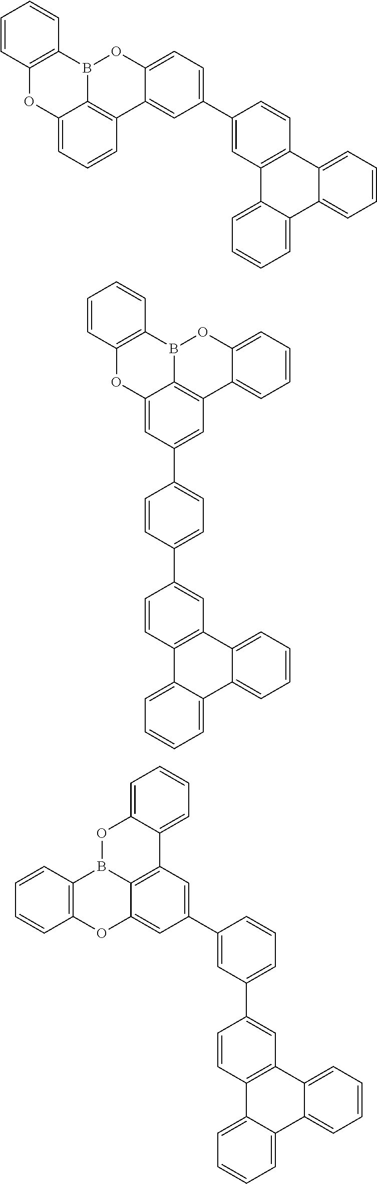

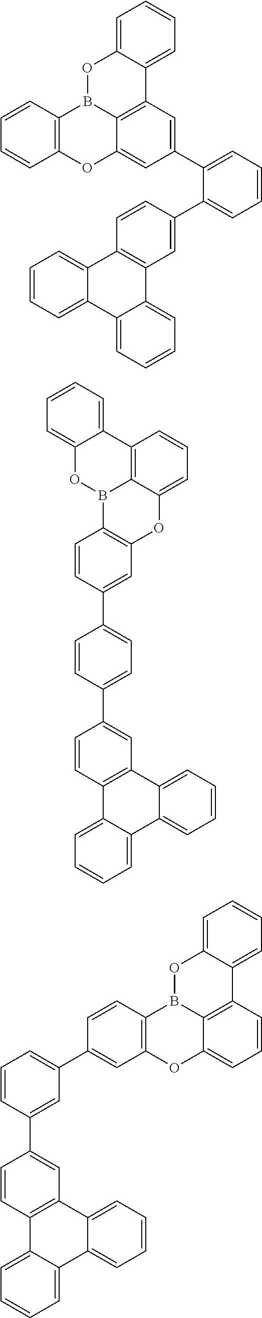 [SMILES: c1ccc2c(c1)Oc1cc(-c3ccccc3-c3ccc4c5ccccc5c5ccccc5c4c3)cc3c1B2Oc1ccccc1-3 ; c1ccc2c(c1)OB1c3ccc(-c4ccc(-c5ccc6c7ccccc7c7ccccc7c6c5)cc4)cc3Oc3cccc-2c31 ; c1cc(-c2ccc3c(c2)Oc2cccc4c2B3Oc2ccccc2-4)cc(-c2ccc3c4ccccc4c4ccccc4c3c2)c1]

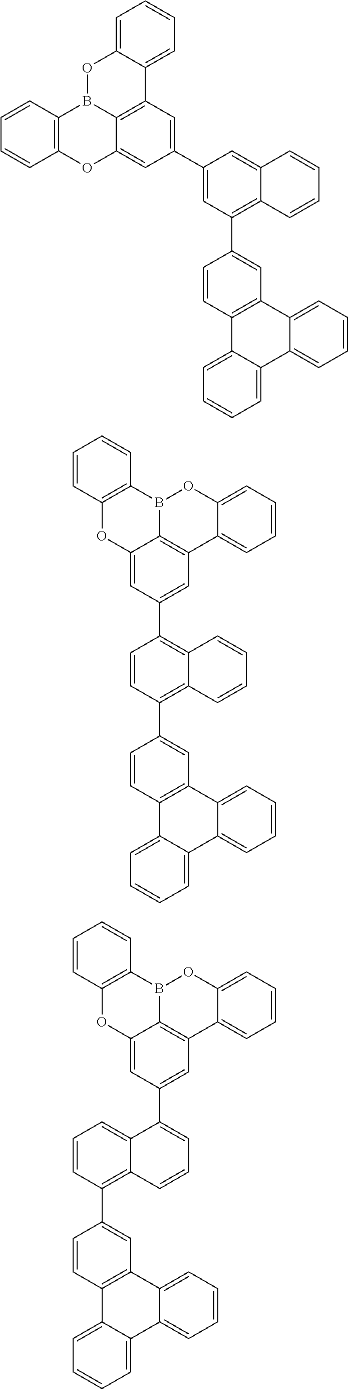

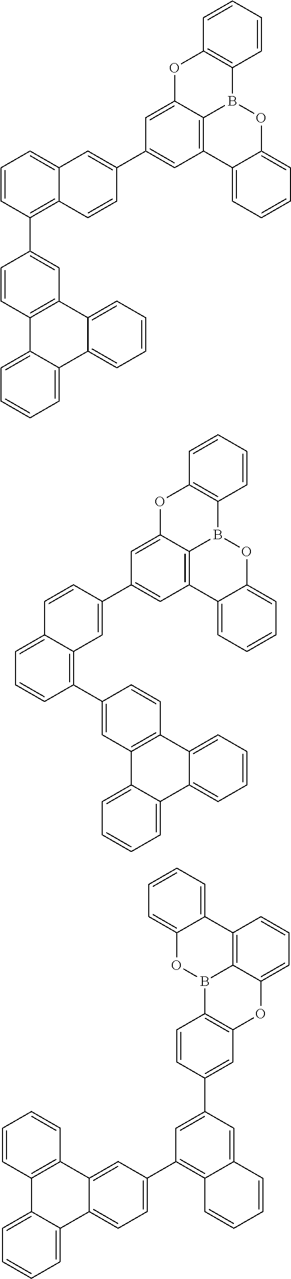

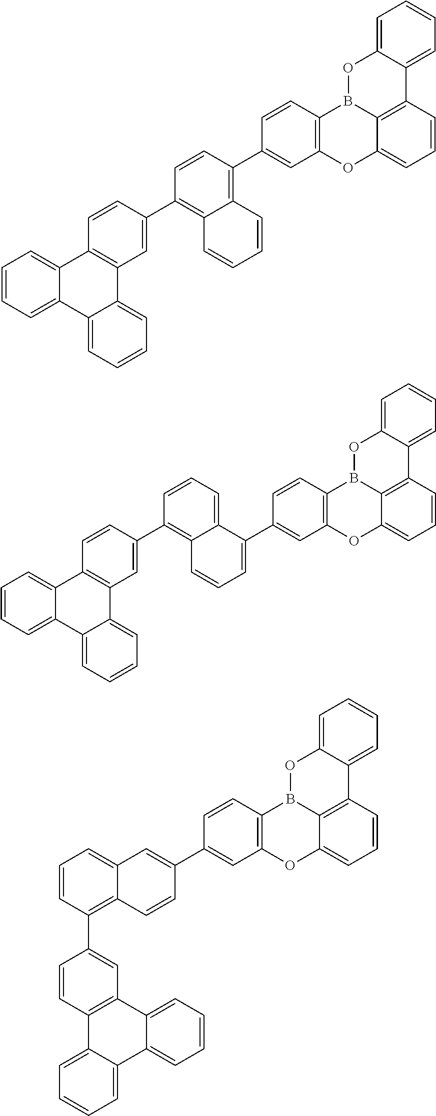 [SMILES: c1ccc2c(c1)OB1c3ccc(-c4ccc(-c5ccc6c7ccccc7c7ccccc7c6c5)c5ccccc45)cc3Oc3cccc-2c31 ; c1ccc2c(c1)OB1c3ccc(-c4cccc5c(-c6ccc7c8ccccc8c8ccccc8c7c6)cccc45)cc3Oc3cccc-2c31 ; c1ccc2c(c1)OB1c3ccc(-c4ccc5c(-c6ccc7c8ccccc8c8ccccc8c7c6)cccc5c4)cc3Oc3cccc-2c31]

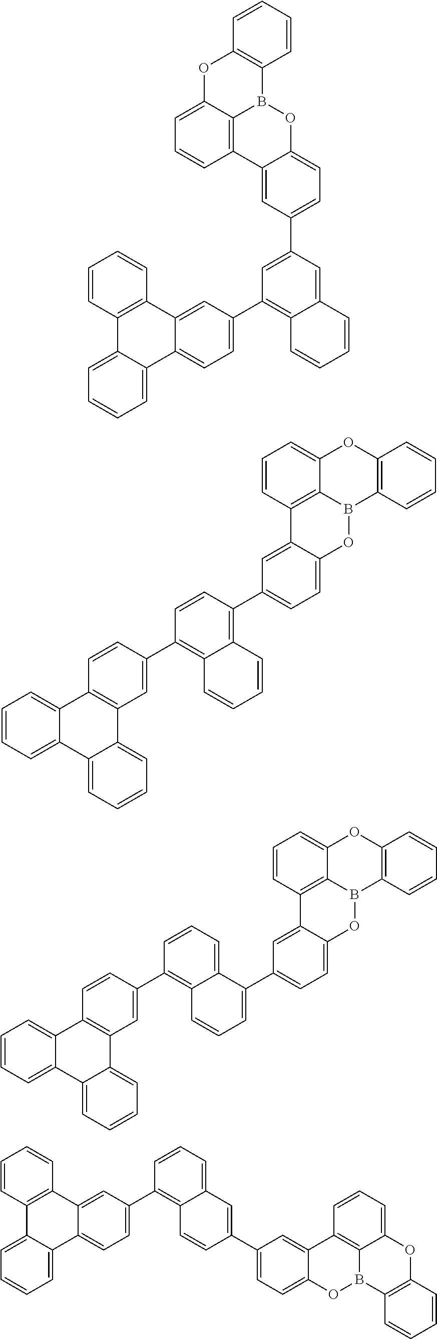 [SMILES: c1ccc2c(c1)Oc1cccc3c1B2Oc1ccc(-c2cc(-c4ccc5c6ccccc6c6ccccc6c5c4)c4ccccc4c2)cc1-3 ; c1ccc2c(c1)Oc1cccc3c1B2Oc1ccc(-c2ccc(-c4ccc5c6ccccc6c6ccccc6c5c4)c4ccccc24)cc1-3 ; c1ccc2c(c1)Oc1cccc3c1B2Oc1ccc(-c2cccc4c(-c5ccc6c7ccccc7c7ccccc7c6c5)cccc24)cc1-3 ; c1ccc2c(c1)Oc1cccc3c1B2Oc1ccc(-c2ccc4c(-c5ccc6c7ccccc7c7ccccc7c6c5)cccc4c2)cc1-3]

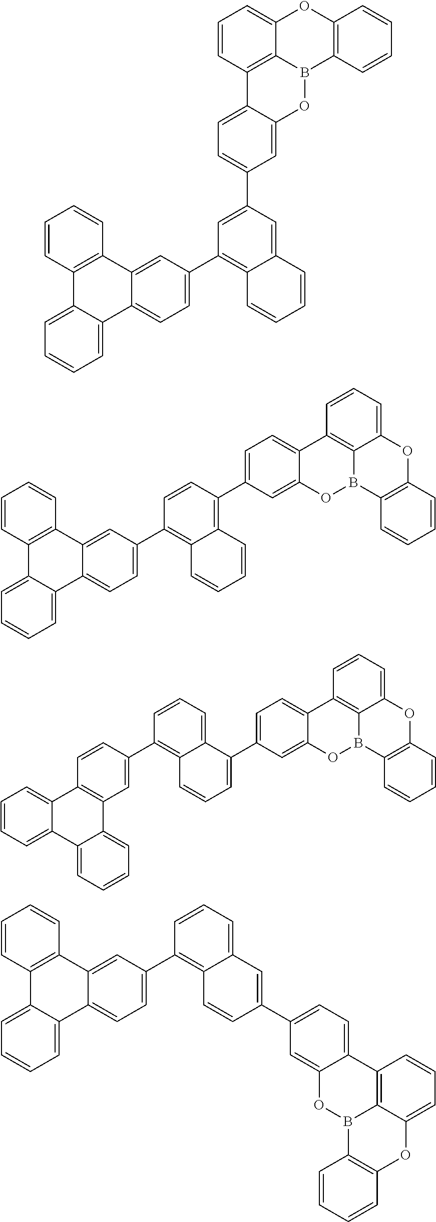 [SMILES: c1ccc2c(c1)Oc1cccc3c1B2Oc1cc(-c2cc(-c4ccc5c6ccccc6c6ccccc6c5c4)c4ccccc4c2)ccc1-3 ; c1ccc2c(c1)Oc1cccc3c1B2Oc1cc(-c2ccc(-c4ccc5c6ccccc6c6ccccc6c5c4)c4ccccc24)ccc1-3 ; c1ccc2c(c1)Oc1cccc3c1B2Oc1cc(-c2cccc4c(-c5ccc6c7ccccc7c7ccccc7c6c5)cccc24)ccc1-3 ; c1ccc2c(c1)Oc1cccc3c1B2Oc1cc(-c2ccc4c(-c5ccc6c7ccccc7c7ccccc7c6c5)cccc4c2)ccc1-3]

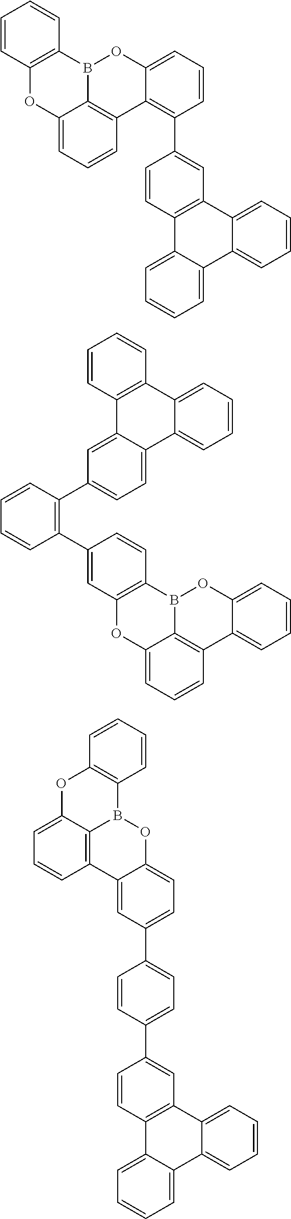

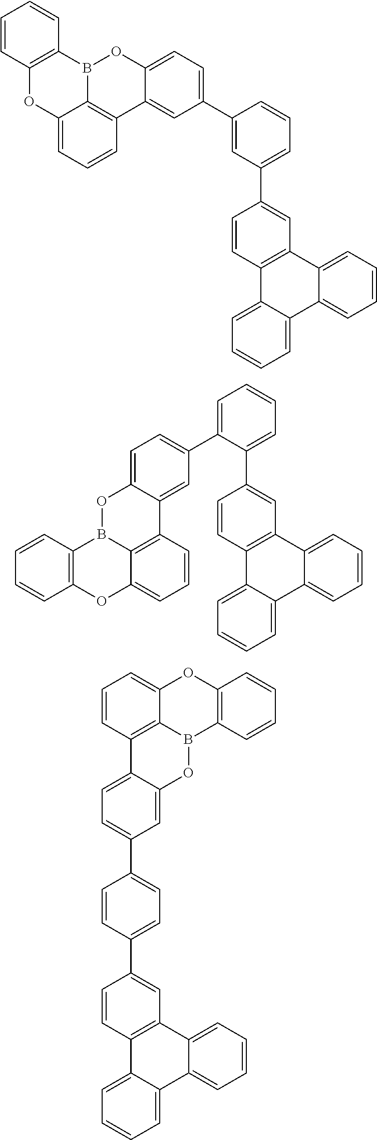

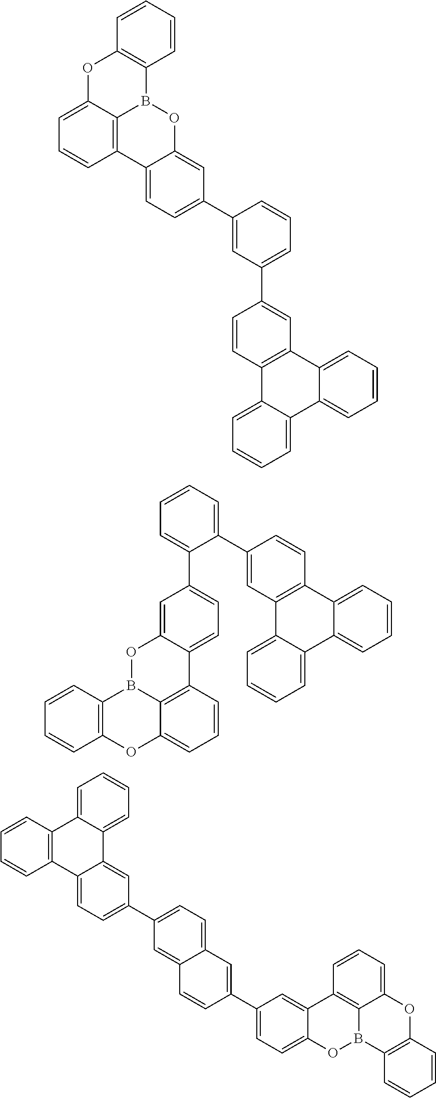

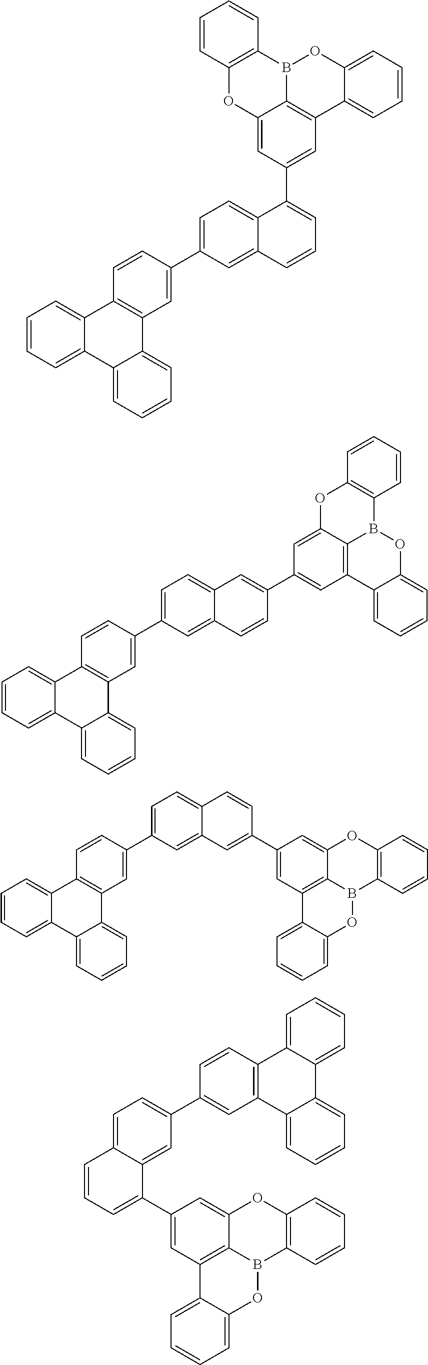

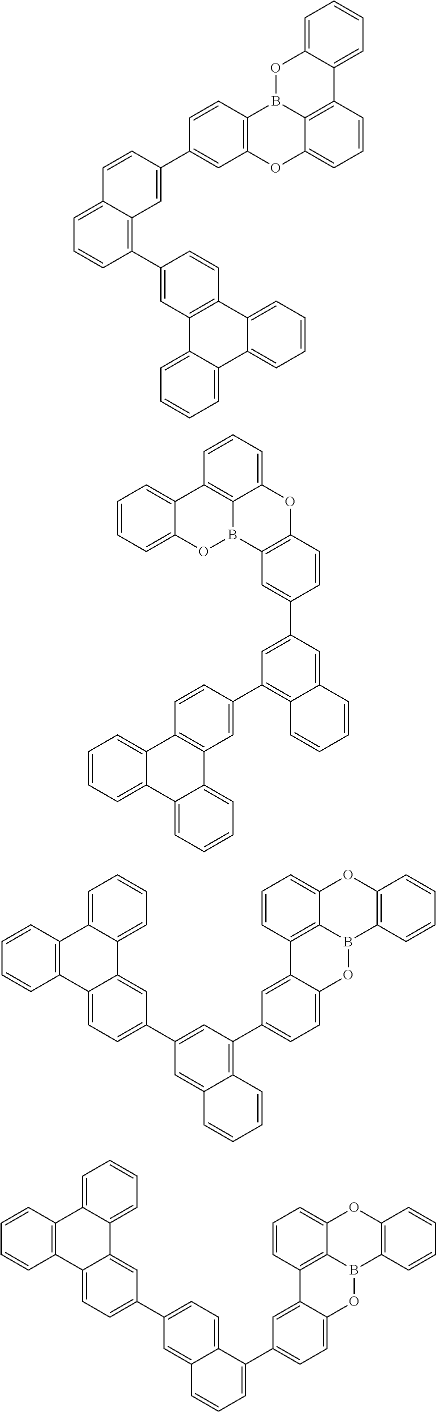

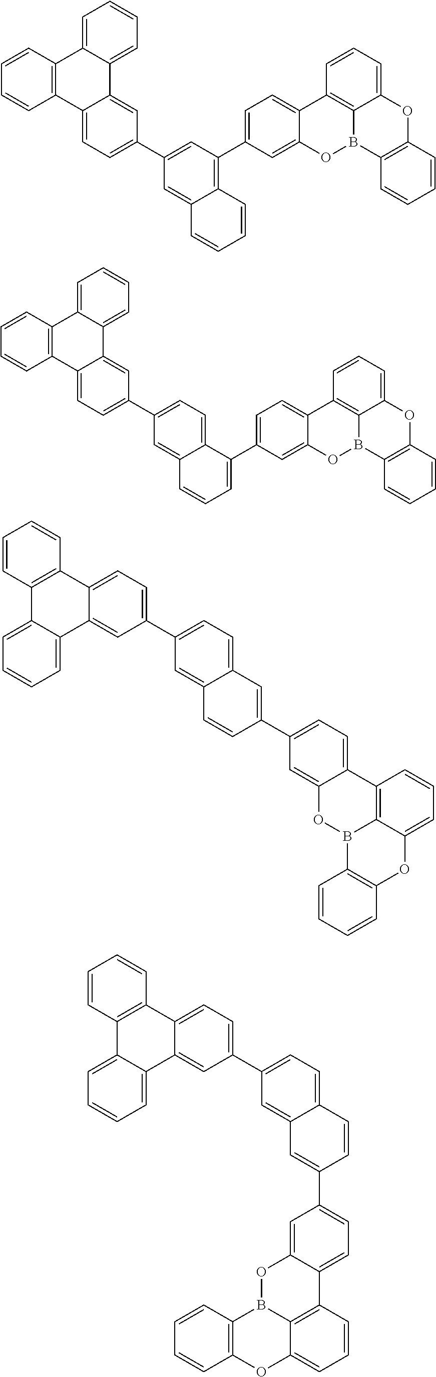 [SMILES: c1ccc2c(c1)Oc1cccc3c1B2Oc1cc(-c2cc(-c4ccc5c6ccccc6c6ccccc6c5c4)cc4ccccc24)ccc1-3 ; c1ccc2c(c1)Oc1cccc3c1B2Oc1cc(-c2cccc4cc(-c5ccc6c7ccccc7c7ccccc7c6c5)ccc24)ccc1-3 ; c1ccc2c(c1)Oc1cccc3c1B2Oc1cc(-c2ccc4cc(-c5ccc6c7ccccc7c7ccccc7c6c5)ccc4c2)ccc1-3 ; c1ccc2c(c1)Oc1cccc3c1B2Oc1cc(-c2ccc4ccc(-c5ccc6c7ccccc7c7ccccc7c6c5)cc4c2)ccc1-3]

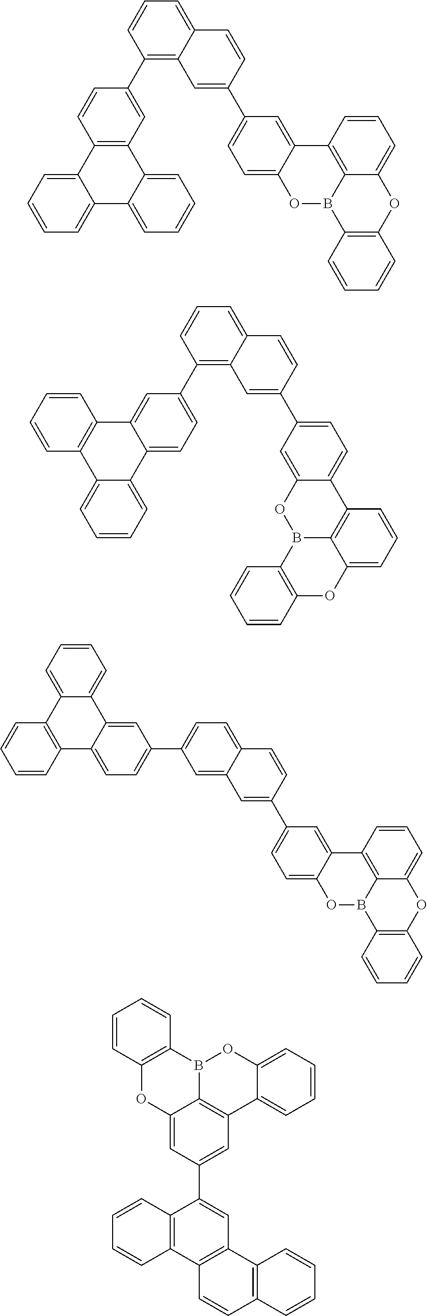 [SMILES: c1ccc2c(c1)Oc1cccc3c1B2Oc1ccc(-c2ccc4cccc(-c5ccc6c7ccccc7c7ccccc7c6c5)c4c2)cc1-3 ; c1ccc2c(c1)Oc1cccc3c1B2Oc1cc(-c2ccc4cccc(-c5ccc6c7ccccc7c7ccccc7c6c5)c4c2)ccc1-3 ; c1ccc2c(c1)Oc1cccc3c1B2Oc1ccc(-c2ccc4ccc(-c5ccc6c7ccccc7c7ccccc7c6c5)cc4c2)cc1-3 ; c1ccc2c(c1)Oc1cc(-c3cc4c5ccccc5ccc4c4ccccc34)cc3c1B2Oc1ccccc1-3]

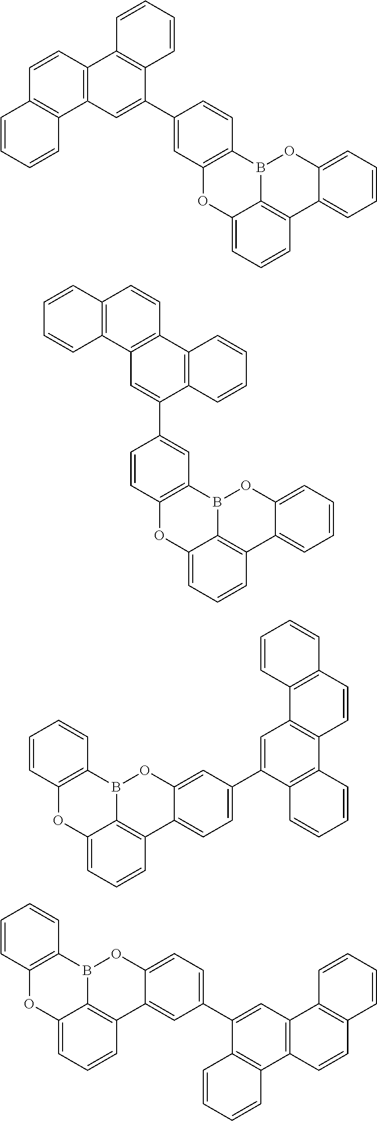

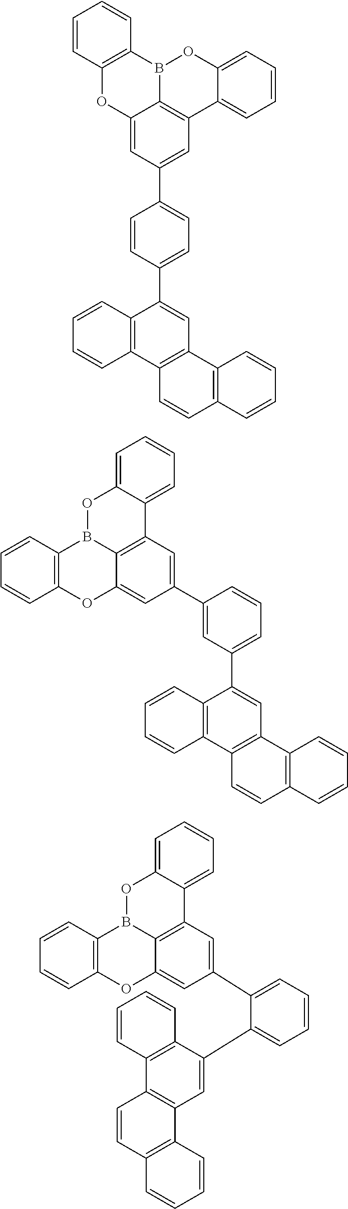

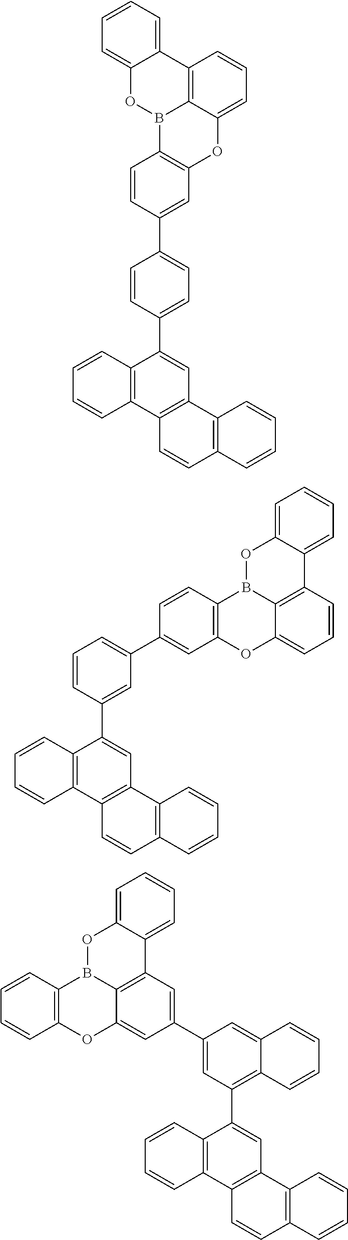

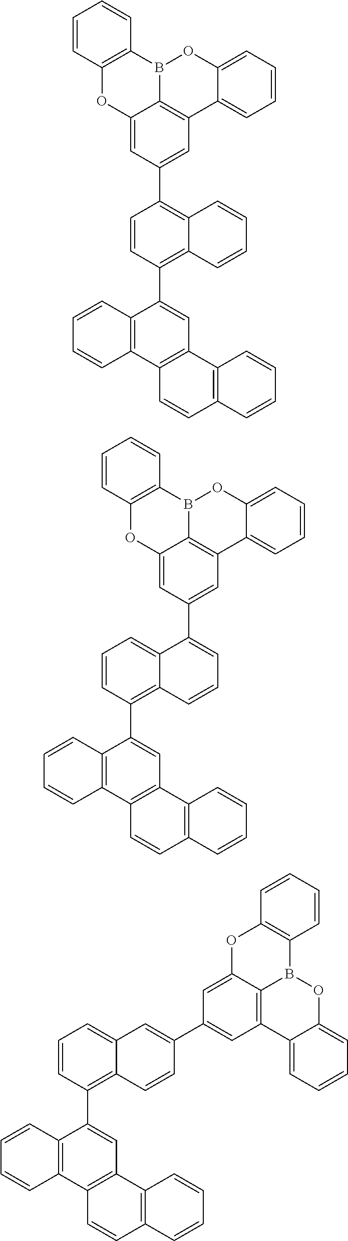

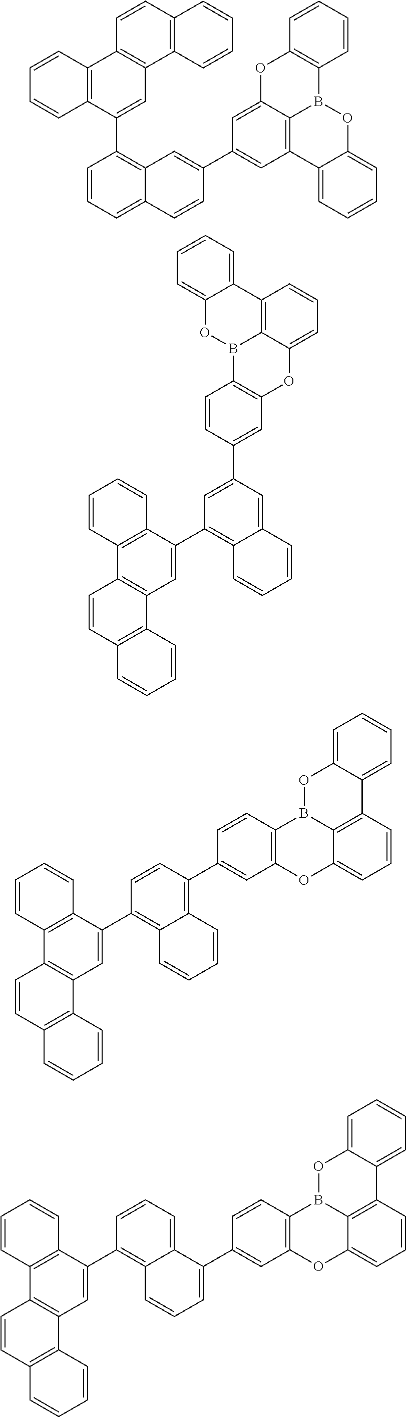

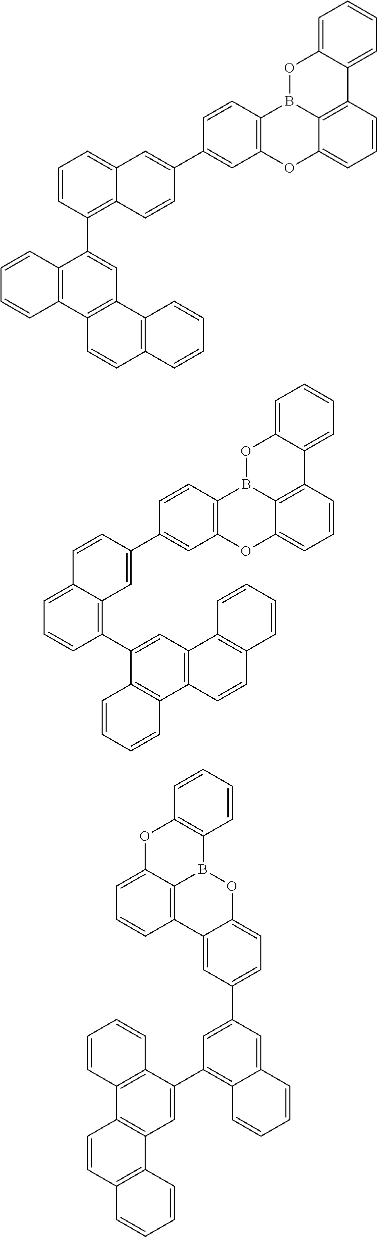 [SMILES: c1ccc2c(c1)OB1c3ccc(-c4ccc5c(-c6cc7c8ccccc8ccc7c7ccccc67)cccc5c4)cc3Oc3cccc-2c31 ; c1ccc2c(c1)OB1c3ccc(-c4ccc5cccc(-c6cc7c8ccccc8ccc7c7ccccc67)c5c4)cc3Oc3cccc-2c31 ; c1ccc2c(c1)Oc1cccc3c1B2Oc1ccc(-c2cc(-c4cc5c6ccccc6ccc5c5ccccc45)c4ccccc4c2)cc1-3]

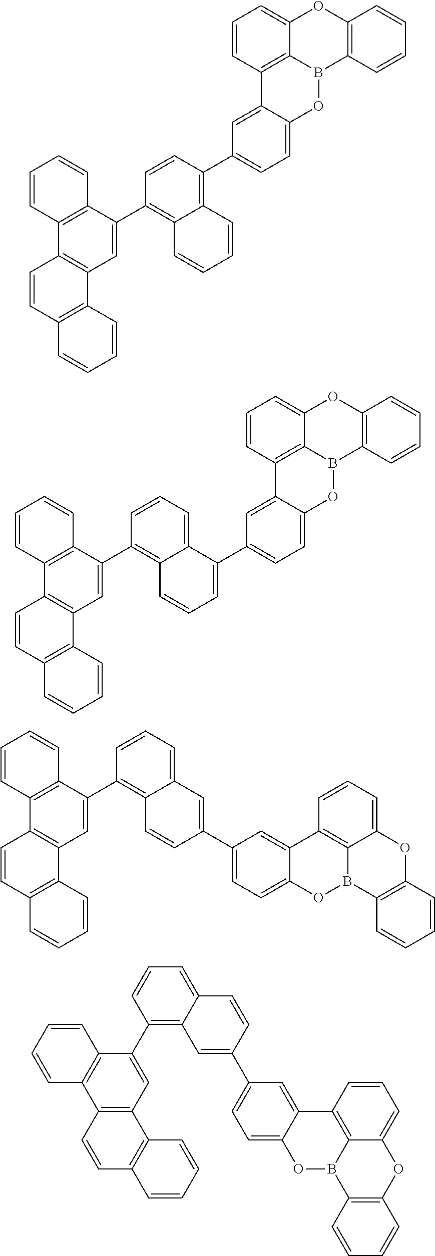

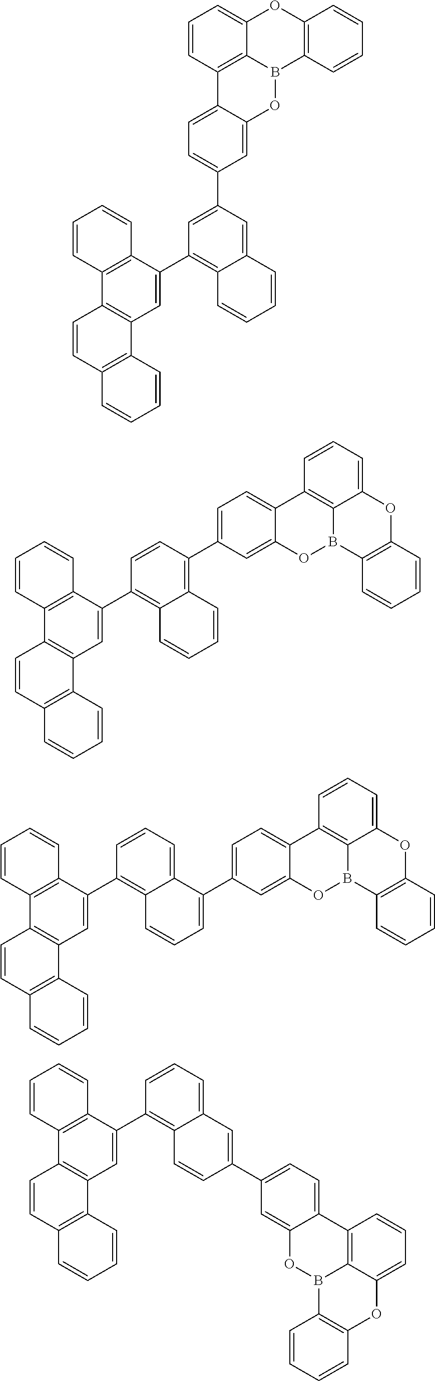

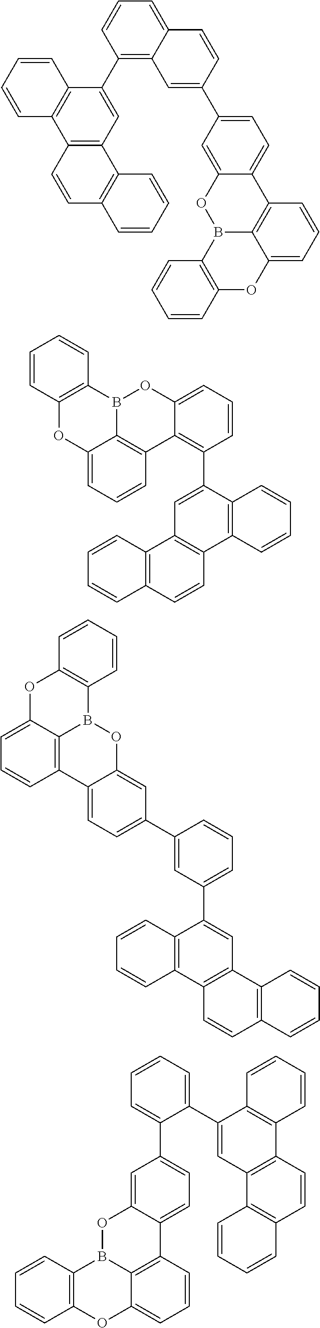

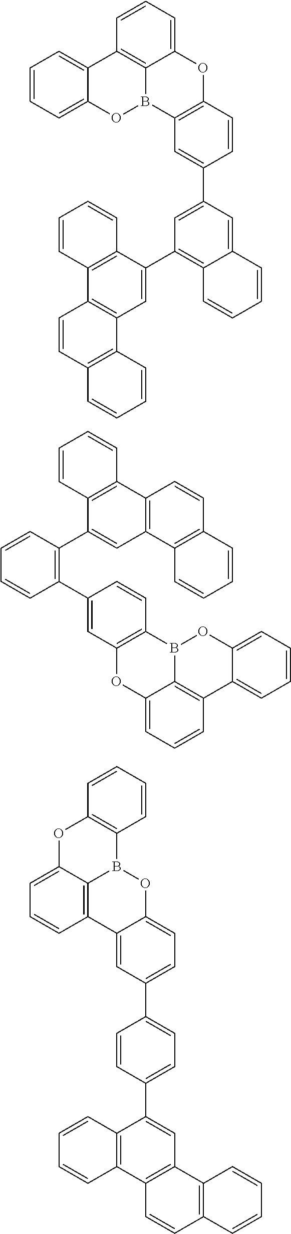

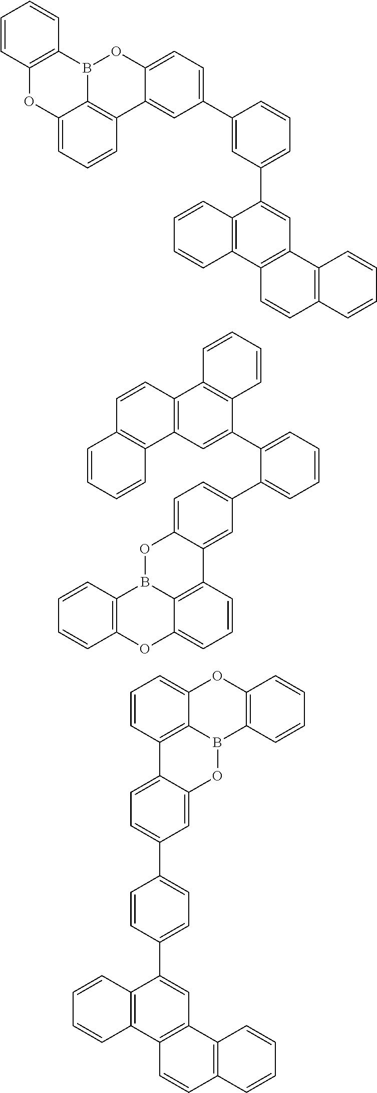

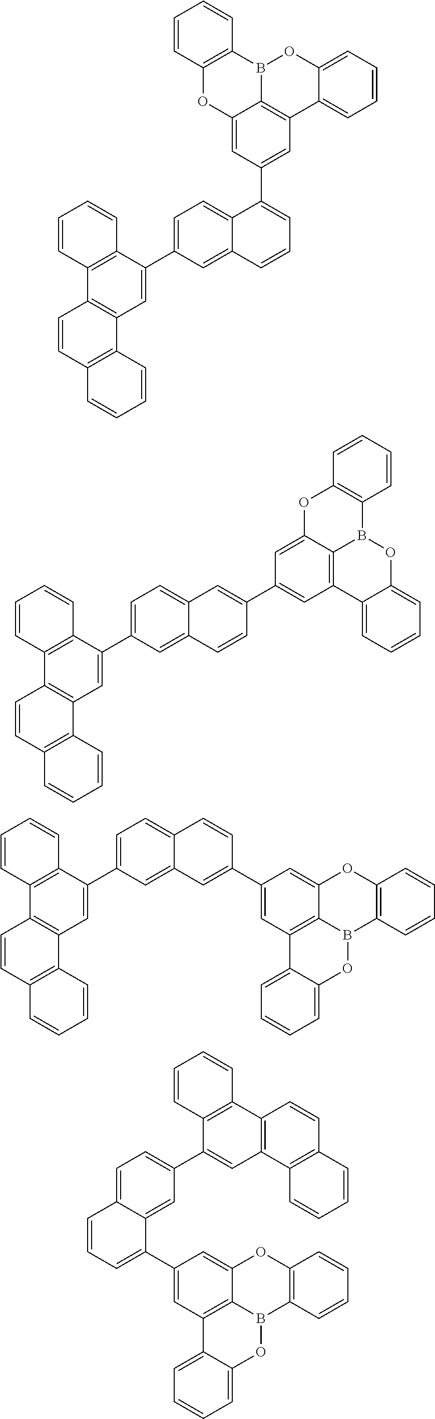

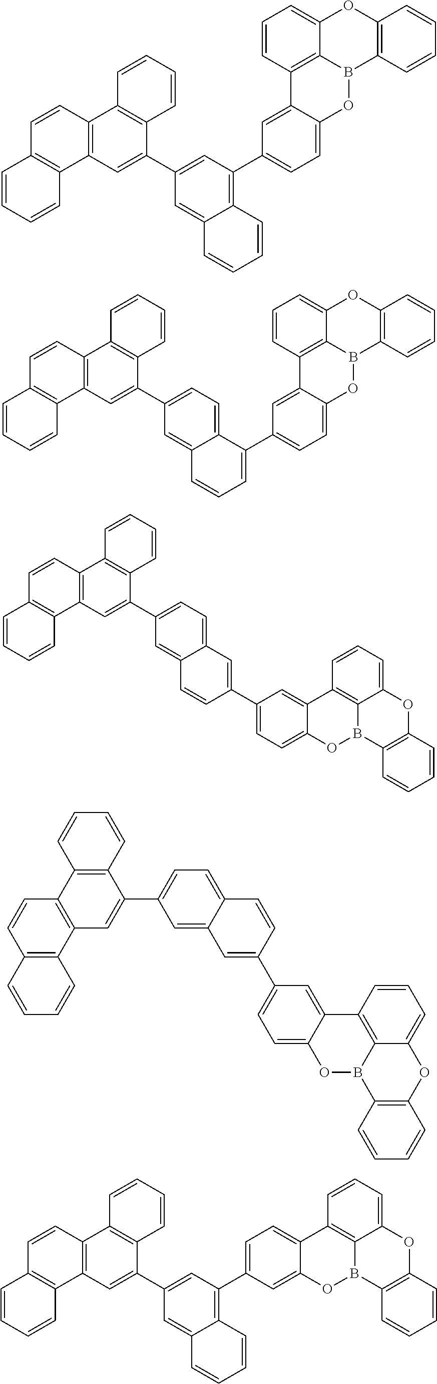

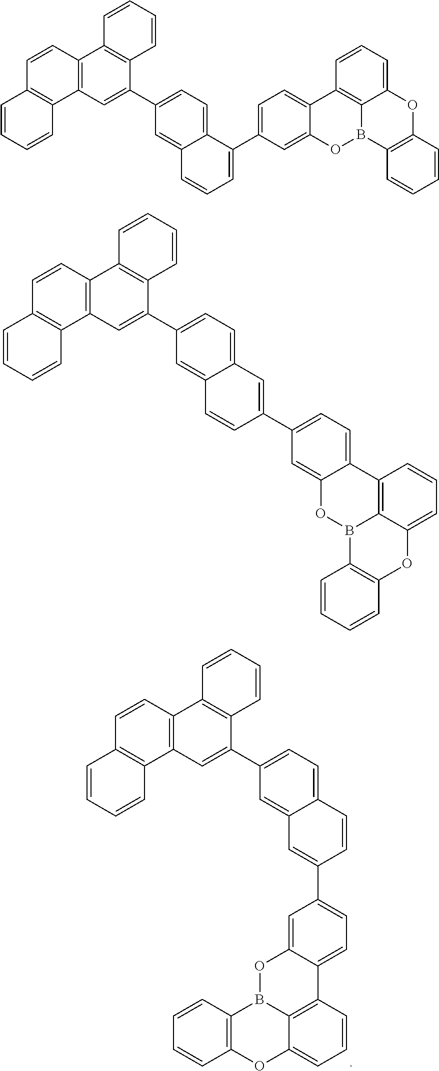 [SMILES: c1ccc2c(c1)Oc1cccc3c1B2Oc1cc(-c2cccc4cc(-c5cc6c7ccccc7ccc6c6ccccc56)ccc24)ccc1-3 ; c1ccc2c(c1)Oc1cccc3c1B2Oc1cc(-c2ccc4cc(-c5cc6c7ccccc7ccc6c6ccccc56)ccc4c2)ccc1-3 ; c1ccc2c(c1)Oc1cccc3c1B2Oc1cc(-c2ccc4ccc(-c5cc6c7ccccc7ccc6c6ccccc56)cc4c2)ccc1-3]

9. The organic light emitting device of claim 1, wherein the compound represented by Chemical Formula 2 is any one of the following structures:

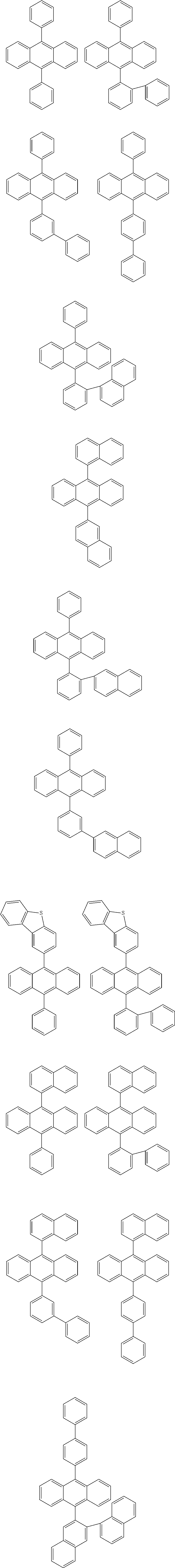

[chemical structure]

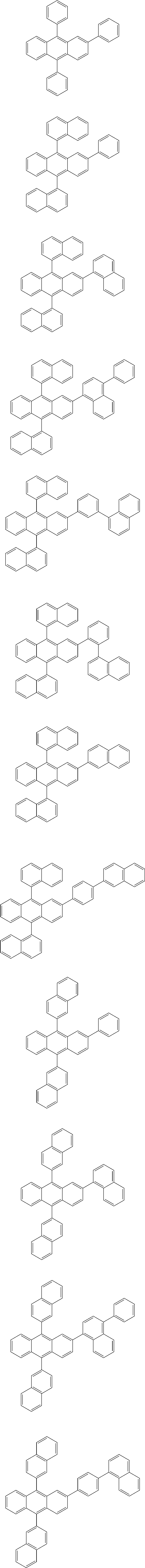

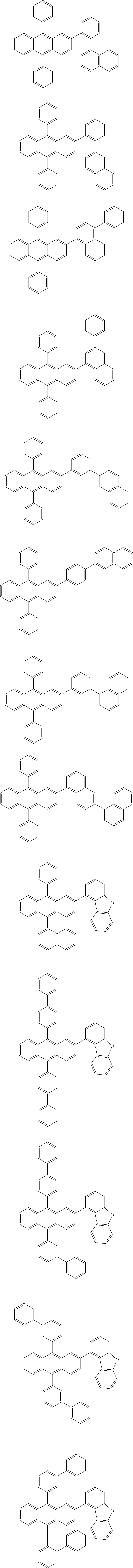

[chemical structure]

[chemical structure]

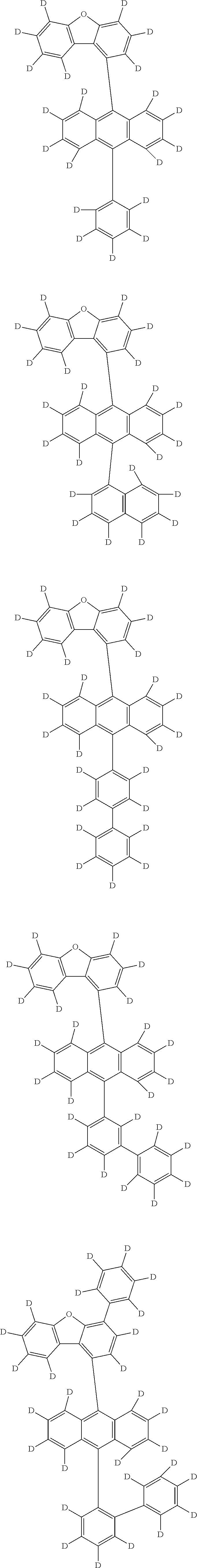

[chemical structure]

[chemical structure]

[chemical structure]

[chemical structure]

10. The organic light emitting device of claim 1, wherein a weight ratio of the compound represented by Chemical Formula 1 and the compound represented by Chemical Formula 2 is 1:99 to 50:50.

11. The organic light emitting device of claim 1, wherein the light emitting layer comprises the compound of Chemical Formula 1 and the compound of Chemical Formula 2 in a single layer.

12. The organic light emitting device of claim 1, wherein the light emitting layer comprises a first light emitting layer comprising a compound represented by Chemical Formula 1 and a second light emitting layer comprising a compound represented by Chemical Formula 2.

13. The organic light emitting device of claim 1, wherein the light emitting layer further comprises a dopant.

14. The organic light emitting device of claim 1, wherein an organic material layer having one or more layers is further provided between the anode and the cathode, and the organic material layer comprises one or more layers of a hole transport layer, a hole injection layer, a hole transport and injection layer, an electron blocking layer, an electron transport layer, an electron injection layer, an electron transport and injection layer, and a hole blocking layer.
